(19) United States
(12) Patent Application Publication
(10) Pub. No.: US 2023/0028912 A1
(43) Pub. Date: Jan. 26, 2023

(54) Automatic Design Assessment and Smart Analysis

(71) Applicant: Baldur Andrew Steingrimsson, Wilsonville, OR (US)

(72) Inventors: Baldur Steingrimsson, Wilsonville, OR (US); Bao Phan, Wilsonville, OR (US); Kwan Yi, Richmond, KY (US); Eric Smith, El Paso, TX (US); Tathagata Ray, Las Cruces, NM (US)

(73) Assignee: Imagars LLC, Wilsonville, OR (US)

(21) Appl. No.: 17/942,329

(22) Filed: Sep. 12, 2022

Related U.S. Application Data
(63) Continuation-in-part of application No. 14/567,516, filed on Dec. 11, 2014, now Pat. No. 9,923,949.
Application No. 14/567,516 is a continuation-in-part of application No. 15/613,183, filed on Jun. 3, 2017, now Pat. No. 10,853,536.
Application No. 15/613,183 is a continuation-in-part of application No. 16/182,389, filed on Nov. 6, 2018, now Pat. No. 11,501,042.

(51) Int. Cl. G06F 30/27

(52) U.S. Cl. CPC G06F 30/27

(57) ABSTRACT

1. The invention presents a mechanism for assessing student designs against learning outcomes from the Accreditation Board for Engineering and Technology. Changes in formulation of the learning outcomes can be simply accommodated by changing association between the learning outcomes and performance indicators, but keeping assessment rubrics the same.

2. We present a plugin for automatically verifying engineering requirements formulated in the SysML system modeling language. The plugin employs a generic verification method consisting of check points systematically positioned along the function chain.

3. Smart Modeling and Simulation is an automated system for creating simulation models, performing rapid simulations and interactively interpreting the results. It can account for complex multi-physics interactions not traditionally supported by commercial analysis software.

4. We also present a system for efficient non-linear analysis of civil engineering structures, one accounting for complex interactions, and yet offering an intuitive interface based on a minimal set of assumptions.

### CROSS REFERENCE TO RELATED APPLICATIONS

Provisional patent application No. 61/800,985, titled Method and Apparatus for Automatic Recognition and Representation of Image Sketches, filed on Mar. 15, 2013.

Utility patent application Ser. No. 13/865,549, titled Recognition and Representation of Image Sketches, filed on Apr. 18, 2013.

U.S. Pat. No. 9,923,949 B2, titled All-Electronic Ecosystems for Design and Collaboration, granted on Mar. 20, 2018.

U.S. Pat. No. 10,853,536 titled Requirement Verification Engine and Analytics, granted on Dec. 1, 2020.

Utility patent application Ser. No. 16/182,389, titled Decisions with Big Data, filed on Nov. 6, 2018.

Provisional patent application No. 62/818,841, filed on Mar. 15, 2019.

Utility patent application Ser. No. 16/782,829, titled Machine Learning to Accelerate Alloy Design, filed on Feb. 5, 2020.

Utility patent application Ser. No. 17/497,900, titled Machine Learning to Accelerate Design of Energetic Materials, filed on Mar. 3, 2022.

### Acknowledgement of Federal Funding

This utility patent is the result of research conducted under support of National Science Foundation Awards U.S. Pat. Nos. 1,447,395 and 1,632,408.

### BACKGROUND OF THE INVENTION

### 1. Technical Field Description

### 1.1 Improving Productivity of Design Instructors or Engineering Departments

For accreditation of engineering programs by ABET, engineering programs must have documented student learning outcomes that support the program educational objectives (ABET 2019). Automatic assessment of students' work against ABET learning outcomes (1 through 7) helps engineering programs prepare the data needed for ABET reporting and evaluation. Such assessment helps improve the productivity of instructors of design classes as well as of engineering departments, by reducing the time it takes to prepare the data needed for ABET reporting and evaluation.

ABET expects the documented learning outcomes, that are mentioned above, and that support the program educational objectives, to apply to individual students. Assuming that deliverables by a team of design students, e.g., design reports by a capstone design team, can be assessed, it is far from trivial to dissect such deliverables, to accurately identify the contributions of individual students, and to accurately assess the individual students against the ABET learning outcomes.

### 1.2 Automatic Requirement Verification as Plug-In to Established Design Tools

The Ecosystem for Design Assessment and Verification, also referred to as the Ecosystem design software, interfaces with Computer Aided Design (CAD) systems and analysis software (SW), for the purpose of identifying design oversights early, aiding with human decision making, and providing productivity improvements (cost savings) to its users (SteingrimssonKulkarni 2020). Per FIG. 1, there can be significant cost savings associated with automatic requirement verification. According to R. S. M. Harry (Harry 1999),
“If a reliability problem is detected during engineering, the cost of the product goes up by a factor of 10. If the problem is caught in production phase, the cost of the product increases by a factor of 100 or more.”

A generative design method is based on building a genotype of the design within a history based parametric CAD system and then, varying its parameters randomly within pre-defined limits to generate a set of distinctive designs (SivamKrish 2011). The generative design method may be suitable complex multi-criteria design problems where important performance criteria are uncomputable. The resulting designs are then filtered through various constraint envelopes representing geometric viability, manufacturability, cost and other performance related constraints, and thus reducing the vast design space into a smaller viable design space represented by a set of distinctive designs. These resulting designs can then be further developed by the designer (SivamKrish 2011).

1.3. Automatic Requirement Verification in Context with Model-Based Systems Engineering

Over course of the past decade or two, Model-Based Systems Engineering (MBSE) technology has matured as evidenced by the development of Systems Modeling Language (SysML) tools and frameworks that support engineers in development efforts from requirements through hardware and software implementation. MBSE holds significant promise for accelerating, reducing overhead labors, and improving the quality of systems development, especially in the cases of automotive or aerospace system development. Nevertheless, a bottleneck remaining pertains to the coordination and integration of system development across distributed organizations, such as the multiple partners developing lunar gateway and eventually for the exploration of Mars (NasaMbseDistributed 2020).

Requirement verification has been one of the top priorities at NASA Jet Propulsion Laboratory (JPL) over course of the past decade or two. Requirement verification entails an important problem, and a big problem, that NASA has been addressing at various levels. A number of NASA engineers have been trying to use SysML system modeling language to address parts of the problem in recent years (NasaMbseDistributed 2020).

Model-based systems engineering technologies for distributed development comprise both a critical capability and a bottleneck for developments related to NASA's human exploration. As NASA looks to enable sustainable return to the Moon, followed by future exploration of Mars, components such as Lunar Gateway and Commercial Lunar Payload Services (CLPS) will require partnership with a variety of communities. Building on the success of international partnerships associated with the International Space Station (ISS), space agencies from multiple governments are looking to play a role on the Lunar Gateway. Of particular interest has been the inclusion of the rapidly growing commercial space industry, which has looked to play an important role in supporting a sustained presence on the Moon. All of these prospective partners are expected to have their own design capabilities, their own development processes and internal constituencies to support. Integrating and enabling disparate systems, built in different locations by different stakeholders (owners), to all work cohesively together, will require substantial upgrade to NASA's core systems engineering capabilities (NasaMb seDi stributed 2020).

NASA's areas of particular need include (NasaMbseDistributed 2020):
1. Methodologies that support integration among tools and exchange of information between multidisciplinary stakeholders (artifacts) using automated intelligent reasoning (NasaMb seDi stributed 2020).
2. Definition of open interface standards and tools that are capable of enabling inspection of distributed models across engineering domains (NasaMbseDistributed 2020).
3. Tools or systems, that allow models to be shared across development environments, and that provide means for tracing the resulting system model back to contributions made by individual partners (NasaMbseDistributed 2020).
4. Modeling environments, that facilitate user interaction from multiple stakeholders, with varying degree of expertise in MBSE (NasaMbseDistributed 2020).
5. Continuous integration and verification of safety critical system requirements, that may depend on disparate development sources (NasaMbseDistributed 2020).

To such an end, NASA is seeking innovative system engineering modeling methods and tools that address the following (NasaMbseDistributed 2020):
1. Definition, design, development and execution of future science missions, through development and utilization of advanced methods or tools, that empower more comprehensive, broader, and deeper system and subsystem modeling, while enabling these models to be utilized earlier in the lifecycle (NasaMbseDistributed 2020).
2. Enablement of disciplined system analysis for the design of future missions, including modeling of decision support for those missions as well as integrated models of technical and programmatic aspects of future missions (NasaMbseDistributed 2020).

Such innovative system engineering modeling methods and tools should ideally leverage approaches, based on MBSE or system modeling language (SysML), that have been piloted across NASA. Furthermore, such innovative system engineering modeling methods and tools should allow for easier integration of disparate model types and be compatible with current, agile design processes (NasaMbseDistributed 2020).

NASA's specific areas of interest include:
1. Models and tools, that correspond to the conceptual design phase, that allow design teams to easily develop, populate, and visualize very broad, multidimensional trade spaces (NasaMbseDistributed 2020).
2. Methods for characterizing and selecting optimum candidates from those trade spaces, particularly at the level of architectural designs. There is particular interest in models and tools that facilitate comprehensive comparison of architectural variants of systems (NasaMbseDistributed 2020).
3. Capabilities for rapid generation models of function or behavior of complex systems, either at the level of system or subsystem designs. Such models are expected to be capable of eliciting robust estimates of system performance, given appropriate environments and activity timelines. Such models should, further, be tailored (NasaMbseDistributed 2020):
(a) To support emergent usage of autonomy, both in mission operations and flight software, as well as growing emphasis on auto-coding (NasaMbseDistributed 2020).
(b) To operate within highly distributed design environments. Here, models and/or infrastructure needs to be capable of supporting/accommodating designers that may be geographically separated (similar to Open Innovation environments). This encompasses considerations associated with near-real-time (concurrent) collaboration processes associated model integration and configuration management practices (NasaMbseDistributed 2020).
(c) To be capable of execution at varying levels of fidelity or uncertainty. Preferably, the models should have the ability to quickly adjust the fidelity to match the requirements of the simulations, e.g., from broad-based simulation, to in-depth simulation, and back again to broad-based simulation (NasaMbseDistributed 2020).
4. Target models, e.g., phenomenological or geophysical models, that represent planetary surfaces, interiors, atmospheres, etc., as well as associated tools and methods that allow for integration into system design or process models for simulation of instrument responses. Such models may be algorithmic or numeric, but should be useful to designers wishing to optimize remote sensing systems for those planets (NasaMbseDistributed 2020).

By offering the automatic requirement verification in the form of a plugin, or add-on, to established design tools, organizations can continue to leverage existing design tools and processes. This mitigates risk and facilitates adoption of the verification mechanism.

### 1.4. Digital Assistants for Science and Engineering

NASA is also seeking innovative solutions that combine modern digital technologies, such as natural language processing, speech recognition, machine vision, machine learning or artificial intelligence, and virtual reality or augmented reality, to create digital assistants for science and engineering. Such digital assistants can range in capability from low-level cognitive tasks, such as information search, information categorization and mapping, information surveys or semantic comparison, to expert systems and to autonomous ideation (NasaDigitalAssistants 2020).

NASA is, further, interested in digital assistants that can reduce the cognitive workload of its engineers and scientists, so that they can concentrate their talents on innovation and discovery. Digital assistant solutions can target tasks characterized as research, engineering, operations, data management and analysis (of science data, ground and flight test data or simulation data), business or administrative (NasaDigitalAssistants 2020).

The digital assistants considered by NASA include (NasaDigitalAssistants 2020):
1. Digital assistants that use the semantic, numeric, and graphical content of engineering artifacts (e.g., requirements, design, verification) to automate traces among the artifacts and to assess completeness and consistency of traced content. Such digital assistants (or agents) may use semantic comparison to determine whether the full scope of a requirement can be verified based on the description(s) of the test case(s) traced from it. Similarly, such digital assistants may be able to identify from design artifacts any functional, performance, or non-functional attributes of the design under consideration that do not trace back to requirements. Presently, this type of work is performed by project system engineers, quality assurance personnel, and major milestone review teams (NasaDigitalAssistants 2020).
2. Digital assistants that are capable of identifying current or past work related to an idea, by providing a list of related government documents, academic publications, and/or popular publications. Such digital assistants may prove useful in characterizing the state-of-the-art, when proposing or reviewing an idea for government funding. Engineers and scientists accomplish this presently by executing multiple searches using different combinations of keywords from the idea text, each on a variety of search engines and databases. Then, the engineers or scientists read dozens of documents and establish their relevance. NASA is looking for digital assistive technologies to significantly reduce the workload involved (NasaDigitalAssistants 2020).
3. Digital assistants that are capable of highlighting lessons learned, suggest reusable assets, highlight past solutions or suggest collaborators based on the content that the engineer or scientist is currently working on. NASA is interested in digital solutions that provide capabilities for parsing textual and/or graphical information from an in-progress work product and search the knowledge bases, in possession by the Agency, project repositories, asset repositories, and other in-progress work products, to identify information or assets that are relevantly similar. Such digital assistants can then notify the engineer using the digital assistant of the relevant information and/or its author, who may be viewed as a potential collaborator (NasaDigitalAssistants 2020).
4. Digital assistants that are capable of recommending an action in real-time to operators of a facility, vehicle or another physical asset. Such digital assistants could work from a corpus of system information, such as design artifacts, operator manuals, maintenance manuals, and operating procedures, to correctly identify the current state of a system, given sensor data, telemetry, component outputs, or other real-time data. The digital assistants may then be able to use the same information to autonomously recommend a remedial action to the operator when it detects a failure, to warn the operator when their actions will result in a hazard or loss of a mission objective, or to suggest a course of action to the operator that will achieve a new mission objective given by the operator (NasaDigitalAssistants 2020).
5. Digital assistants that are capable of creating one or more component or system designs from a concept of operations, a set of high-level requirements, or a performance specification. Such digital assistants would preferably be capable of combining reinforcement learning techniques, generative-adversarial networks, and simulations, to autonomously idea solutions.
6. Expert systems that are capable of using a series of questions to generate an initial system model (e.g., using Systems Modeling Language [SysML]), plans, estimates, and other systems engineering artifacts.

Note that these digital assistants exhibit significant resemblance with the querying (search) engine described in the patent application “Decisions with Big Data” (Steingrimsson 2018b). FIG. 16 of (Steingrimsson 2018b) presents a retrieval model, one utilizing latent semantic analysis (LSA). FIG. 18, FIG. 20 and FIG. 22 of (Steingrimsson 2018b) offer examples featuring representative input queries along with corresponding outputs.

### 1.5 Smart Modeling & Simulation: “Plug-and-Play” for Modeling Engineering Structures

Conventional Finite Element Analysis (FEA) packages, such as ANSYS and ABAQUS, are designed for the general purpose and for engineers who are quite familiar with FEA theory. These general packages can be used to solve some engineering problems in many areas including construction, ship building, and automotive. However, different industries have different needs and unique problems.

Smart Modeling and Simulation (SMS) represents the process of system development and use of a computer-generated model to simulate the design, analysis, manufacturing process and operation of electro-mechanical systems. SMS provides the opportunity to integrate design, analysis and manufacturing, and can reduce the time and costs associated with design and manufacturing. This is not possible using traditional design tools, which require that a separate tool be performed at the end of the design process, thus reducing the opportunities for the early modifications that can improve the performance of the design and analysis process as well as of the product.

### 1.6 Nonlinear Analysis of Civil Structures (in Context of a Design Ecosystem)

FIG. 2 presents Finite-Element Analysis for civil engineering design projects in context of the Ecosystem for Design Assessment and Verification (the Ecosystem design software). Per FIG. 2, the Ecosystem design software lends itself well to civil engineering design projects involving structures. Civil structures, such as buildings, bridges or pavements, are subjected to rigid codes. Similar to mechanical designs, civil structures are governed by factors of safety, and tend to employ high factors of safety. The Ecosystem design software can help with assessment of designs involving civil structures against the applicable codes and standards.

Commercial software for Finite-Element Analysis, such as Abaqus, ANSYS or SAP 2000 tend to rely on many input parameters (many assumptions), and are widely regarded as complicated. One aspires to carry out macroscopic modeling (simulations) of civil structures, even nonlinear analysis, such that the regular engineers can understand. Structural engineers, for example, aspire to carry out nonlinear analysis of a building, subjected to an earthquake, with the least amount of inputs. Presently, designers of civil structures tend to be asked many elaborate questions by the analysis software throughout the analysis process (esp. prior to an analysis run).

Common beam elements assume elastic, non-breaking behavior. New technologies, such as base isolation devices or dumping devices (energy absorption devices), cannot be modeled accurately with elastic elements. For accurate analysis, nonlinear behavior of the elements needs to be accounted for.

Further along such lines, nonlinear analysis of civil structures can presently be characterized as follows:
1. The structural engineers are likely familiar with material properties of the structural materials, such as steel.
2. But the structural engineers may be confused with matrix presentation of these numbers, or with the numbers defining a particular structure, in software applications presently available for nonlinear structural analysis.
3. Hence, structural engineers may not feel confident enough with the software facilities presently offered for nonlinear analysis of civil engineering structures, including the user interface.
4. For that reason, the structural engineers may be tempted to err on the side of caution, avoid taking responsibility for the assumptions made in the nonlinear analysis of the civil structures (in case they think they are not fully comprehending something). The structural engineers may even consider avoiding the nonlinear structural analysis altogether.
5. If given a real earthquake scenario, with two spatial degrees of freedom, the structural engineers may not feel confident enough to carry out meaningful nonlinear analysis of such scenarios.

After all, analysis of civil structures tends to be a conservative field of engineering, and the structural engineers tend to be risk adverse.

On the other hand, software used for analysis of civil structures, including non-linear analysis, will ideally provide an efficient user interface, similar to the ones featured in the mobile smart phones. Software for nonlinear structural analysis will ideally feature an efficient iPhone-like user interface, one that does not rely on many assumptions.

This invention expands the Ecosystem design framework to civil engineering design projects, with emphasis on civil structures. More specifically, in this invention, we seek to:
1. Adapt the Ecosystem interface, such that it properly, and conveniently, captures entities from civil engineering design projects.
2. Integrate combined geometric and material nonlinearity-based structural frame analysis and design capabilities into the Ecosystem.
3. Abstract out some of the details, offer the user with an efficient user interface, but still one offering significant flexibility.

### 2. Description of Prior Art

### 2.1 Automatic Verification of Engineering Requirements—ML-Based Approaches to Engineering Design—Generative Designs

For an exposition of the prior art on automatic assessment of designs against engineering requirements, and an ML-based approach to engineering design, refer to (Steingrimsson 2017), (Steingrimsson 2018), (Steingrimsson 2018b), (SteingrimssonKulkarni 2020) and to the references listed therein.

For an additional exposition of the prior art on generative designs, refer to (MarinovCharrotFurutua 2021), (Willi sMorri sB asti an 2020), (D all owroS1 avinSrivastavarusi a 2021), (StraterFurutaSchneider 2021), (B andaraShayani Szkurl at 2022), (GrossmanBradnerFitzmaurice 2022), (HillerBlankenship 2021), (StoddartBenjaminNagy 2019), (BenjaminNagy 2022), (AndersonGrossman 2021), (FanJiang 2021), (AndersonCorosDesai 2020), (CheongEbrahimiIorio 2021), (KuniakvskyAkionaChen 2021a), (KuniakvskyAkionaChen 2021b), (EomBurlaRodriguez 2021), (EomBurlaRodriguez 2022), (Harri sB andaraSzkurl at 2022), (BandaraRutoMorris 2022), (WeinbergKim 2021), (KimWeinberg 2022), (HarrisGroomBandara 2022), (SubramaniyanBaruaErno 2021), (BurlaEomRodriguez 2021), (Whitney Chen0 singa 2021), (EomRodri guezW einb erg 2022), (BandaraWillisHarrisB anadyga 2020), (CheongEbrahimi 2022), (Benj aminStoddartVillaggi 2021), (GrauHarris 2021), (ChenOsingaIkhena 2022), (BianchiAgrawalHaobsh 2022), (RazzellEdwardsRogers 2021), (CheongFitzmauriceGrossman 2021), (SrivastavaGruenewaldGrimm 2020), (Gava6ovaGulan 2016), (Davi esHaleyDanielyan 2021), (Lafreni ereGrossmanWeingarten 2020), (TrivediNourbakhshBergin 2022), (MingdongYelin 2022), (Benj aminZhaoVillaggi 2021), (YuHallet 2022), (ChalupkaBeebeDonnelly 2020), (AndersonDavisFitzmaurice 2022), (DaviesHaleyDanielyan 2020), (DaviesHaleyDanielyan 2021) and (DaviesHaleyDanielyan 2022).

2.2 Automatic Assessment against ABET Learning Outcomes 1-7—Improving Productivity of Design Instructors or Engineering Departments

For an exposition of the prior art on automatic assessment against ABET learning outcomes, refer to (ABET 2019), (Steingrimsson 2017), (SteingrimssonKulkarni 2020), (Sundaraj an 2014) and the references therein.

### 2.3 Improving Productivity Through Automatic Requirement Verification by Providing Plug-Ins for Established Design Tools

NASA has been trying to use SysML to address requirement verification in some form or fashion for the past several years. Serious attempts to use SysML seem to be mostly aimed at early project lifecycle phases, where it's important to keep track of design parameters such as mass, and power against a design that is in flux. Team-X at NASA has focused on pre-project design trades, along with studies that may demonstrate a mission concept yielding at least one potential solution that makes sense. As such, they have not had many hard requirements to verify. But other teams have used SysML in later phases of missions (Wagner 2018).

As (Karban 2016) shows, it is possible to express and verify some requirements in a SysML tool, with appropriate extensions. However, this wasn't easy to do, even though the team consisted of some of the world's leading authorities on SysML modeling (Karban 2016). In addition, (Jenkins 2015) shows how to model requirements in SysML as “shall statements”.

Although there may have been attempts to model ground systems and mission operations in SysML, we are not aware of any serious reliance on these models for engineering purposes. To our knowledge, modeling of workflows at NASA has in part revolved around using Business Process Model and Notion (Wagner 2018), (ObjectMgmtGroup 2018). The most serious attempt to applying a model-based approach for requirement analysis may have involved the Thirty Meter Telescope Project (TMT) (Incose 2019), (GitHub 2019), (MbseWiki 2019). Ref. (Incose 2019) describes application of an Executable Systems Engineering Method, along with an Open-source Engineering Environment, for specification, analysis and verification of requirements of TMT's Alignment and Phasing System and the Narrow Field Infrared Adaptive Optics System. The value proposition for applying this MBSE approach was to establish precise requirements and fine-grained traceability to system designs, and to verify key requirements using executable SysML models, beginning in early development.

The previous work on the Thirty Meter Telescope project has demonstrated that it is feasible to verify certain classes of requirements in SysML (Incose 2019), (GitHub 2019), (MbseWiki 2019). It has been demonstrated it is relatively easy to verify simple static parameters, such as size and mass. It is a little more difficult to verify, at least through simulations, constraints that are related by a second-order relationship with the system properties. And it is a lot more difficult to verify constraints on properties, that have high uncertainty associated with them, or where probabilistic methods are required. It also can be very difficult to verify certain anti-constraints, such as lack of faults or mistakes in a design (Incose 2019), (GitHub 2019), (MbseWiki 2019).

Red Canyon Software in Rio Rancho NM has developed an OpenSATTM framework for satellite design automation for responsive space (Santangelo 2007), (Santangelo 2008). According to (Santangelo 2007) and (Santangelo 2008), Red Canyon Software is developing next-generation of collaborative aerospace design automation tools to meet needs by the Department of Defense for Responsive Space. A central idea of “responsive space” is to deploy a satellite from idea to launch in less than two weeks. “SATBuilder” represents an artificial intelligence based collaborative design environment that automates the design process and tracks the design to the requirements from the customer. The “SATBuilder” collaborative design environment utilizes the open-source “OpenSAT” architecture as a basis for its infrastructure.

For additional information on automatic requirement verification and autonomous system-level fault diagnosis, in context with model-based systems engineering and/or space applications, refer to the following publications from the Small Satellite Conference, which is held annually (usually in August) in Logan UT, as well as to the references cited in these publications: (GizziOwensPellegrino 2022), (HuangFerguson 2021), (FuchsMurillo 2021), (HalvorsonShortBush 2021), (MenciaKoerksenYap 2021), (Gill etteGeorgeCastle 2021), (ObataAraiAsada 2021), (FugmannKlinker 2021) and (MasutaniGershomNunes 2020).

Issued patents and patent applications on MBSE include (EckCassandraWellman 2020), (QianWei 2022), (OgnevHerreraTeague 2021), (YapingZhijieLiangcong 2022), (JinJunjunXiaoguang 2020) and (PeijieSanyuHongfei 2022). Ref (EckCassandraWellman 2020) presents computational accelerator architecture that facilitates change management of jobs in a MBSE system, where each MBSE job contains multiple individually identifiable descriptions. Here, the linked data stores narrative-oriented, variable-strength links between certain narratives of MBSE work, where the links indicate relationships between those particular narratives. Further, the revision control engine detects revisions made to MBSE job descriptions and selectively indicates revision requests to other descriptions in response to those changes, according to the individual strengths of the links associated with the changed descriptions. Ref. (QianWei 2022) presents a method and device for analyzing interlocking function defects based on MBSE, and an interlocking system composed of Scade model logic and C code program logic. Ref. (OgnevHerreraTeague 2021) expands on information management in MBSE modeling tools, specifically one that includes functionality for sharing an MBSE model with multiple outside vendors using multiple versions of the MB SE model. Ref (YapingZhijieLiangcong 2022) presents an integrated analysis method of Fault Tree Analysis (FTA) and Failure Mode and Effect Analysis (FMEA) based on MBSE. Ref. (JinJunjunXiaoguang 2020) presents a MBSE-based modeling and simulation method for an on-board electrical system. The invention described in (JinJunjunXiaoguang 2020) specifically includes: modeling and simulating the top-level conceptual level of the on-board electrical system based on SysML; referring to the SysML model, selecting the most optimal system for each subsystem of the system. While the model is used to guide the construction of unit-level models, and to provide standardized guidelines for the modeling of different departments and fields at the unit level, so that the interfaces, data flows and behaviors of the models built in various departments and fields are coordinated, and the co-simulation based on a Functional Mock-up Interface can be carried out smoothly, the model does not seem to provide means for automatic verification of requirements. The invention presented in Ref. (PeijieSanyuHongfei 2022) relates to a rapid demonstration method for a rocket small loop based MBSE. While (EckCassandraWellman 2020), (QianWei 2022), (OgnevHerreraTeague 2021), (JinJunjunXiaoguang 2020) and (PeijieSanyuHongfei 2022) do address MBSE, these patents and patent applications do not seem to specifically address automatic requirement verification in context with MBSE. As for Ref. (YapingZhijieLiangcong 2022), this invention seems to center around automatic generation of FTA and FlVfEA from an Excel file using a plugin. Whereas the invention described in Ref (YapingZhijieLiangcong 2022) does address the design process, the design process, fault tree or failure mode analysis, it does not seem to address automatic verification of the design requirements. Ref. (YapingZhijieLiangcong 2022) seems to be limited to automatic generation of the FTA or FMEA reports.

### 2.4. Digital Assistants for Science and Engineering

Much of the prior art from (Steingrimsson 2018b), related to the latent semantic analysis, also applies to the Digital Assistants for Science and Engineering. Additional prior art of relevance includes content from NASA on the “Crew Interactive Mobile Companion” [(NasaMeetCimon 2018), (MeetCimonNasa 2018)], (Manj ulaYagleReith 2017), (AmburSchwartzMavris 2017), (Rohaidi 2018), and (Soderstrom 2019).

The Word2Vec technique for natural language processing has been patented by Google, with U.S. Pat. No. 10922488 B1 granted on Feb. 16, 2021 (MikolovChenCorrado 2021). Tomas Mikolov lead a team of researchers at Google that created and published the Word2Vec technique back in 2013.

Issued patents and patent applications on digital assistants include (LemaySabatelliAnzures 2019), (CranfillJonesKudurshian 2019), (ReddyHowardHarrison 2019), (GruberPitschel 2019), (PhippsGenaroShrum 2021), (FrazzingaroGargThomson 2022) and (ChristopherBaldwin 2022). Ref. (LemaySabatelliAnzures 2019) describes a method for operating a digital assistant on a computing device. Note that Ref (LemaySabatelliAnzures 2019), (CranfillJonesKudurshian 2019) and (ChristopherBaldwin 2022) seem to succeed the patent application Ref (Steingrimsson 2018b), which was filed on Nov. 6, 2018. Ref. (ReddyHowardHarrison 2019) relates to digital personal digital assistant interaction by replication and rich multimedia in response. Unlike the present invention, the digital personal assistant described in Ref (ReddyHowardHarrison 2019) interacts with a digital personal digital assistant persona, as opposed to, for example, requesting that the digital personal digital assistant obtain information or perform some other task on the user's behalf. Further, unlike the present invention, the response of the digital personal assistant described in Ref. (ReddyHowardHarrison 2019) to verbal input from the user includes multimedia objects (e.g., images, video content or audio content), that are displayed within or played by the user interface of the digital personal digital assistant, and that relate to references to popular culture. Ref. (GruberPitschel 2019) describes a method for user training by an intelligent digital assistant. The method itself outlined in (GruberPitschel 2019) does not seem to utilize neural networks or latent semantic analysis, although neural networks or latent semantic indexing are featured in the quite extensive list of prior art presented. Ref. (PhippsGenaroShrum 2021) addresses synchronization and task delegation of digital assistants more so than the querying (search) mechanism itself. An initial instance of a digital assistant on an electronic device no. #1 obtains a set of data corresponding to a second instance of a digital assistant on a electronic device no. #2, and updates one or more settings of the first instance of the digital assistant, based on the received set of data. Ref. (PhippsGenaroShrum 2021) does seem to address neural networks or latent semantic analysis applied to the querying (search) mechanism, although neural networks or latent semantic indexing are featured in the fairly extensive list of prior art presented. Ref (FrazzingaroGargThomson 2022) addresses feedback analysis of a digital assistant. Similar to (PhippsGenaroShrum 2021), Ref (FrazzingaroGargThomson 2022) seems to primarily address interactions between digital assistants. A method is described that “includes, at an electronic device with one or more processors and memory, obtaining a first set of data corresponding to one or more interactions between a user and the digital assistant on the electronic device; obtaining a second set of data corresponding to one or more interactions between the user and an application on the electronic device; and storing the first set of data and the second set of data.” Neural networks are mentioned, as a part of general background coverage of speech recognition models and machine learning mechanisms, as well as a part of the somewhat extensive listing of the prior art presented, but do not seem to be featured in the invention itself. Similarly, latent semantic analysis is only featured in the prior art cited, but not in the invention itself.

### 2.5. Smart Modeling & Simulation: “Plug-and-Play” for Modeling Engineering Structures

The integration of design, analysis and manufacturing of electro-mechanical systems, for the purpose of reducing time and cost associated with design and manufacturing, is not possible using traditional design applications, which require a separate tool to be performed at the end of the design process, thus reducing opportunities for early modifications that can improve performance.

The SMS system accommodates and extends the work of Dr. Sung Yi et. al. in the area of pick-and-place for electronic packaging. In addition to having developed software featuring ready-made geometries, inter-operability and automatic meshing, Dr. Sung Yi has, with his colleagues, created advanced material models based on mathematical equations capturing complex multi-physics interactions. For further information, refer to (Yi 2015) (SteingrimssonKulkarni 2020) (SzeYaoYi 2000), (YiHiltonAhmad 1997), (Yi 1997), (YiLingYing 1998), (YiLingYing 1999), (YiLingYing 2000), (YiLingYing 2001), (LiuYiOng 2005), (TranChuaYi 2012), (LamYi 2012) and (Yi 2012).

(LangemyrBertilssonNordmark 2015), (ArthurShapiro2013), (CzingerB alzerPenmetsa 2021a) and (CzingerBalzerPenmetsa 2021b) may comprise the closest prior art analogues to the smart modeling and simulation system presented in this invention. Ref (LangemyrBertilssonNordmark 2015) discloses techniques for representing and modeling systems in which each system corresponds to an application mode. This can be done for one or more geometries using local and/or non-local couplings. Physical quantities can be modeled, for each application mode, and may be defined using a graphical user interface. Ref (ArthurShapiro2013) addresses the use of Bulk Flow Fluid Elements (BFFE) to model thermal fluid-structure interactions. Thermal fluid-structure interactions may be considered a subset of the multi-physics analyses supported by the SMS system. The SMS system provides facilities, such as plug-and-play, not covered in (ArthurShapiro2013). Ref (CzingerBalzerPenmetsa 2021a) and Ref. (CzingerBalzerPenmetsa 2021b) address systems and methods for design and fabrication of a vehicle subassembly, specifically of a vehicle chassis. In the case of (CzingerBalzerPenmetsa 2021b), the vehicle chassis may comprise one or more vehicle chassis modules or chassis substructures that are formed from a plurality of customized chassis nodes and connecting tubes. Although the vehicle chassis modules or chassis substructures may be interchangeably and removably connected, to provide a vehicle chassis having a set of predetermined chassis safety or performance characteristics, neither (CzingerBalzerPenmetsa 2021a) nor (CzingerBalzerPenmetsa 2021b) provide a generic system for plug-and-play.

### 2.6 Nonlinear Analysis of Civil Structures

Material nonlinearity in a beam section of a civil structure is associated with plasticization of the section and with the extent of plasticization throughout the member length. Displacement or stiffness-based formulation of beam elements invariably assumes that the plastic behavior is concentrated at the end nodes of the beam. This assumption of concentrated plasticity is a “mathematical abstraction, because it implies infinite strains” (Powell 1986). In force or flexibility-based beam formulation it is ensured that the plasticity spreads along the member length, and the member sectional stress-resultants remain in equilibrium with the nodal stress-resultants. The force-based beam element is advantageous with regards to simulating spread of plasticity. However, barring few (Larsa 2016). (RohSivaselvan 2009), most of the commercial and academic structural analysis software (ABAQUS 2016), (McKenna 2016), (ADINA 2016), (SAP 2000) use the stiffness-based beam formulations for nonlinear dynamic analysis. This is because the stiffness-based formulation adheres to the general FEA procedure. The force-based beam lacks a strain-displacement interpolation function. This invention incorporates multi-level iterations in the force-based beam such that it is expected to outperform the stiffness-based beams in dynamic analyses.

The commercial ABAQUS and ANSYS FEA software provide capabilities for non-linear analysis. For background information on non-linear analysis in ABAQUS, refer for example to (PracticalFEA 2021), (TrendingMechVideos 2018a), (TrendingMechVideos 2018b) or (TrendingMechVideos 2018c). For background information on non-linear analysis in ANSYS, refer for example to (EDRMedeso 2021), (DrDalyO 2016) or (Tech.G.Ansys 2016). According to (NguyenWaas 2016), errors associated with lack of energy conservation issues in incremental FEA using commercial codes, that have been broadly adopted in solid and structural mechanics analyses, have been reported by (BazantGattuVorel 2012), (JiWaasBazant 2010a), (JiWaasBazant 2010b), (JiWaas 2010), (VorelBazantGattu 2013), (BazantVorel 2014), (VorelBazant 2014). Specifically, Ref (BazantGattuVorel 2012) demonstrated significant errors in load and energy for identification problems of structures made of highly compressible materials. Non-physical response of a simple shear problem, predicted by various commercially available FEA codes, was further demonstrated in (JiWaasBazant 2010a).

SAP 2000 is presented by its vendor, Computers & Structures, Inc. (CSI), a structural and earthquake engineering software company, as the industry standard for structural analysis. CSI states that its solvers, in particular the SAPFire Analysis Engine, have been tried and tested by industry for over 45 years. The SAPFire Analysis Engine is reported to support multiple 64-bit solvers for analysis optimization and to perform both eigen and Ritz analyses. SAP 2000 provides a single user interface to perform modeling, analysis, design and reporting (SAP 2000). SAP 2000 is a general-purpose software application in the sense that the user can model any kind of geometry and carry out analysis and design. For a nice, general background overview of the SAP 2000 software for structural analysis, refer to pages 8 — 11 of (MichaelHopper 2009). For a background on capabilities of the SAP 2000 software, related to nonlinear analysis, refer, e.g., to (ComputersAndStructuresInc 2011) or (ComputersAndStructuresInc 2014).

Some of the concerns expressed over the SAP 2000 software relate to (1) high license cost, (2) complexity, i.e., many input assumptions being required, and (3) unintuitive user interface, i.e., need for in-depth familiarity by the user with FAE theory. Although the SAP 2000 software is quite costly, its customers seem to be willing to accept the set price. Hence, the high price seems to be justified (the software seems to be priced at market value). The intent of this invention is to improve the accuracy of the FEA modeling and to simplify the user interface.

ETABS is a special-purpose software application that accesses the same analysis engine as SAP 2000. ETABS is a special-purpose software in the sense that it has been designed for specificuse, i.e., forbuilding systems. ETABS provides all the necessary tools for building systems as well as help in geometry formation of building systems. ETABS is mostly utilized for handling large-scale seismic (or wind) projects, and does support nonlinear modeling (Etabs. Sap 2022).

PERFORM 3D, also developed by CSI, is strictly a nonlinear analysis software program that is used for performance assessment of 3D structures subjected to seismic events (MichaelHopper 2009). Structural models can be imported directly into PERFORM 3D from SAP 2000. Structural engineers are, therefore, likely to migrate to PERFORM 3D, a more specialized program for evaluation of buildings using performance-based design principles. For additional information, refer to pages 11-13 of (MichaelHopper 2009).

LARZ is a specialized software application originally developed to calculate the nonlinear seismic response of reinforced concrete frames (MichaelHopper 2009). Since its inception in 1975, the LARZ software has been enhanced such as to enable study of frame-wall structures. LARZ incorporates several hysteresis models to properly characterize the moment-rotation cyclical response of reinforced concrete members. Hysteris models, such as the Takeda hysteresis model, the Sina hysteresis model, the Otani hysteresis model, the Simple Bilinear model, and the Q-hysteresis model can all be invoked from the LARZ program. For additional information, refer to pages 5-8 of (MichaelHopper 2009).

RISA 3D is a three-dimensional (3D) general-purpose, rapid interactive structural analysis (RISA) software. RISA is reported to be simple to use and support rigorous 2^{nd} order analysis. It alsopermits the user to set up detailed templates for concrete members (Risa3d 2022).

STructural Analysis And Design (STAAD) is a structural analysis and design software application originally developed by Research Engineers International in 1997. STAAD and STAAD.Pro are among the most widely used structural analysis and design software products worldwide. STAAD and STAAD.Pro can apply more than 90 international steel, concrete, timber and aluminum design codes (Staad.Pro 2022).

RAM Structural System (RAM SS) from Bentley is another integrated 3D static and dynamic structural analysis and design software for buildings. RAM SS is claimed to easily produce high-quality and economical designs for structural design projects involving various concrete, steel or joist building materials. RAM SS has been developed for concrete and steel-framed building systems that are subjected to lateral, dynamic, and gravity loads (BentleyRamSS 2022).

OpenSees, maintained by the University of California in Berkeley, is a software framework for developing applications to simulate the performance of structural and geotechnical systems subjected to earthquakes. The goal of the OpenSees project is to improve the modeling and computational simulation in earthquake engineering through open-source development (OpenSees 2022). It has been reported that it can take long time (even 2-3 weeks) to complete analysis using the OpenSees framework. The framework may call for huge processors. Further, some structural engineers consider the interface not that user friendly.

(HuynhKnezevicPateraLi 2015), (StevenJamsBungiorno 2012), (KimDaeJung 2006), (ShucaiZuqingYanming 2020), (ChenHauserBoyle 2015), (ParkerPayne 2019), (BouzinovBelyi 2016), (YoungChaWooramChoi 2021), (ThomasWinantAlanJeary 2021) and (NigelJohnGreenwood 2020) may comprise the closest prior art analogues to the nonlinear analysis for civil structures and earthquake engineering presented in this invention. Neither (HuynhKnezevicPateraLi 2015), (StevenJamsBungiorno 2012), (KimDaeJung 2006), (ShucaiZuqingYanming 2020), (ChenHauserBoyle 2015), (ParkerPayne 2019), (BouzinovBelyi 2016), (YoungChaWooramChoi 2021), (ThomasWinantAlanJeary 2021) nor (NigelJohnGreenwood 2020) address interactions between force-based beam elements which comprise a key aspect of this invention in regards to nonlinear analysis of civil structures.

### REFERENCES

(ABET 2019) ABET, Criteria for Accrediting Engineering Programs, 2019-2020, https://www.abet.org/accreditation/accreditation-criteria/criteria-for-accrediting-engineering-programs-2019-2020/#GC3, 2019.

(ABETassessment101 2022) G. Rogers, “Assessment 101: Assessment Tips with Gloria Rogers, Ph.D. Surveys and Questionnaires: Do They Measure Up?”, https://www.abet.org/wp-content/uploads/2015/04/surveys-and-questionaires.pdf, accessed on Sep. 10, 2022.

(WikipediaMoodle 2022) Wikipedia, “Moodle”, https://en.wikipedia.org/wiki/Moodle, accessed on Sep. 10, 2022.

(D2L 2022) D2L, “Build Better Learning Experiences”, https://www.d21.com/, accessed on Sep. 10, 2022.

(WikipediaBlackboardLearn 2022) Wikipedia, “Blackboard Learn”, https://en.wikipedia. org/wiki/Blackboard Learn, accessed on Sep. 10, 2022.

(Canvas 2022) Instructure, “Canvas LMS solutions for school and beyond”, https://www.instructure.com/canvas, accessed on Sep. 10, 2022.

(EdLink 2022) EdLink, “What's the Difference Between an SIS and an LMS?”, https://ed. link/community/whats-the-difference-between-an-sis-and-an-lms/, accessed on Sep. 10, 2022.

(Steingrimsson 2017) B. Steingrimsson, R. Jones, F. Etesami and S. Yi, Ecosystem for Engineering Design Learning—A Comparative Analysis, International Journal of Engineering Education, Vol. 33, No. 5, pp. 1499-1517, 2017.

(SteingrimssonKulkarni 2020) B. Steingrimsson and A. Kulkarni, Automatic Requirement Verification Engine and Analytics, U.S. Pat. No. 10,853,536, https://patents.google.com/patent/US10853536B1/, granted on Dec. 1, 2020.
(Jones 2015) R. Jones, “A Digital Ecosystem for Learning and Team Design: A Feasibility Study,” Master Report, Portland State University, June 2015.

(PhanPonderJimenez 2016) B. Phan, J. Ponder, C. Jimenez, R. Lawrence, A. Ferrante, M. Larson-Weber, S. Levin, S. Randall, “Redesign of a Spacer Cart for Improved Functionality and Safety”, ME 493 Final Report, Portland State University, Jun. 3, 2016.

(Sundaraj an 2014) S. Sundarajan, A Strategy for Sustainable Student Outcomes Assessment for a Mechanical Engineering Program that Maximizes Faculty Engagement, https:// lib.dr.iastateedu/cgi/viewcontent.cgi?article=1052&context=me_conf Iowa State University Digital Repository, June, 2014.

(ACRL 2000) Association of College and Research Libraries. “Information Literacy Competency Standards for Higher Education.” American Library Association. 2000. http://www.acrl.org/ala/mgrps/divs/acrl/standards/standards.pdf (accessed May 15, 2015).

(Yi 2015) S. Yi, Manual of Example Problems of EPA, SW Manual, 2015.

(Steingrimsson 2018) B. Steingrimsson, All-Electronic Ecosystems for Design and Collaboration, U.S. Pat. No. 9,923,949, granted on Mar. 20, 2018.

(Steingrimsson 2018b) B. Steingrimsson, M. Kisialiou, R. Jones, A. Kulkarni and K. Yi, Decisions with Big Data, Utility Patent application Ser. No. 16,182,389, https://patents.google.com/patent/US20190087529A1/, filed on Nov. 6, 2018.

(Harry 1999) R. S. M. Harry, Six Sigma: The Breakthrough Management Strategy Revolutionizing the World's Top Corporations, Reed Business Information, Inc., 1999.

(SivamKrish 2011) S. Krish, “A Practical Generative Design Method”, Computer-Aided Design, Vol. 43, No. 1, pp. 88 — 100, January, 2011.

(Steingrimsson 2013) B. Steingrimsson, Recognition and Representation of Image Sketches, U.S. Utility patent application Ser. No. 13/865,549, filed on Apr. 18, 2013.

(Wagner 2018) D. Wagner, E-mail communications, January-March, 2018.

(Karban 2016) R. Karban, F.G. Dekens, S. Herzig, M. Elaasar, and N. Jankevičius, “Creating System Engineering Products with Executable Models in a Model-Based Engineering Environment,” in Proceedings Volume 9911, Modeling, Systems Engineering, and Project Management for Astronomy VI, 2016.

(Jenkins 2015) S. J. Jenkins and B. F. Cole, “Connecting Requirements to Architecture and Analysis via Model-Based Systems Engineering,” in AIAA Infotech @ Aerospace, AIAA SciTech Forum, (AIAA 2015-1116), 2015.

(ObjectMgmtGroup 2018) Object Management Group, “Business Process Model and Notation,” http://www.bpmn.org/, Accessed on Feb. 24, 2018.

(Paredis 2018) C. Paredis, “System Analysis Using SysML Parametrics: Current Tools and Best Practices,” Georgia Institute of Technology, https://openmodelica.org/images/docs/modprod2011-tutorial/modprod2011-tutorial4-Chris-Paredis-SysML-Parametrics.pdf, Accessed on Mar. 3, 2018.

(Wolfrom 2018) J. Wolfrom and S. Friedenthal, “Modeling with SysML,” http://www. jhuapl.edu/ott/technologies/docs/modelingwithsysmltutorial.pdf, Accessed on Mar. 3, 2018.

(Seidewitz 2018) E. Seidewitz, “SysML v2 and MBSE: The Next Ten Years”, Model Driven Solutions, http://www.slideshare.net/seidewitz/sysml-v2-and-mbse-the-next-ten-years, Oct. 16, 2018.

(Incose 2019) SEBoK Wiki, “Applying a Model-Based Approach to Support Requirements Analysis on the Thirty-Meter Telescope,” https://www.sebokwiki.org/wiki/Applying_a_Model-Based_Approach_to_Support_Requirements_Analysis_on_the_Thirty-Meter_Telescope, Mar. 14, 2019.

(GitHub 2019) GitHub, “Thirty Meter Telescope System Model in SysML”, https//github.com/Open-MBEE/TMT-SysML-Model, accessed on Mar. 14, 2019.

(GitHubOpenMbee 2022) GitHub, “Open-MBEE”, https://github.com/Open.-MBEE/mdk, accessed on Aug. 23, 2022.

(GitHubJpllmce 2022) GitHub, “JPL-IMCE”, https://github.com/JPL-IMCE/gov.nasa.jpl. imce.profileGenerator.application, accessed on Aug. 23, 2022.

(OmgSystemsModeling 2022) OMG Systems Modeling Language, “SysML v2: The Next-Generation Systems Modeling Language”, http://www.omgsysml.org/SysML-2.htm, accessed on Aug. 23, 2022.

(IbmKnowledgeCenter 2022) IBM Knowledge Center, Creating Rational Rhapsody Plug-Ins, http://www.ibm.com/support/knowledgecenter/SSB2SSB2MU_8.1.0/com.ibm.rhp.customization. doc/topics/rhp_c_ext_rhp_plugins.html, accessed on Aug. 23, 2022.

(ModelingDesignSparx 2022) SparX Systems, “Modeling & Design Platform”, https://sparxsystems.com.au/products/#MDG-extensions accessed on Aug. 23, 2022.

(NoMagicSysMlPlugin 2022) No Magic, “SysML Plugin”, https://www.nomagic.com/product-addons/magicdraw-addons/sysml-plugin, accessed on Aug. 23, 2022.

(VisualParadigmPlugin 2022) Visual Paradigm, “How to Develop Visual Paradigm Plug-in?”, http://www.visual-paradigm.com/tutorials/plugin.jsp, accessed on Aug. 23, 2022.

(EclipsePapyrusStandards 2022) Eclipse Foundation, “Papyrus/Code Standards”, https://wiki.eclipse.org/Papyrus/Code_Standards, accessed on Aug. 23, 2022.

(MbseWiki 2019) OMG MBSE Wiki, “Telescope Modeling Challenge Team”, http://www.omgwiki.org/MBSE/doku.php?id=mbse:telescope, Mar. 14, 2019.

(Santangelo 2007) A. Santangelo, “OpenSAT, a framework for satellite design automation for responsive space”, https://doi.org/10.2514/6.2007-2910, AIAA Infortech@ Aerospace, 2007 Conference and Exhibit, Rohnert Park Calif., May 7-10, 2007.

(Santangelo 2008) A. Santangelo, “OpenSAT and SATBuilder: A Satellite Design Environment for Responsive Space”, https://doi.org/10.2514/6.2008-1127, 46th AIAA Aerospace Sciences Meeting and Exhibit, Reno Nev., Jan. 7-10, 2008.

(NasaMbseDistributed 2020) NASA, “Model Based Systems Engineering for Distributed Development”, https://sbir.nasa.gov/content/model-based-system-engineering-distributed-development-0, Jan. 3, 2020.

(FriedenthalOster 2022) S. Friedenthal, C. Oster, “Architecting Spacecraft with SysML—A model-Based Systems Engineering Approach”, https://sysml-models.com/spacecraft/, accessed on Aug. 22, 2022.

(FriedenthalWolfrom 2010) S. Friedenthal, J. Wolfrom, “Modeling with SysML”, https:// www/jhuapl_edu/Content/software/ModelingwithSysMLTutorial .pdf, Tutorial presented at INCOSE 2010 Symposium, Chicago Ill., July 2010.

(NasaDigitalAssistants 2020), NASA, “T11.04Digital Assistants for Science and Engineering”, https:sbir.nasa.gov/lightbox/solicitation_subtopic/61721724, released on Jan. 18, 2020.

(NasaMeetCimon 2018) NASA, “Space to Ground: Meet CIMON: Jul. 6, 2018”, https://www.nasa.gov/mediacast/space-to-ground-meet-cimon-07062018, Jul. 5, 2018.

(MeetCimonNasa 2018) NASA, “Meet CIMON, the 1st Robot with Artificial Intelligence to Fly in Space”, https://www.space.com/41041-artificial-intelligence-cimon-space-exploration.html, Jun. 29, 2018.

(EricBrower 2019) Eric W. Brower, NASA JPL Systems Environment, Phoenix International Users' Conference, Annapolis Md., Apr. 17-19, 2018.

(KarbanCrawfordTrancho 2018) R. Karban, A. G. Crawford, G. Trancho, M. Zamparelli, S. Herzig, I. Gomes, M. Piette and E. Brower, “The OpenSE Cookbook: a practical, recipe based collection of patterns, procedures, and best practices for executable systems engineering for the Thirty Meter Telescope”, SPIE Digital Library, Jul. 10, 2018.

(AndrewKetsdever, 2019) Andrew Ketsdever, “MAE 5595 Space Mission Analysis”, http:// eas.uccs.edu/˜aketsdev/MAE%205595_files_UCC_Lecture%201_v2.pdf, Mar. 25, 2019.

(GerstenmaierCrusan 2022) W. Gerstenmaier, J. Crusan, “Cislunar and Gateway Overview”, Space Policy Directive-1, https://www.nasa.gov/sites/default/files/atoms/files/cislunar-update-gerstenmaier-crusan-v5a.pdf, accessed on Aug. 22, 2022.

(ChrisParedis 2022) C. Paredis, “System Analysis using SysML Parametrics: Current Tools and Best Practices, https://openmodelica.org/images/docs/modprod2011-tutorial/modprod/2011-tutorial4-Chris-Paredis-SysML-Parametrics.pdf, accessed on Aug. 22, 2022.

(ManjulaYagleReith 2017) M. Y. Ambur, J. J. Yagle, W. Reith, E. McLarney, “Big Data Analytics and Machine Intelligence Capability Development at NASA Langley Research Center: Strategy, Roadmap, and Progress”, NASA Technical Memorandum, http://ntrs.nasa.gov/citations/20170000676, published on Dec. 1, 2016, acquired on Jan. 20, 2017.

(AmburSchwartzMavris 2017) M. Ambur, K. G. Schwartz and D. N. Mavris, “Machine Learning Technologies and Their Applications for Science and Engineering Domains Workshop—Summary Report”, NASA Technical Memorandum, https://ntrs.nasa.gov/citations/20170000679, published on Dec. 1, 2016, acquired on Jan. 20, 2017.

(Rohaidi 2018)N. Rohaidi, “HowNASA Uses AI on Mars,” GovInsider, https://govinsider. asia/security/tom-soderstrom-jpl-nasadigital-assitants-curiosity-rover/, Jan. 31, 2018.

(Soderstrom 2019) T. Soderstrom, “A peek at artificial intelligence in action at NASA Jet Propulsion Laboratory,” The Enterprisers Project, https://enterprisersproject.com/article/2019/5/artificial-intelligence-jpl-nasa, May 9, 2019.

(MikolovChenCorrado 2021) T. Mikolov, K. Chen, G. S. Corrado and J. A. Dean, “Computing numeric representations of words in a high-dimensional space”, https://patents. google.com/patent/US10922488B1/, U.S. Pat. No. 10922488 B1, granted on Feb. 16, 2021.

(EckCassandraWellman 2020) Christopher R Eck, Cassandra L. Wellman and Jagannath Chirravuri, “Computational accelerator system, method and non-transitory machine-readable medium for facilitating change management of works in a model-based system engineering (mbse) system”, http://patents.google.com/patent/TW1711969B, Patent Application TW 1711969 B, granted on Dec. 1, 2020.

(QianWei 2022) Zhang Qiang and Wang Wei, “MB SE-based interlocking function defect analysis method and device and interlocking system”, https://patents.google.com/patent/CN109815124B/, Patent Application CN 109815124 B, granted on Feb. 15, 2022.

(OgnevHerreraTeague 2021) I. Ognev, K. M. Herrera Teague, “Information management in mbse modeling tools”, http://patents.google.com/patent/US20210357550A1/, Patent Publication No. US 2021/0357550 A1, published on Nov. 18, 2021.

(YapingZhijieLiangcong 2022) Li Yaping, Zhao Zhijie, Zhu Liangcong, Zhang Wenfeng, Mao Chengyuan, Liu Xiong, Feng Shuhong, Hong Rong, “FTA and FMEA integrated analysis method based on MBSE”, https://patents.google.com/patent/CN114218772A/. Patent Publication No. CN114218772A, published on Mar. 22, 2022.

(PeijieSanyuHongfei 2022) Zhu Peijie, Lu Sanyu, Ke Hongfei, Yang Tianheng, Xiong Shuangwu, Liang Jiawei, Yang Yue, Ma Daoyuan, Luo Shu, Ruan Caixia, “MBSE-based rocket small-loop rapid demonstration method and device”, https://patents.google.com/patent/CN114637665.A1, Patent Publication No. CN114637665A, published on Jun. 17, 2022.

(JinJunjunXiaoguang 2020) Xiao Jin, Chang Junjun, Hu Xiaoguang, Wang Shaojie and Chen Tianyou, “MBSE-based modeling simulation method for on-missile electrical system”, https://patents.google.com/patent/CN106774588A/, published on Jan. 10, 2020.

(LemaySabatelliAnzures 2019) S. O. Lemay, A. F. Sabatelli, F. A. Anzures, I. Chaudhri, S. Forstall, G. Novick, “Interface for a virtual digital assistant”, https://patents.google.com/patent/US20190220247A1/, US Patent ApplicationNo. US 2019/0220247 A1, published on Jul. 18, 2019.

(CranfillJonesKudurshian 2019) E. C. Cranfill, B. Jones, A. D. Kudurshian and H. J. Saddler, “Intelligent digital assistant in a multi-tasking environment”, https://patents.google.com/patent/AU2019213416B2/, Patent Application No. AU 2019213416 B2, granted on Nov. 21, 2019.

(ReddyHowardHarrison 2019) Mooni Reddy, Robert Jay Howard III, Deborah Harrison, Sogol Bimalekzadeh, “Interaction of digital personal digital assistants by reproduction, and rich multimedia in response”, https://patents.google.com/patent/JP6505117B2/, Patent Application No. JP 6505117 B2, Apr. 24, 2019.

(GruberPitschel 2019) T. R. Gruber and D. W. Pitschel, “User training by intelligent digital assistant”, https://patents.google.com/patent/AU2017221861B2/, Patent Application No. AU 2017221864 B2, granted on Jun. 20, 2019.

(PhippsGenaroShrum 2021) Benjamin S. Phipps and Genaro Prazingarokal F. Shrum, “Synchronization and task delegation of digital assistants”, https://patents.google.com/patent/KR1102304323B 1/, Patent Application No. KR 102304323 B1, granted on Sep. 23, 2021.

(FrazzingaroGargThomson 2022) G. Frazzingaro, A. Garg, B. Thomson, A. Kumar, R. N. Shah, M. S. Seigel and L. Li, “Feedback analysis of a digital assistant”, https://patents.google.com/patent/US11301477B2/, patent application Ser. No. 11/301,477 B2, granted on Apr. 12, 2022.

(ChristopherBaldwin 2022) C. F. Baldwin, “Method and apparatus for adjusting a digital assistant persona”, https://patents.google.com/patent/US11227312B2, patent application Ser. No. 11/227,312 B2, granted on Jan. 18, 2022.

(LangemyrBertilssonNordmark 2015) L. Langemyr, D. Bertilsson, A. Nordmark, P. O. Persson and J. Long, “Method for assembling the finite element discretization of arbitrary weak equations involving local or non-local multiphysics couplings”, https:/patents.google.com/patent/US8954302B2/, U.S. Pat. No. 8,954,302 B2, granted on Feb. 10, 2015.

(ArthurShapiro2013) Arthur B. Shapiro, “Thermal Fluid-Structure Interaction Simulation in Finite Element Analysis”, http://patents.google.com/patent/CN101833595B/, Patent No. CN 101833595B, granted on Mar. 27, 2013.

(CzingerBalzerPenmetsa 2021a) K. R. Czinger, W. B. Balzer, P. V. Penmetsa, Z. M. Omohundro, M. M. O'Brien, B. W. TenHouten and R. W. Hoyle, “Systems and methods for vehicle subassembly and fabrication”, https://patents.google.com/patent/US10960929B2, patent Ser. No. 10/960,929B2, granted on Mar. 30, 2021.

(CzingerBalzerPenmetsa 2021b) K. R. Czinger, W. B. Balzer, P. V. Penmetsa, Z. M. Omohundro, M. M. O'Brien, B. W. TenHouten and R. W. Hoyle, “Systems and methods for vehicle subassembly and fabrication”, https://patents.google.com/patent/US20210261197 A1/, Patent Application No. US 20210261197 A1, published on Aug. 26, 2021.

(GizziOwensPellegrino 2022) E. Gizzi, H. Owens, N. Pellegrino, C. Trombley, J. Marshall and J. Sinapov, “Autonomous System-Level Fault Diagnosis in Satellites Using Housekeeping Telemetry”, Small Satellite Conference, Logan Utah, Aug. 6, 2022.

(MelvilleHarleyLopez 2022) J. Melville, J. Harley, M. Lopez, M. Crabtree and S. Lacy, “Methods for Data-Centric Small Satellite Anomaly Detection”, Small Satellite Conference, Logan Utah, Aug. 6, 2022.

(HuangFerguson 2021) Y. Huang and P. A. Ferguson, “Automated Fault-Detection for Small Satellite Pointing Control Systems Using One-Sided Learning”, Small Satellite Conference, Logan Utah, August, 2021.

(FuchsMurillo 2021) C. M. Fuchs and N. M. Murillo, “Autonomous Fault-Tolerant Avionics for Small COTS Satellites: to Reality and Prototype”, Small Satellite Conference, Logan Utah, August, 2021.

(HalvorsonShortBush 2021) M. Halvorson, C. J. Short, A. Bush, B. Scruggs, J. Lazenby, S. Kilgore, S. Spearman, W. Garrison and P. Poe, “Model-Based Systems Engineering and F′: Proof of Concept Via the Creation of an On-Orbin Textual Command Parsing Component for the ABEX Mission”, Small Satellite Conference, Logan Utah, August, 2021.

(MenciaKoerksenYap 2021) P. Bernal-Mencia, K. Doerksen, C. Yap, “Machine Learning for Early Satellite Anomaly Detection”, Small Satellite Conference, Logan Utah, August, 2021.

(GilletteGeorgeCastle 2021) A. Gillette, A. George, J. P. Castle, “Design and Validation of an Autonomous Mission Manager towards Coordinated Multi-Spacecraft Missions”, Small Satellite Conference, Logan Utah, August, 2021.

(ObataAraiAsada 2021) T. Obata, M. Arai, S. Asada, T. Imaizumi and Y. Suzuki, “The Autonomous System Architecture of the Small SAR Satellite Operation System and Orbit Autonomous Operation Experiences”, Small Satellite Conference, Logan Utah, August, 2021.

(FugmannKlinker 2021) M Fugmann and S. Klinker, “An Automated Constellation Design & Mission Analysis Tool for Finding the Cheapest Mission Architecture”, Small Satellite Conference, Logan Utah, August, 2021.

(MasutaniGershomNunes 2020) M. Masutani, Y. B. Gershom and M. Nunes, “Model Based Systems Engineering Applied to a 3U CubeSat Case Study”, Small Satellite Conference, Logan Utah, August, 2020.

(SteingrimssonFanKulkarni 2020) B. Steingrimsson, X. Fan, A. Kulkarni, D. Kim and P. K. Liaw, Machine Learning to Accelerate Alloy Design, Utility Patent application Ser. No. 16,782,829, Publication No. US-2020-0257933-A1, https://patents.google.com/patent/US20200257933A1l, filed on Feb. 5, 2020.

(SzeYaoYi 2000) K. Y. Sze, L. Q. Yao and S. Yi, A Hybrid Stress ANS Solid-Shell Element and Its Generalization for Smart Structure Modeling. Part II—Smart Structure Modeling, International Journal for Numerical Methods in Engineering, Vol. 48, pp. 565-582, 2000.

(YiHiltonAhmad 1997) S. Yi, H. H. Hilton and M. F. Ahmad, A Finite Element Approach for Cure Simulation of Thermosetting Matrix Composites, Computers & Structures, Vol. 64, No. 1-4, pp. 383-388, 1997.

(Yi 1997) S. Yi, Finite Element Analysis of Free Edge Stresses in Nonlinear Viscoelastic Composites under Uniaxial Extension, Bending and Twisting Loadings, International Journal for Numerical Methods in Engineering, Vol. 40, p. 4225-4238, 1997.

(YiLingYing 1998) S. Yi, S. F. Ling and M. Ying, Finite Element Analysis of Composite Structures with Smart Constrained Layer Damping, Advances in Engineering Software, Vol. 29, No. 3-6, pp. 265 — 271, 1998.

(YiLingYing 1999) S. Yi, S. F. Ling, M. Ying, H. H. Hilton, and J. R. Vinson, Finite Element Formulation for Anisotropic Coupled Piezoelectro-Hygro-Thermo-Viscoelasto-Dynamic Problems, International Journal for Numerical Methods in Engineering, Vol. 45, pp. 1531-1546, 1999.

(YiLingYing 2000) S. Yi, S. F. Ling and M. Ying, Large Deformation Finite Element Analyses of Composite Structures Integrated with Piezoelectric Sensors and Actuators, Finite Elements in Analysis and Design, vol. 35, pp. 1-15, 2000.

(YiLingYing 2001) S. Yi, S. F. Ling and M. Ying, Time-Domain Analyses of Acoustics-Structure Interactions for Piezoelectric Transducers, Acoustical Society of America, Vol. 109, pp. 2762, 2001.

(LiuYiOng 2005) L. Liu, S. Yi, L. S. Ong, K. S. Chian, S. Osiyemi, S. H. Lim and F. Su, Chemothermal Modeling and Finite-Element Analysis for Microwave Cure Process of Underfill in Flip-Chip Packaging, IEEE Transactions on Electronics Packaging Manufacturing, Vol. 28, No. 4, pp. 355-363, 2005.

(TranChuaYi 2012) H. Tran, Y. F. Chua, S. Yi and P. Geng, Effects of Microstructure on Thermal Fatigue Life Prediction of Solder Joints, Proceedings of 14^{th} International Conference on Electronic Materials and Packaging, 2012.

(LamYi 2012) Effects of Molding Compounds on Warpage and Damage of PBGA after Post Mold Curve, Proceedings of 14^{th} International Conference on Electronic Materials and Packaging, 2012.

(Yi 2012) S. Yi, Finite Element Analysis of Inductive Proximity Sensors, Internal Report for Pepperl & Fuchs (MPG) PTE Ltd., 2012.

(Powell 1986) G. Powell and P. Chen, “3D Beam-Column Element with Generalized Plastic Hinges,” Journal of Engineering Mechanics, Vol. 112, No. 7, pp. 627-641, 1986.

(Larsa 2016) LARSA, “Larsa, Inc.,” 68 South Service Road, Suite 100, Melville, N.Y. 11747, 2016.

(RohSivaselvan 2009) A. M., Roh, H. S., Sivaselvan, M. V., Kunnath, S. K., Valles, R. E., Madan, A., Li, C., Lobo, R., and Park, Y. J. Reinhorn, “IDARC2D Version 7.0: A Program for the Inelastic Damage Analysis of Structures.,” Technical Report MCEER, University at Buffalo, SUNY, 2009.

(ABAQUS 2016) ABAQUS, “ABAQUS Student Edition,” Dassault Systemes Simulia Corp., Providence, R.I., USA, 2016.

(McKenna 2016) McKenna, F, Fenves, G, and Scott, M et. al., “The Open System for Earthquake Engineering Simulation,” Pacific Earthquake Engineering Research Center, University of California, Berkeley, Calif., USA., 2016.

(ADINA 2016) ADINA, “Automatic Dynamic Incremental Nonlinear Analysis,” ADINA R & D, Inc., 71 Elton Avenue Watertown, Mass. 02472, USA, 2016.

(PracticalFEA 2021) Practical FEA, “Different types of Non linearity in CAE/FEA|Abaqus”, https://www.youtuhc.com/watch?v=UJi93OOi2ao, Aug. 3, 2021.

(TrendingMechVideos 2018a) TrendingMechVideos, “Abaqus tutorials—Non Linear analysis of a Cantilever I-Beam”, https://www.youtube.com/watch?v=qwZ3301p9gM&t=100s, Jan. 14, 2018.

(TrendingMechVideos 2018b) TrendingMechVideos, “Abaqus tutorials—Non linear analysis of a Hollow Section(3D Solid)”, https://www.youtube.com/watch?v=4PXtQe0KN6Q, Jan. 9, 2018.

(TrendingMechVideos 2018c) TrendingMechVideos, “Abaqus Tutorial Videos—Non linear Analysis of Fixed Beam”, https://www.youtube.com/watch?v=oJliBpMNkaY, Mar. 20, 2018.

(EDRMedeso 2021) EDRMedeso, “Non-Linear Structural Analysis with ANSYS Mechanical Ansys Tutorial”, https://www.youtube.com/watch?v=ZljfZ70toyY, Apr. 19, 2021

(DrDalyO 2016) DrDalyO, “ANSYS 17.0 Tutorial—Non Linear Plastic Deformation I-Beam”, http://youtube.com/watch?v=mAZKGNcDDvs, Feb. 13, 2016.

(Tech.G.Ansys 2016) Tech. G, “Ansys|Static Structural|How To Create Simple Nonlinear Analysis”, https://www.youtube.com/watch?v=6QgwPg80IQs, Oct. 9, 2016.

(NguyenWaas 2016) N. Nguyen and A.M. Waas, “Nonlinear, finite deformation, finite element analysis”, Zeitschrift fur Angewandte Mathematik and Physik, Vol. 67, No. 35, 2016.

(BazantGattuVorel 2012) Z.P. Bazant, M. Gattu and J. Vorel, “Work conjugacy error in commercial finite-element codes: its magnitude and how to compensate for it”, Proceedings of the Royal Society A, Vol. 468, pp. 3047-3058, 2012.

(JiWaasBazant 2010a) W. Ji, A. M. Waas and Z. P. Bazant, “On the importance of work-conjugacy and objective stress rates in finite deformation incremental finite element analysis”, Journal of Applied Mechanics, Vol. 80, DOI: 10.1115/1.4007828, 2010.

(JiWaasBazant 2010b) W. Ji, A.M. Waas and Z.P. Bazant, “Errors caused by non-work-conjugate stress and strain measures and necessary corrections in finite element programs”, Journal of Applied Mechanics, Vol. 77, DOI: 10.1115/1.4000916, 2010.

(JiWaas 2010) W. Ji and A.M. Waas, “2d elastic analysis of the sandwich panel buckling problem benchmark solutions and accurate finite element formulations”, Zeitschrift fur Angewandte Mathematik and Physik, Vol. 61, pp. 897-917, 2010.

(VorelBazantGattu 2013) J. Vorel, Z. P. Bazant and M. Gattu, “Elastic soft-core sandwich plates: critical loads and energy errors in commercial codes due to choice of objective stress rate”, Journal of Applied Mechanics, Vol. 80, 2013.

(BazantVorel 2014) Z. P. Bazant and J. Vorel, “Energy-conservation error due to use of green-naghdi objective stress rate in commercial finite-element codes and its compensation”, Journal of Applied Mechanics, Vol. 81, DOI: 10.1115/1.4024411, 2014.

(VorelBazant 2014) J. Vorel and Z.P. Bazant, “Review of energy conservation errors in finite element softwares caused by using energy-inconsistent objective stress rates”, Advances in Engineering Software, Vol. 72, pp. 3-7, 2014.

(SAP 2000) SAP 2000, “SAP2000 Integrated Finite Element Analysis and Design of Structures,” Computers and Structures, Inc, 1646 N. California Blvd., Suite 600 Walnut Creek, Calif. 94596 USA, 2016.

(MichaelHopper 2009) Michael W. Hopper, “Analytical Models for the Nonlinear Seismic Response of Reinforced Concrete Frames”, https://etda.libraries.psu.edu/files/final_submissions/4432, Master of Science thesis, submitted to the Graduate School of the College of Engineering at the Pennsylvania State University, December, 2009.

(ComputersAndStructuresInc 2014) Computers and Structures Inc., “SAP2000-29 Fast Nonlinear Analysis: Watch & Learn”, https://www.youtube.com/watch?v=ufbFG9e4yjU, May 12, 2014.

(ComputersAndStructuresInc 2011) Computers and Structures Inc., “SAP2000-20 Nonlinear Shear Walls: Watch & Learn”, http://www.youtube.com/watch?v=Y7z6IYxF-eQ, Nov. 23, 2011.

(OpenSees 2022) OpenSees, “What Is OpenSees”, https://opensees.berkeley.edu/, accessed on Aug. 16, 2022.

(Risa3d 2022) RISA, “RISA-3D Versatile Solution for Any Structure”, https://risa.com/products/risa-3d, accessed on Aug. 16, 2022.

(Staad.Pro 2022) Wikipedia, “STAAD”, https://en.wikipedia.org/wiki/STAAD, accessed on Aug. 16, 2022.

(Etabs.Sap 2022) The Engineering Community, “Comparison between ETABS and SAP 2000”, https://www.theengineeringcommunity.org/comparison-between-etabs-and-sap2000/, accessed on Aug. 16, 2022.

(BentleyRamSS 2022) Bentley, “RAM Structural System”, https://www.bentleysoftware. lk/pdf/8/5.pdf, accessed on Aug. 16, 2022.

(HuynhKnezevicPateraLi 2015) D. B. P. Huynh, D. J. Knezevic, A. T. Patera and H. Li, “Methods and apparatus for constructing and analyzing component-based models of engineering systems”, http://patents.google.com/patent/US9213788B2/, granted on Dec. 15, 2015.

(KimDaeJung 2006) Kim Dae-Jung, “Structural analysis method of continuous beam”, https://patents.google.com/patent/KR100561778B1/, granted on Mar. 16, 2006.

(StevenJamsBungiorno 2012) Steven James Bungiorno, “Method and apparatus for increasing the energy dissipation of structural elements”, https://patents.google.com/patent/US8215068B2/, granted on Jul. 10, 2012.

(ShucaiZuqingYanming 2020) Le Shucai Zhou Zuqing Zhu Yanming Gao Peijun, “Mechanical Analysis Method for Semi-rigid Performance of Externally Decorated Column Casing Connections”, http://patents.google.com/patent/CN10750653B/, granted on Oct. 30, 2020.

(ChenHauserBoyle 2015) Shen-En Chen, Edwin W. Hauser, Charles G. Boyle, Meenu Natarajan, “Method and system for remotely inspecting bridges and other structures”, https://patents.google.com/patent/US9036861B2/, granted on May 19, 2015.

(ParkerPayne 2019) David H. Parker, John M. Payne, “Methods for measuring and modeling the process of prestressing concrete during tensioning/detensioning based on electronic distance measurements”, https://patents.google.com/patent/US10203268B/, granted on Feb. 12, 2019.

(BouzinovBelyi 2016) Pavel A. Bouzinov and Mikhail Belyi, “Effectively solving structural dynamics problems with modal damping in physical coordinates”, http:patents.google.com/patent/US10061878B2/, granted on Aug. 28, 2018.

(YoungChaWooramChoi 2021) Young Jin Cha, Wooram Choi, “Structure defect detection using machine learning algorithms”, https://patents.google.com/patent/US11144814B2/, granted on Oct. 12, 2021.

(ThomasWinantAlanJeary 2021) Thomas Arthur Winant and Alan Peter Jeary, “System and method for determining the risk of failure of a structure”, https://patents.google.com/patent/US10928271B2/, granted on Feb. 23, 2021.

(NigelJohnGreenwood 2020) Nigel John Conrad Greenwood, “System and method for modelling system behaviour”, https://patents.google.com/patent/US20200302094A1/, published on Sep. 24, 2020.

(SolidworksAPl 2015) Solidworks API, “What does it take to learn the Solidworks API?,” http://swapi.wordpress.com/, Dec. 26, 2015.

(Solidworks 2015) Solidworks, “API Support,” https://www.Solidworks.com/sw/support/ api-support.htm, Dec. 26, 2015.

(ApiSupport 2015) API Support, “API Wizards Online,” http://support.ptc.com/suport/apiwizard.htm, Dec. 26, 2015.

(SolidworksSetMaterialExample 2022) SolidWorks API Help, “Set Materila Example (C#)”, https://help.solidworks.com/2018/english/api/sldworksapi/Set_Material_Example_CSharp.htm, accessed on Sep. 4, 2022.

(SolidworksExtractBomSldDrw 2022) SolidWorks, “API: Extracting a derived BOM for a .slddrw file (C#)”, https://forum.solidworks.com/thread/200192, accessed on Sep. 4, 2022.

(SolidWorksTraverseAssembly 2022) SolidWorks API Help, “Traverse Assembly Example (C++ COM”, https://help.solidworks.com/2016/english/api/sldworksapi/traverse_assembly_example_cplusplus_com_htm, accessed on Sep. 6, 2022.

(SolidWorksGetComponentList 2022) SolidWorks, “How can I get Component list in the order of design tree”, https://forum.solidworks.com/thread/40159, accessed on Sep. 6, 2022.

(SolidWorksTraverseAssembly 2022) SolidWorks API Help, “Traverse Assembly at Component Level Example (VBA)”, https://help.solidworks.com/2015/english/api/sldworksapi/traverse_assembly_at_component_level_example_vb_htm, accessed on Sep. 6, 2022.

(SolidWorksMassProperties 2022) SolidWorks API Help, “Mass Properties”, http://help. solidworks.com/2018/english/api/sldworkapiprogguide/Overview/Mass_Properties.htm, accessed on Sep. 6, 2022.

(SolidWorksGetMassProperties 2022) SolidWorks API Help, “Get Mass Properties of Multibody Assembly Component Example (C#)”, http://help.solidworks.com/2018/english/api/sldworksapi/Get_Mass_Properties_of_Multibody_Assembly_Component_Example_CSharp.htm, accessed on Sep. 6, 2022.

(SolidWorksGetMassPropMethod 2022) SolidWorks API Help, “GetMassProperties Method (ISwDMConfiguration)”, http://help.solidworks.com/2018/english/api/swdocmgrapi/SolidWorks.Interop.swdocumenting˜SolidWorks.Interop.swdocumentmgr. ISwDMConfiguration˜GetMassProperties.html, accessed on Sep. 6, 2022.

(SolidWorksGettingStarted 2022) SolidWorks API Help, “Getting Started”, https://help.solidworks.com/2018/English/api/swdocmgrapi/GettingStarted-swdocmgrapi. html?id=fa2eb5edca4f469d9bf5957eda976dca#Pg0, accessed on Sep. 6, 2022.

(SolidWorksBomOverview 2022) SolidWorks Help, “Bill of Materials Overview”, https://help.solidworks.com/2018/english/SolidWorks/sldworks/c_Bill_of_Materials1/htm?verRe direct=1, accessed on Sep. 7, 2022.

(SolidWorksGetComponents 2022) SolidWorks API Help, “Get Components in Each BOM Table Row Example (C#)”, https://solidworks.com/2018/english/api/sldworksapi/Get_Components_in_Each_BOM_Table_Row_Example_CSharp_htm, accessed on Sep. 7, 2022.

(SolidWorksGetMatesExample 2022) SolidWorks API Help, “Get Mates Example (C#)”, https://solidworks.com/2018/english/api/sldworksapi/Get_Mates_Example_CSharp.htm, accessed on Sep. 7, 2022.

(SolidWorksGetFeatureReversed 2022) SolidWorks API Help, “Get Features in Reverse Order Example (C#)”, http://solidworks.com/2018/engish/api/sldworksapi/Get_Feature_in_Reverse_Order_Example_CSharp.htm, accessed on Sep. 7, 2022.

(SolidWorksGetSaveFlag 2022) SolidWorks API Help, “GetSaveFlag Method (IModelDoc2)”, http://help.solidworks.com/2019/english/api/sldworksapi/SOLIDWOKS, Interop.sldworks˜SOLIDWORK.Interop.sldworks.IModelDoc2˜GetSaveFlag.html, accessed on Sep. 7, 2022.

(SolidWorksDetermineDocumentDirty 2022) SolidWorks API Help, “Determine if Document is Dirty Example (VBA)”, https://help.solidwoks.com/2019/english/api/sldworksapi/SOLIDWORKS.Interop.sldworks˜SOLIDWORKS.Interop.sldworks.IModelDoc2˜GetSaveFlag, html, accessed on Sep. 7, 2022.

(SolidWorksIBody2Interface 2022) SolidWorks API Help, “IBody2 Interface Members”, https://help.solidworks.com/2020/english/api/sldworksapi/SolidWorks.Interop.sldworks˜SolidWorks.Interon.sldworksIBody2_member.html, accessed on Sep. 7, 2022.

(SolidWorksIComponent2Interface 2022) SolidWorks API Help, “IComponent2 Interface Members”, http://help.solidworks.com/2017/english/api/sldworksapi/solidworks.interop. sldworks˜solidworks.interop.sldworks.icomponent2_members.html, accessed on Sep. 7, 2022.

(SolidWorksIModelDoc2Interface 2022) SolidWorks API Help, “IModelDoc2 Interface”, https://help.solidworks.com/2020/Englsh/api/sldworksapi/SOLIDWORKS.Interop.sldworks˜SOLIDWORKS.Interop.sldworks/IModelDoc2.html, accessed on Sep. 7, 2022.

(SolidWorksVisibleProperty 2022) SolidWorks API Help, “Visible Property (ISldWorks)”, http://help.solidworks.com/2018/english/api/sldworksapi/solidworks.interop.sldwo rks˜solidworks.interop.sldworks.isldworks˜visigle.html, accessed on Sep. 8, 2022.

(SolidWorksGetBoxMethod 2022) SolidWorks API Help, “GetBox Method (IAssemblyDoc)”, https://help.solidworks.com/2018/english/api/sidworksapi/solidworks.interop. Sldworks˜solidworks.interop.sldworks.iassemblydoc˜getbox.html, accessed on Sep. 8, 2022.

(SolidWorksUnits 2022) SolidWorks API Help, “Units”, http://help.solidworkscom/2018/english/api/sldworksapiprogguide/overview/units.htm, accessed on Sep. 8, 2022.

(SolidWorksTessellation 2022) SolidWorks API Help, “Tessellate a Body Example (C#)”, https://help.solidworks.com/2018/english/api/sldworksapi/Tessellate_a_Body_Example_CSharp.htm, accessed on Sep. 8, 2022.

(MikeSpens 2017) Mike Spens, “Automating SolidWorks 2017 Using Macros”, 1^{st} edition, http://www.amazon.com./Automating-SOLIDWORKS-2017-Using-Macros/dp/1630570842, 2017.

(ObjectARX 2015) AutoDesk Network, “ObjectARX,” http://usa.autodesk.com/adsk/serlet/index?siteID=123112&id=773204, Dec. 26, 2015.

(CatiaV5 2015) ENG-TIPS.com, “Catia V5 Plug-in Developement Documentation?,” http://www.eng-tips.com/viewthread.cfm?qid=345694, Dec. 26, 2015.
(StackOverflow 2015), “Accessing parts with Abaqus ODB C++ API,” http:// stackoverflow.com/questions/11782417/accessing-parts-with-abaqus-odb-c-api , Dec. 26, 2015.

(ParaView 2015) ParaView, “ParaView for Structural Analysis,” http://www.paraview. org.structural-analysis/, Dec. 9, 2015.

(CdAdapco 2015) CD-Adapco, “JAVA™ Scripting—Process Automation,” http://www3.cd-adapco.com/training/course/java_scriping_process_automation.html, Dec. 26, 2015.

(Pole 2015) POLE, “Portable Library for Structured Storage,” http://www.dimin. net/software/pole/, Dec. 23, 2015.

(ANSYS 2015) ANSYS, “ANSYS Basic Analysis Procedures Guide,” http://mostreal.sk/html/guide_55/g-bas/ GBAS18.htm, Dec. 26, 2015.

(DassaultDevGuide 2016) Dassault Systemes, “Developer's Guides,” http:/www.3ds. com/support/documentation/developers-guides!, Jan. 25, 2016.

(PtcCreo 2016) PTC University Learning Exchange, “All PTC Creo Tutorials,” http://learningexchange.ptc.com/tutorials/by_product/product_id:1, Jan. 27, 2016.

(AutoDesk 2013) AutoDesk 2013, “User's Guide,” http://docs.autodesk.com/ACDMAC/2013/ENU/PDFs/acdmac_2013_users_guide.pdf, Jan. 25, 2016.

(Abaqus 2016) ABAQUS 6.13, “Abaqus Scripting User's Guide,” https://dsk.ippt-pan.pl/docs/abaqus/v6.13/books/cmd&default_htm, Jan. 22, 2016.
(Ansys 2015) ANSYS, “Customizing ANSYS Workbench,” https://support.ansys.com/ staticassets/ANSYS/Conference/Houstion/downloads/Customizinig%20ANSYS%20Workbench.pdf, Dec. 26, 2015.

(DassaultSystemes 2017) Dassault Systemes, “Importing Geometry”, http://help. Solidworks.com/2012/English/Solidworks/sldworks/Importing_Geometry.htm, Jun. 16, 2017.

(CdAdapco 2016) CD-Adapco, “The Steve Portal,” https://steve.cd-adapco.com/Site_Login, Jan. 25, 2016.

(OpenCascade 2015) Open Cascade, “Home,” http://www.opencascade.com/, Dec. 26, 2015.

(LibreCAD 2015) LibreCAD, “Adding DWG Support,” http://blog.librecad.org/2011/04/adding-dwg--support/, Dec. 26, 2015.

(GNU 2015) GNU Operating System, “GNU LibreDWG,” http://www.gnu.org/software/libredwg/, Dec. 26, 2015.

(SourceForge 2015) SourceForge, “OpenDWG,” http://sourceforge.net/projects/opendwg/, Dec. 26, 2015.

(abapy 2015) abapy, “Tutorial,” http://abapy.readthedocs.org/en/lastest/tutorial.html #introduction, Dec. 26, 2015.

(FreeCAD 2015) FreeCAD, “Welcome!,” http://www.freecadweb.org/, Dec. 26, 2015.

(WikipediaCOM 2022) Wikipedia, “Component Object Model,” https://en.wikipedia.org/wiki/Component_Object_Model, Sep. 3, 2022.

(OpenFOAM 2015) OpenFOAM, “Free Open Source CFD,” http://www.openfoam.org/, Dec. 26, 2015.

(SiemensProgramming 2022) Siemens, “NX 10 Programming Tools Help”, https://docs. plm.automation.siemens.com/tdoc/nx/10/nx_api#uid:index, accessed on Aug. 17, 2022.

(BelegaRay 2017) B. Belega, H. C. Manglekar, and T. Ray, “Effects of axial-shear-flexure interaction in static and dynamic responses of steel beams,” Journal of Constructional Steel Research,Vol 131, pp. 83-93, 2017.

(MicrosoftCOM 2018) Microsoft, COM, https://docs.microsoft.com/en-us/windows/desktop/com, 2018.

(MicrosoftDeveloper 2018) Microsoft Developer Network, “Introduction to COM and ATL”, https://msdn.microsoft.com/en-us/library/727z646z.aspx, 2018.

(DassaultSystemes 2018) Dassault Systemes, “SolidWorks API Help”, http://help. solidworks.com/2018/english/api/sldworksapiprogguide/welcome.htm, 2018.

(DassaultSystemesSolidWorks 2018) Dassault Systemes, “SolidWorks Document Manager API Help”, http://help.solidworks.com/2018/english/api/SWHelpList.html?id=3dc7dc25cf854e1e989e3253af3ae87 e#Pg0, 2018.

(DassaultVirtualComponents 2018) Dassault Systemes, “Virtual Components”, http://help.solidworks.com/2018/english/solidworks/sldworks/c_vc_virtual_components_overiew.htm, 2018.

(EsriDeveloperNetwork 2018) ESRI Developer Network, IObjectFactory Interface, http://edndoc.esri.com/arcobjects/9.2/ComponentHelp/esriFramework/IOjectFactory.htm, 2018.

(NoMagicDeveloperGuide 2022) No Magic, “No Magic Product Developer Guide”, https://docs.nomagic.com/display/MD184/Developer+Guide, accessed on Aug. 23, 2022.

(NoMagicJavaDocs 2022) No Magic, “Java Docs”, http://jdocs.nomagic.com/184/, accessed on Aug. 23, 2022.

(Word2Vec 2022) Wikipedia, “Word2Vec”, https://en.wikipedia.org/wiki/Word2vec, accessed on Aug. 19, 2022.

(SemanticSimilarity 2022) Wikipedia, “Semantic similarity”, https://en.wikipedia.org/wiki/Semantic_simiarity, accessed on Aug. 19, 2022.

(CosineSimilarity 2022) Wikipedia, “Cosine similarity”, https://en.wikipedia.org/wiki/Cosine_similality, accessed on Aug. 19, 2022.

(WordEmbedding 2022) Wikipedia, “Word embedding, https://en.wikipedia.org/wiki/Word_embedding, accessed on Aug. 19, 2022.

(MarinovCharrotFurutua 2021) M. C. Marinov, P. H. Charrot, S. Furuta, N. Santhanam, J. N. Hallet, S. A. Barley, J. A. Flower, G. T. Finnigan, S. N. Meshkat, I. E. Henley, T. W. Barback, M. Sapun, M. Amagliani, P. Wolski, “Conversion of generative design geometry to editable and watertight boundary representation in computer aided design”, https://patents.google.com/patent/US20210232120A1/, US patent application no. US 20210232120 A1, published on Jul. 29, 2021.

(WillisMorrisBastian 2020) K. D. D. Willis, N. J. W. Morris, A. L. Bastian, A. A. T. Butscher, D. Grandi, S. Furuta, J. G. Lambourne, T. W. Barback, M. C. Marinov, M. Amagliani, J. J. Chen, M. A. Smell, B. M. Frank, H. Shayani, C. M. Wade, N. Santhanam, “Boundary based generative design with 2.5-axis subtractive manufacturing constraint for computer aided design and manufacturing”, https://patents.google.com//patent/WO2020097578A2/, Intentational patent application no. WO 2020097578 A2, published on May 14, 2020.

(DallowroSlavinSrivastavarusia 2021) L. Dallowro, E. Slavin III, S. Srivastavarusia, L. Mirabella, S. R. Muvati, A. M. Canedo and E. Arisoi, “A system for automated generative design synthesis using data from design tools and knowledge from digital twin graphs”, https://patents.google.com/patent/KR102257939B1/, Korean patent application no. KR 102257939 B1, granted on May 27, 2021.

(StraterFurutaSchneider 2021) J. T. Strater, S. Furuta, K. J. Schneider, B. M. Frank, M. A. Smell, J. A. Flower, N. Santhanam, “Facilitated editing of generative design geometry in computer aided design user interface”, https://patent.google.com/patent/US10896541B2/, US patent application no. U.S. Pat. No. 10,896,541 B2, granted on Jan. 19, 2021.

(BandaraShayaniSzkurlat 2022) K. M. K. Bandara, H. Shayani, D. L. Szkurlat, “Generative design shape optimization with controlled convergence for computer aided design and manufacturing”, http://patents.google.com.patent/US20220004682A1/, US patent application no. US 20220004682 A1, published on Jan. 6, 2022.

(GrossmanBradnerFitzmaurice 2022) Tovi Grossman, Erin Bradner, George Fitzmaurice, Ali Baladaran Hashemi, Michael Gluck, Justin Frank Mateika, “Techniques for Visualizing and Exploring Large-Scale Generative Design Datasets”, https://patents.google.com/patent/JP7030211B2/, Japanese patent application no. JP 7030211 B2, granted on Mar. 4, 2022.

(HillerBlankenship 2021) Jonathan Hiller and Jesse C. Blankenship, “Chained Iterative Application of Computer Aided Generative Design for Optimized Geometries”, https://patents.google.com/patent/US20210216674A1/, US patent application no. US 20210216674 A1, published on Jul. 15, 2021.

(StoddartBenjaminNagy 2019) James Stoddart, David Benjamin, Danil Nagy, Damon Lau, “Generative design techniques for automobile designs”, https://patents.google,com/patent/US20190347382A1/, US patent application no. US 20190347382 A1, published on Nov. 14, 2019.

(BenjaminNagy 2022) D. Benjamin and D. Nagy, “Generative design for architecture”, https://patents.google.com/patent/US11308246B2/, US patent application no. U.S. Pat. No. 11,308,246 B2, granted on Apr. 19, 2022.

(AndersonGrossman 2021) F. Anderson, T. Grossman and G. Fitzmaurice, “Trigger-action-circuits: leveraging generative design to enable novices to design and build circuitry”, https://patents.google.com/patent/US11113439B2, US patent application no. U.S. Pat. No. 11,113,439 B2, granted on Sep. 7, 2021.

(FanJiang 2021) J. A. Fan, J. Jiang, “Systems and Methods for Generative Models for Design”, https://patents.google.com/patent/US20210390396A1/, US patent publication no. US 2021 0390396 A1, published on Dec. 16, 2021.

(AndersonCorosDesai 2020) F. Anderson, S. Coros, R. Desai, T. Grossman, J. F. Matejka, G. Fitzmaurice, “Generative design techniques for robot behavior”, https:/patents.google.com/patent/US20200030988A1/, US patent publication no. US 2020 0030988 A1, published on Jan. 30, 2020.

(CheongEbrahimilorio 2021) H. Cheong, M. Ebrahimi, F. Iorio, A. Butscher, “Techniques for applying generative design to the configuration of mechanical assemblies”, https://patents.google.com/patent/US2020157965A1/, US patent publication no. US 2021 0157965 A1, published on May 27, 2021.

(KuniakvskyAkionaChen 2021a) Michael Kuniaysky, Nicholas Akiona, Michael Nai-An Chen, “Generating style grammars for generative design”, https://patents.google. com/patent/US20210286921A1/, US patent publication no. US 2021 0286921 A1, published on Sep. 16, 2021.

(KuniakvskyAkionaChen 2021b) Michael Kuniaysky, Nicholas Akiona, Michael Nai-An Chen, “Generative design using style grammars”, https://patents.google.com/patent/US20210279377A1/, US patent publication no. US 2021 0279377 A1, published on Sep. 9, 2021.

(EomBurlaRodriguez 2021) J. Eom, R. K. Burla, J. Rodriguez, B. McKittrick Weiss, N. Li, “Computer aided generative design with filtering to facilitate 2.5-axis subtractive manufacturing processes”, https://patents.google.com/patent/WO2021236054A1, patent publication no. WO 2021 236054 A1, published on Nov. 25, 2021.

(EomBurlaRodriguez 2022) J. Eom, R. K. Burla, J. Rodriguez, B. McKittrick Weiss, N. Li, “Computer aided generative design with filtering to facilitate 2.5-axis subtractive manufacturing processes”, https//patents.google.com/patent/US20210356939A1/, patent publication no. US 2021 0356939 A1, granted on Aug. 9, 2022.

(HarrisBandaraSzkurlat 2022) A. J. Harris, K. M. K. Bandara, D. L. Szkurlat, A. A. T. Butscher, A. C. K. Y. Ruto, “Generative design shape optimization with damage prevention over loading cycles for computer aided design and manufacturing”, https://patents.google.com/patent/ U.S. Pat. No. 11,321,508B2/, US patent publication no. U.S. Pat. No. 11,321,508 B2, published on Jan. 6, 2022.

(BandaraRutoMorris 2022) K. M. K. Bandara, A. C. K. Y. Ruto, N. J. W. Morris, A. G. L. Jones, “Generative design shape optimization with singularities and disconnection prevention for computer aided design and manufacturing”, https://patents.google.com/patent/ US20220091580A1/, US patent publication no. US 2022 0091580 A1, published on Mar. 24, 2022.

(WeinbergKim 2021) David Jon Weinberg and Nam Ho Kim, “Computer aided generative design with layer boundary determination to facilitate 2.5-axis subtractive manufacturing processes”, http://patents.google.com/patent/US2021036500A1/, US patent publication no. US 2021 0365004 A1, published on Nov. 25, 2021.

(KimWeinberg 2022) Nam Ho Kim and David Jon Weinberg, “Computer aided generative design with tool size control to facilitate 2.5-axis subtractive manufacturing processes”, https://patents.google.com/patent/US11243510B2/, U.S. Pat. No. 11,243,510B2, granted on Feb. 8, 2022.

(HarrisGroomBandara 2022) A. J. Harris, A. I. Groom, K. M. K. Bandara, A. A. T. Butscher, D. L. Szkurlat, “Generative design shape optimization using build material strength model for computer aided design and manufacturing”, https://patents.google.com/patent/US20220004679A1/, US patent publication no. US 2022 0004679 A1, published on Jan. 6, 2022.

(SubramaniyanBaruaErno 2021) A. K. Subramaniyan, A. Barua, D. Erno, “Framework for rapid additive design with generative techniques”, https://patents.google.com/patent/US11079738B2/, U.S. Pat. No. 11,079,738B2, granted on Aug. 3, 2021.

(BurlaEomRodriguez 2021) R. K. Burla, J. Eom, J. Rodriguez, “Computer aided generative design with overall thickness control to facilitate manufacturing and structural performance”, http://patents.google.com/patent/US20210350036A1/ US patent publication no. US 2021 0350036 A1, published on Nov. 11, 2021.

(WhitneyChenOsinga 2021) Violet Whitney, Difei Chen, Douwe Osinga, Kabir Soorya, Jack Amadeo, Brian Ho, Okalo Ikhena, Amanda Meurer, Samara Trilling, Dan Vanderkam, “Methods, systems, and media for modifying open space access using generative design”, https://patents.google.com/patent/US20210148710A1/, US patent publication no. US 2021 0148710 A1, published on May 20, 2021.

(EomRodriguezWeinberg 2022) J. Eom, J. Rodriguez, D. J. Weinberg, S. N. Meshkat, J. Dalidd, R. K. Burla, “Application of boundary conditions on voxelized meshes in computer aided generative design”, http://patents.google.com/patent/US20220067240A1/, US patent publication no. US 2022 0067240 A1, published on Mar. 3, 2022.

(BandaraWillisHarrisBanadyga 2020) K. M. K. Bandara, K. D. D. Willis, A. J. Harris, A. Banadyga, A. A. T. Butscher, H. Shayani, “Hollow topology generation with lattices for computer aided design and manufacturing”, https://patents.google.com/patent/US10635088B1/, US publication U.S. Pat. No. 10,635,088 B1, published on Apr. 28, 2020.

(CheongEbrahimi 2022) Hyunmin Cheong, Mehran Ebrahimi, “Generative design techniques for soft robot manipulators”, https:patents.google.com/patent/EP3978209A1/, European patent publication no. EP3978209A1, published on Apr. 6, 2022.

(Benj aminStoddartVillaggi 2021) David Benjamin, James Stoddart, Lorenzo Villaggi, Danil Nagy, “Generative design pipeline for urban and neighborhood planning”, https:/patents.google.com/patent/US20210374298A1/, US patent publication no. US20210374298A1, published on Dec. 2, 2021.

(GrauHarris 2021) M. Grau, A. J. Harris, “Generative shell design for simulations”, http://patents.google.com/patent/US20210224432A1/, US patent publication no. US20210224432A1, published on Jul. 22, 2021.

(ChenOsingaIkhena 2022) D. Chen, D. Osinga, O. Ikhena, V. Whitney and J. Amadeo, “Methods, systems, and media for generative urban design with spreadsheet and model integration features”, https://patents.googie.com/patent/US20220114294A1/, US patent publication no. US 2022 0114294 A1, published on Apr. 14, 2022.

(BianchiAgrawalHaobsh 2022) T. Bianchi, R. Agrawal and S. Haobsh, “Methods, systems, and media for generative urban design with user-guided optimization features”, https://patents.google.com/patent/US20220114293A1 /, US patent publication no. US 2022 0114293 A1, published on Apr. 14, 2022.

(RazzellEdwardsRogers 2021) M. R. Razzell, L. Edwards, N. D. Rogers, H. Shayani, “3D geometry generation for computer aided design considering subtractive manufacturing forces”, https://patents.google.com/patent/US11200355B2/, U.S. Pat. No. 11,200,355B2, granted on Dec. 14, 2021.

(TrivediNourbakhshBergin 2022) A. Trivedi, M. Nourbakhsh, M. Bergin, F. Iorio, “Simplifying designs of mechanical assemblies via generative component consolidation”, http://patents.google.com/patent/US11281819B2/, U.S. Pat. No. 11,281,819B2, granted on Mar. 22. 2022.

(CheongFitzmauriceGrossman 2021) H. Cheong, G. Fitzmaurice, T. Grossman, R. H. Kazi, A. B. Hashemi, “Three-dimensional generative design based on two-dimensional sketching”, https://patents.google.com/patent/US11113865B2/, U.S. Pat. No. 11,113,865B2, granted on Sep. 7, 2021.

(SrivastavaGruenewaldGrimm 2020) S. Srivastava, T. Gruenewald, S. Grimm, P. Gocev, L. Dalloro, A. Haselböck, G. Havur, D. Smirnov, M. Ringsquandl, D. S. Cao, “Machine learning-based generative design for process planning”, patent publication no. WO2020167316A1, published on Aug. 20, 2020.

(GavačováGulan 2016) Jana Gava6ova, Martin Gulan, “Involvement of the generative design system of shaped parts”, https://patent.google.com/patents/SK7489Y1/, patent publication no. SK7489Y1, published on Jul. 1, 2016.

(DaviesHaleyDanielyan 2021) Thomas Davies, Michael Haley, Ara Danielyan, Morgan FABIAN, “Shaped-based techniques for exploring design spaces”, https://patents.google.com/patent/US11126330B2/, U.S. Pat. No. 11,126,330B2, granted on Sep. 21, 2021.

(LafreniereGrossmanWeingarten 2020) B. Lafreniere, T. Grossman, A. Weingarten, G. Fitzmaurice, “Computer-aided techniques for iteratively generating designs”, https://patents.google.com/_patent/US20200242201A1/, US patent publication no. US 2020 0242201 A1, published on Jul. 30, 2020.

(MingdongYelin 2022) Z. Mingdong, S. Yelin, “A Generative Design Method for Plane Mechanisms with a Given Motion Trajectory”, https://patents.google.com/patent/CN110427672, China patent no. CN110427672B, granted on Feb. 11, 2022.

(BenjaminZhaoVillaggi 2021) D. Benjamin, D. Zhao, L. Villaggi, “Generative design techniques for multi-family housing projects”, https://patents.google.com/patent/US20210150085A1/, US patent publication no. US 202 10150085 A1, published on May 20, 2021.

(YuHallet 2022) Huagang Yu, Justin Nicholas Hallet, “Topology optimization of structure with multiple targets”, https://patents.google.com/patent/US11288417B2/, U.S. Pat. No. 11,288,417 B2, granted on Mar. 29, 2022.

(ChalupkaBeebeDonnelly 2020) K. Chalupka, C. Beebe, J. Donnelly, D. A. Teegarden, J. Venugopalan, S. Srivastava, L. Mirabella, S.R. Musuvathy, “Computerized system and method for generative circuit design with machine-learned networks”, https://patents.google.com/patent/WO2020185207A1/, patent application no. WO2020185207A1, published on Sep. 17, 2020.

(AndersonDavisFitzmaurice 2022) F. Anderson, J. Davis, G. Fitzmaurice, T. Grossman, M. Stroetzel, “Artificial intelligence-based techniques for design generation in virtual environments”, https:patents.google.com/patent/US20220067228A1/ US patent publication no. US 2022 0067228 A1, published on Mar. 3, 2022.

(DaviesHaleyDanielyan 2020) T. Davies, M. Haley, A. Danielyan, M. Fabian, “Shaped-based techniques for exploring design spaces”, https://patents.google.com/patent/US20200134909A1/, US patent publication no. US 2020 0134909 A1, published on Apr. 30, 2020.

(DaviesHaleyDanielyan 2021) T. Davies, M. Haley, A. Danielyan, M. Fabian, “Shaped-based techniques for exploring design spaces”, htttps://patents.google.com/patent/EP3874395A1/, Europenpatent publication no. EP3874395A1, published on Sep. 8, 2021.

(DaviesHaleyDanielyan 2022) T. Davies, M. Haley, A. Danielyan, M. Fabian, “Shaped-based techniques for exploring design spaces”, https://patents.google.com/patent/US11380045B2/, U.S. Pat. No. 11,380,045B2, patent granted on Jul. 5, 2022.

### SUMMARY OF THE INVENTION

This invention expands upon the e-design assessment engine described in (SteingrimssonKulkarni 2020). We refer to the generalized assessment engine as an Engine for Automatic Design Assessment and Smart Analysis.

For accreditation of engineering programs by ABET, engineering programs must have documented student outcomes that support the program educational objectives (ABET 2019). Automatic assessment of students' work against ABET learning outcomes (1 through 7) helps engineering programs prepare the data needed for ABET reporting and evaluation. Such assessment helps improve the productivity of instructors of design classes as well as of engineering departments, by reducing the time it takes to prepare the data needed for ABET reporting and evaluation.

This innovation, furthermore, extends present SysML's capabilities in terms of automatic verification of engineering requirements through interaction, based on a parametric model, or through a margin block (Paredis 2018), (Wolfrom 2018), by providing a plugin formulation.

Smart Modeling and Simulation systems provide numerous advantages over conventional finite element applications, including plug-and-play, inter-operability, auto-configuration, access to advanced material models, plus the ability to account for complex multi-physics through proper mathematical models and sequencing. SMS is a front-end module, with automated scripts for local or global analysis, ready-made geometries for plug-and-play, and a 1-button solution for meshing and multi-physics diagnosis.

The Smart Modeling and Simulation system exhibits various advantages compared to conventional FEA codes:
1. The proposed system offers the ability to quickly create models using standard drag-and-drop with wide variety of ready-made components from a database.
2. The SMS system works with a wide variety of computer aided design (CAD) formats to help with layouts.
3. The SMS system provides the ability to automatically launch most analyses, including the automatic mesh generation.
4. The SMS system features unique coupled multi-physics, such as chemo-hygro-thermo-piezoelectric-viscoelastic analyses which other simulation software has not been able to provide.
5. The SMS system analyzes multi-physics based on the existing proven tools and analysis plug-and-play.
6. The SMS system offers access to comprehensive material databased on data analytics for materials.
7. The SMS system provides great user-friendly visualization and navigation in the CAD or analysis systems.

For the design of civil engineering structures, this invention presents new nonlinear dynamic analysis and design software tools for fixed-base and base-isolated frame structures that outperform the existing, displacement-based academic and commercial software in several aspects. This novel, force-based beam element approach takes into account the axial-biaxial shear-biaxial flexure interaction surface, and adds multi-level, iterative, robust and economical dynamic solution methods for three-dimensional beam elements. Preliminary investigations demonstrate that this approach can lead to promising outcomes. The force-based element approach proposed has the potential to impact current computational and design procedures for strong ground motions (earthquakes), by providing accuracy superior to the present displacement-based elements.

### DESCRIPTION OF THE DRAWINGS

FIG. 1 presents the cost benefits of early defect identification, resulting from automatic requirement verification, in context of the V-model of systems engineering.

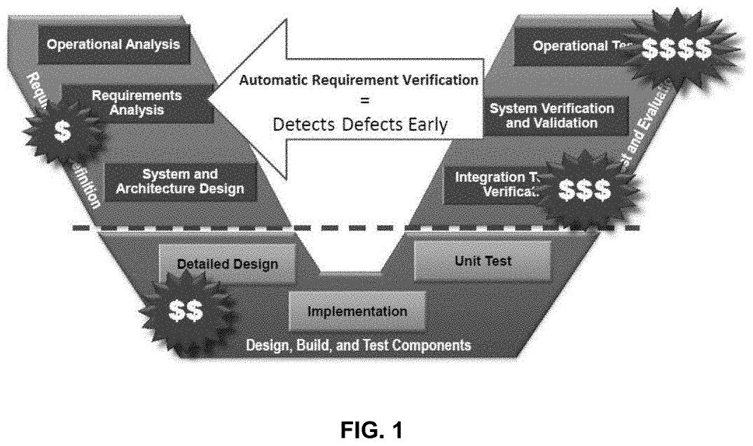

FIG. 2 puts the design of civil or mechanical engineering structures in the context of an Ecosystem for automatic design assessment and smart analysis.

FIG. 3 presents a dependency diagram for an Ecosystem for automatic design assessment and smart analysis.

FIG. 4 illustrates a flow diagram, obtained from (SteingrimssonKulkarni 2020), for an engine for design assessment (for automatic assessment of engineering designs against engineering requirements).

FIG. 5 presents a method for correlating the engineering requirements with source files from engineering design tools and comparing. FIG. 4 and FIG. 5 are both referred to as an e-Design Assessment Engine. In this patent application, and as noted above, we enhance this engine and include it in an Engine for Automatic Design Assessment and Smart Analysis.

FIG. 6 provides depiction of the original design of the spacer cart. FIG. 6a shows the original design of the entire spacer cart. FIG. 6b illustrates the first of the three main issues with the original design of the spacer cart: The cart arms have experienced structural issues; fractures on the arms and the framing around the arms have been frequent. FIG. 6c illustrates the second of the three main issues with the original design of the spacer cart: On the crossbar, a cotter pin has been used to secure the bar in place when the cart has been placed or removed from a transmission line; the use of the cotter pin has presented an ergonomic issue, since the pin has been hard to place or remove. FIG. 6d illustrates the second of the three main issues with the original design of the spacer cart: The squeeze wheel assembly, used to maintain the arms in contact with the transmission lines has exhibited one ergonomic issue, involving the squeeze wheel being difficult to mount or unmount, as well as a second ergonomic issue, involving the squeeze wheel being difficult to adjust.

FIG. 7 provides a depiction of the redesigned spacer cart.

FIG. 8 illustrates verification of a cost requirement at a high level. The observed cost for the spacer cart is obtained by aggregating the material cost, the component cost, and the assembly cost, and comes out as $1,773+$4,760+20* 5=$6.633.

FIG. 9 illustrates aggregation of the observed cost from the Bill of Materials for individual subsystems from the spacer cart example.

FIG. 10 provides a high-level comparison of the requirements for weight and dimensions from the spacer cart example against outputs from a pertinent design tool.

FIG. 11 illustrates optional, manual decomposition of weight requirements, from the spacer cart example, to the subsystem level.

FIG. 12 illustrates aggregation of the observed weight and dimensions for the individual subsystems comprising the spacer cart example.

FIG. 13 presents results of automatic verification of cost, weight and dimensional requirements, for designs involving a spacer cart and a bolt tester, in context with the Ecosystem design software. FIG. 13a presents Requirement Validation tab from the Ecosystem design software for the spacer cart example (results from automatic verification of requirements related to cost, weight and dimensions). FIG. 13b captures results of automatic verification of requirements related to cost, weight and dimensions for the bolt tester example (also from the Requirement Validation tab of the Ecosystem design software).

FIG. 14 offers schematic depiction from the spacer cart example of the process used for automatically verifying the requirement for the product cost.

FIG. 15 presents an algorithm for extraction of recursively extracting the assembly / component dependence for a generic SolidWorks assembly, along with the mass properties and bounding box.

FIG. 16 presents an algorithm for extraction of Bill of Material from a generic SolidWorks assembly, part or drawing file.

FIG. 17 offers schematic depiction from the spacer cart example of the process used for automatically verifying requirements related to product weight and dimensions.

FIG. 18 presents a master assembly, select subassemblies as well as components from examples involving the spacer cart and the bolt tester. FIG. 18a illustrates a master assembly, select subassemblies and components from the spacer cart example, along with mass properties. FIG. 18b illustrates a master assembly, select subassemblies and components from the bolt tester example, along with mass properties. FIG. 18c and FIG. 18d present expanded view of the meta-data extracted (mass properties and bounding box) for the spacer cart and bolt tester examples.

FIG. 19 captures the design process and design flow assumed in assessment of students' design work against ABET learning outcomes.

FIG. 20 shows a PDF version of a score card from a capstone design project involving a bolt tester. FIG. 20 captures the scoring of a student design project against the ABET learning outcomes 1-7.

FIG. 21 shows a PDF version of a score card from a capstone design project involving the spacer cart. FIG. 20 and FIG. 21 capture the scoring of a student design project against the ABET learning outcomes 1-7.

FIG. 22 shows a score card from a capstone design project involving the spacer cart, after the score card has been exported from the Ecosystem software into a .csv file and the .csv file imported into Microsoft Excel.

FIG. 23 captures the web architecture supported by the Ecosystem design software. FIG. 23a presents typical data management for a capstone design project. FIG. 23b illustrates configuration of a root directory for shared access.

FIG. 24 outlines mechanism for overwrite prevention supported by the Ecosystem design software. FIG.24a captures the architecture for overwrite prevention supported. FIG. 24b presents user dialogs associated with file merging for overwrite prevention.

FIG. 25 presents a user interface supported by the Ecosystem design software (the start-up menu).

FIG. 26 presents a user interface (the corresponding start-up menu) for a Korean version of the Ecosystem design software.

FIG. 27 presents a Manufacturing tab from the Ecosystem design software, one that corresponds to the Final design phase. The Manufacturing tab provides enhanced capabilities for tracking parts manufactured in-house or through outsourcing.

FIG. 28 illustrates how the size of images imported into the Design Description tab can be automatically resized, upon the user adjusting the column width or row height of the table into which the images are imported. FIG. 28a illustrates automatic scaling of images imported into the Design Description tab upon adjustment of row height or column width. FIG. 28b presents an automatically enlarged image for a spacer cart, resulting from the user manually increasing height for row 1 in the table.

FIG. 29 illustrates capabilities of the Ecosystem design software for importing SolidWorks part or assembly files, identifying CAD files through a recursive search, and extracting meta-data such as related to the mass properties of the parts or assemblies imported. FIG. 29a presents the results of a recursive search for part and assembly files from a root directly. Upon right-clicking on specific part file, the user can open up the part file in an eDrawingsViewer, SolidWorks or CATIA directly from the Ecosystem dsign software. FIG. 29b presents a SolidWorks assembly that has been imported into the Ecosystem design software. Upon right-clicking on a specific part file, the user can access mass properties and other SolidWorks meta-data extracted.

FIG. 30 illustrates tab renaming capabilities in the Ecosystem design software.

FIG. 31 presents a SysML plugin for automatic requirement verification in the context of a representative tool environment.

FIG. 32 outlines a high-level approach to automatic verification of engineering requirements in the context of a generic SysML function chain. The approach consists of working your way down the function chain, starting from the beginning, and applying checks at each step along the way. The checks are first applied to the input data and then to the functions. Fⱼ represents a function with activities at step j in the process. D₀ and D₁ represent the input data to function F₁. D₂ represents the data produced by function

FIG. 33 presents a “distributed” version of FIG. 32. Here, the evaluation of the functions F₁, F₂ and F₃ is carried out at different locations. FIG. 33a depicts evaluation of the function Fi at Location A. FIG. 33b depicts evaluation of the function F₂ at Location B. FIG. 33c depicts evaluation of the function F₃ at Location C.

FIG. 34 presents a preferred approach to automatic verification of engineering requirements in a “distributed” form in SysML. FIG. 34 has been adapted from (FriedenthalOster 2022).

FIG. 35 presents a modified version of an OpenCAE systems environment. FIG. 32 has been adapted from (EricBrower 2019).

FIG. 36 outlines organization of a SysML package diagram model for the FireSat example. FIG. 36 has been adapted from (FriedenthalOster 2022).

FIG. 37 captures specification of Requirement Table Mission Requirements from the FireSat example. FIG. 37 has been adapted from (FriedenthalOster 2022).

FIG. 38 captures specification of Requirement Diagram Mission requirements from the FireSat example. FIG. 38 has been adapted from (FriedenthalOster 2022).

FIG. 39 illustrates an approach to integration of the Gateway (an exploration and science output in orbit around the moon). FIG. 39 has been adapted from (GerstenmaierCrusan 2022).

FIG. 40 presents subsystem decomposition applied to the Gateway.

FIG. 41 illustrates simple subsystem decomposition applied to the FireSat example.

FIG. 42 presents an adapted version of the querying engine from (Steingrimsson 2018b) with a neural network replacing LSA.

FIG. 43 presents a high-level conceptual framework for the Smart Modeling and Simulation system, in context with the automatic design assessment and smart analysis.

FIG. 44 outlines a high-level framework with the Smart Modeling and Simulation presented as a front-end module within the automatic design assessment and smart analysis.

FIG. 45 presents a high-level overview of the main steps in Smart Modeling and Simulation (analysis).

FIG. 46 presents a high-level depiction of the approach for plug-and-play with pre-made geometric models.

FIG. 47 presents an example of a geometric model for a half of a QFP created using a Smart Modeling and Simulation system. FIG. 47a specifies the quantities defining the dimensions of a “gull wing” lead. FIG. 47b shows “gull wing” leads extending from one side of a quad flat package (a surface-mounted integrated circuit package).

FIG. 48 shows how an FE solver can be launched with an input file (solution parameters) from a Smart Modeling and Simulation system.

FIG. 49 presents a rendering of the geometry editing function.

FIG. 50 summarizes a new method for modeling stress interactions at macroscopic level for inelastic range. FIG. 50a defines the forces acting upon a beam element. FIG. 50b defines the microscopic model for a given material. FIG. 50c offers a depiction of the macroscopic axial-flexure-shear interaction model that we are creating.

FIG. 51 presents definition of key terms in analysis of a civil structural frame. L refers to the node length of a beam element. D denotes the displacement in the horizontal direction deformation, due to the forces applied. FIG. 51a illustrates the forces that assumed to apply on a discretized version of a civil structure (e.g., a building). FIG. 5 lb presents a magnified view of a single membrane (beam element).

FIG. 52 presents comparison with the operation of traditional, displacement-based beam elements, employed by commercial FEA SW, such as ABAQUS or ANSYS.

FIG. 53 presents comparison of the story drift from the new force-based beam element method (with larger time steps) with that of traditional displacement-based beam elements (ABAQUS). FIG. 53 shows that, for the case of a 27 sec earthquake, one can attain nearly same accuracy with coarser time steps for the force-based method as with commercial FEA SW (ABAQUS).

FIG. 54 present comparison of story drift responses for coarser discretization of the new force-based beam element method with that of the traditional displacement-based beam element method (ABAQUS). FIG. 54 illustrates that the force-based methods can yield more accurate results, compared to commercial FEA SW (ABAQUS), but with coarser discretization. GL refers to the number of discretization points per membrane. FIG. 54a presents the story drift response for the new force-based beam element method. FIG. 54b presents the story drift response for the traditional displacement-based beam element method (ABAQUS).

FIG. 55 presents a template for grading a student progress report, one capturing progress through concept design, against an instructor grading rubric.

FIG. 56 presents an Ecosystem facility for team formation. This facility is aimed at improving instructor productivity. The facility helps with matching capstone design students up against the design projects available.

FIG. 57 presents Requirement Diagrams in context with the nine diagrams supported by SysML. FIG. 57 has been adapted from (FriedenthalWolfrom 2010).

FIG. 58 presents a system decomposition process using SysML, in context with the spacer cart example.

FIG. 59 provides representation of system-level requirements for an automotive design in SysML. FIG. 59 is obtained from (FriedenthalWolfrom 2010).

FIG. 60 presents an association between system and subsystem requirements in SysML. FIG. 60 is obtained from (FriedenthalWolfrom 2010).

FIG. 61 presents SysML requirement diagram showing requirements verification pattern. FIG. 61 is obtained from (ChrisParedis 2022).

FIG. 62 present a function of the Java plugin for MagicDraw at a high level.

FIG. 63 presents standard APIs and services providing mechanism for interoperability. FIG. 63 is adapted from (Seidewitz 2018).

FIG. 64 shows how the Smart Modeling and Simulation system can enable designers to apply (specify) loads, temperature or heat flux. FIG. 64a illustrates how the Smart Modeling and Simulation system can enable designers to apply (specify) temperature. FIG. 64b illustrates how the Smart Modeling and Simulation system can enable designers to apply (specify) heat flux.

FIG. 65 shows how the Smart Modeling and Simulation system can allow designers to specify boundary conditions for the mechanical response of a quarter cylinder subjected to static thermal loading.

FIG. 66a shows how the Smart Modeling and Simulation system can provide means for automatic mesh generation. FIG. 66b shows auto generated mesh from the mesh selected per the configuration from FIG. 66a.

FIG. 67 shows how the Smart Modeling and Simulation system can allow designers to specify material properties. FIG. 67a presents a user interface for creation of material properties. FIG. 67b presents a user interface for specification of the following, isotropic properties: Young's modulus, Poisson ratio, coefficient of thermal expansion and coefficient of moisture expansion. FIG. 67c presents a user interface for specification of the following, isotropic properties: Specific heat and conductivity. FIG. 67d shows how the Smart Modeling and Simulation system provides means for applying certain material, that has already been defined, in the form of solid or plate to a given design.

FIG. 68 presents a user interface for a 3D CAD tool supporting Smart Modeling and Simulation.

FIG. 69 illustrates one possible rendering of a 1-button meshing solution.

FIG. 70 presents one possible rendering of a 2D interface, based off the sketch recognition system of (Steingrimsson 2013), with LabView-like linking capabilities.

FIG. 71 shows how the Smart Modeling and Simulation system can allow designers to load in a pre-made finite element model for a sensor, define the material properties, and associate with specific functions. FIG. 71a shows how temperature can be defined for a specific segment. FIG. 71b shows how the Definition menu can be expanded to accommodate line items (drop-downs) with options pre-populated from material databases.

FIG. 72 presents an overview over sequential thermal-stress analysis.

FIG. 73 captures the essence of a user-friendly interface for nonlinear analysis of civil engineering structures.

FIG. 74 presents schematics for the front, top and side views of a sample building. The dimension presented in the top view is in the units of meters. The top view also presents the layout of the columns in each story. FIG. 74a presents schematics for the front and top views of the sample building. FIG. 74b presents schematics for the side view of the sample building.

FIG. 75 presents user inputs for building and acceleration analysis. FIG. 75a emphasizes the part of the part of the user inputs pertaining to the number of floors, the number of stories and column types. FIG. 75b contains the same image as FIG. 75b, but highlights the run time and the Rayleigh damping ratio.

FIG. 76 illustrates floor and story input form for each floor and story.

FIG. 77 presents floor and story input data prompts. FIG. 77a presents a floor input data prompt, whereas FIG. 77b presents a story input data prompt.

FIG. 78 presents source code from a Matlab® file titled “NEW TRIAL.m”.

FIG. 79 presents results of Base Simulation of Stories 0-2 (top left to right), 3-5 (bottom left to right). The base case (Case 1) can be thought of as a fixed base which means story no. 0 has infinite stiffness. FIG. 79a shows acceleration as a function of time for story (floor) no. 0 for this case. FIG. 79b shows acceleration as a function of time for story (floor) no. 1 for this case. FIG. 79c shows acceleration as a function of time for story (floor) no. 2 for this case. FIG. 79d shows acceleration as a function of time for story (floor) no. 3 for this case. FIG. 79e shows acceleration as a function of time for story (floor) no. 4 for this case. FIG. 79f shows acceleration as a function of time for story (floor) no. 5 for this case.

FIG. 80 presents results of Base-Isolated Simulation with Story 0 kₓ and k_{y}=2×10¹ N of Stories 0-2 (top left to right), 3-5 (bottom left to right). FIG. 80a shows acceleration as a function of time for story (floor) no. 0 for the civil structure assumed. FIG. 80b shows acceleration as a function of time for story (floor) no. 1 for the civil structure assumed. FIG. 80c shows acceleration as a function of time for story (floor) no. 2 for the civil structure assumed. FIG. 80d shows acceleration as a function of time for story (floor) no. 3 for the civil structure assumed. FIG. 80e shows acceleration as a function of time for story (floor) no. 4 for the civil structure assumed. FIG. 80f shows acceleration as a function of time for story (floor) no. 5 for the civil structure assumed.

FIG. 81 presents results of Base-Isolated Simulation with Story 0 kx and k_{y}=2×10² N of Stories 0-2 (top left to right), 3-5 (bottom left to right). FIG. 81a shows acceleration as a function of time for story (floor) no. 0 for the civil structure assumed. FIG. 81b shows acceleration as a function of time for story (floor) no. 1 for the civil structure assumed. FIG. 81c shows acceleration as a function of time for story (floor) no. 2 for the civil structure assumed. FIG. 81d shows acceleration as a function of time for story (floor) no. 3 for the civil structure assumed. FIG. 81e shows acceleration as a function of time for story (floor) no. 4 for the civil structure assumed. FIG. 81f shows acceleration as a function of time for story (floor) no. 5 for the civil structure assumed.

FIG. 82 presents results of Base-Isolated Simulation with Story 0 kₓ and k_{y}=2×10³ N of Stories 0-2 (top left to right), 3-5 (bottom left to right). FIG. 82a shows acceleration as a function of time for story (floor) no. 0 for the civil structure assumed. FIG. 82b shows acceleration as a function of time for story (floor) no. 1 for the civil structure assumed. FIG. 82c shows acceleration as a function of time for story (floor) no. 2 for the civil structure assumed. FIG. 82d shows acceleration as a function of time for story (floor) no. 3 for the civil structure assumed. FIG. 82e shows acceleration as a function of time for story (floor) no. 4 for the civil structure assumed. FIG. 82f shows acceleration as a function of time for story (floor) no. 5 for the civil structure assumed.

FIG. 83 presents results of Base-Isolated Simulation with Story 0 kx and k_{y}=2×10⁴ N of Stories 0-2 (top left to right), 3-5 (bottom left to right). FIG. 83a shows acceleration as a function of time for story (floor) no. 0 for the civil structure assumed. FIG. 83b shows acceleration as a function of time for story (floor) no. 1 for the civil structure assumed. FIG. 83c shows acceleration as a function of time for story (floor) no. 2 for the civil structure assumed. FIG. 83d shows acceleration as a function of time for story (floor) no. 3 for the civil structure assumed. FIG. 83e shows acceleration as a function of time for story (floor) no. 4 for the civil structure assumed. FIG. 83f shows acceleration as a function of time for story (floor) no. 5 for the civil structure assumed.

FIG. 84 presents results of Base-Isolated Simulation with Story 0 kₓ and k_{y}=2×10⁵ N of Stories 0-2 (top left to right), 3-5 (bottom left to right). FIG. 84a shows acceleration as a function of time for story (floor) no. 0 for the civil structure assumed. FIG. 84b shows acceleration as a function of time for story (floor) no. 1 for the civil structure assumed. FIG. 84c shows acceleration as a function of time for story (floor) no. 2 for the civil structure assumed. FIG. 84d shows acceleration as a function of time for story (floor) no. 3 for the civil structure assumed. FIG. 84e shows acceleration as a function of time for story (floor) no. 4 for the civil structure assumed. FIG. 84f shows acceleration as a function of time for story (floor) no. 5 for the civil structure assumed.

### DETAILED DESCRIPTION OF THE PREFERRED EMBODIMENTS

### 1. Definitions

Table 1 captures the primary definitions and acronyms used in the patent.

TABLE 1
Summary of the primary definitions and acronyms.

| Name | Definition |
|---|---|
| ABET | Accreditation Board for Engineering |
| | and Technology |
| API | Application Program Interface |
| ATL | Active Template Library |
| BFFE | Bulk Flow Fluid Elements |
| BOM | Bill of Material |
| BPA | Bonneville Power Administration |
| BPMN | Business Process Model and Notion |
| CAD | Computer Aided Design |
| CAE | Computer Assisted Engineering |
| CFD | Computational Fluid Dynamics |
| COM | Component Object Model |
| CLPS | Commercial Lunar Payload Services |
| CSI | Computers & Structures, Inc. |
| D2L | Desire-to-Learn |
| DLL | Dynamic Linking Library |
| EPA | Engineering Process Analysis |
| FE | Finite-Element |
| FEA | Finite Element Analysis |
| FMEA | Failure Mode and Effect Analysis |
| FTA | Fault Tree Analysis |
| IDE | Integrated Development Environment |
| ISS | International Space Station |
| JNI | Java Native Interface |
| JPL | Jet Propulsion Laboratory |
| LSA | Latent Semantic Analysis |
| MBSE | Model-Based Systems Engineering |
| NASA | National Aeronautics and Space |
| | Administration |
| PDF | Portable Document Format |
| QFP | Quad Flat Package |
| RISA | Rapid Interactive Structural Analysis |
| SMAD | Space Mission Design |
| SMS | Smart Modeling and Simulation |
| STAAD | STructural Analysis And Design |
| SysML | Systems Modeling Language |
| SW | Software |
| TMT | Thirty Meter Telescope |
| XML | Extendable Mark-Up Language |

### 2. Best Mode of the Invention

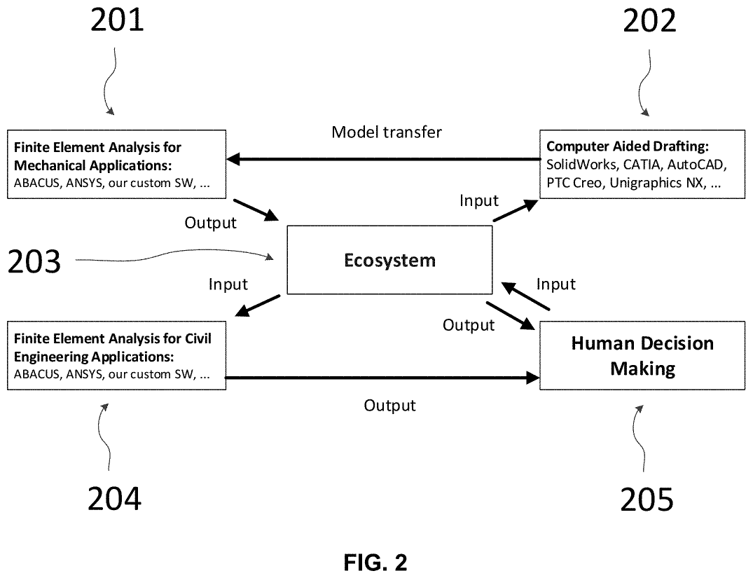

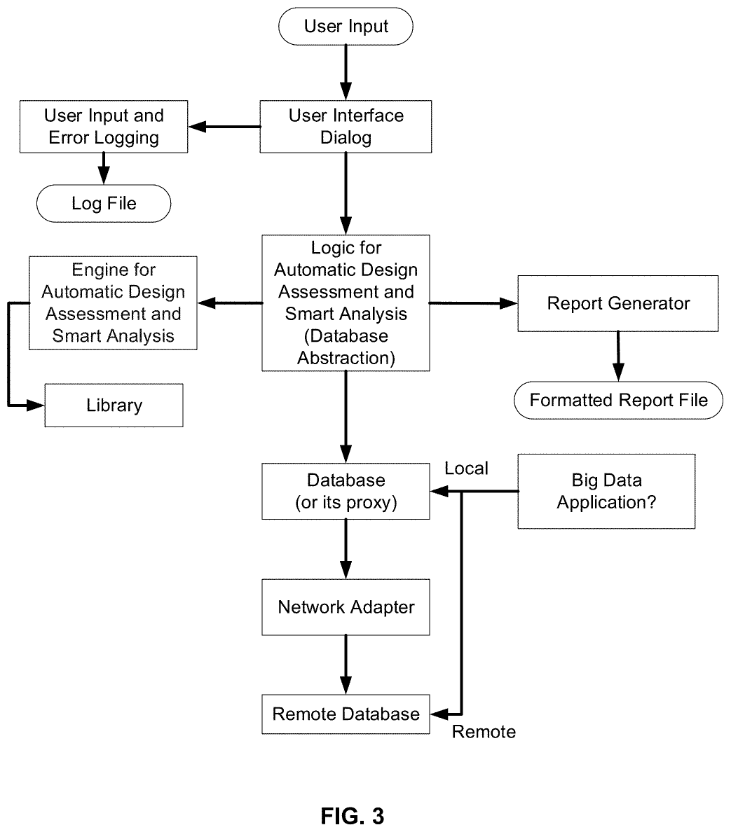

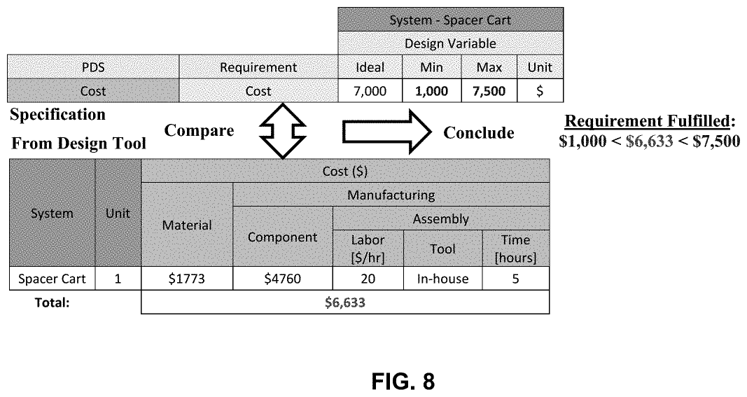

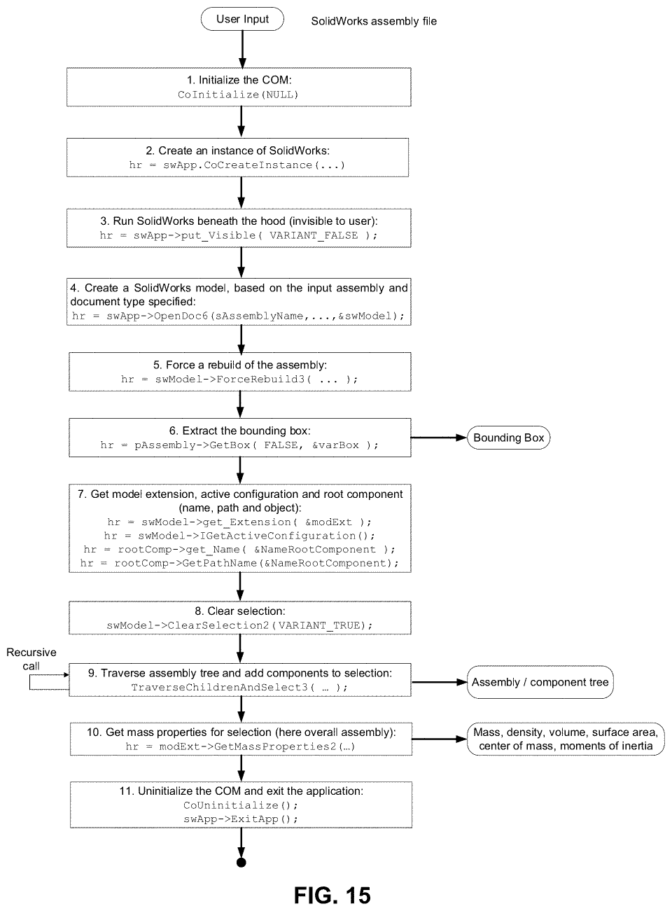

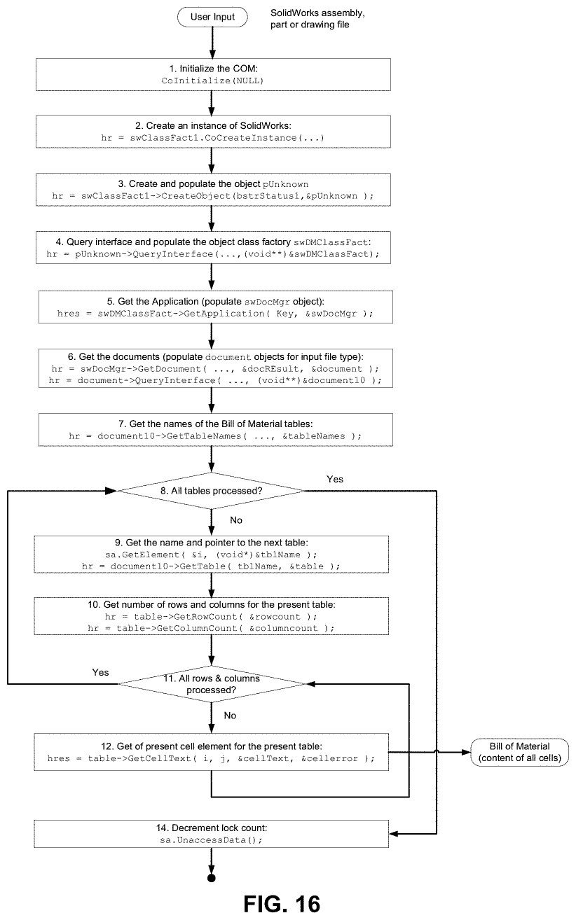

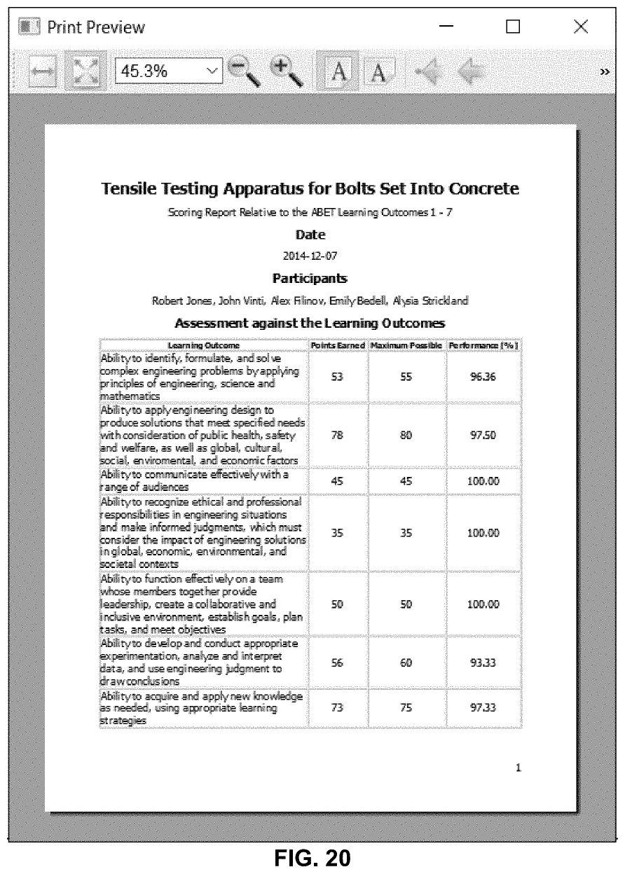

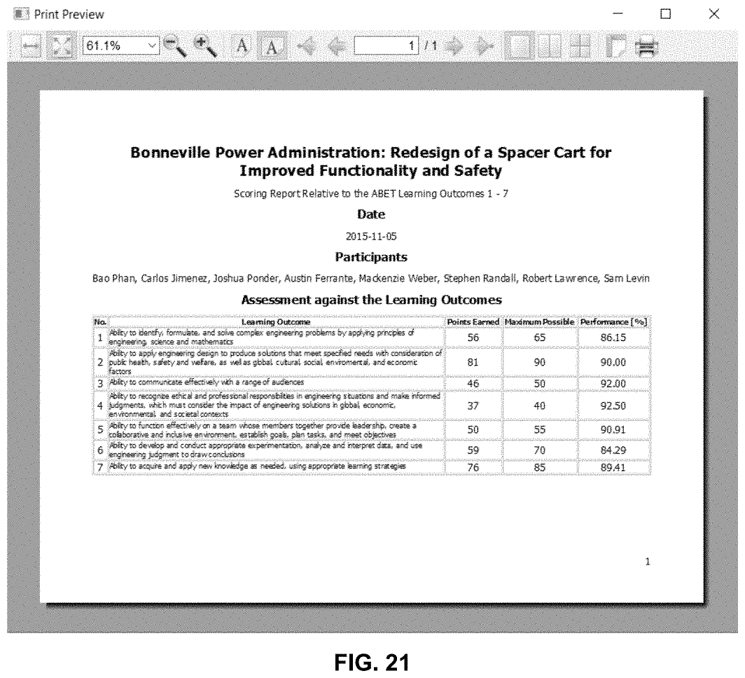

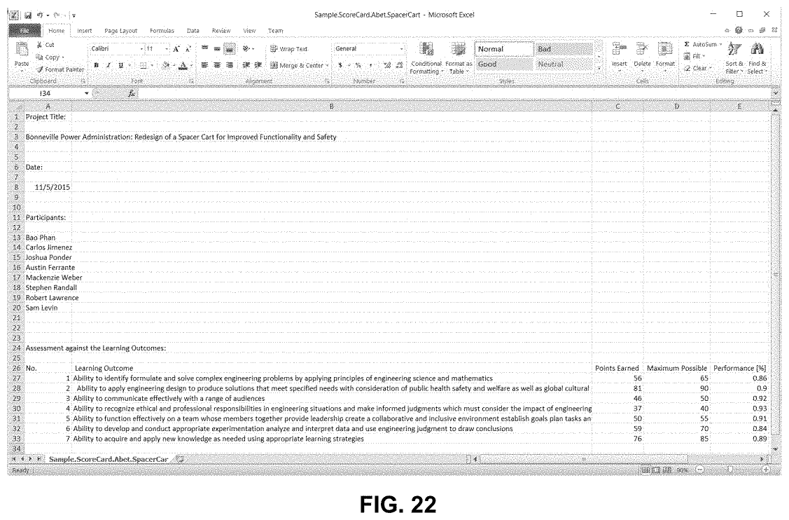

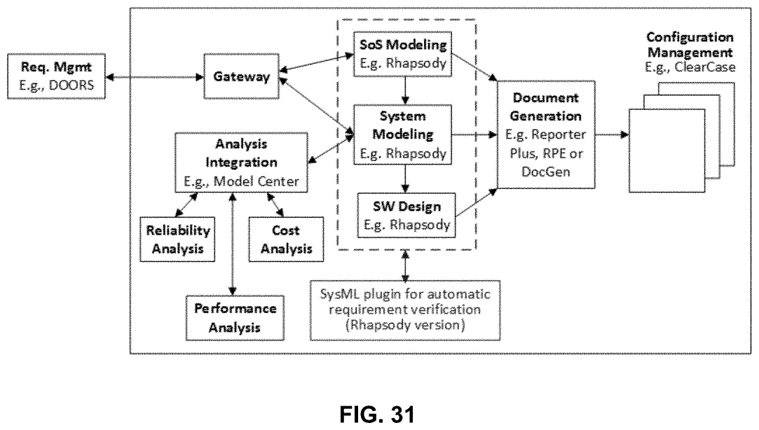

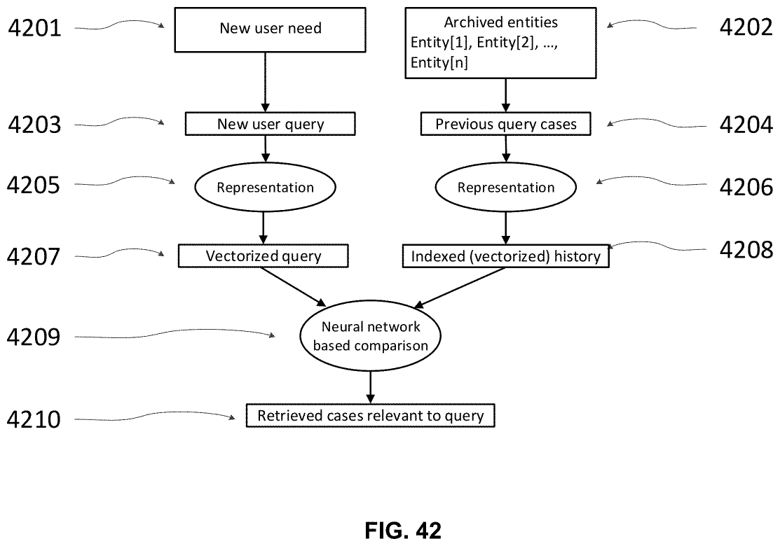

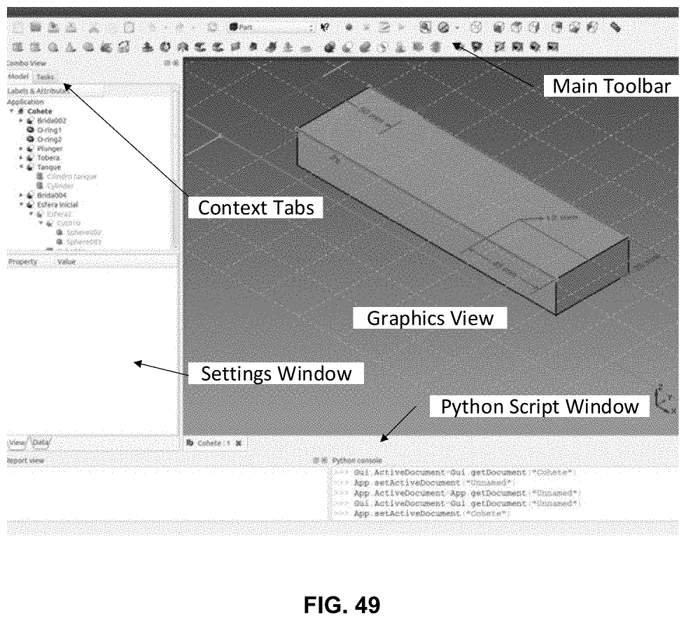

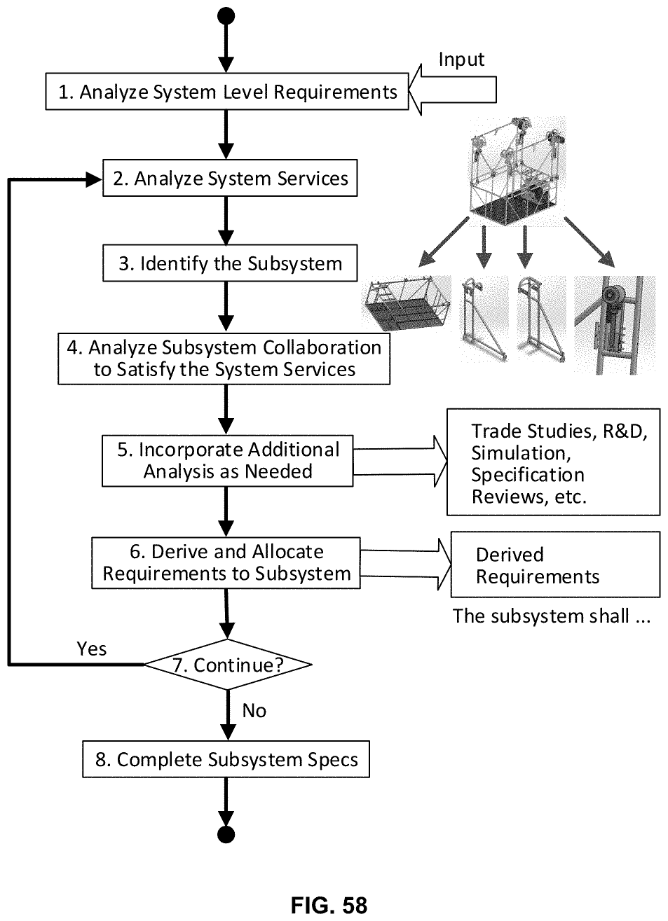

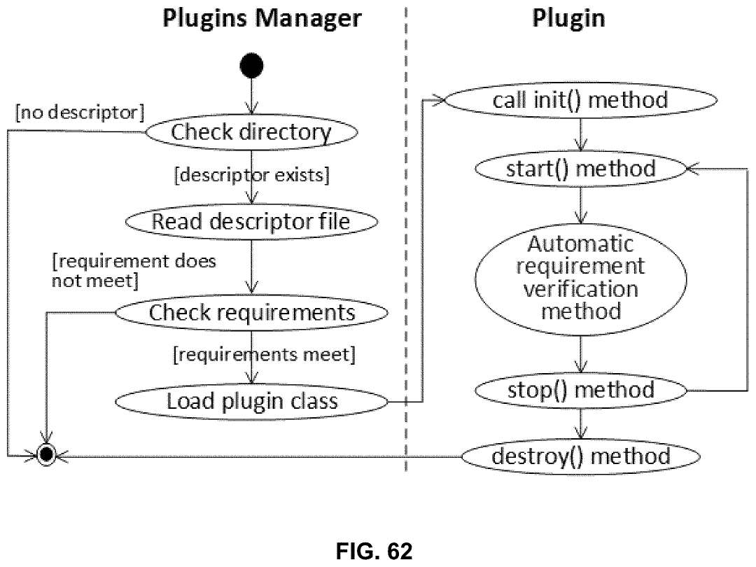

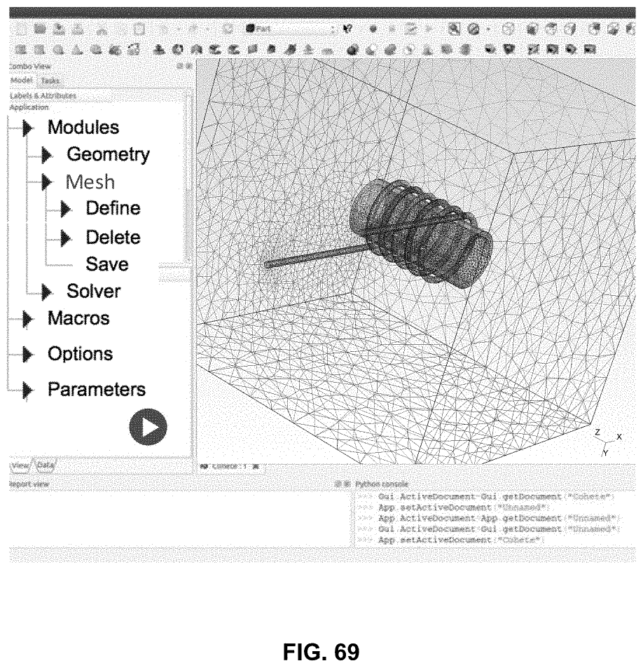

FIG. 2-FIG. 5, FIG. 8-FIG. 12, FIG. 15-FIG. 16, FIG. 20-FIG. 22, FIG. 31-FIG. 35, FIG. 42-FIG. 46, FIG. 49-FIG. 52, FIG. 58, FIG. 62, FIG. 69-FIG. 70 and FIG. 72-FIG. 73 capture the best mode contemplated by the inventors, according to the concepts of the present invention. FIG. 2 puts the design of civil or mechanical engineering structures in the context of an Ecosystem for automatic design assessment and smart analysis. FIG. 3 presents a dependency diagram for an Ecosystem for automatic design assessment and smart analysis.

### 3. Automatic Verification of Engineering Requirements—ML-Based Approaches to Engineering Design—Generative Designs (Continuation-in-Part)

1. High-Level Structure of Engine for Automatic Assessment against Engineering Requirements

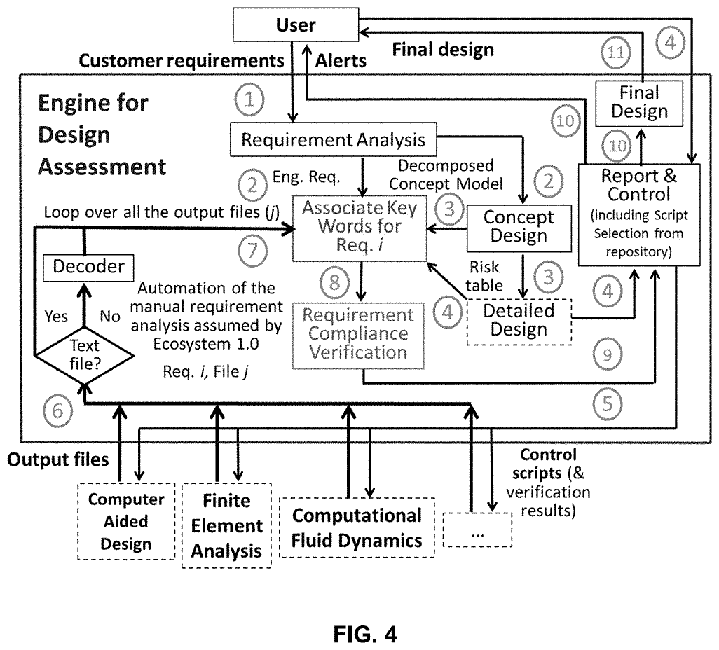

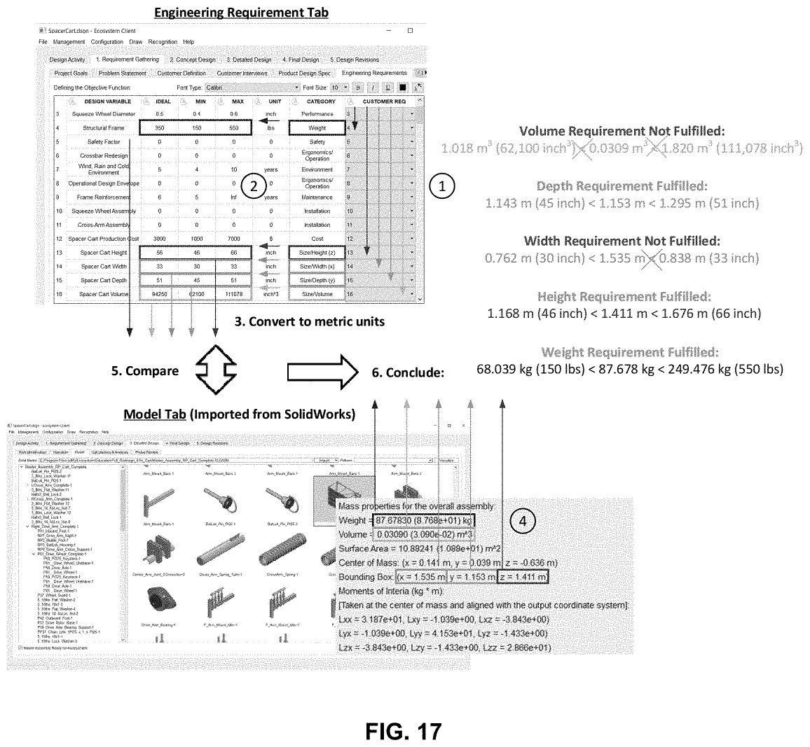

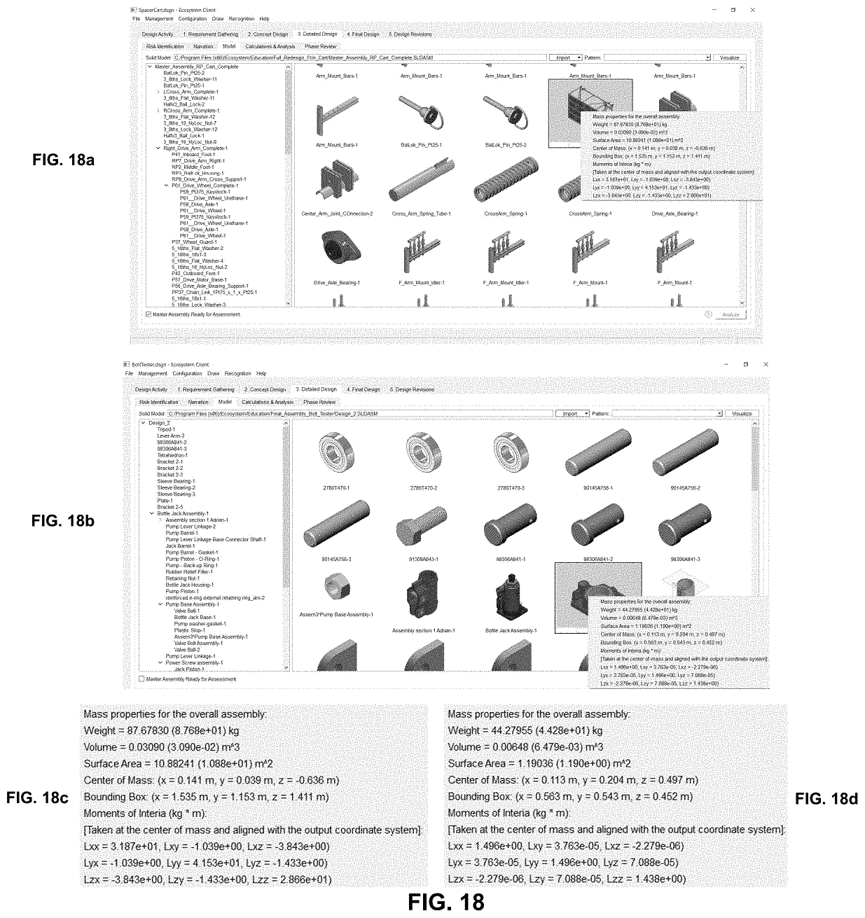

The assessment engine, shown in FIG. 4, and obtained from (SteingrimssonKulkarni 2020), presents a framework for automatic assessment of engineering designs against engineering requirements. The assessment engine offers automation of the compliance verification of engineering designs with the engineering requirements. This capability demarks significant progress in achieving the overall goals of increased productivity and minimum rework. The enumerated labels in FIG. 4 are taken to represent the sequence of operation listed below:
1. In Step 1, Customer Requirements from the User are fed into the Requirement Analysis module.
2. In Step 2, Engineering Requirements from the Requirement Analysis are fed into the module for Associating (matching) Key Words for Requirement i with appropriate parameters from output file j from the design tools (from Step 7). FIG. 16, FIG. 17 and FIG. 18 of (SteingrimssonKulkarni 2020) provide further examples as to how this is done.
3. In Step 3, the Decomposed Concept Model from the Concept Design is fed into the module for Associating Key Words for Req. i. In Step 3, the Concept Model is also presented for Detailed Design.
4. In Step 4, the Risk Table from the Detailed Design is provided to the module for Associating (matching) Key Words for Requirement i with appropriate parameters from output file j from the design tools. In Step 4, pertinent analyses of interest are also provided to the Report & Control module. The selection of scripts, from a library of readily available scripts pertinent to the categories of analyses of interest and the corresponding design tools, is further explained below. The script selection is ultimately up to the User.
5. In Step 5, the pertinent scripts selected from the repository are provided to the design tools.
6. In Step 6, the output of the design tools are provided to the decoding module. Table 6 expands on the decoding mechanism.
7. In Step 7, the appropriate parameters from output file j from the design tools is associated with key words for Requirement i.
8. Step 8 consists of Requirement Compliance Verification. The matching gray-scale color coding for steps in FIG. 17 and FIG. 18 of (SteingrimssonKulkarni 2020) titled “Simple Comparison” and “Key Word & Parameter Extraction” is meant to illustrate how the requirement compliance verification is carried out.
9. In Step 9, the output ofthe Requirement Compliance Verification is fed to the Report & Control unit.
10. In Step 10, the Report & Control unit provides the findings from the Requirement Compliance Verification to the User in the form of Alerts. In Step 10, the findings from the Requirement Compliance Verification is also incorporated into the Final Design.
11. In Step 11, the User accesses the Final Design.

### 2. Practical Example Demonstrating Automatic Assessment Against Engineering Requirements

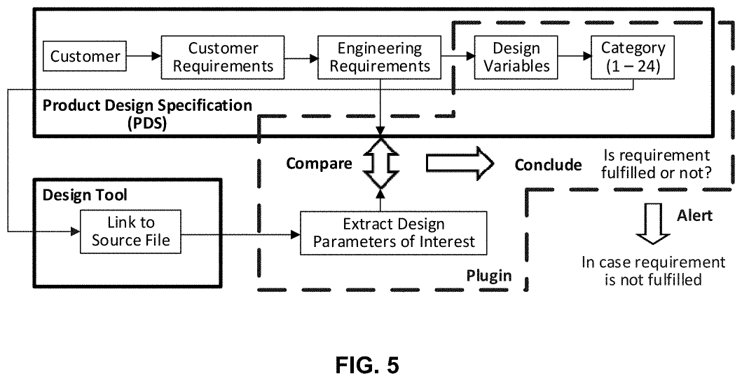

At a high level, the engineering requirements can be verified through an association with the files containing the relevant design information, as illustrated in FIG. 5. Table 1 provides additional specifics on this association. The requirements are grouped into 24 standardized categories. For each category, Table 1 lists the relevant source files containing the design files with information needed for verification of requirements from that category (tells e-design assessment engine where to look).

TABLE 2
Source files corresponding to the 24
categories of engineering requirements.

| No. | Category | Relevant Source Files (from Design Tool) |
|---|---|---|
| 1 | Aesthetics | Color, Shape, Form, Texture, Finish, . . . |
| 2 | Company | Company Requirement, Certain |
| | Procedures | Standard such as GD&T or ISO 9000 |
| 3 | Competition | Marketing |
| 4 | Cost | Product, Manufacture, Tools |
| 5 | Disposal | Recyclable, Bio-Degradable, Green, . . . |
| 6 | Documentation | Legal Issues; Litigation, Safety, |
| | | Operation & Service Documents |
| 7 | Environment | Temperature Range, Rain, Humidity, Dust, . . . |
| 8 | Ergonomics/ | Users/Buyers Need, Marketing, |
| | Operation | |
| 9 | Function | Users Requirement, Company |
| | | Requirement, System/Sub-system |
| | | Accomplishment |
| 10 | Installation | Connection Geometry, Models to Install |
| 11 | Life in Service | Years, Cycles, . . . |
| 12 | Maintenance | Professional/Government/Industry |
| | | Guideline, Company Preference |
| 13 | Manufacturing | Buyers Demand, Cost, Warranty, |
| | | Marketing, Quality Assurance, . . . |
| 14 | Materials | Company Guidelines, Regulations |
| | | Restrict, Marketing, Codes |
| 15 | Packaging | Package Sizes, Weight, |
| | | Damage Resistance, Cost |
| 16 | Patents/Legal | Liability Law Suits Associated with |
| | | Similar Products, Relevant Patents |
| 17 | Performance | Speed, Capacity, Power, Efficiency, |
| | | Accuracy, Return on Investment, . . . |
| 18 | Quality/ | Company Warranty, Failure Rate, . . . |
| | Reliability | |
| 19 | Quantity | Company Requirement, Marketing, . . . |
| 20 | Safety | Government Requirement, Professional |
| | | Codes and Standards, Warning |
| | | Labels, Degrees of Abuse, . . . |
| 21 | Shipping | Package Sizes, Weight, Damage |
| | | Resistance, Distance, Cost |
| 22 | Size/Volume | Dimension, Volume, . . . |
| 23 | Timelines | Management, Company Requirement, . . . |
| 24 | Weight | Desired Weight, Modular, Lifting Points, . . . |

### I. A Sample Project Involving Redesign of a Spacer Cart

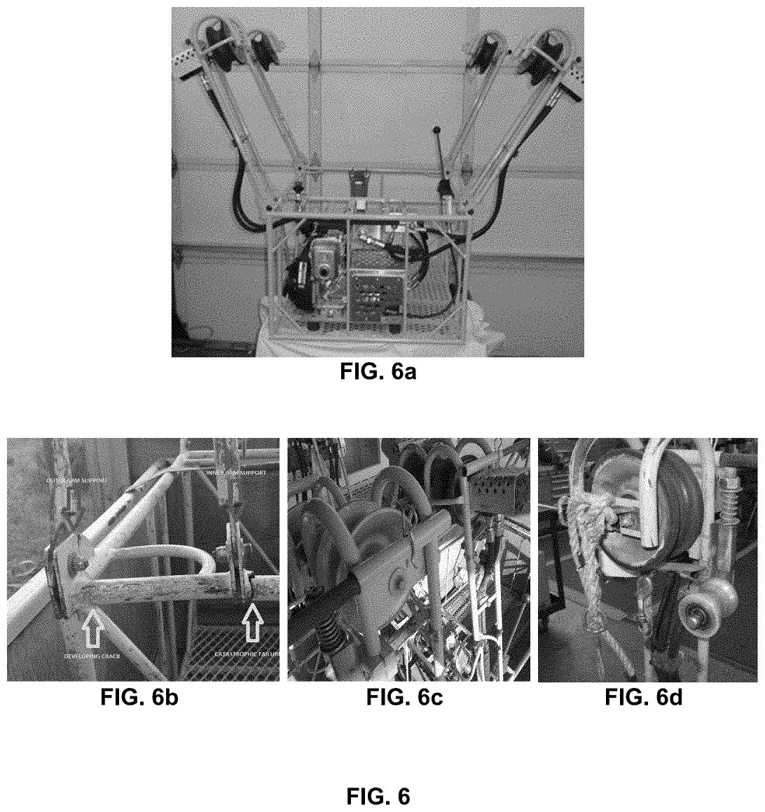

The Bonneville Power Administration (BPA) designed their own aerial line cart to address the operation of performing repairs on high-voltage transmission lines in the Pacific Northwest. However, the previous design had defects related to structural integrity and ergonomics. The original design of the spacer cart, shown in FIG. 6a, suffered from the following three issues (PhanPonderJimenez 2016):
1. The cart arms experienced structural issues. Fractures on the arms and the framing around the arms were, therefore, frequent (see FIG. 6b).
2. On the crossbar, a cotter pin is used to secure the bar in place when the cart is placed/removed from the transmission line. The use of the cotter pin presents an ergonomic issue, since the pin is hard to place/remove (see FIG. 6c).
3. The squeeze wheel assembly, used to maintain the arms in contact with the transmission lines has two ergonomic issues. First, the issue is that the squeeze wheel is difficult to mount and unmount. Second, the squeeze wheel is difficult to adjust.

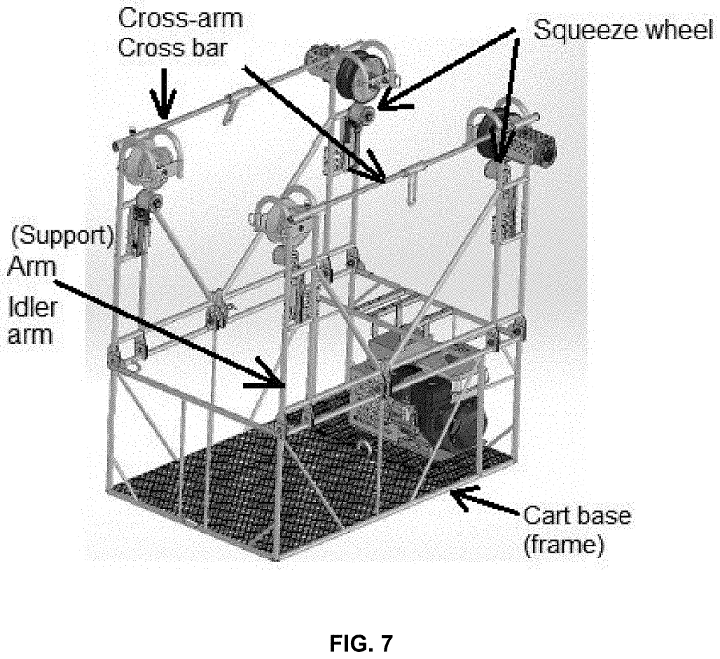

Hence, BPA sought to redesign their original spacer cart design. Overall scope of the spacer cart redesign project was limited to addressing limitations involving safety and functional aspects of the previous design. The goal of the new design was to reduce stresses in the frame of the spacer cart caused by impacts sustained by the arms during normal operation, and to address access and ease of use issues experienced with the arms of the spacer cart, cross-bars, and pinch wheel assemblies. These new designs must all pass design requirements and envelopes specified by BPA for line clearance. FIG. 7 provides a depiction of the redesigned spacer cart (PhanPonderJimenez 2016).

TABLE 3
The primary system requirements for the spacer
cart redesign project. The base cart is excluded
from the cost budget, since it had already been developed
and included as an original component of the spacer cart.

| Design Variable | IDEAL | MIN | MAX | Unit | Category |
|---|---|---|---|---|---|
| Angle of Incline | 35 | 30 | 40 | degree | Performance |
| Weight Rating | 550 | 400 | 560 | lbf. | Performance |
| Cart Height | 20 | 19 | 21 | inch | Size/shape |
| Cart Length | 51 | 50 | 51 | inch | Size/shape |
| Cart Width | 33 | 32 | 33 | inch | Size/shape |
| Pinch wheels | 0.5 | 0.4 | 0.6 | inch | Performance |
| diameter | | | | | |
| Structural Frame | 550 | 540 | 1000 | lbs. | Safety |
| Safety Factor | Not specified (BPA | | | | Safety |
| Crossbar | simply to approve) | | | | Ergonomics/ |
| redesign | | | | | Operation |
| Wind, rain and | 5 | 4 | 10 | years | Environment |
| cold | | | | | |
| environment | | | | | |
| Operational | Not specified (BPA | | | | Ergonomics/ |
| design | simply to approve) | | | | Operation |
| envelope | | | | | |
| Frame | 5 | 4 | 10 | years | Maintenance |
| reinforcement | | | | | |
| Pinch wheel | Not specified (BPA | | | | Installation |
| assembly | simply to approve) | | | | |
| Cross-arm | | | | | Installation |
| bar assembly | | | | | |
| Cost | 3,000 | 1,000 | 7,000 | $ | Cost |

### 2. Redesign of the Spacer Cart: System Requirements

Table 3 lists the system requirements for the spacer cart redesign project (PhanPonderJimenez 2016). Note the all-numeric presentation of the system requirements.

### 3. Sample Analysis of Requirements Related to the Product Cost

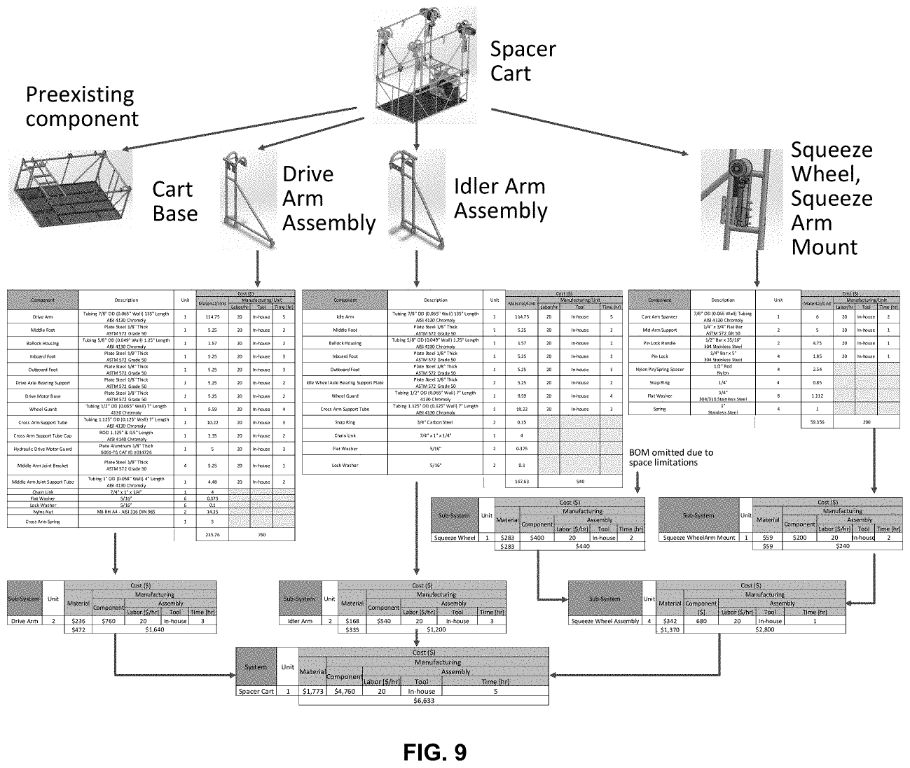

As can be done for many of the system requirements, we apply subsystem decomposition to analyze the requirement for the product cost. As the designer goes through the design process, there comes a point where the Bills of Material (BOMs) for the subsystems becomes available. At this point, the automatic requirement verification imports the BOMs, e.g., from a tool such as SolidWorks, and then aggregates the material costs, the component costs and the assembly costs. FIG. 8 presents the high-level comparison, whereas FIG. 9 outlines cost aggregation for the subsystems. The cost analysis illustrates that the spacer cart redesign did fulfill the cost requirement:
$1,000<$6,633$7,500.
   The requirements can be verified as soon as the pertinent design files (here, the BOM) become available. Designers do not need to wait till the end of the design phase to verify all the system requirements.

### 4. Extending the Verification to Requirements Involving Weight and Dimensions

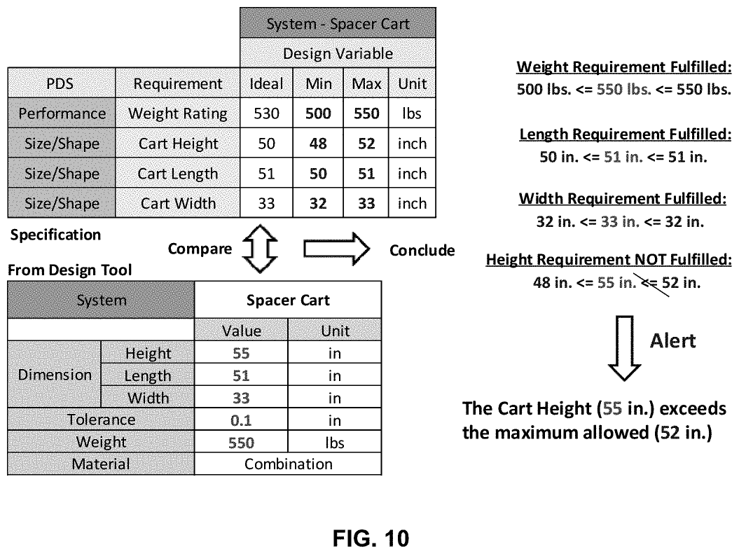

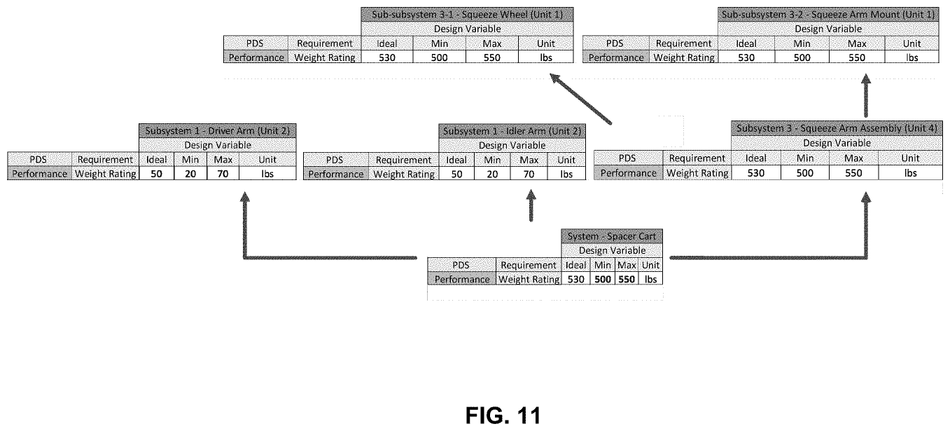

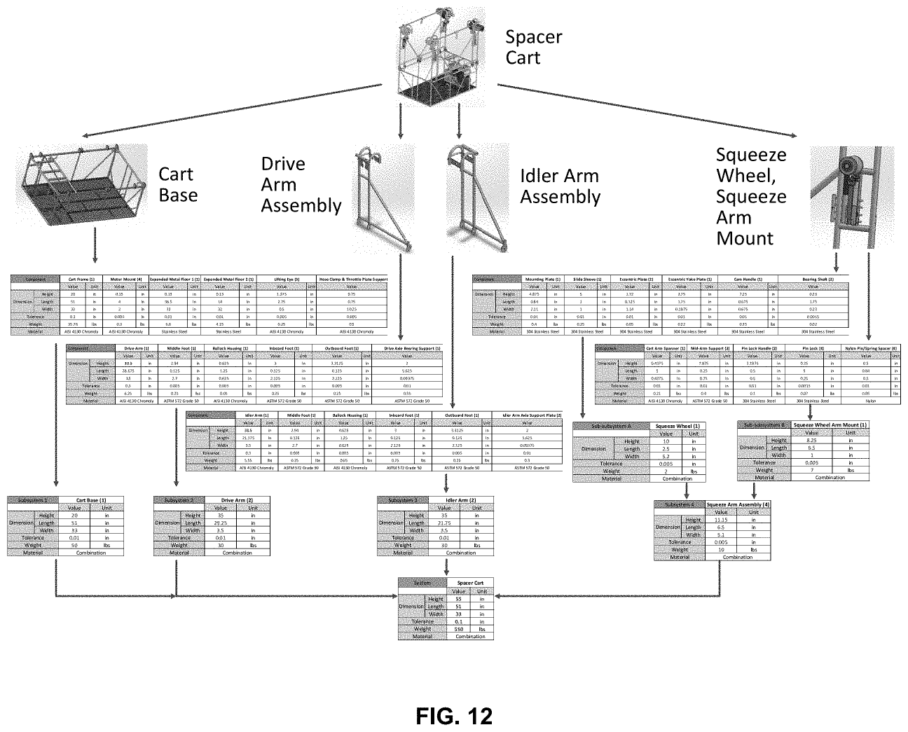

The subsystem decomposition can be extended to verification of requirements related to weight and dimensions. FIG. 10 presents high-level comparison resembling FIG. 8, whereas FIG. 11 and FIG. 12 outline the analysis of the weight and dimensions for the subsystems (the specified and the observed values). As before, the weight and dimensions may be extracted from the solid modeling tool of choice (e.g., SolidWorks). In this case, possible overlap for the dimensions can be accounted for, by considering the base cart and drive/idler arm, since the squeeze wheel assembly is the part that connects to the arms. Therefore, the dimension of the cart is equal to the dimension of the base cart and the arms. Note that the decomposition of the specified values in FIG. 11 is optional. In the end, we verify against the system requirements, not the subsystem requirements. If the requirements are decomposed further, to the subsystem level, the designer needs to do this manually utilizing his or her subject matter expertise (this part of the process is presently not automated). FIG. 10 shows the spacer cart design does (barely) fulfill the requirements for the weight, length and width, but not for the dimension. Hence, the alert:

### The Cart Height (55 in.) Exceeds the Maximum Allowed (52 in.)

Many of the system requirements remaining can be analyzed in an analogous fashion. For example, to check the requirement concerning the 5-year reliability (min. 4 years, max. 10 years), the designer can conduct Monte Carlo simulation, one that generates random failure times from each component's failure distribution. We recognize that reliability in general may be a complicated subject. In general, the requirements need to be properly categorized, each category addressed separately, and prioritized accordingly.

3. Automatic Assessment in Context with the Ecosystem Design Software

### 1. Ecosystem Implementation of Automatic Verification of Requirements for Cost, Weight and Dimensions Summarized

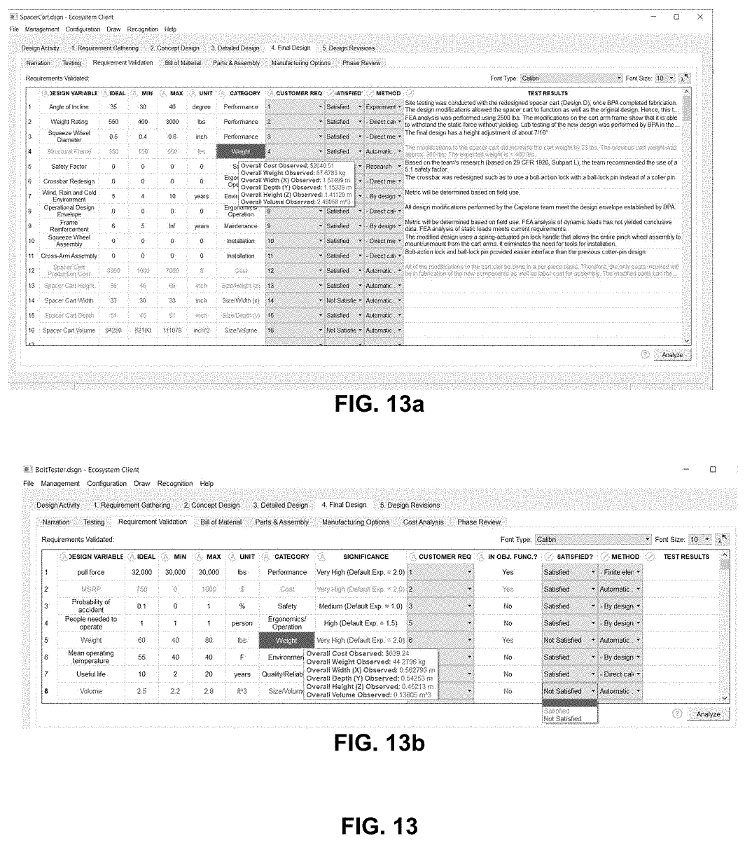

FIG. 13a and FIG. 13b shows how the results of automatic verification of cost, weight and dimensional requirements are represented in the Ecosystem design software, for designs involving the spacer cart and a bolt tester.

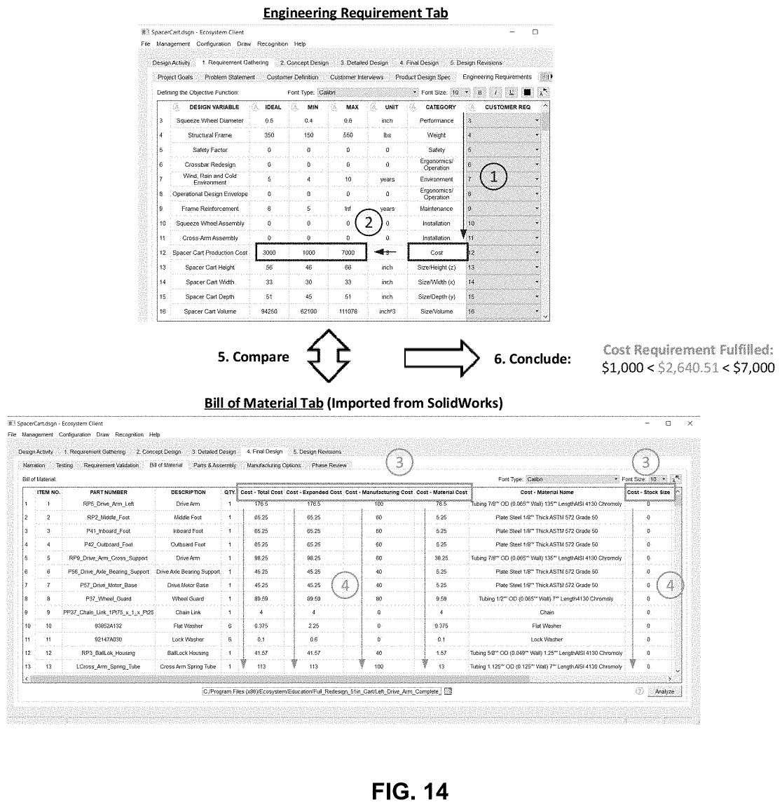

FIG. 14 illustrates, in context with the Ecosystem design software, a process that can be employed for automatically verifying requirements related to product cost. Based on the requirement category specified, Step 1 consists of identifying the requirement (row in FIG. 4) in the Engineering Requirement tab containing the cost requirement for the system. Step 2 involves simply identifying the MIN. and MAX. values for the cost requirement listed. In Step 3, the algorithm identifies the columns in the Bill of Material imported that contain a ‘Cost’ quantity of some sort. For each column with a ‘Cost’ item, Step 4 entails computation of the row-sum for that column, and then picking the largest row-sum for all such columns (the total cost summed over all the parts). In Step 5, we compare the total cost to the MIN. and MAX. values from the Engineering Requirement tab. Based on such comparison, we conclude in Step 6 whether the cost requirement has been fulfilled or not.

Although we will demonstrate how to extract the design information (parameters) mentioned in FIG. 5, FIG. 8 and FIG. 10 specifically from the SolidWorks design tool, the automatic verification of the engineering requirements outlined in this invention is not limited to SolidWorks. Similar approach can be devised to extract the corresponding design information (parameters) from design tools, e.g., from PTC, Autodesk or Siemens.

### 2. Background on Components, Features, External References and Virtual Components in SolidWorks

In general, a SolidWorks assembly comprises of components and features. A SolidWorks component can have features. The features of an assembly are referred to as assembly-level features. A component, in this context, can consist of a part or another assembly. One can obtain assembly components by utilizing the GetComponents (IAssemblyDoc) method. Through proper calls to GetComponents( ) one can iterate over each component, extract the associated data, and then use. In particular, one can iterate over each component and extract the features, through proper calls to GetFeatures( ). One can obtain a model document of a component, in an analogous fashion, by utilizing the GetModelDoc2 (IComponent2) method. And from the model document, one can obtain its type, if it is a part or an assembly, etc.

In general, a SolidWorks part file can contain bodies, features or both. In SolidWorks, during creation of an assembly or a part file, the user needs to specify if the user wishes to create an assembly or part. The decision about creation of an assembly or a part is done at the very start of the design (“File→New” provides the user with the same type of an option). For a C# example illustrating how to get all of the mates (IMate2 and IMateInPlace objects) for all of the components in a SolidWorks assembly, refer to (SolidWorksGetMatesExample 2022). For a C# example illustrating how to get the names and types of features in a FeatureManager design tree in a reverse chronological order, refer to (SolidWorksGetFeatureReversed 2022).

Furthermore, external references and virtual components relate to how an assembly is structured. When a software object for an assembly is constructed in SolidWorks, one can add subassemblies, paths or components to the assembly. When a subassembly is added as a path, one is storing a link to the subassembly. The link is referred to as an external reference. A virtual component refers to a component that is stored as a component in the assembly, not as an external reference. For additional information, refer to Ref (DassaultVirtualComponents 2018).

If one is just looking to extract the external references from a SolidWorks part, assembly or a drawing, then the references can be extracted using the SolidWorks Document Manager. The references can also be extracted using the SolidWorks API. An advantage of using the SolidWorks Document Manager for this relates to the fact that the SolidWorks Document Manager reads the data from the SolidWorks file directly. In this way, one may avoid a costly open operation and improve performance. Moreover, the SolidWorks Document Manager may be packaged up with the design software in question and used without full installation of SolidWorks on the computer, on which the design software is run. For specifics, refer to the method GetExternalFeatureReferences2 (ISwDMDocument18) .

In case the SolidWorks Document Manager is used, it needs to be registered with the operating system, e.g., the Windows operating system, on the computer, where the design software is run, during installation of the design software. For information on how to register the dynamic linking library (DLL) SwDocumentMgr.dll containing the SolidWorks Document Manager, refer to (SolidWorksGettingStarted 2022).

A table for the Bill of Material can be contained in a SolidWorks drawing or an assembly file. Although the BOM is more common in a drawing file, it can also be present in an assembly file. A SolidWorks drawing file can contain Excel-based BOMs or a table-based BOM, but not both. To insert an Excel-based BOM into a SolidWorks drawing file, one must have Microsoft Excel installed on the computer, where SolidWorks runs. If one is accessing (extracting) a BOM table as a SolidWorks feature construct, then analogous source code should work, both for extracting the BOM table from a SolidWorks drawing and from a SolidWorks assembly file. For additional information, refer to (SolidWorksB omOverview 2022) and (SolidWorksGetComponents 2022).

Moreover, SolidWorks can provide the designer with information on which documents have been modified. Through the SolidWorks API, SolidWorks offers software developers with events, like IsModified( ), that they can harvest for this purpose. In addition, the method GetSaveFlag (IModelDoc2) specifies whether the SolidWorks document is currently “dirty” (i.e., has been modified since it was opened) and needs to be saved. For additional information, refer to (SolidWorksGetSaveFlag 2022) or (SolidWorksDetermineDocumentDirty 2022).

An XAML file in SolidWorks usually contains mesh data along with numeric parameters like diameter. In a SolidWorks part file, such data is usually stored natively as feature parameters.

### 3. Key Assumptions for Specific SolidWorks Implementation of Automatic Verification of Requirements

To such effect, we recommend using the SolidWorks API for extracting both mass properties and thumbnail images (for sake of efficiency). If one is only looking to extract the thumbnail images, then these can be extracted using the SolidWorks Document Manager without SolidWorks otherwise being installed on the computer, on which the design software is run.

It is further assumed that the SolidWorks API is invoked from the Ecosystem design software through a dedicated interface implemented as a class whose header features no SolidWorks-specific data structures (only standard data structures of the programming language preferred, say standard C++ data structures). The intent here is to shield the software architecture of the design software from the SolidWorks-related code. The architecture of the design software should have no dependencies on SolidWorks-specific data types.

### 4. Specific SolidWorks Implementation of Verification of Requirements for Weight and Dimensions

FIG. 15 presents an algorithm for recursively extracting the assembly/component dependence for a generic SolidWorks assembly, along with the mass properties and bounding box. FIG. 16 further outlines the process of importing Bills of Material into the Ecosystem design software from SolidWorks assembly, part or drawing files.

At a high level, there are two ways to retrieve the mass properties:
1. One can iterate over each component, retrieve the body for each component, call GetMassProperties( ) separately on each body, and add the values.
2. One can call can call IMassPropery::AddBodies( ) or IMassPropery::IAddBodies( ) either on assembly or body, to specify the bodies (parts) that the mass property object should refer to. In this case, the bodies can either be from a subset of the document's body list or from temporary bodies.
   In both cases, the density needs to be set before invoking GetMassProperties( ). Neither approach returns moments of inertia taken at output coordinate system. Note that each specified body should either come from the owning document or be a temporary body. If the body does not satisfy either case, then it is not used when calculating the mass properties. Note also that the calculations of the mass properties include all available bodies in the SolidWorks document data structure. In the case of a SolidWorks part, all of the solid bodies are included in the calculations of the mass properties. In the case of a SolidWorks assembly, all of the bodies in all of the components are used in the calculations. For additional explanations, refer to (Soli dWorksMassProperties 2022) or (SolidWorksGetMassProperties 2022).

In Step 1 of FIG. 15, we are initializing the Component Object Model (COM). The input to Step 1 consists of a SolidWorks assembly file. The COM is a binary-interface standard for software components introduced by Microsoft in 1993, and used to enable inter-process communication object creation in a large range of programming languages (WikipediaCOM 2022). The SolidWorks Document Manager API is a COM object contained in SwDocumentMgr.dll, per the note above. In Step 2, we are creating an instance of SolidWorks. In Step 3, we are launching SolidWorks beneath the hood (invisible to the user). In Step 4, we are creating a SolidWorks model, based on the input assembly and the document type specified. In Step 5, we have configured the Ecosystem design software such that the forcing of the rebuild is omitted, but the user is notified, and asked to manually rebuild the assembly, if necessary. The swModel object mentioned in Steps 5, 7 and 8 is of type IModelDoc2. The IModelDoc2 interface of the SolidWorks documents, i.e., parts, assemblies and drawings (SolidWorksIModelDoc2Interface 2022). API provides access to In Step 6, we are extracting a bounding box for the assembly. In Step 7, we are retrieving model extension, active configuration and root component (name, path and object). In Step 8, we are clearing the list of components selected. In Step 9, we are recursively traversing the assembly tree and adding components to a list featuring the components selected. Step 9 results in an assembly/component tree. In Step 10, we are obtaining the mass properties for the components selected (for the overall assembly). In Step 10, we are utilizing the GetMassProperties2( ) method to associate information related to mass properties, density, volume, surface area, center of mass and moments of inertia with the components comprising the assembly/component tree. In Step 11, we are un-initializing the COM and exiting the application.

In Step 4 of FIG. 15, one can employ a light version of OpenDoc6( ), for the purpose of reducing the footprint required.

In Step 5 of FIG. 15, we came to discover that skipping the forcing of the rebuild for every SolidWorks assembly imported could result in a significant speed-up. One can also configure the Ecosystem design software such that the forcing of a rebuild is omitted, but the user notified, and asked to manually rebuild the assembly, if necessary.

At a high level, in Step 9 of FIG. 15, one needs to traverse the assembly/component tree recursively, get the parent, then call GetChilden( ), and possibly call GetComponents( ), to get the associated components.

More specifically, in Step 9 of FIG. 15 (in the function TraverseChildrenAndSelect3(( ), we first first add the present component to the list of the component items selected:
hr=swComp->Select4(VARIANT_TRUE, NULL, VARIANT_FALSE, &retVal);
   Second, we retrieve the name and path for the present component:
hr=swComp->GetPathName(&Name);
   Third, we obtain the number of children for the present component:
hr=swComp->IGetChildrenCount(&nChildren);
   Fourth, if the present component has no children, then we exit the recursive routine:
if(nChildren<1) return;
   But if the present component does have some children, then we retrieve these children:
hr=swComp->GetChildren(&vComps);
   We then loop over the children. Within the for-loop over the children, we first query the interface
hr=pDispTemp->Querylnterface(IID_IComponent2, (vold**)&tempComp);
   Second, we retrieve the paths for each of the child components:
hr=tempComp->GetPathName(&tmpCompName);
   Third, we retrieve the paths for each of the child components:
hr=tempComp->get Name2(&tmpCompName2);
   Fourth, we archive the names both for the child and the parent components:
wstring msg=tmpCompName2;
(*p_stComponentShortNameVectGenericAssembly).push_back(msg.c_str( )); msg=tmpCompName;
(*p_stComponentVectGenericAssembly).push_back(msg.c_str( )); msg=Name;
(*p_stParentVectGenericAssembly).push back(msg.c str( ));
   Finally, we call the function TraverseChildrenAndSelect3( ) in a recursive fashion, by passing the new component list as an input argument:
TraverseChildrenAndSelect3(swModel, modExt, pSwApp, tempComp,
p_stComponentShortNameVectGenericAssembly,
p_stComponentVectGenericAssembly, p_stParentVectGenericAssembly);

The GetMassProperties2( ) method utilized in Step 10 of FIG. 15, provides the mass properties of the components selected (here all the components in the assembly). As shown in FIG. 17, the mass properties include the weight, volume, surface area, center of mass, bounding box and moments of inertia. If one is looking for mass properties of components (of a sub-assembly, individual parts etc.) one needs to set a “UseSelected” flag and select all the components which one is looking to include in the calculations. The advantage here is that one does not need to call GetBodies( ) for each component separately.

For an example of how to traverse an assembly using an IComponents2 object, refer to (SolidWorksTraverseAssembly 2022), (SolidWorksGetComponentList 2022) and (SolidWorksTraverseAssembly 2022). Here, the method IComponent2::IGetChildren( ) returns an array, so the code must be used as a part of an in-process DLL. If an in-process DLL is not a preferred approach, one can employ the method IComponent2::GetChildren( ) which returns data structures of type VARIANT.

### 5. Rational for SolidWorks Implementation of Verification of Requirements for Weight and Dimensions

The rational for relying on the SolidWorks API, as opposed to the SolidWorks Document Manager, for extracting the mass properties, pertains to the fact you don't have the ability to select components, in case you use the SolidWorks Document Manager. In this case, you get mass properties for whatever is in the configuration. One can, however, create different configurations in SolidWorks. For additional information, refer to (SolidWorksGetMassPropMethod 2022).

### 6. Alternatives to SolidWorks Implementation of Verification of Requirements for Weight and Dimensions

As an alternative to the GetMassProperties2( ) method, one can utilize the method GetMassProperties Method (IBody2).

As another alternative, one can traverse the assembly-part tree twice. On the first pass, one can retrieve the mass properties for the individual components (at the component level). But on the second pass, one can select (add) components to the overall assembly, and then retrieve the mass properties, for the purpose of obtaining correct mass properties for the overall assembly.

As yet another alternative, the SolidWorks Document Manager can be called in parallel with the SolidWorks API, the thumbnail images extracted in a single pass, using the SolidWorks Document Manager, and then loaded into the Ecosystem design software.

### 7. Specific SolidWorks Implementation of Verification of Requirements for Cost of an Assembly (a Product)

In Step 1 of FIG. 16, we are initializing the COM. The input to Step 1 consists of a SolidWorks assembly, part or a drawing file. In Step 2, we are creating an instance of SolidWorks. In Step 3, we are creating and populating the object pUnknown. In Step 4, we are querying the interface and populating the object class factory swDMClassFact. In Step 5, we are retrieving an object comprising the application. Or more specifically, we are populating the object swDocMgr. In Step 6, we are retrieving the SolidWorks documents. Or more specifically, we are populating the document object for input file type. In Step 7, we are retrieving the names of the Bill of Material tables. In Steps 8-11, we are looping through the SolidWorks tables that comprise the Bill of Material. In Step 8, we are enquiring if all of these SolidWorks tables have been processed? If all of the SolidWorks tables have been processed, then we transition to Step 14, where we decrement a lock count. If all of the SolidWorks tables have not yet been processed in Step 8, then we transition to Step 9, where we obtain the name and pointer to the next SolidWorks table comprising the Bill of Material. In Step 10, we obtain the number of rows and columns for the present SolidWorks table. In Step 11, we check if all of the rows and columns comprising the present SolidWorks table have been processed. If all of the rows and columns for the present SolidWorks table have already been processed, then we transition back to Step 8. If all of the rows and columns for the present SolidWorks table have not all been processed yet, then we transition to Step 12, where we obtain the cell text for the present cell element for the present SolidWorks table. The output of Step 12 (and the output of the algorithm) is the Bill of Material, i.e., all of the SolidWorks tables together with content of each of the cells.

For additional references on how to extract a Bill of Material from a SolidWorks drawing file, refer to (SolidworksExtractBom SldDrw 2022). For references on how to develop macros for SolidWorks, SolidWorks Workgroup or Enterprise PDM, refer to (MikeSpens 2017).

8. Towards Automatic Verification of Requirements Involving the Material Properties from Table 2
One can obtain the names of the material schema, material databases, and bodies in a SolidWorks part file. One can achieve this using the methods GetMaterialDatabases( ) and GetMaterialSchemaPathName( ). To set a SolidWorks material property for a given body, one can use the method SetMaterialProperty( ). Ref. (SolidworksSetMaterialExample 2022) provides an example showing how to apply a SolidWorks material property to all the bodies comprising a SolidWorks component.
9. Towards Automatic Verification of Other Requirements from Categories Listed in Table 2

Once the mass properties for the selection have been obtained in Step 10, and the assembly / component tree has been extracted, one can extract additional properties (members) from the bodies associated with the components:
CComQIPtr<IComponent2>pComp;
pComp=pCompDispArray[i];
   Here pComp represents an object corresponding to a single part file from the assembly. One can store in vBodyArr the sub-assemblies (bodies) behind each component pComp:

```
psaBody = V_ARRAY( &vBodyArr );
LPDISPATCH* pBodyDispArray = NULL;
hr = SafeArrayAccessData( psaBody, (void**) &pBodyDispArray );
Once we have looped over and extracted the bodies
for( int j = 0; j < BodyCount; j++ )
{
  pBody = pBodyDispArray[j];
we can configurate the material properties for the bodies
hr = pBody->SetMaterialProperty( configName, dbName, material,
    &retVal );
```

or access a variety of other properties about the bodies listed in Table 4-Table 8.

TABLE 4
Public members of the IBody2 interface of the SolidWorks
API (extracted from Ref.
(SolidWorksIBody2Interface 2022)). Obsolete members
and public properties have been omitted.

| Member | Description |
|---|---|
| AddConstantFillets | Creates constant radius fillets on |
| | the specified edges on this body |
| AddProfileArc | Creates an arc profile curve and |
| | returns a pointer to that curve |
| AddProfileBspline | Creates an B-spline profile curve |
| | and returns a point to that curve |
| AddProfile- | Adds a profile B-spline |
| BsplineByPts | |
| AddProfileLine | Creates a line profile curve and |
| | returns a pointer to that curve |
| AddPropertyExtenion2 | Adds a property extension to this body |
| AddVertexPoint | Adds a vertex |
| ApplyTransform | Applies a transform to this body |
| Copy2 | Gets a copy of this body |
| CreateBaseFeature | Creates a base feature for the imported body |
| CreateBlendSurface | Creates a constant radius rolling- |
| | ball blend surface (also known as a |
| | pipe surface) between two side surfaces |
| CreateBodyFromFaces | Creates a temporary body from the faces |
| CreateBody- | Creates a body from a list of trimmed surfaces |
| FromSurfaces | |
| CreateBoundedSurface | Creates a bounded surface from |
| | an independent base surface |
| CreateBsplineSurface | Creates a new B-spline surface |
| CreateExtrusionSurface | Creates a new surface of extrusion |
| | (infinitely long tabulated cylinder) |
| GreateNewSurface | Creates a handle for a new surface |
| | to serve as geometry for a face to |
| | be added to the body |
| CreateOffsetSurface | Creates a new surface offset |
| | from an existing surface |
| CreatePlanarSurface | Creates a new infinite planar surface |
| CreatePlanar- | Creates a planar trim surface for this body |
| TrimSurfaceDLL | |
| CreateRevolution- | Creates a new surface of revolution |
| Surface | |
| CreateRuledSurface | Creates a ruled surface from the |
| | specified curves and apex point |
| CreateTempBody- | Creates a temporary body from a |
| FromSurfaces | list of existing trimmed surfaces |
| GreateTrimmedSurface | Creates a trimmed surface from a |
| | base surface and a list of existing |
| | trimming curves |
| DeleteBlends3 | Removes a set of fillet faces from a |
| | temporary body and heals the body |
| DeleteFaces5 | Deletes a set of faces from a temporary body |
| DeleteFaces- | Creates sheet bodies from deleted faces |
| MakeSheetBodies | |
| DeSelect | Deselects this body |
| Diagonse | Gets the IDiagnoseResult object for this body |
| Display3 | Displays this temporary body in the |
| | context of the specified part or component |
| DisplayWire- | Displays a temporary body in the |
| FrameXOR | given part's context in XOR mode |
| DraftBody2 | Adds drafts to the specified faces |
| | on a temporary body. This method |
| | modifies the body. |
| EnumFaces | Returns an enumerated list of the faces in a body |
| ExtendSurface | Creates a new temporary body |
| | by extending the selected edges |
| FindAttribute | Finds an attribute on a body |
| GetBodyBox | Gets the bounding box for this body |
| GetCoincidence- | Calculates the transformation matrix, |
| Transform2 | which would make the input |
| | body coincident with this body if the |
| | transformation matrix is applied |
| GetEdgeCount | Gets the number of edges for this body |

TABLE 5
Additional public members of the IBody2 interface
of the SolidWorks API (extracted from
Ref. (SolidWorksIBody2Interface 2022)).
Obsolete members and public properties have been omitted.

| Member | Description |
|---|---|
| GetEdges | Gets the edges for this body |
| GetExcessBodyArray | Gets the excess bodies after sewing |
| GetExtremePoint | Calculates the extreme point of the |
| | model in the specified direction |
| GetFaceCount | Gets the number of faces in this body |
| GetFaces | Gets all of the faces on the body |
| GetFeatureCount | Gets the number of features in this |
| | body in a multibody sheet metal part |
| GetFeatures | Gets the features in this body in |
| | a multibody sheet metal part |
| GetFirstFace | Finds the first face in a body and returns the face |
| GetFirstSelectedFace | Gets the first selected face on this body. |
| | For use with IBody:: |
| | GetProcessedBodyWithSelFace and intended for |
| | IGES routines |
| GetIgesErrorCode | Gets the current IGES error code |
| GetIgesErrorCount | Gets the number of errors encountered |
| | while running an IGES routine |
| GetIntersectionEdges2 | Gets the edges resulting from the |
| | intersection of the specified tool |
| | body and this body |
| GetMassProperties | Gets the mass properties of this body |
| GetMaterialIdNames2 | Gets the material name for this body |
| Getmaterial- | Gets the names of the material |
| PropertyName | database and the material for the |
| | specified configuration |
| GetMaterial- | Gets the material name for this body; |
| UserName2 | the material name is visible to the user |
| GetMiddleSurface | Inserts a midsurface in a body |
| GetNextSelectedFace | Gets the next selected face. |
| | For use with IBody2:: |
| | GetProcessedBodyWithSelFace |
| | and intended for IGES routines |
| GetOriginal- | Gets the original body from this |
| PatternedBody | patterned body. Also gets the transformation |
| | of this body with respect to the original body. |
| GetProcessedBody2 | Pre-processes the geometry of the |
| | body using the specified parameters |
| GetProcessedBody- | Gets a processed body |
| WithSelFace | |
| GetPropertyExtension2 | Gets the specified property |
| | extension on this body |
| GetSelectedFaceCount | Gets the number of selected |
| | faces on this body. For use with |
| | IBody2::GetProcessedBodyWithSelFace and |
| | IBody2::IGetPrcoessedBodyWithSelFace |
| | and intended for IGES routines. |
| GetSelectedFaced | Gets the selected faces. For use |
| | with IBody2::GetProcessed |
| | BodyWithSelFace and intended |
| | for IGES routines. |
| GetSelectionId | Gets the selection ID of the body, if one exists |
| GetSheetBody | Gets a sheet (surface) body in this body |
| GetTessellation | Gets the ITellellation object |
| GetTexture | Gets the texture applied to this |
| | body in the specified configuration |
| GetTrackingIDs | Gets the tracking IDs assigned to this body |
| GetTrackingIDsCount | Gets the number of tracking IDs on this body |
| GetType | Gets the type of the body |

TABLE 6
Additional public members of the IBody2
interface of the SolidWorks API (extracted from
Ref. (SolidWorksIBody2Interface 2022)). Obsolete
members and public properties have been omitted

| Member | Description |
|---|---|
| GetUpdateStamp | Gets the update stamp for the |
| | body as of the last rebuild |
| GetVertexCount | Gets the number of vertices in this body |
| GetVertices | Gets the vertices in this body |
| HasMaterial- | Gets whether this body has an apperance |
| PropertyValues | |
| Hide | Hides this temporary body in the |
| | context of the specified part |
| HideBody | Hides or shows this body |
| IAddProfileArc | Creates an arc profile curve |
| | and returns a pointer to that curve |
| IAddProfileArcDLL | Adds a profile arc |
| IAddProfileBspline | Creates an B-spline profile curve |
| | and returns a pointer to that curve. |
| IAddProfileBsplineByPts | Adds a profile B-spline |
| IAddProfileBsplineDLL | Adds a profile B-spline |
| IAddProfileLine | Creates a line profile curve and |
| | returns a pointer to that curve |
| IAddProfileLineDLL | Adds a profile line |
| IAddVertexPoint | Adds a vertex |
| ICombineVolumes | Combines the volumes of two bodies |
| ICopy | Gets a copy of this body |
| ICreateBaseFeature | Creates a base feature for the imported body |
| ICreateBlendSurface | Creates a constant radius rolling- |
| | ball blend surface (also known as a |
| | pipe surface) between two side surfaces |
| ICreateBodyFromFaces | Creates a temporary body from the faces |
| ICreateBoundedSurface | Creates a bounded surface from |
| | an independent base surface |
| ICreateBsplineSurface | Creates a new B-spline surface |
| ICreateBspline- | Creates a B-spline surface in this body |
| SurfaceDLL | |
| ICreateExtrusionSurface | Creates a new surface of extrusion |
| | (infinitely long tabulated cylinder) |
| ICreateExtrusion- | Creates an extruded surface |
| SurfaceDLL | |
| ICreateNewSurface | Creates a handle for a new surface |
| | to serve as geometry for a face to |
| | be added to the body |
| ICreateOffsetSurface | Creates a new surface offset |
| | from an existing surface |
| ICreatePlanarSurface | Creates a new infinite planar surface |
| ICreatePlanarSurfaceDLL | Creates a planar surface |
| ICreatePlanar- | Creates a planar trim surface for this body |
| TrimSurfaceDLL | |
| ICreatePsplineSurfaceDLL | Creates a B-surface from a piecewise surface |
| ICreateRevolutionSurface | Creates a new surface of revolution |
| ICreateRevolution- | Creates a surface of revolution for this body |
| SurfaceDLL | |
| ICreateRuledSurface | Creates a ruled surface from the |
| | specified curves and apex point |
| ICreateTemp- | Creates a temporary body from a |
| BodyFromSurfaces | list of existing trimmed surfaces |
| IDeleteBlends3 | Removes a set of fillet faces from a |
| | temporary body and heals the body |
| IDeleteFaces- | Creates sheet bodies from deleted faces |
| MakeSheetBodies | |
| IDeleteFacesMake | Gets the number of sheet bodies to |
| SheetBodiesCount | create from the deleted faces. |
| IDisplayWireFrameXOR | Displays a temporary body in |
| | given part's context in XOR mode. |
| IDraftBody2 | Adds drafts to the specified faces |
| | on a temporary body. This |
| | method modifies the body. |

TABLE 7
Additional public members of the IBody2 interface
of the SolidWorks API (extracted from
Ref. (SolidWorksIBody2Interface 2022)). Obsolete
members and public properties have been omitted

| Member | Description |
|---|---|
| IExtendSurface | Creates a new temporary body |
| | by extending the selected edges |
| IGetBodyBox | Gets the bounding box for this body |
| IGetEdges | Gets the edges for this body |
| IGetExcess- | Gets the excess bodies after sewing |
| BodyArray | |
| IGetExcess- | Gets the number of excess bodies |
| BodyCount | |
| IGetFaces | Gets all of the faces on the body |
| IGetFeatures | Gets the features in this body |
| | in a multibody sheet metal part |
| IGetFirstFace | Finds the first face in a body |
| | and returns the face |
| IGetFirst- | Gets the first selected face |
| SelectedFace | on this body. For use with |
| | IBody2::IGetProcessedBodyWithSelFace |
| | and intended for IGES routines. |
| IGetIntersection- | Gets the number of intersecting edges |
| EdgeCount | between this body and the specified tool body |
| IGetMassProperties | Gets the mass properties of this body |
| IGetMaterial- | Gets the color of the specified face |
| Property | |
| ValuesForFace | |
| IGetMiddleSurface | Inserts a midsurface in a body |
| IGetNext- | Gets the next selected face. For use with |
| SelectedFace | IBody2::GetProcessedBodyWithSelFace |
| | and intended for IGES routines. |
| IGetProcessedBody | Gets a processed body |
| WithSelFace | |
| IGetSelectedFaces | Gets the selected faces. |
| | For use with IBody2::GetProcessed |
| | BodyWithSelFace and intended for IGES routines. |
| IGetSheetBody | Gets a sheet (surface) body in this body |
| IGetTessellation | Gets the ITessellation object |
| IGetTrackingIDs | Gets the tracking IDs assigned to this body. |
| IGetVertices | Gets the vertices in this body |
| IHide | Hides a temporary body using |
| | the specified part's context |
| IMatchedBoolean4 | Performs a matched boolean on |
| | the specified bodies and supports an |
| | optional list of faces that match exactly. |
| IOperations2 | Performs add, cut, and intersect |
| | (unite, subtract, and interfere) operations |
| | between two temporary bodies. |
| IRemoveFaces- | Removes the specified faces from |
| FromSheet | a sheet (surface) body |
| IRemoveMaterial- | Removes the material property values |
| Property | (e.g., color) from the body in the |
| | specified configurations in parts and assemblies. |
| ISave | Saves this body |
| ISectionBySheet | Sections a body using a sheet (surface) body |
| ISetCurrentSurface | Places an existing surface into a |
| | temporary body that is under construction. |
| IsMeshBody | Gets whether this body is a mesh body |
| IsPatternSeed | Gets whether this body is the |
| | seed of a patterned body |
| IsSheetMetal | Gets whether this body was |
| | created by a sheet metal feature |
| IsTemperaryBody | Gets whether the body is a temporary body |
| MakeOffset | Creates a new temporary body by |
| | offsetting the selected surface body by |
| | the specified distance and in the specified direction. |

TABLE 8
Additional public members of the IBody2 interface of the SolidWorks API (extracted from Ref.
(SolidWorksIBody2Interface 2022)). Obsolete members and public properties have been omitted

| Member | Description |
|---|---|
| MatchedBoolean4 | Performs a matched boolean on the specified bodies and supports an |
| | optional list of faces that match exactly |
| MinimumRadius | Gets the minimum radius of this body |
| Negate | Reverses the direction (i.e., orientation) of the body. |
| OffsetPlanarWireBody | Offsets a planar wire body in the normal plane by the specified distance. |
| Operations2 | Performs add, cut, and intersect (unite, subtract, and interfere) operations |
| | between two temporary bodies. |
| RemoveFacesFromSheet | Removes the specified faces from a sheet (surface) body |
| RemoveMaterialProperty | Removes the material property values (e.g., color) from the body in the |
| | specified configurations in parts and assemblies. |
| RemoveRedundantTopology | Removes redundant topology from the body |
| RemoveTexture | Removes the texture applied to this body in the specified configuration |
| RemoveTextureBy | Removes the texture applied to this body in the specified display state |
| Displaystate | |
| RemoveTrackingID | Removes a tracking ID assigned to this body |
| ResetEdgeTolerances | Resets the tolerance on all edges of this body |
| ResetPropertyExtension2 | Clears all values stored in the property extension |
| Save | Saves this body |
| Select2 | Selects this body and marks it |
| SetCurrentSurface | Places an existing surface into a temporary body that is under construction |
| SetIgesInfo | Sends IGES-specific data to the geometric modeler |
| SetMaterialIdName2 | Sets the material name for this body |
| SetMaterialProperty | Sets the material for this body |
| SetMaterialUserName2 | Sets the material name for this body. This material name is visible to user. |
| SetTexture | Applies texture to this body in the specified configuration |
| SetTextureByDisplayState | Sets the texture applied to this body in the specified display state |
| SetTrackingID | Assigns a tracking ID to this body |

Similarly, one can utilize the IComponents2 interface to extract a variety of data associated with specific SolidWorks components:

```
for( int i = 0; i < nCopmCount; i++ )
{
  CComQIPtr <IComponent2> pComp;
  pComp = pCompDispArray[i];
// hr = pComp->SetMaterialPropertyValues2 ( VARIANT
  Material_values/*[in]*/, long Config_opt/*[in]*/, VARIANT
  Config_names/*[in]*/ );
  hr = pComp->get_Name2 ( &sCompMateName );
```

Table 9-Table 12 list a subset of members of the IComponent2 interface from the SolidWorks API.

TABLE 9
Members of the IComponent2 interface of the SolidWorks API (extracted from Ref.
(SolidWorksIComponent2Interface 2022)). Obsolete members and public properties omitted.

| Member | Description |
|---|---|
| AddPropertyExtension | Adds a property extension to this component |
| DeSelect | Deselects this component |
| EnumBodies3 | Gets the bodies in the component in a multibody part |
| EnumRelatedBodies | Creates an enumerated list of bodies |
| EnumSectionedBodies | Gets the sectioned bodies seen in the specified view and returns |
| | them in an enumerated list |
| FeatureByName | Gets the specified feature for this component |
| FindAttribute | Finds an attribute on a component |
| FirstFeature | Gets the first feature in this component |
| GetBodies3 | Gets the bodies in this component |
| GetBody | Gets the body that belongs to this instance of this component |
| GetBox | Gets the bounding box for component |
| GetChildren | Gets all of the children components of this component |
| GetConstrainedStatus | Gets the constrained status of this component |
| GetCorrespending | Gets the corresponding object in the context of the assembly for a |
| | specific instance of the component |
| GetCorrespondingEntity | Gets the entity that corresponds with the Dispatch pointer in the |
| | context of the component |
| GetDecals | Gets the decals applied to this component |
| GetDecalsCount | Gets the number of decals applied to this component |
| GetDrawingComponent | Gets the drawing component for this component |
| GetHiddenUnloaded | Gets the number of hidden children components of this component |
| ChildrenCount | that were not loaded when an assembly was opened selectively. |
| GetID | Gets the component ID for this component |
| GetImportedPath | Gets the full path name of the model imported for this component |
| GetMaterialIdName | Gets the material name for this component |
| GetMaterialProperty | Gets the material properties for this component |
| Values2 | |
| GetMaterialUserName | Gets the user-visible name of the material for this component |
| GetMates | Gets the mates for this component |
| GetModelDoc2 | Gets the model document for this component |
| GetModelMaterial | Gets the material properties of this lightweight component in the |
| PropertyValues | specified configuration |
| GetModelTexture | Gets the texture applied to this lightweight component in the |
| | specified configuration |
| GetParent | Gets the parent component |
| GetPathName | Gets the full path name for this component |
| GetPropertyExtension | Gets the property extension on this component |
| GetRenderMaterials2 | Gets the appearances applied to this component in the specified |
| | display states |

TABLE 10
Additional members of the IComponent2 interface of the SolidWorks API (extracted from
Ref. (SolidWorksIComponent2Interface 2022)). Obsolete members and public properties omitted.

| Member | Description |
|---|---|
| GetRenderMaterialsCount2 | Gets the number of appearances applied to this component in |
| | the specified display states |
| GetSectionedBodies | Gets the sectioned bodies in the specified section view |
| GetSelectByIDString | Gets the name of the component for possible use with |
| | IModelDocExtension: :SelectByID2, for selectively opening a |
| | document using ISldWorks: :OpenDoc7 and |
| | IDocumentSpecification, etc. |
| GetSmartComponentData | Gets the features, components, and feature references of a |
| | Smart Component |
| GetSpecificTransform | Get the collapsed or exploded transform of a component when |
| | the assembly is exploded |
| GetSuppression | Gets the suppression state of this component |
| GetTessNorms | Gets the normal vector for each of the triangles, which make |
| | up the shaded picture tessellation for the component |
| GetTessTriangles | Gets the triangles that make up the shaded picture tessellation |
| | for this component |
| GetTessTriStripEdges | Gets the edge IDs for the triangle strips |
| GetTessTriStripNorms | Gets the normal vector for each of the triangles, which make |
| | up the shaded picture tessellation for this component |
| GetTessTriStrips | Gets the vertices that make up the shaded picture tessellation |
| | for this component |
| GetTexture | Gets the texture applied to this component in the specified |
| | configuration |
| GetTotalTransform | Combines the original transform of this component with the |
| | presentation transform of this component |
| GetUnloadedComponent | Gets the component's unloaded children components' path |
| Names | names, referenced configuration names, reasons why they are |
| | unloaded, document types, and names |
| GetVisibility | Gets the visibility state for this component |
| HasMaterialPropertyValues | Gets whether this component has an appearance |
| HasUnloadedComponents | Gets whether this component has hidden or suppressed |
| | unloaded children components |
| IFindAttribute | Finds an attribute on a component |
| IGetBody | Gets the body that belongs to this instance of this component |
| IGetBox | Gets the bounding box for component |
| IGetChildren | Gets all of the children components of this component |
| IGetChildrenCount | Gets the number of children components for this component. |
| IGetCorrespondingEntity | Gets the entity that corresponds with the Dispatch pointer in |
| | the context of the component |
| IGetDecals | Gets the decals applied to this component |
| IGetMaterialPropertyValue | Gets the material properties for this component |

TABLE 11
Additional members of the IComponent2 interface of the SolidWorks API (extracted from Ref.
(SolidWorksIComponent2Interface 2022)). Obsolete members and public properties have been omitted.

| Member | Description |
|---|---|
| IGetMaterialProperty | Gets the color of the specified face |
| ValuesForFace | |
| IGetModelMaterial | Gets the material properties of this lightweight component in the |
| PropertyValues | specified configuration |
| IGetTemporaryBodyID | Gets the current body tag ID, which is not a permanent ID |
| IGetTessNorms | Gets the normal vector for each of the triangles, which make up |
| | the shaded picture tessellation for the component |
| IGetTessTriangleCount | Gets the number of triangles that make up the shaded picture |
| | tessellation for this component |
| IGetTessTriangles | Gets the triangles that make up the shaded picture tessellation for |
| | this component |
| IGetTessTriStripEdges | Gets the edge IDs for the triangle strips |
| IGetTessTriStripEdgeSiz | Gets the number of tessellation triangle edges |
| IGetTessTriStripNorms | Gets the normal vector for each of the triangles, which make up |
| | the shaded picture tessellation for this component |
| IGetTessTriStrips | Gets the vertices that make up the shaded picture tessellation for |
| | this component |
| IGetTessTriStripSize | Gets the array size of floats required to contain the data returned |
| | when calling IComponent2: :IGetTessTriStrips |
| IGetVisibility | Gets the visibility state for this component |
| IListExternalFile | Gets the names and statuses of the external references on the |
| References2 | component |
| IRemoveMaterial | Removes material property values from the component |
| Property2 | |
| IsDisplayDataOutOfDate | Gets the status of the display data for this component |
| IsEnvelope | Gets whether this component is an envelope |
| ISetMaterial | Sets the material properties for this component |
| PropertyValues2 | |
| ISetVisibility | Sets the visibility state for this component |
| IsFixed | Gets whether the component is fixed or floating |
| IsHidden | Gets whether this component is hidden or suppressed |
| IsLoaded | Gets whether a component is loaded |
| IsMirrored | Gets whether this component is mirrored |
| IsPatternInstance | Gets whether the component is a member of a pattern instance |
| IsRoot | Gets whether this component is the root component |
| IsSmartComponent | Gets whether this component is a Smart Component |
| IsSuppressed | Gets whether this component is suppressed |
| ListExternalFile | Gets the names and statuses of the external file references on the |
| References2 | component |
| ListExternalFile | Gets the number of external references on the component |
| ReferencesCount | |

TABLE 12
Additional members of the IComponent2 interface of the SolidWorks API (extracted from Ref.
(SolidWorksIComponent2Interface 2022)). Obsolete members and public properties have been omitted.

| Member | Description |
|---|---|
| MakeVirtual2 | Makes this component and optionally its child components virtual |
| | by saving them in the current assembly |
| RemoveMaterialProperty2 | Removes the appearance from the component |
| RemovePresentation | Removes the presentation transform from this component |
| Transform | |
| RemoveTexture | Removes the texture from this component in the specified configuration |
| RemoveTextureBy | Removes the texture applied to this component in the specified display state |
| DisplayState | |
| ResetPropertyExtension | Clears all of the values stored in the property extension |
| SaveVirtualComponent | Saves a virtual component to an external file |
| Select4 | Selects the component |
| SetCosmosWorksMaterial | Assigns the material to use during analysis to this component |
| SetMaterialIdName | Sets the material name for this component |
| SetMaterialPropertyValues2 | Sets the material properties for this component |
| SetMaterialUserName | Sets the material user name for this component |
| SetSmartComponentData | Sets the features, components, and feature references of a Smart Component |
| SetSuppression2 | Sets the suppression state of this component |
| SetTexture | Applies texture to this component in the specified configuration. |
| SetTextureByDisplayState | Sets the texture applied to this component in the specified display state. |
| SetTransformAndSolve2 | Sets the transform and solves for the mates for this component |
| SetVisibility | Sets the visibility state for this component |
| UpdateExternalFile | Updates the external file references of this model |
| References | |

Further along such lines, one can utilize the IModelDoc2 interface to extract a variety of data related to the SolidWorks model swModel mentioned in Step 5, 7 and 8 of FIG. 15:

// Here we are querying for the units used by the SolidWorks model (assembly).
// >> Note that unless otherwise stated, all SOLIDWORKS API functions use metric
units.
// >> Specifically, the SOLIDWORKS API accepts or returns values as meters,
radians, kilograms, square meters, or cubic meters.
//>>http://help.solidworks.com/2018/english/api/sldworksapiprogguide/overview/units.htm
hr = swModel->IGetUnits( unitArray );

Table 13-Table 26 list a subset of members of the IModelDoc2 interface from the SolidWorks API.

TABLE 13
Members of the IModelDoc2 interface of the SolidWorks API (extracted from Ref.
(SolidWorksIModelDoc2Interface 2022)). Obsolete members and public properties omitted.

| Member | Description |
|---|---|
| ActivateSelectedFeature | Activates the selected feature for editing. |
| AddConfiguration3 | Adds a new configuration to this model document |
| AddDiameterDimension2 | Adds a diameter dimension at the specified location for the selected item. |
| AddDimension2 | Creates a display dimension at the specified location for selected entities. |
| AddFeatureMgrView3 | Adds the specified tab to the FeatureManager design tree view |
| AddHorizontalDimension2 | Creates a horizontal dimension for the currently selected |
| | entities at the specified location |
| AddIns | Displays the Add-In Manager dialog box |
| AddLightSource | Adds a type of light source to a scene with the specified names |
| AddLightSourceExtProperty | Stores a float, string, or integer value for the light source |
| AddLightToScene | Adds a light source to a scene |
| AddLoftSection | Adds a loft section to a blend feature |
| AddPropertyExtension | Adds a property extension to this model |
| AddRadialDimension2 | Adds a radial dimension at the specified location for the selected item |
| AddSceneExtProperty | Stores a float, string, or integer value for a scene |
| AddVerticalDimension2 | Creates a vertical dimension for the currently selected entities at the |
| | specified location |
| AlignOrdinate | Aligns the selected group of ordinate dimensions |
| AlignParallelDimensions | Aligns the selected linear dimensions in a parallel fashion |
| BlankRefGeom | Hides the selected reference geometry in the graphics window. |
| BlankSketch | Hides the selected sketches |
| BreakDimensionAlignment | Breaks the association of any selected dimensions belonging to an |
| | alignment group (parallel or collinear) |
| ClearSelection2 | Clears the selection list |
| ClearUndoList | Clears the undo list for this model document |
| Close | Not implemented. Use ISldWorks: :CloseDoc. |
| CloseFamilyTable | Closes the design table currently being edited |
| ClosePrintPreview | Closes the currently displayed Print Preview page for this document |
| ClosestDistance | Calculates the minimum distance between the specified geometric objects |
| CreateArcByCenter | Creates an arc by center in this model document |
| GreateCenterLineVB | Creates a center line from P1 to P2 and can be used in Visual |
| | Basic for Applications (VBA) and other forms of Basic that do not support |
| | SafeArrays |
| CreateClippedSplines | Creates one or more sketch spline segments that are clipped against a |
| | given (x1, y1), (x2, y2) rectangle. This rectangle lies in the space of the |
| | active 2D sketch. |

TABLE 14
Additional members of the IModelDoc2 interface of the SolidWorks API (extracted from Ref.
(SolidWorksIModelDoc2Interface 2022)). Obsolete members and public properties omitted.

| Member | Description |
|---|---|
| CreateGroup | Creates an annotation group from the currently selected annotations. |
| DeActivateFeatureMgrView | Deactivates a tab in the FeatureManager design tree view |
| DebugCheckIgesGeom | Dumps a IGES geometry check |
| DeleteAllRelations | Deletes all existing relations |
| DeleteBendTable | Deletes a bend table |
| DeleteBkgImage | Deletes any background image |
| DeleteConfiguration2 | Deletes a configuration |
| DeleteDesignTable | Deletes the design table for this document, if one exists |
| DeleteFeatureMgrView | Removes the specified tab in the FeatureManager design tree |
| DeleteLightSource | Deletes a light source |
| DeleteNamedView | Deletes the specified model view |
| DeriveSketch | Creates a derived sketch |
| DeSelectByID | Removes the selected object from the selection list. |
| DimPreferences | Sets dimension preferences |
| DissolveLibraryFeature | Dissolves the selected library features |
| DissolveSketchText | Dissolves sketch text |
| DragTo | Drags the specified end point |
| DrawLightIcons | Draws any visible light icons |
| EditConfiguration3 | Edits the specified configuration |
| EditCopy | Copies the currently selected items and places them in the clipboard |
| EditCut | Cuts the currently selected items and places them on the Microsoft |
| | Windows Clipboard |
| EditDatumTargetSymbol | Edits a datum target symbol |
| EditDelete | Deletes the selected items |
| EditOrdinate | Puts the currently selected ordinate dimension into edit mode so you |
| | could add more ordinate dimensions to this group |
| EditRebuild3 | Rebuilds only those features that need to be rebuilt in the active |
| | configuration in the model |
| EditRedo2 | Repeats the specified number of actions in this SOLIDWORKS session |
| EditRoute | Makes the last selected route the active route |
| EditSeedFeat | Gets the pattern seed feature, based on the selected face, and displays |
| | the Edit Definition dialog for that feature |
| EditSketch | Allows the currently selected sketch to be edited |
| EditSketchOrSingle | Edits a selected sketch or feature sketch |
| SketchFeature | |
| EditSuppress2 | Suppresses the selected feature, the selected component, or the owning |
| | feature of the selected face |
| EditUndo2 | Undoes the specified number of actions in the active SOLIDWORKS |
| | session |

TABLE 15
Additional members of the IModelDoc2 interface of the SolidWorks API (extracted from Ref.
(SolidWorksIModelDoc2Interface 2022)). Obsolete members and public properties omitted.

| Member | Description |
|---|---|
| EditUnsuppress2 | Unsuppresses the selected feature or component |
| EditUnsuppressDependent2 | Unsuppresses the selected feature or component and their dependents. |
| EntityProperties | Displays the Properties dialog for the selected edge or face |
| EnumModelViews | Gets the model views enumeration in this document |
| FeatEdit | Puts the current feature into edit mode |
| FeatEditDef | Displays the Feature Definition dialog and lets the user edit the values |
| FeatureByPositionReverse | Gets the nth from last feature in the document |
| FeatureChamfer | Creates a chamfer feature |
| FeatureReferenceCurve | Creates a reference curve feature from an array of curves |
| FileSummaryInfo | Displays the File Summary Information dialog box for this file |
| FirstFeature | Gets the first feature in the document |
| FontBold | Enables or disables bold font style in the selected notes, dimensions, |
| | and GTols |
| FontFace | Changes the font face in the selected notes, dimensions, and GTols |
| FontItalic | Enables or disables italic font style in the selected notes, dimensions, |
| | and GTols |
| FontPoints | Changes the font height (specified in points) in the selected notes, |
| | dimensions, and GTols |
| FontUnderline | Enables or disables underlining the selected notes, dimensions, |
| | and GTols |
| FontUnits | Changes font height (specified in current system units) in the selected |
| | notes, dimensions, and GTols |
| ForceRebuild3 | Forces a rebuild of all features in the active configuration in the model |
| ForceReleaseLocks | Releases the locks that a file system places on a file when it is opened |
| | and detaches that file from the file system |
| GetAddToDB | Gets whether entities are added directly to the SOLIDWORKS database |
| GetAmbientLightPropertie | Gets the ambient light properties for this model document |
| GetAngularUnits | Gets the current angular unit settings |
| GetArcCentersDisplayed | Gets whether the arc centers are displayed |
| GetBendState | Gets the current bend state of a sheet metal part |
| GetBlockingState | Gets the current value of the SOLIDWORKS blocking state, within the |
| | range of values accessible by IModelDoc2: :SetBlockingState |
| GetConfigurationByName | Gets the specified configuration |
| GetConfigurationCount | Gets the number of configurations |
| GetConfigurationNames | Gets the names of the configurations in this document |

TABLE 16
Additional members of the IModelDoc2 interface of the SolidWorks API (extracted from Ref.
(SolidWorksIModelDoc2Interface 2022)). Obsolete members and public properties omitted.

| Member | Description |
|---|---|
| GetConsiderLeadersAsLine | Gets whether the display data of a leader is included as lines when the lines are |
| | retrieved from a view or annotation in this document |
| GetCurrentCoordinate | Gets the name of the current coordinate system or an empty string for |
| SystemName | the default coordinate system |
| GetDefaultTextHeight | Gets the default text height in use for this document |
| GetDesignTable | Gets the design table associated with this part or assembly document |
| GetDirectionLightProperties | Gets the directional light properties |
| GetDisplayWhenAdded | Gets whether new sketch entities are displayed when created |
| GetEntityName | Gets the name of the specified face, edge, or vertex |
| GetEquationMgr | Gets the equation manager |
| GetExternalReferenceName | Gets the name of the externally referenced document (in the case of a join or |
| | mirrored part) |
| GetFeatureCount | Gets the number of features in this document |
| GetFeatureManagerWidth | Gets the width of the FeatureManager design tree |
| GetFirstAnnotation2 | Gets the first annotation in the model |
| GetFirstModelView | Gets the first view in a model document |
| GetGridSettings | Gets the current grid settings |
| GetLayerManager | Gets the layer manager for the current drawing document |
| GetLightSourceCount | Gets the number of light sources |
| GetLightSourceExtProperty | Gets a float, string, or integer value stored for the light source |
| GetLightSourceIdFromName | Gets the ID of the specified light source |
| GetLightSourceName | Gets the name of a light source used internally by the SOLIDWORKS application |
| GetLineCount | Gets the number of lines in the current sketch |
| GetLines | Gets all of the lines in the current sketch |
| GetModelViewNames | Gets a list containing the names of each model view in this document |
| GetNext | Gets the next document in the current SOLIDWORKS session |
| GetNumDependencies | Gets the number of strings returned by IModelDoc2: :GetDependencies2 |
| GetPathName | Gets the full path name for this document, including the file name |
| GetPointLightProperties | Gets point light properties |
| GetPopupMenuMode | Gets the current pop-up menu mode |
| GetPropertyExtension | Gets the specified property extension on this model |
| GetRayIntersectionsPoints | Gets the intersection point information generated by IModelDoc2: :RayIntersections. |

TABLE 17
Additional members of the IModelDoc2 interface of the SolidWorks API (extracted from Ref.
(SolidWorksIModelDoc2Interface 2022)). Obsolete members and public properties omitted.

| Member | Description |
|---|---|
| GetRayIntersections | Gets the topology intersections generated by |
| Topology | IModelDoc2: :RayIntersections |
| GetSaveFlag | Gets whether the document is currently dirty and needs to be saved |
| GetSceneBkgDIB | Gets background image as a LPDIBSECTION |
| GetSceneExtProperty | Gets a float, string, or integer value stored for the scene |
| GetSpotlightProperties | Gets the spotlight properties |
| GetStandardViewRotation | Gets the specified view orientation matrix with respect to the Front view |
| GetTessellationQuality | Gets the shaded-display image quality number for the current document |
| GetTitle | Gets the title of the document that appears in the active window's title bar |
| GetToolbarVisibility | Gets the visibility of a toolbar |
| GetType | Gets the type of the document |
| GetUnits | Gets the current unit settings, fraction base, fraction value, and significant digits |
| GetUpdateStamp | Gets the current update stamp for this document |
| GetUserUnit | Gets this document's units settings |
| GetVisibilityOf | Gets whether construction (reference) planes are currently visible |
| ConstructPlanes | |
| GetZebraStripeData | Gets zebra line data |
| HideComponent2 | Hides the selected component |
| HideCosmeticThread | Hides the selected cosmetic thread. |
| HideDimension | Hides the selected dimension in this document |
| HideShowBodies | Sets whether to hide or show the bodies in the model |
| HideSolidBody | Hides the currently selected solid body |
| IAddConfiguration3 | Adds a new configuration to this model document |
| IAddDiameterDimension2 | Adds a diameter dimension at the specified location for the selected item |
| IAddHorizontalDimension2 | Creates a horizontal dimension for the current selected entities at the specified |
| | location |
| IAddRadialDimension2 | Adds a radial dimension at the specified location for the selected item |
| IAddVerticalDimension2 | Creates a vertical dimension for the currently selected entities at the specified |
| | location |
| IClosestDistance | Calculates the distance and closest points between two geometric objects |
| ICreateArc2 | Creates an arc based on a center point, a start, an end point, and a direction |
| ICreateCenterLine | Creates a center line from P1 to P2 |
| ICreateCircle2 | Creates a circle based on a center point and a point on the circle |

TABLE 18
Additional members of the IModelDoc2 interface of the SolidWorks API (extracted from Ref.
(SolidWorksIModelDoc2Interface 2022)). Obsolete members and public properties omitted.

| Member | Description |
|---|---|
| ICreateCircleByRadius2 | Creates a circle based on a center point and a specified radius |
| ICreateClippedSplines | Creates one or more sketch spline segments that are clipped against a |
| | given (x1, y1), (x2, y2) rectangle. This rectangle lies in the space of |
| | the active 2D sketch. |
| ICreateEllipse2 | Creates an ellipse using the specified center point and points |
| ICreateEllipticalArc2 | Creates a partial ellipse given a center point, two points that specify |
| | the major and minor axis, and two points that define the elliptical |
| | start and end points. |
| ICreateEllipticalArcByCenter | Creates an elliptical arc trimmed between two points |
| ICreateLine2 | Creates a sketch line in the currently active 2D or 3D sketch |
| IFeatureByPositionRevers | Gets the nth from last feature in the document |
| IFeatureReferenceCurve | Creates a reference curve feature from an array of curves |
| IFirstFeature | Gets the first feature in the document |
| IGet3rdPartyStorage | Gets the IStream interface to the specified third-party stream inside |
| | this SOLIDWORKS document |
| IGetActiveSketch2 | Gets the active sketch. |
| IGetAngularUnits | Gets the current angular unit settings. |
| IGetConfigurationByName | Gets the specified configuration |
| IGetConfigurationNames | Gets the names of the configurations in this document |
| IGetDependencies2 | Gets all of the model's dependencies |
| IGetDesignTable | Gets the design table associated with this part or assembly document |
| IGetEntityName | Gets the name of the specified face, edge, or vertex |
| IGetFirstAnnotation2 | Gets the first annotation in the model |
| IGetFirstModelView | Gets the first view in a model document |
| IGetLayerManager | Gets the layer manager of the current drawing document |
| IGetLines | Gets all of the lines in the current sketch |
| IGetModelViewNames | Gets a list containing the names of each model view in this document |
| IGetNext | Gets the next document in the current SOLIDWORKS session |
| IGetNumDependencies2 | Gets the number of strings returned by |
| | IModelDoc2: :IGetDependencies2 |
| IGetRayIntersectionsPoints | Gets the intersection point information generated by |
| | IModelDoc2: :IRayIntersections |
| IGetRayIntersectionsTopology | Gets the topology intersections generated by |
| | IModelDoc2: :IRayIntersections |
| IGetStandardViewRotation | Gets the specified view orientation matrix with respect to the Front view. |
| IGetUnits | Gets the current unit settings, fraction base, fraction value, and |
| | significant digits |
| IGetUserUnit | Gets this document's units settings |

TABLE 19
Additional members of the IModelDoc2 interface of the SolidWorks API (extracted from Ref.
(SolidWorksIModelDoc2Interface 2022)). Obsolete members and public properties omitted.

| Member | Description |
|---|---|
| IGetVersionHistoryCount | Gets the size of the array required to hold data returend by |
| | IModleDoc2: :IVersionHistory |
| IInsertDatumTag2 | Inserts a datum tag symbol at the selected location |
| IInsertGtol | Creates a new geometric tolerance symbol (GTol) in this document |
| IInsertNote | Inserts a note in this document |
| IInsertProjectedSketch2 | Projects the selected sketch items from the current sketch onto a selected surface |
| IInsertSketchForEdge | Inserts a sketch for IFeatureManager: :InsertSheetMetalEdgeFlange2 in this |
| Flange | sheet metal part. |
| IInsertSketchText | Inserts sketch text |
| IInsertWeldSymbol3 | Inserts a weld symbol into the model |
| IListAuxiliaryExternal | Gets the names of auxiliary external file references for this model |
| FileReferences | |
| IMultiSelectByRay | Selects multiple objects of the specified type that are intersected by a ray from |
| | point (x, y, z in meters) in direction vector (x, y, z) within a distance radius. |
| Insert3DSplineCurve | Inserts a 3D-spline curve through the selected reference points |
| InsertAxis2 | Inserts a reference axis based on the currently selected items with an option |
| | to automatically size the axis |
| InsertBendTableEdit | Inserts a bend table and puts the bend table into its edit state |
| InsertBendTableNew | Inserts a new bend table into the model document |
| InsertBendTableOpen | Inserts an existing bend table from a file into this model document |
| InsertBkgImage | Inserts the scene background image |
| InsertCompositeCurve | Inserts a composite curve based on selections |
| InsertConnectionPoint | Adds a connection point based on the selected point and selected planar item |
| InsertCurveFile | Creates a curve |
| InsertCurveFileBegin | Creates a curve |
| InsertCurveFileEnd | Creates a curve |
| InsertCurveFilePoint | Creates a point for a curve |
| InsertDatumTag2 | Inserts a datum tag symbol at a selected location |
| InsertDome | Inserts a dome |
| InsertExtendSurface | Extends a surface along the selected faces or edges |
| InsertFamilyTableEdit | Edits an open design table from Microsoft Excel |
| InsertFamilyTableNew | Inserts an existing design table from the model into the selected drawing view |
| InsertFamilyTableOpen | Inserts the specified Microsoft Excel design table |
| InsertFeatureReplaceFace | Creates a Replace Face feature |
| InsertFeatureShell | Creates a shell feature |

TABLE 20
Additional members of the IModelDoc2 interface of the SolidWorks API (extracted from Ref.
(SolidWorksIModelDoc2Interface 2022)). Obsolete members and public properties omitted.

| Member | Description |
|---|---|
| InsertFeatureShell | Adds thickness to a face in a multi-thickness shell feature |
| AddThickness | |
| InsertGtol | Creates a new geometric tolerance symbol (GTol) in this document |
| InsertHatchedFace | Hatches the selected faces or closed sketch segments in a drawing |
| InsertHelix | Creates a constant-pitch helix or spiral |
| InsertLoftRefSurface2 | Creates a loft surface from the selected profiles, centerline, and guide curves |
| InsertNewNote3 | Creates a new note |
| InsertNote | Inserts a note in this document |
| InsertObject | Activates the Microsoft Insert Object dialog |
| InsertOffsetSurface | Inserts an offset surface |
| InsertPlanarRefSurface | Inserts a planar reference surface |
| InsertPoint | Inserts a point in this model document |
| InsertRadiateSurface | Creates a radiate surface based on the selections |
| InsertRefPoint | Inserts a reference point based on the current selections |
| InsertRip | Creates a rip feature |
| InsertRoutePoint | Adds a route point based on the selected point |
| InsertSheetMetalBreak | Inserts a break corner into a sheet metal part |
| Corner | |
| InsertSheetMetalClosed | Inserts a sheet metal closed corner into this model document |
| Corner | |
| InsertSheetMetalFold | Inserts a fold feature at the selected objects |
| InsertSheetMetalJog | Inserts a sheet metal jog in the current model document |
| InsertSheetMetalUnfold | Inserts an unfold feature at the selected objects |
| InsertSketchForEdge | Inserts a sketch for IFeatureManager: :InsertSheetMetalEdgeFlange2 in this |
| Flange | sheet metal part. |
| InsertSketchPicture | Inserts a picture into the current sketch |
| InsertSketchPictureData | Inserts a picture into the current sketch |
| InsertSketchPictureDatax64 | Inserts a picture into the current sketch in 64-bit applications |
| InsertSketchText | Inserts sketch text |
| InsertSplinePoint | Inserts a spline point |
| InsertSplitLineProject | Splits a face by projecting sketch lines onto the face |
| InsertSplitLineSil | Splits a face by creating split lines along the silhouette of the selected faces |
| InsertWeldSymbol3 | Inserts a weld symbol into the model |
| InspectCurvature | Adds curvature combs to the selected sketch segment |
| IParameter | Gets the specified parameter |
| IRelease3rdPartyStorage | Releases the specified third-party stream |

TABLE 21
Additional members of the IModelDoc2 interface of the SolidWorks API (extracted from Ref.
(SolidWorksIModelDoc2Interface 2022)). Obsolete members and public properties omitted.

| Member | Description |
|---|---|
| IsActive | Gets whether the specified assembly component is shown or hidden in |
| | this model document |
| IsEditingSelf | Gets whether this model is being edited in the context of another document |
| ISetAngularUnits | Sets the current angular units |
| ISetNextSelectionGroupId | Sets the group ID for all remaining selections |
| ISketchSplineByEqnParams | Creates a spline on the active 2D sketch using the specified b-curve parameters |
| IsLightLockedToModel | Gets whether the specified light is fixed |
| IsOpenedReadOnly | Gets whether a SOLIDWORKS document is open in read-only mode |
| IsOpenedViewOnly | Gets whether a SOLIDWORKS document is open in view-only mode |
| IsTessellationValid | Gets whether the current set of facets is valid |
| IVersionHistory | Gets an array of strings indicating the versions in which this model document |
| | was saved, including the SOLIDWORKS version in which the model |
| | document is currently opened and which is the last value returned in the array. |
| LBDownAt | Generates a left mouse button press (down) event |
| LBUpAt | Generates a left-mouse button release (up) event |
| ListAuxiliaryExternal | Gets the names of auxiliary external file references for this model |
| FileReferences | |
| ListAuxiliaryExternal | Gets the number of auxiliary external file references for this model |
| FileReferencesCount | |
| Lock | Blocks the modifying commands in the user interface, effectively locking |
| | the application |
| LockAllExternalReference | Locks all external references |
| LockLightToModel | Locks or unlocks the specified light |
| MoldDraftAnalysis | Performs a mold draft analysis |
| MultiSelectByRay | Selects multiple objects of the specified type that are intersected by a ray from |
| | point (x, y, z in meters) in direction vector (x, y, z) within a distance radius |
| NameView | Creates a named view using the current view |
| ObjectDisplayAsIcon | Shows the current OLE object as an icon |
| ObjectDisplayContent | Shows the current OLE object's content |
| ObjectResetsize | Sets the size of the current OLE object to the default |
| Parameter | Gets the specified parameter |
| ParentChildRelationship | Shows the Parent/Child Relationships dialog for the selected feature. |
| Paste | Pastes the contents of the Microsoft Windows Clipboard at the current |
| | insertion point. |
| PrintDirect | Prints the current document to the default printer |

TABLE 22
Additional members of the IModelDoc2 interface of the SolidWorks API (extracted from Ref.
(SolidWorksIModelDoc2Interface 2022)). Obsolete members and public properties omitted.

| Member | Description |
|---|---|
| PrintPreview | Displays the Print Preview page for the current document |
| Propertysheet | Displays the selected object's property sheet |
| Quit | Closes the active document without saving changes (see Remarks) |
| ReattachOrdinate | Reattaches an ordinate dimension to a different entity |
| ReloadOrReplace | Reloads or replaces the current model document |
| RemoveGroups | Removes any annotation groups in the current selection |
| RemoveInspectCurvature | Removes curvature combs from the selected curved sketch segment |
| RemoveItemsFromGroup | Removes the selected annotations from their annotation groups |
| ResetBlockingState | Resets the blocking state for the SOLIDWORKS menus |
| ResetLightSource | Resets the properties for a light source |
| ExtProperty | |
| ResetPropertyExtension | Clears all values stored in the property extension |
| ResetSceneExtProperty | Resets the extension property for a scene |
| Save3 | Saves the current document |
| SaveBMP | Saves the current view as a bitmap (BMP) file |
| Scale | Scales the part |
| ScreenRotate | Switches between model and screen center rotation |
| SelectedEdgeProperties | Sets the property values of the selected edge |
| SelectedFaceProperties | Sets the material property values of the selected face |
| SelectedFeatureProperties | Sets the property values of the selected feature |
| SelectLoop | Selects the loop that corresponds to the selected edge |
| SelectMidpoint | Puts the midpoint (swSelMIDPOINTS) of that edge on the selection list and |
| | removes the edge from the selection list when an edge is selected |
| SelectTangency | Selects all faces tangent to the selected face |
| SetAmbientLightProperties | Sets ambient light properties |
| SetAngularUnits | Sets the current angular units |
| SetArcCentersDisplayed | Sets the current arc centers displayed setting |
| SetBendState | Sets the bend state of a sheet metal part |
| SetBlockingState | Sets the blocking state for the SOLIDWORKS menus |
| SetConsiderLeadersAsLines | Sets a flag on the document that indicates whether the display data of a leader |
| | should be included as lines when the lines are retrieved from a view or |
| | annotation in this document. |
| SetDirectionLightProperties | Sets direction light properties |
| SetFeatureManagerWidth | Sets the width of the FeatureManager design tree |
| SetLightSourceName | Sets the light source name used internally by the SOLIDWORKS software. |

TABLE 23
Additional members of the IModelDoc2 interface of the SolidWorks API (extracted from
Ref. (SolidWorksIModelDoc2Interface 2022)). Obsolete members and public properties omitted.

| Member | Description |
|---|---|
| SetLightSourceProperty | Sets the light source property values |
| ValuesVB | |
| SetParamValue | Sets the value of selected dimension (or parameter) |
| SetPickMode | Returns the user to the default selection mode |
| SetPointLightProperties | Sets point light properties |
| SetPopupMenuMode | Sets the pop-up menu mode. |
| SetReadOnlyState | Sets whether this document is read-only or read-write |
| SetSaveAsFileName | Sets the Save As filename from within the FileSaveAsNotify2 |
| | event handlers, thereby, bypassing the Save As dialog. |
| SetSaveFlag | Flags the document as dirty |
| SetSceneBkgDIB | Sets background image described by DIBSECTION data |
| SetSpotlightProperties | Sets the spotlight properties |
| SetTessellationQuality | Sets the shaded-display image quality number for the current |
| | document |
| SetTitle2 | Sets the title of a new document |
| SetToolbarVisibility | Sets the visibility of a toolbar |
| SetUnits | Sets the units used by the end-user for the model |
| SetZebraStripeData | Sets the zebra-line data |
| ShowComponent2 | Shows the selected component |
| ShowConfiguration2 | Shows the named configuration by switching to that |
| | configuration and making it the active configuration |
| ShowCosmeticThread | Shows the selected cosmetic thread |
| ShowNamedView2 | Shows the specified view |
| ShowSolidBody | Shows the selected solid body |
| Sketch3DIntersections | Creates new sketch segments based on the selected surfaces |
| SketchAddConstraints | Adds the specified constraint to the selected entities |
| SketchAlign | Aligns the selected sketch entities |
| SketchArc | Creates an arc in the current model document |
| SketchCenterline | Adds a centerline to the current model document |
| SketchConstrain | Makes the selected sketch entities coincident |
| Coincident | |
| SketchConstrain | Makes the selected sketch entities concentric |
| Concentric | |
| SketchConstrainParallel | Makes the selected sketch entities parallel |
| SketchConstrainPerp | Makes the selected sketch entities perpendicular |
| SketchConstrainTangent | Makes the selected entities tangent |
| SketchConstraintsDel | Deletes the specified relationship (constraint) on the currently |
| | selected sketch item |
| SketchConstraintsDelAll | Deletes all of the constraints on the currently selected sketch |
| | segment |
| SketchConvertIsoCurves | Converts ISO-parametric curves on a selected surface into a |
| | sketch entity. |

TABLE 24
Additional members of the IModelDoc2 interface of the SolidWorks API (extracted from
Ref. (SolidWorksIModelDoc2Interface 2022)). Obsolete members and public properties omitted.

| Member | Description |
|---|---|
| SketchMirror | Creates new entities that are mirror images of the selected |
| | entities |
| SketchModifyFlip | Flips the the active or selected sketch about the specified |
| | coordinate system axis |
| SketchModifyRotate | Rotates the coordinate system of the active or selected sketch |
| SketchModifyScale | Scales the active or selected sketch |
| SketchModifyTranslate | Translates the coordinate system of the active or selected |
| | sketch |
| SketchOffsetEdges | Offsets the edges of the selected entities |
| SketchOffsetEntities2 | Generates entities in the active sketch by offsetting the selected |
| | geometry by the specified amount |
| SketchSpline | Starts a spline, or continues one, using the specified point |
| SketchTangentArc | Creates a tangent arc in the current model document |
| SketchUndo | Undoes the last sketch command |
| SketchUseEdgeCtrline | Uses this centerline in sketch |
| SkToolsAutoConstr | Automatically constrains the active sketch |
| Toolbars | Turns the specified SolidWorks toolbars on and off |
| ToolsDistance | Computes distance |
| ToolsGrid | Shows and hides the grid in this model document |
| ToolsMacro | Not implemented |
| ToolsMassProps | Calculates the mass properties |
| ToolsSketchScale | Scales a sketch |
| ToolsSketchTranslate | Translates a sketch |
| UnBlankRefGeom | Shows the selected, hidden reference geometry in the graphics |
| | window |
| UnblankSketch | Shows a hidden sketch |
| UnderiveSketch | Changes a sketch to underived. |
| UnLock | Reverses IModelDoc2: : Lock and changes the status bar |
| | message to Process Complete. |
| UnlockAllExternal | Unlocks all external references |
| References | |
| UserFavors | Specifies whether geometric relations are automatically created |
| | as you add sketch entities |
| VersionHistory | Gets an array of strings indicating the versions in which this |
| | document was saved, including the SolidWorks version in |
| | which the model document is currently opened and which is |
| | the last value returned in the array. |
| ViewConstraint | Shows the constraints for the current model document |
| ViewDispCoordinate | Toggles the display of coordinate systems on and off |
| Systems | |
| ViewDisplayCurvature | Toggles the display of surface curvature on and off |

TABLE 25
Additional members of the IModelDoc2 interface of the SolidWorks API (extracted from
Ref. (SolidWorksIModelDoc2Interface 2022)). Obsolete members and public properties omitted.

| Member | Description |
|---|---|
| ViewDisplayFaceted | Sets the current display mode to show the facets that make up |
| | a shaded picture of STL output |
| ViewDisplayHiddengreyed | Sets the current display mode to Hidden Lines Visible |
| ViewDisplayHiddenremoved | Sets the current display mode to Hidden Lines Removed |
| ViewDisplayShaded | Sets the current display mode to Shaded |
| ViewDisplayWireframe | Sets the current display mode to Wireframe |
| ViewDispOrigins | Toggles the display of origins off and on |
| ViewDispRefaxes | Toggles the display of reference axis on and off |
| ViewDispRefplanes | Toggles the display of reference planes on and off |
| ViewDispRefPoints | Shows and hides the reference points for the current model |
| | document |
| ViewDispTempRefaxes | Toggles the display of temporary reference axes on and off |
| ViewOglShading | Sets the current display subsystem to use OpenGL |
| ViewOrientationUndo | Undoes previous view orientation changes that were made |
| | interactively by the user |
| ViewRotate | Rotates the view of the current model |
| ViewRotateminusx | Dynamically rotates the view around x in a negative direction |
| | with the current increment |
| ViewRotateminusy | Dynamically rotates the view around y in a negative direction |
| | with the current increment |
| ViewRotateminusz | Dynamically rotates the view around z in a negative direction |
| | with the current increment |
| ViewRotateplusx | Rotates the view around x in a positive direction with the |
| | current increment |
| ViewRotateplusy | Rotates the view around y in a positive direction with the |
| | current increment |
| ViewRotateplusz | Rotates the view around z in a positive direction with the |
| | current increment |
| ViewRotXMinusNinety | Dynamically rotates the view by negative 90 about x |
| ViewRotXPlusNinety | Dynamically rotates the view by 90 about x |
| ViewRotYMinusNinety | Dynamically rotates the view by negative 90 about y |
| ViewRotYPlusNinety | Dynamically rotates the view by 90 about y |
| ViewRwShading | Sets the current display subsystem to use renderware |
| ViewTranslate | Translates the view |
| ViewTranslateminusx | Dynamically shifts the view left |
| ViewTranslateminusy | Dynamically shifts the view down |
| ViewTranslateplusx | Dynamically shifts the view right |
| ViewTranslateplusy | Dynamically shifts the view up |
| ViewZoomin | Zooms the current view in by a factor of 20% |
| ViewZoomout | Zooms the current view out by a factor of 20%. |
| ViewZoomto | Zooms the view to the selected box |
| ViewZoomTo2 | Zooms to the specified region |

TABLE 26
Additional members of the IModelDoc2 interface of the SolidWorks API (extracted from
Ref. (SolidWorksIModelDoc2Interface 2022)). Obsolete members and public properties omitted.

| Member | Description |
|---|---|
| ViewZoomtofit2 | Zooms the currently active view to fit the screen |
| ViewZoomToSelection | Zooms the display to the selection |
| WindowRedraw | Redraws the current window |

While requirements involving weight, cost, dimensions or surface area lend themselves fairly well to automatic assessment, the inventors recognize there may be some requirements that may prove to be more difficult to verify automatically. In case of weight, cost, dimensions or surface area, related parameters can be reliably extracted from design tools, such as SolidWorks Hence, there is no interpretation involved and no chance of errors. But requirements such as, “Design shall be waterproof”, “Design shall not have sharp edges”, “Design shall be easy to handle” or “Design shall be easy to carry” may be more difficult to assess automatically. Requirements involving ergonomics may also be considered somewhat tough to assess automatically. In case of verification of requirements, that prove somewhat difficult to assess automatically, designers may welcome querying tools, such as described in FIG. 42 or in (Steingrimsson 2018b), that allow designers to query for information considered of importance for the design at hand. The designer may be interested in finding out what is the maximum stress that the design can handle? This invention supplements the automatic design assessment with such querying tools (big data querying and analysis tools such as described in FIG. 42 or in (Steingrimsson 2018b)). In one embodiment of this invention, the automatic requirement verification is used conjunction with querying tools, for purpose of improving designer productivity and usability (through interactions with the user). The designer may welcome efficient answer to questions such as “What is the standard size of a screw?” or “What is the size of the bearing?”

### 10. Accurate Estimation of Bounding Box at the Assembly Level—Accounting for Overlap Between Components

In verification of requirements involving product dimension, it is important to accurately estimate the bounding box at the assembly level, as opposed to the component level, and to account for overlap between components. The following options exist for estimation of the bounding box:
1. One can employ the assembly-level method GetBox (IAssemblyDoc) .
2. One can obtain the rectangle that results from tessellating the bodies.
3. One can utilize the GetBox (IAssemblyDoc) method in combination with tessellation to improve the accuracy of the bounding box estimation.

For background context, note that the bounding box information is not stored as a meta-data in the SolidWorks assembly files. Hence, the bounding box information cannot be read directly using the SolidWorks Document Manager. There is presently no SolidWorks Document Manager API that can provide the user with the bounding box information, without first starting SolidWorks. The bounding box information is considered a feature, meaning it needs to be computed on the fly using the SolidWorks API. One needs to open the SolidWorks assembly file and read the bounding box information using the SolidWorks API. However, if desired, one can open up an instance SolidWorks SW (launch SolidWorks as a process from the design software host), read in the assembly file, get the bounding box data, and then close the SolidWorks. One can configure a visibility property, when launching the SolidWorks from the host design software, and set the visibility to false. For additional information on the Visible property in ISldWorks, refer to (SolidWorksVisibleProperty 2022).

In one embodiment of the invention the method GetBox (IAs s embl yDo c) returns the bounding box. The X, Y, Z points returned by SolidWorks represent the lower- and upper-diagonal corners that bound the component with the box sides parallel to the X, Y and Z axes. The resulting box will enclose the object, but may not be the tightest. As per the SolidWorks documentation, the values returned are approximate and shall not be used for comparison or calculation purposes. Furthermore, the bounding box may vary after rebuilding the SolidWorks model. For additional information, refer to (SolidWorksGetBoxMethod 2022).

Unless otherwise specified, all SolidWorks API functions utilize metric units. The SolidWorks API accepts or returns values as meters, radians, kilograms, square meters, or cubic meters. Hence, when querying for the bounding box, the individual dimensions of the bounding box will be returned in the units of meters. For confirmation, refer to (SolidWorksUnits 2022).

A tessellation or tiling refers to the covering of a surface, often a plane, using one or more geometric shapes, referred to as tiles, with no overlaps and no gaps. Another embodiment of the invention relies on the method (C# source code steps) presented in Ref. (SolidWorksTessellation 2022) for tessellating a SolidWorks body. The method in Ref (SolidWorksTessellation 2022) does not give you exact way to calculate the coordinates. But the method returns vertices, facets and locations, from which the left-most, right-most, top-most, bottom-most, front-most and back-most coordinates of the assembly can be determined.

In the preferred embodiment of the invention the bounding box estimate from the GetBox (IAssemblyDoc) method is compared, contrasted, and possibly combined, with the bounding box from the tessellation, for purpose of improving accuracy of the estimation.

### 11. Automatic Verification of Requirements for Weight and Dimensions for Spacer Cart Example

FIG. 17 illustrates, in context with the Ecosystem design software, an example of a process that can be employed for automatically verifying requirements related to product weight. Similar to the process in FIG. 14, Step 1 consists of identifying the requirement (row) in the Engineering Requirement tab containing the weight requirement specified. Step 2 involves simply identifying the MIN. and MAX. values for the weight requirement listed. In Step 3, we are converting the MIN. and MAX values for the weight into metric units (kg), to match the unit for the weight values extracted from SolidWorks. Step 4 consists of retrieving the overall weight from the SolidWorks assembly imported, using the algorithm outlined in FIG. 15. In Step 5, we compare the total weight of the SolidWorks assembly to the MIN. and MAX. values from the Engineering Requirement tab (in consistent metric units). Based on this comparison, we conclude in Step 6 whether the weight requirement has been fulfilled or not.

FIG. 18a and FIG. 18b present examples of a generic SolidWorks assembly (a system design) that have been imported into the Model tab of the Detailed Design phase of the Ecosystem design software from the spacer cart example. The SolidWorks assembly is a generic tree structure that can consist of multiple sub-assemblies (sub-systems) together with associated part files (components). FIG. 18a-FIG. 18d also illustrate the mass properties and bounding box extracted.

4. Association with Generative Designs

The AFML-based approach to engineering design presented in (Steingrimsson 2018b) and (SteingrimssonKulkarni 2020) has an association with generative designs. AI-driven generative design seeks to automatically create optimal designs from a set of system design requirements. The goal is to autonomously create optimal design, from a set of system design requirements, such as loads, constraints, preferred materials and manufacturing processes, for the purpose of reducing the time-to-market as well as the product cost.

4. Automatic Assessment against ABET Learning Outcomes 1-7—Improving Productivity of Design Instructors or Engineering Departments (Continuation-in-Part)

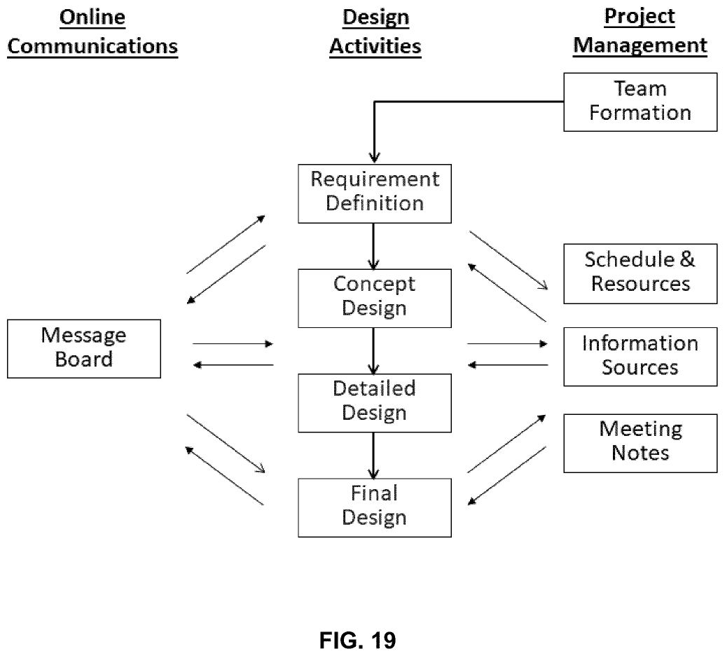

FIG. 19 captures the design process and design flow assumed here. The Ecosystem design framework of (SteingrimssonKulkarni 2020), and the automatic assessment of students' design projects captured in the design Ecosystem, against the ABET learning outcomes, and presented in Tables 1-4 of (SteingrimssonKulkarni 2020), can be further extended such as to support the instructor facilities listed below:
1. Automation in scoring against the full suite of ABET criteria (previously A-K, now 1-7).
2. Automation in grading of designers', e.g., students', reports against instructor rubric.
3. Automation in team formation.

Table 27 provides an illustration of how a representative capstone program maps against the ABET Criteria (A — K). The automatic scoring against the ABET criteria would help improve the instructor productivity. Such assessment could help the engineering departments a lot. The assessment reports provided by the Ecosystem, such as the shown in FIG. 20-FIG. 22, can help engineering departments in terms of reporting and compliance. These assessment reports can be included in the body of documents presented during ABET compliance reviews. These assessment reports would be provided to the capstone instructors, but could also be made available to sponsors or even members of advisory boards.

Note that Table 3 of (SteingrimssonKulkarni 2020) presents a mapping between established performance indicators for information literacy competency from the Association of College and Research Libraries standards for higher education and four (4) learning outcomes, but not the entire suite of ABET learning outcomes (1-7). Table 29, on the other hand, presents a mapping between the aforementioned performance indicators and the full suite of ABET learning outcomes (1-7).

TABLE 27
Mapping of a typical capstone program against the ABET criteria (old A-K).

| ID | ABET Criteria | ME 491 | ME 492 | ME 493 |
|---|---|---|---|---|
| A | An ability to apply knowledge of mathematics, | | | X |
| | science and engineering | | | |
| B | An ability to design and conduct experiments, | X | | X |
| | as well as to analyze and interpret data | | | |
| C | An ability to design a system, component or | X | | X |
| | process to meet desired needs | | | |
| D | An ability to function on multi-disciplinary | X | | X |
| | teams | | | |
| E | An ability to identify, formulate and solve | | | X |
| | engineering problems | | | |
| F | An understanding of professional and ethical | X | | X |
| | responsibility | | | |
| G | An ability to communicate effectively | X | | X |
| H | The broad education necessary to understand the | | | |
| | impact of engineering solutions in a global and | | | |
| | societal context | | | |
| I | A recognition of the need for, and an ability to | | | |
| | engage in life-long learning | | | |
| J | A knowledge of contemporary issues | | | |
| K | An ability to use the techniques, skills, and | | | X |
| | modern engineering tools necessary for | | | |
| | engineering practice | | | |

TABLE 28
Quantitative mapping of a single capstone class, ME 491, against old ABET criteria (A-K).

| ME 491 | | | | | | | | | | | | | | | |
|---|---|---|---|---|---|---|---|---|---|---|---|---|---|---|---|
| | | Number of | Total | Program Learning Outcomes (ABET A-K Outcomes) | | | | | | | | | | | |
| | Course Objective | Hours | Fract | A | B | C | D | E | F | G | H | I | J | K | [symbol] |
| 1 | The ability to translate customer | 2 | [symbol] | 0.00 | 0.00 | [symbol] | 0.00 | 0.00 | 0.00 | 0.00 | 0.00 | 0.00 | 0.00 | 0.00 | [symbol] |
| | needs into emergency requirements | | | | | | | | | | | | | | |
| 2 | The ability to use physical prototypes | 1 | 0.10 | 0.00 | 0.00 | [symbol] | 0.00 | 0.00 | 0.00 | 0.00 | 0.00 | 0.00 | 0.00 | 0.00 | [symbol] |
| | to design explore design options. | | | | | | | | | | | | | | |
| 3 | The ability to use physical prototypes | 1 | 0.10 | 0.00 | [symbol] | [symbol] | 0.00 | 0.00 | 0.00 | 0.00 | 0.00 | 0.00 | 0.00 | 0.00 | [symbol] |
| | to measure performance of | | | | | | | | | | | | | | |
| | engineering [symbol] . | | | | | | | | | | | | | | |
| 4 | The ability to effectively communicate | [symbol] | 0.05 | 0.00 | 0.00 | 0.00 | 0.00 | 0.00 | 0.00 | [symbol] | 0.00 | 0.00 | 0.00 | 0.00 | [symbol] |
| | design concepts and decisions in [symbol] | | | | | | | | | | | | | | |
| | and [symbol] . | | | | | | | | | | | | | | |
| 5 | The ability to [symbol] a team that has | 1 | 0.10 | 0.00 | 0.00 | 0.00 | [symbol] | 0.00 | [symbol] | 0.00 | 0.00 | 0.00 | 0.00 | 0.00 | [symbol] |
| | explicitly articulated set of shared | | | | | | | | | | | | | | |
| | values. | | | | | | | | | | | | | | |
| 6 | The ability to make sustained and [symbol] | 1 | 0.10 | 0.00 | 0.00 | 0.00 | [symbol] | 0.00 | 0.00 | 0.00 | 0.00 | 0.00 | 0.00 | 0.00 | [symbol] |
| | contributions to team goals. | | | | | | | | | | | | | | |
| 7 | The ability to identify a prospective | [symbol] | 0.05 | 0.00 | 0.00 | 21.85 | [symbol] | 0.00 | 0.00 | 0.00 | 0.00 | 0.00 | 0.00 | 0.00 | [symbol] |
| | project that matchs the team's | | | | | | | | | | | | | | |
| | goals and capabilities | | | | | | | | | | | | | | |
| 8 | The ability [symbol] a project proposal | 3 | [symbol] | 0.00 | 0.00 | [symbol] | [symbol] | 0.00 | 0.00 | 17.60 | 0.00 | 0.00 | 0.00 | 0.00 | [symbol] |
| | to a sponsor that demonstrates an | | | | | | | | | | | | | | |
| | understanding of your client's needs | | | | | | | | | | | | | | |
| | and that includes a reasonable plan | | | | | | | | | | | | | | |
| | for meeting those needs. | | | | | | | | | | | | | | |

[symbol]

indicates data missing or illegible when filed

TABLE 29
Association of the ABET learning outcomes 1-7 with performance indicators for information literacy
competency from the Association of College and Research Libraries standards for higher education.

| | Phase | | | | Outcome | | | | | | |
|---|---|---|---|---|---|---|---|---|---|---|---|
| Performance Indicator | RG | CD | DD | FD | 1 | 2 | 3 | 4 | 5 | 6 | 7 |

Standard 1: Determines the nature and extent of information
needed

| Defines and articulates the need for information | H | H | H | H | H | H | M | M | M | H | H |
|---|---|---|---|---|---|---|---|---|---|---|---|
| Identifies a variety of types and formats of potential sources for | H | M | H | L | M | M | L | M | L | H | H |
| information | | | | | | | | | | | |
| Considers the costs and benefits of acquiring the needed | L | M | H | H | M | M | L | M | L | H | H |
| information | | | | | | | | | | | |
| Reevaluates the nature and extent of the information need | M | H | H | M | H | M | L | M | L | H | H |
| Standard 2: Accesses needed information effectively and | | | | | | | | | | | |
| efficiently | | | | | | | | | | | |
| Selects the most appropriate investigative methods or information | M | M | H | M | H | M | L | L | L | H | H |
| retrieval systems for accessing the needed information | | | | | | | | | | | |
| Extracts, records, and manages information and its sources | H | H | H | H | M | H | L | M | L | H | M |
| Standard 3: Evaluates information and its sources critically and | | | | | | | | | | | |
| incorporates selected information into his or her knowledge base | | | | | | | | | | | |
| and value system | | | | | | | | | | | |
| Summarizes the main ideas to be extracted from the information | H | H | H | H | M | M | M | L | H | M | M |
| gathered | | | | | | | | | | | |
| Articulates and applies initial criteria for evaluating both the | H | H | H | H | M | M | L | L | L | H | M |
| information and its sources | | | | | | | | | | | |
| Synthesizes main ideas to construct new concepts | H | H | M | L | M | M | H | L | H | M | M |
| Compares new knowledge with prior knowledge to determine the | L | H | H | M | M | M | L | M | L | H | H |
| value added, contradictions, or other unique characteristics of the | | | | | | | | | | | |
| information | | | | | | | | | | | |
| Determines whether the new knowledge has an impact on the | H | H | H | M | L | M | L | M | M | L | M |
| individual's value system and takes steps to reconcile differences | | | | | | | | | | | |
| Validates understanding and interpretation of the information | H | H | H | H | M | M | H | L | H | L | M |
| through discourse with other individuals, subject-area experts, | | | | | | | | | | | |
| and/or practicioners | | | | | | | | | | | |
| Determines whether the initial query should be revised | H | H | H | M | M | L | M | M | L | M | M |
| Standard 4: Uses information effectively to accomplish a specific | | | | | | | | | | | |
| purpose | | | | | | | | | | | |
| Applies new and prior information to the planning and creation of a | L | H | H | H | M | H | L | L | L | L | M |
| particular product or performance | | | | | | | | | | | |
| Revises the development process for the product or performance | M | M | M | H | M | H | L | L | L | L | M |
| Communicates the product or performance effectively to others | H | H | H | H | L | M | H | M | H | L | M |
| Standard 5: Understands many of the economic, legal, and social | | | | | | | | | | | |
| issues surrounding the use of information and accesses and uses | | | | | | | | | | | |
| information ethically and legally | | | | | | | | | | | |
| Acknowledges the use of informaiton sources in communicating | H | M | H | M | M | H | M | M | M | L | L |
| the product or performance | | | | | | | | | | | |

Similar to (SteingrimssonKulkarni 2020), we score the students' design work against the ABET learning outcomes using the formulas listed below:

$$Performance ( {Outcome}_{i} ) = \frac{Subtotal ( Outcome )}{MaxPossible ( Outcome )} , i = 1 , 2 , 3 , 4 , 5 , 6 or 7 \qquad ( 1 )$$

where

Subtotal(Outcome)=Σ_{PIs} OutcomeBinary(Outcome, PI)*PerformanceAssessment(PI) (2)

and

MaxPossible(Outcome)=Σ_{PIs} OutcomeBinary(Outcome, PI)*(Maximum Score(=5)) (3)

The association between the learning outcomes and the performance indictors,

OutcomeBinary(Outcome, PI), is computed as follows:

$$\begin{matrix}OutcomeBinary \\ ( Outcome , PI )\end{matrix} = \{ \begin{matrix}2 , if PI exhibits high degree of correlation with Outcome in Table 4 \\ 1 , if PI exhibits medium degree of correlation with Outcome in Table 4 \\ 0 , if PI exhibits low degree of correlation with Outcome in Table 4.\end{matrix}$$

The assessment of the performance indicators, PerformanceAssessment(PI), is achieved using the rubrics presented in Table 30-Table 33. Note that the rubrics consist mostly of discrete (countable) metrics. The countable nature of the rubrics allows the rubrics to be assessed using a computerized approach.

Note, furthermore, that since the performance indicators remain the same for the four learning outcomes listed in (SteingrimssonKulkarni 2020), (Jones 2015), for the learning outcomes A-K as well as for the learning outcomes 1-7, and since the rubrics are tied to the performance indicators, one can use the same assessment rubrics for assessing these learning outcomes. What changes between scoring against the four learning outcomes listed in (SteingrimssonKulkarni 2020), (Jones 2015) vs. the learning outcomes A-K or vs. the learning outcomes 1-7 is the aggregation (weighting) of the rubric elements, i.e., OutcomeBinary(Outcome,PI). However, evaluation of the quantities PerformanceAssessment(PI) remains the same.

TABLE 30
Sample results from manual scoring of the bolt tester test case for the requirements gathering design
phase against the four learning outcomes listed in (SteingrimssonKulkarni 2020), (Jones 2015).

| | Outcome | | | | Performance Assessment | | |
|---|---|---|---|---|---|---|---|
| Performance Indicator | 1 | 2 | 3 | 4 | Beginning | Developing | Developed |
| Defines and articulates | X | X | X | X | No sources of | 1 source | multiple sources |
| the need for information | | | | | customer needs | identified but | identified but |
| Identifies a variety of | X | X | X | X | identified or | no needs | no needs |
| types and formats of | | | | | queried | associated | associated |
| potential sources for | | | | | | | |
| information | | | | | | | |
| Extracts, records, and | X | X | X | X | | | |
| manages information and | | | | | | | |
| its sources | | | | | | | |
| Summarizes the main | X | | X | | No | 1 need | Some needs |
| ideas to be extracted | | | | | requirements | corresponds to | (<50%) |
| from the information | | | | | defined from | an engineering | correspond to |
| gathered | | | | | needs | requirement | at least 1 |
| | | | | | | | engineering |
| | | | | | | | requirement |
| Articulates and applies | X | | | X | No FR, OBJ | Some FR, OBJ | No FR, OBJ |
| initial criteria for | | | | | ranked and | ranked, fitness | ranked, fitness |
| evaluating both the | | | | | fitness function | function not | function |
| information and its | | | | | not determined | determined | determined |
| sources | | | | | | | |
| Synthesizes main ideas | X | X | X | X | Requirements | At least 1 CN | At least 1 |
| to construct new concepts | | | | | not categorized | identified | FR, but no |
| | | | | | | | PR identified |
| Determines whether the | X | X | | X | Mission | | Mission |
| new knowledge has an | | | | | statement and | | statement or |
| impact on the individual's | | | | | problem | | problem |
| value system and takes | | | | | narrative not | | narrative |
| steps to reconcile | | | | | specified | | specified |
| differences | | | | | | | |
| Determines whether the | X | X | | X | | | |
| initial query should | | | | | | | |
| be revised | | | | | | | |
| Validates understanding | X | X | | | Members have | 1 member has | Members have |
| and interpretation of the | | | | | not | attempted to | established |
| information through discourse | | | | | communicated | establish thread | communication |
| with other individual, subject- | | | | | within the | communication | thread with |
| area experts, and/or practicioners | | | | | ecosystem | | some members |
| | | | | | | | participating |
| | | | | | | | (<50%) |
| Communicates the product | X | X | X | X | Customers, | 1 of 4 | 2 of 4 |
| or performance effectively | | | | | needs, | communicated | communicated |
| to others | | | | | requirements, | appropriately | appropriately |
| | | | | | and fitness not | | |
| | | | | | communicated | | |
| | | | | | appropriately | | |
| Acknowledges the use of | X | | X | | No | | Some |
| information sources in | | | | | documentation | | documentation |
| communicating the product | | | | | referenced | | referenced |
| or performance | | | | | | | |

| | Performance Assessment | | Outcome Binary | | | |
|---|---|---|---|---|---|---|
| Performance Indicator | Accomplished | Exemplary | 1 | 2 | 3 | 4 |
| Defines and articulates | 1 source | multiple sources | 1 | 1 | 1 | 1 |
| the need for information | identified with | identified, and | | | | |
| | an associated | each source has | | | | |
| | need | an associated need | | | | |
| Identifies a variety of | | | 1 | 1 | 1 | 1 |
| types and formats of | | | | | | |
| potential sources for | | | | | | |
| information | | | | | | |
| Extracts, records, and | | | 1 | 1 | 1 | 1 |
| manages information and | | | | | | |
| its sources | | | | | | |
| Summarizes the main | Most needs | All needs | 1 | 0 | 1 | 0 |
| ideas to be extracted | (>50%) | correspond to | | | | |
| from the information | correspond to | at least 1 | | | | |
| gathered | at least 1 | engineering | | | | |
| | engineering | requirement | | | | |
| | requirement. | | | | | |
| Articulates and applies | Some FR, OBJ | All FR, OBJ | 1 | 0 | 0 | 1 |
| initial criteria for | ranked, fitness | ranked, fitness | | | | |
| evaluating both the | function | function | | | | |
| information and its | determined | determined | | | | |
| sources | | | | | | |
| Synthesizes main ideas | At least 1 | At least 1 | 1 | 1 | 1 | 1 |
| to construct new concepts | FR identified, | FR, at least 1 | | | | |
| | and 1 PR, OBJ | PR, at least 1 | | | | |
| | or CN identified | OBJ, at least 1 | | | | |
| | | CN identified | | | | |
| Determines whether the | | Mission | 1 | 1 | 0 | 1 |
| new knowledge has an | | statement and | | | | |
| impact on the individual's | | problem | | | | |
| value system and takes | | narrative | | | | |
| steps to reconcile | | specified | | | | |
| differences | | | | | | |
| Determines whether the | | | 1 | 1 | 0 | 1 |
| initial query should | | | | | | |
| be revised | | | | | | |
| Validates understanding | Members have | Members have | 1 | 1 | 0 | 0 |
| and interpretation of the | established | established | | | | |
| information through discourse | communication | communication | | | | |
| with other individual, subject- | thread with | thread with at | | | | |
| area experts, and/or practicioners | most members | least 1 post | | | | |
| | participating | from each | | | | |
| | (>50%) | | | | | |
| Communicates the product | 3 of 4 | Customers, | 1 | 1 | 1 | 1 |
| or performance effectively | communicated | needs, | | | | |
| to others | appropriately | requirements, | | | | |
| | | and fitness all | | | | |
| | | defined | | | | |
| | | appropriately | | | | |
| Acknowledges the use of | | All appropriate | 1 | 0 | 1 | 0 |
| information sources in | | documentation | | | | |
| communicating the product | | referenced | | | | |
| or performance | | | | | | |
| | | Subtotal | 53 | 40 | 33 | 40 |
| | | Possible | 55 | 40 | 35 | 40 |
| | | Performance | 0.96 | 1 | 0.94 | 1 |

TABLE 31
Sample results from manual scoring of the bolt tester test case for the concept design phase
against the four learning outcomes listed in (SteingrimssonKulkarni 2020), (Jones 2015).

| | Outcome | | | | Performance Assessment | | |
|---|---|---|---|---|---|---|---|
| Performance Indicator | 1 | 2 | 3 | 4 | Beginning | Developing | Developed |
| Defines and articulates | X | X | X | X | No concepts | 1 concept | >1 concept |
| the need for information | | | | | proposed | proposed, but | proposed, but |
| Extracts, records, and manages | X | X | X | X | | not developed | not developed |
| information and its sources | | | | | | | |
| Synthesizes main ideas to construct | X | X | X | X | No members | 1 member | Some (<50%) |
| new concepts | | | | | contribute to | contributes to | members |
| | | | | | concept | concept | contribute to |
| | | | | | ideation | ideation | concept |
| | | | | | | | ideation |
| Reevaluates the nature and extent of | X | | | X | No concept | 1 concept | Some (<50%) |
| the information need | | | | | models are | model is | concept models |
| | | | | | feasible | feasible | are feasible |
| Summarizes the main ideas to be | X | | X | | No concepts | Some concepts | Some concepts |
| extracted from the information | | | | | evaluated for | evaluated for | evaluated, some |
| gathered | | | | | fitness | fitness, but no | DF evaluated |
| Articulates and applies initial criteria | X | | | X | | DF evaluated | |
| for evaluating both the information and | | | | | | | |
| its sources | | | | | | | |
| Compares new knowledge with prior | X | | | X | Concept not | | Concepts too |
| knowledge to determine the value | | | | | selected for | | similar for |
| added, contradictions, or other unique | | | | | development | | selection, |
| characteristics of the information | | | | | | | fitness variation |
| Applies new and prior information to | X | | X | X | | | too narrow |
| the planning and creation of a | | | | | | | |
| particular product or performance | | | | | | | |
| Determines whether the new | X | X | | X | DF and concept | Some DF (<25%) | Many DF (25- |
| knowledge has an impact on the | | | | | selections do | and concept | 50%) and |
| individual's value system and takes | | | | | not agree with | selections agree | concept |
| steps to reconcile differences | | | | | fitness | with fitness | selections agree |
| | | | | | evaluation | evaluation | with fitness |
| | | | | | | | evaluation |
| Validates understanding and | X | X | | | Members have | 1 member has | Members have |
| interpretation of the information | | | | | not | attempted to | established |
| through discourse with other | | | | | communicated | establish thread | communication |
| individuals, subject-area experts, | | | | | within the | communication | thread with |
| and/or practicioners | | | | | habitat | | some members |
| | | | | | | | participating |
| | | | | | | | (<50%) |
| Determines whether the initial query | X | X | | X | All | >1 CN and FR to | 1 CN and FR to |
| should be revised | | | | | requirements | be added or | be added or |
| | | | | | must be altered | altered | altered |
| Communicates the product or | X | X | X | X | No concepts | 1 concept has | Some (<50%) |
| performance effectively to others | | | | | have associated | associated | concepts have |
| | | | | | graphical | graphical | associated |
| | | | | | representations | representations | graphical |
| | | | | | | | representations |

| | Performance Assessment | | Outcome Binary | | | |
|---|---|---|---|---|---|---|
| Performance Indicator | Accomplished | Exemplary | 1 | 2 | 3 | 4 |
| Defines and articulates | 1 concept | >1 concept | 1 | 1 | 1 | 1 |
| the need for information | proposed and | proposed and | | | | |
| Extracts, records, and manages | decomposed to | decomposed to | 1 | 1 | 1 | 1 |
| information and its sources | exhibit DF and | exhibit DF and | | | | |
| | DP | DP | | | | |
| Synthesizes main ideas to construct | Most (>50%) | All members | 1 | 1 | 1 | 1 |
| new concepts | members | contribute to | | | | |
| | contribute to | concept | | | | |
| | concept | ideation | | | | |
| | ideation | | | | | |
| Reevaluates the nature and extent of | Most (>50%) | All concept | 1 | 0 | 0 | 1 |
| the information need | concept models | models are | | | | |
| | are feasible | feasible | | | | |
| Summarizes the main ideas to be | All concepts | All concepts and | 1 | 0 | 1 | 0 |
| extracted from the information | evaluated and | all DF evaluated | | | | |
| gathered | some DF | | | | | |
| Articulates and applies initial criteria | evaluated | | 1 | 0 | 0 | 1 |
| for evaluating both the information and | | | | | | |
| its sources | | | | | | |
| Compares new knowledge with prior | | Concept | 1 | 0 | 0 | 1 |
| knowledge to determine the value | | selected for | | | | |
| added, contradictions, or other unique | | development | | | | |
| characteristics of the information | | | | | | |
| Applies new and prior information to | | | 1 | 0 | 1 | 1 |
| the planning and creation of a | | | | | | |
| particular product or performance | | | | | | |
| Determines whether the new | Most DF (25- | All DF and | 1 | 1 | 0 | 1 |
| knowledge has an impact on the | 50%) and | concept | | | | |
| individual's value system and takes | concept | selections agree | | | | |
| steps to reconcile differences | selections agree | with fitness | | | | |
| | with fitness | evaluation | | | | |
| | evaluation | | | | | |
| Validates understanding and | Members have | Members have | 1 | 1 | 0 | 0 |
| interpretation of the information | established | established | | | | |
| through discourse with other | communication | communication | | | | |
| individuals, subject-area experts, | thread with | thread with at | | | | |
| and/or practicioners | most members | least 1 post | | | | |
| | participating | from each | | | | |
| | (>50%) | | | | | |
| Determines whether the initial query | 1 CN or FR to | No new CN or | 1 | 1 | 0 | 1 |
| should be revised | be added or | FR to be added | | | | |
| | altered | or altered | | | | |
| Communicates the product or | Most (>50%) | All concepts | 1 | 1 | 1 | 1 |
| performance effectively to others | concepts have | have associated | | | | |
| | associated | graphical | | | | |
| | graphical | representations | | | | |
| | representations | | | | | |
| | | Subtotal | 55 | 33 | 27 | 46 |
| | | Possible | 60 | 35 | 30 | 50 |
| | | Performance | 0.92 | 0.94 | 0.9 | 0.92 |

TABLE 32
Sample results from manual scoring of the bolt tester test case for the detailed design phase
against the four learning outcomes listed in (SteingrimssonKulkarni 2020), (Jones 2015).

| | Outcome | | | | Performance Assessment | | |
|---|---|---|---|---|---|---|---|
| Performance Indicator | 1 | 2 | 3 | 4 | Beginning | Developing | Developed |
| Defines and articulates | X | X | X | X | Few (<25%) risk | Some (25-50%) | Many (50-75%) |
| the need for information | | | | | factors have | risk factors have | risk factors have |
| | | | | | complete assignments | complete assignments | complete assignments |
| Identifies a variety of | X | X | X | X | No solid model, | No solid model, | Solid model |
| types and formats of | | | | | no methods | at least 1 | created at least |
| potential sources for | | | | | specified for | analysis method | 1 method specified |
| information | | | | | analysis | specified for | for few (<25%) |
| | | | | | | some analyses | analysis |
| Reevaluates the nature | X | | | X | Analyses | Analyses | Analyses |
| and extent of the | | | | | completed | completed | completed |
| information need | | | | | support no | support few | support some |
| Determines whether the | X | X | | X | decomposed | (<25%) | (25-50%) |
| initial query should be | | | | | FRs | decomposed | decomposed |
| revised | | | | | | FRs | FRs |
| Selects the most | X | | | | No methods | Few (<25%) | Some (25-50%) |
| appropriate investigative | | | | | selected for | have methods | analyses have |
| methods or information | | | | | analyses | selected | methods |
| retrieval systems for | | | | | | | selected |
| accessing the needed | | | | | | | |
| information | | | | | | | |
| Extracts, records, and | X | X | X | X | No analyses | few (<25%) | Some (25-50%) |
| manages information and | | | | | with graphical | analyses with | analyses with |
| its sources | | | | | and/or textual | graphical and/or | graphical and/or |
| | | | | | support | textual support | textual support |
| Summarizes the main | X | | X | | No | few (<25%) | Some (25-50%) |
| ideas to be extracted | | | | | requirements | requirements | requirements |
| from the information | | | | | verified | verified | verified |
| gathered | | | | | | | |
| Articulates and applies | X | | | X | | | |
| initial criteria for | | | | | | | |
| evaluating both the | | | | | | | |
| information and its | | | | | | | |
| sources | | | | | | | |
| Compares new knowledge | X | | | X | At least 1 critical | At least 1 | At least 1 major |
| with prior knowledge to | | | | | flaw identified | serious flaw | flaw identified |
| determine the value | | | | | which requires | identified which | which requires |
| added, contradictions, | | | | | concept fitness | requires FR or | DP revision |
| or other unique | | | | | reconsideration | DF revision | |
| characteristics of the | | | | | | | |
| information | | | | | | | |
| Determines whether the | X | X | | X | | | |
| new knowledge has an | | | | | | | |
| impact on the individual's | | | | | | | |
| value system and takes | | | | | | | |
| steps to reconcile | | | | | | | |
| differences | | | | | | | |
| Validates understanding | X | X | | | Members have | 1 member has | Members have |
| and interpretation of the | | | | | not | attempted to | established |
| information through discourse | | | | | communicated | establish thread | communication |
| with other individuals, subject- | | | | | within the | communication | thread with |
| area experts, and/or practicioners | | | | | habitat | | some members |
| | | | | | | | participating |
| | | | | | | | (<50%) |
| Applies new and prior | X | | X | X | No DP settings | Few (<25%) DP | Some (25-50%) |
| information to the | | | | | justified by | settings justified | DP settings |
| planning and creation | | | | | analysis | by analysis | justified by |
| of a particular product | | | | | | | analysis |
| or performance | | | | | | | |
| Communicates the product | X | X | X | X | Few (<25%) results | Some (25-50%) | Many (50-75%) |
| or performance effectively | | | | | communicated | results | results |
| to others | | | | | appropriately | communicated | communicated |
| | | | | | | appropriately | appropriately |
| Acknowledges the use of | X | | X | | No analysis | 1 analysis | Some (<50%) |
| information sources in | | | | | methods cited | method cited | analysis |
| communicating the product | | | | | | | methods cited |
| or performance | | | | | | | |

| | Performance Assessment | | Outcome Binary | | | |
|---|---|---|---|---|---|---|
| Performance Indicator | Accomplished | Exemplary | 1 | 2 | 3 | 4 |
| Defines and articulates | Most (>75%) | All risk factors | 1 | 1 | 1 | 1 |
| the need for information | risk factors have | have complete | | | | |
| | complete assignments | assignments | | | | |
| Identifies a variety of | Solid model | Solid model | 1 | 1 | 1 | 1 |
| types and formats of | created, at least | created, at least | | | | |
| potential sources for | 1 method specified | 1 method specified | | | | |
| information | for some (25-50%) | for most (>75%) | | | | |
| | analyses | analyses | | | | |
| Reevaluates the nature | Analyses | Analyses | 1 | 0 | 0 | 1 |
| and extent of the | completed | completed | | | | |
| information need | support many | support most | | | | |
| Determines whether the | (50-75%) | (>75%) | 1 | 1 | 0 | 1 |
| initial query should be | decomposed | decomposed | | | | |
| revised | FRs | FRs | | | | |
| Selects the most | Many (50-75%) | Most (>75%) | 1 | 0 | 0 | 0 |
| appropriate investigative | analyses have | analyses have | | | | |
| methods or information | methods | methods | | | | |
| retrieval systems for | selected | selected, of at | | | | |
| accessing the needed | | least 2 types | | | | |
| information | | | | | | |
| Extracts, records, and | Many (50-75%) | Most (>75%) | 1 | 1 | 1 | 1 |
| manages information and | analyses with | analyses with | | | | |
| its sources | graphical and/or | graphical and/or | | | | |
| | textual support | textual support | | | | |
| Summarizes the main | Many (50-75%) | Most (>75%) | 1 | 0 | 1 | 0 |
| ideas to be extracted | requirements | requirements | | | | |
| from the information | verified | verified | | | | |
| gathered | | | | | | |
| Articulates and applies | | | 1 | 0 | 0 | 1 |
| initial criteria for | | | | | | |
| evaluating both the | | | | | | |
| information and its | | | | | | |
| sources | | | | | | |
| Compares new knowledge | Only minor | No flaws | 1 | 0 | 0 | 1 |
| with prior knowledge to | flaws identified | identified which | | | | |
| determine the value | which require | require changes | | | | |
| added, contradictions, | DP | | | | | |
| or other unique | manipulation | | | | | |
| characteristics of the | | | | | | |
| information | | | | | | |
| Determines whether the | | | 1 | 1 | 0 | 0 |
| new knowledge has an | | | | | | |
| impact on the individual's | | | | | | |
| value system and takes | | | | | | |
| steps to reconcile | | | | | | |
| differences | | | | | | |
| Validates understanding | Members have | Members have | 1 | 1 | 0 | 0 |
| and interpretation of the | established | established | | | | |
| information through discourse | communication | communication | | | | |
| with other individuals, subject- | thread with | thread with at | | | | |
| area experts, and/or practicioners | most members | least 1 post | | | | |
| | participating | from each | | | | |
| | (>50%) | | | | | |
| Applies new and prior | Many (50-75%) | Most (>75%) DP | 1 | 0 | 1 | 1 |
| information to the | DP settings | settings justified | | | | |
| planning and creation | justified by | by analysis | | | | |
| of a particular product | analysis | | | | | |
| or performance | | | | | | |
| Communicates the product | Most (>75%) | All results | 1 | 1 | 1 | 1 |
| or performance effectively | results | communicated | | | | |
| to others | communicated | appropriately | | | | |
| | appropriately | | | | | |
| Acknowledges the use of | Most (>50%) | All analysis | 1 | 0 | 1 | 0 |
| information sources in | analysis | methods cited | | | | |
| communicating the product | methods cited | | | | | |
| or performance | | | | | | |
| | | Subtotal | 56 | 31 | 28 | 38 |
| | | Possible | 70 | 35 | 35 | 45 |
| | | Performance | 0.8 | 0.89 | 0.8 | 0.84 |

TABLE 33
Sample results from manual scoring of the bolt tester test case for the final design phase
against the four learning outcomes listed in (SteingrimssonKulkarni 2020), (Jones 2015).

| | Outcome | | | | Performance Assessment | | |
|---|---|---|---|---|---|---|---|
| Performance Indicator | 1 | 2 | 3 | 4 | Beginning | Developing | Developed |
| Defines and articulates | X | X | X | X | No | 1 manufacturing | at least 1 |
| the need for information | | | | | manufacturing | method or test | manufacturing |
| | | | | | or test plans | plan specified | method |
| | | | | | specified | | specified for |
| | | | | | | | some (<50%) |
| | | | | | | | DF, at least 1 |
| | | | | | | | test specified |
| Considers the costs and | X | | | X | No justification | | Justification for |
| benefits of acquiring the | | | | | for test | | test time or cost |
| needed information | | | | | resources | | provided |
| | | | | | provided | | |
| Extracts, records, and | X | X | X | X | Few (<25%) part | Some (25-50%) | Many (50-75%) |
| manages information and | | | | | or material | part or material | part or material |
| its sources | | | | | sources | sources | sources |
| | | | | | provided | provided | provided |
| Summarizes the main | X | | X | | No bill of | BOM but no | BOM but no |
| ideas to be extracted | | | | | materials | COTS parts and | COTS parts and |
| from the information | | | | | provided | some (<50%) | most (>50%) |
| gathered | | | | | | manufactured | manufactured |
| | | | | | | parts accounted | parts accounted |
| | | | | | | for | for |
| Articulates and applies | X | | | X | No selection | Availability | Availability and |
| initial criteria for | | | | | criteria for | criteria for some | cost criteria for |
| evaluating both the | | | | | manufacturing | (<50%) | some (<50%) |
| information and its | | | | | specified | manufacturing | manufacturing |
| sources | | | | | | processes | processes |
| | | | | | | specified | specified |
| Validates understanding | X | X | | | Members have | 1 member has | Members have |
| and interpretation of the | | | | | not | attempted to | established |
| information through discourse | | | | | communicated | establish thread | communication |
| with other individuals, subject- | | | | | within the | communication | thread with |
| area experts, and/or practitioners | | | | | habitat | | some members |
| | | | | | | | participating |
| | | | | | | | (<50%) |
| Applies new and prior | X | | X | X | Few (<25%) | Some (25-50%) | Many (50-75%) |
| information to the | | | | | necessary part | necessary part | necessary part |
| planning and creation | | | | | and assembly | and assembly | and assembly |
| of a particular | | | | | files provided | files provided | files provided |
| product or performance | | | | | | | |
| Revises the development | X | | | X | Most(>75%) DF | Many (50-75%) | Some (25-50%) |
| process for the product | | | | | lack a feasible | DF lack a | DF lack a |
| or performance | | | | | manufacturing | feasible | manufacturing |
| | | | | | solution forcing | manufacturing | process |
| | | | | | conceptual | solution forcing | requiring |
| | | | | | reconsideration | conceptual | conceptual |
| | | | | | | reconsideration | reconsideration |
| Communicates the product | X | X | X | X | Few (<25%) | Some (25-50%) | Many (50-75%) |
| or performance effectively | | | | | test, BOM, | test, BOM, | test, BOM, |
| to others | | | | | part/assembly, | part/assembly, | part/assembly, |
| | | | | | manufacturing | manufacturing | manufacturing |
| | | | | | materials | materials | materials |
| | | | | | communicated | communicated | communicated |
| | | | | | appropriately | appropriately | appropriately |

| | Performance Assessment | | Outcome Binary | | | |
|---|---|---|---|---|---|---|
| Performance Indicator | Accomplished | Exemplary | 1 | 2 | 3 | 4 |
| Defines and articulates | At least 1 | At least 1 | 1 | 1 | 1 | 1 |
| the need for information | manufacturing | manufacturing | | | | |
| | method | method | | | | |
| | specified for | specified for all | | | | |
| | most (>50%) DF | DF and at least | | | | |
| | and at least 1 | 1 test specified | | | | |
| | test specified | | | | | |
| Considers the costs and | | Justification for | 1 | 0 | 0 | 1 |
| benefits of acquiring the | | test time and | | | | |
| needed information | | cost provided | | | | |
| Extracts, records, and | Most (>75%) | All part and | 1 | 1 | 1 | 1 |
| manages information and | part or material | material sources | | | | |
| its sources | sources | provided | | | | |
| | provided | | | | | |
| Summarizes the main | BOM but most | Complete bill of | 1 | 0 | 1 | 0 |
| ideas to be extracted | (>50%) COTS | materials | | | | |
| from the information | parts and | provided | | | | |
| gathered | manufactured | | | | | |
| | parts accounted | | | | | |
| | for | | | | | |
| Articulates and applies | Availability and | Availability, | 1 | 0 | 0 | 1 |
| initial criteria for | cost criteria for | cost, and | | | | |
| evaluating both the | most (>50%) | capability | | | | |
| information and its | manufacturing | criteria for most | | | | |
| sources | processes | (>50%) | | | | |
| | specified | manufacturing | | | | |
| | | processes | | | | |
| | | specified | | | | |
| Validates understanding | Members have | Members have | 1 | 1 | 0 | 0 |
| and interpretation of the | established | established | | | | |
| information through discourse | communication | communication | | | | |
| with other individuals, subject- | thread with | thread with at | | | | |
| area experts, and/or practitioners | most members | least 1 post | | | | |
| | participating | from each | | | | |
| | (>50%) | | | | | |
| Applies new and prior | Most (>75%) | All necessary | 1 | 0 | 1 | 1 |
| information to the | necessary part | part and | | | | |
| planning and creation | and assembly | assembly files | | | | |
| of a particular | files provided | provided | | | | |
| product or performance | | | | | | |
| Revises the development | Few (<25%) DF | All components | 1 | 0 | 0 | 1 |
| process for the product | lack a | are | | | | |
| or performance | manufacturing | manufacturable | | | | |
| | process | within desired | | | | |
| | requiring | tolerances | | | | |
| | conceptual | | | | | |
| | revision | | | | | |
| Communicates the product | Most | All test, BOM, | 1 | 1 | 1 | 1 |
| or performance effectively | (>75%)test, | part/assembly, | | | | |
| to others | BOM, | manufacturing | | | | |
| | part/assembly, | materials | | | | |
| | manufacturing | communicated | | | | |
| | materials | appropriately | | | | |
| | communicated | | | | | |
| | appropriately | | | | | |
| | | Subtotal | 40 | 16 | 21 | 30 |
| | | Possible | 45 | 20 | 25 | 35 |
| | | Performance | 0.889 | 0.8 | 0.84 | 0.857 |

It is important to keep in mind that the ABET it looking to separately assess the individual students comprising a design team against the ABET learning outcomes. To that end, one can note that the performance indicators
“Validates understanding and interpretation of the information through discourse with other individuals, subject-area experts, and/or practitioners”
“Communicates the product or performance effectively to others”
   may require logging (tracking) students' communications, for example through a message board. Further, effective communication of product or performance to others may be the subject of instructor verification. FIG. 20-FIG. 22 capture quantitative reports, presented in a standardized format (standardized across the participating students). Such reports can be presented to ABET as a part of an overall package. The intent is not to make the ABET assessment completely automatic, but to reduce the time it takes instructors and academic departments to compile the data needed for ABET reporting.

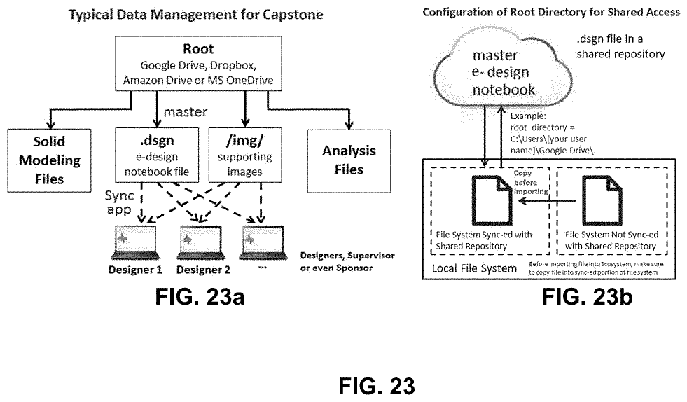

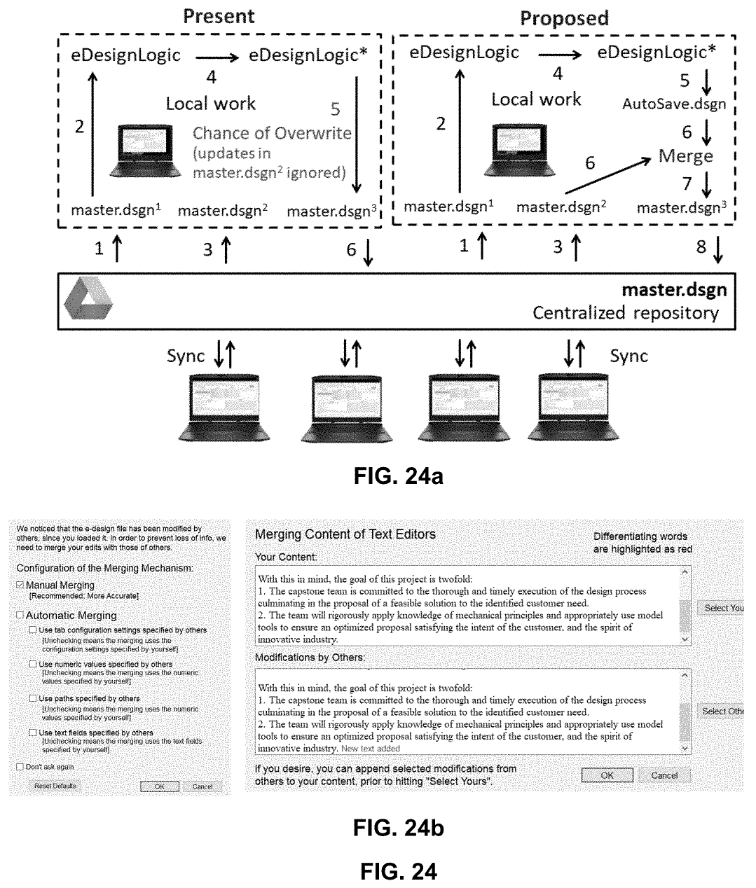

As for the Ecosystem design software itself, FIG. 23 captures the web architecture supported. The Ecosystem design software additionally supports mechanism for overwrite prevention, presented in FIG. 24. If another user were to modify an e-design notebook file, simultaneous to saving of modifications for the present user, the system can identify that the e-design notebook file has been changed, and that edits by the present user need to be merged with the ones from other users.

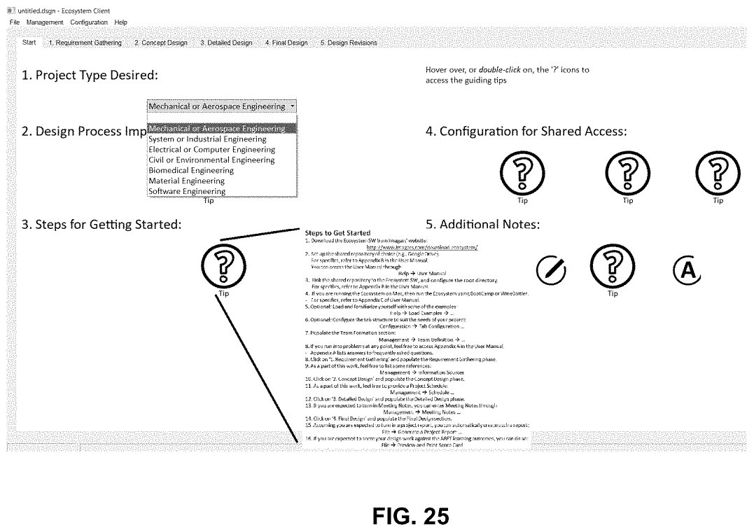

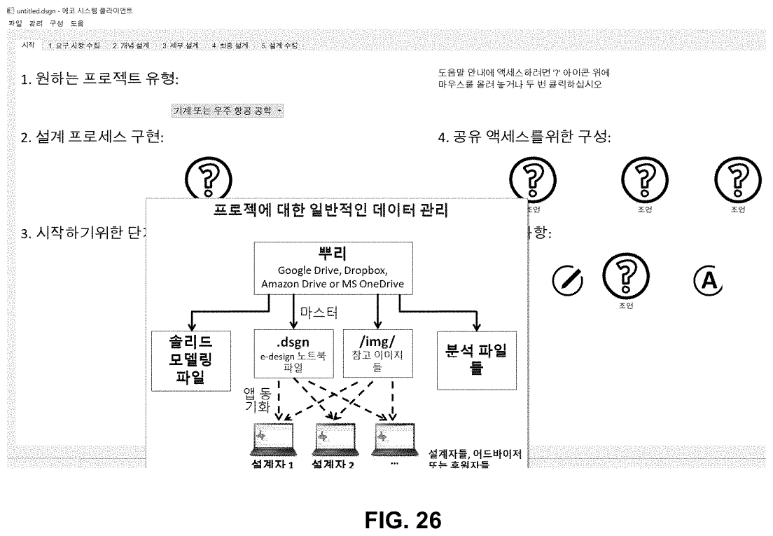

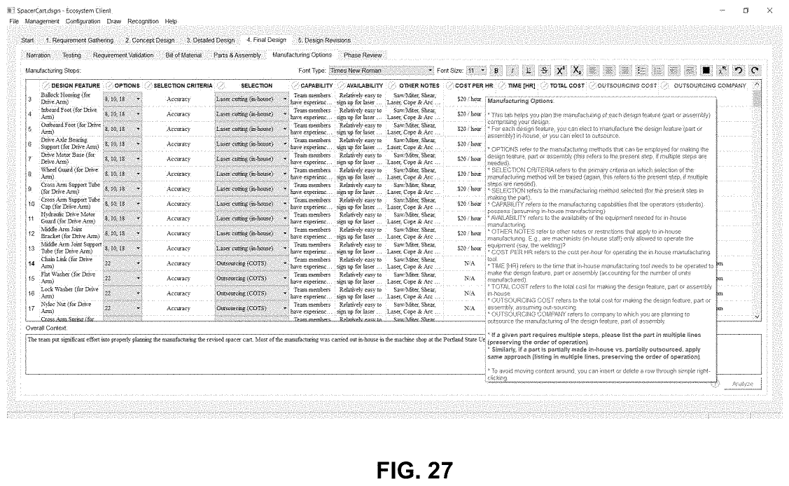

As shown in FIG. 25, the user interface for the Ecosystem design software supports the following modes: “Mechanical and Aerospace Engineering”, “System or Industrial Engineering”, “Electrical and Computer Engineering”, “Civil or Environmental Engineering”, “Biomedical Engineering”, “Material Engineering” and “Software Engineering”. FIG. 26 presents the same user interface for a Korean version of the Ecosystem design software. FIG. 27 presents a Manufacturing tab from the Ecosystem design software, one that corresponds to the Final design phase. The Manufacturing tab provides enhanced capabilities for tracking parts manufactured in-house or through outsourcing.

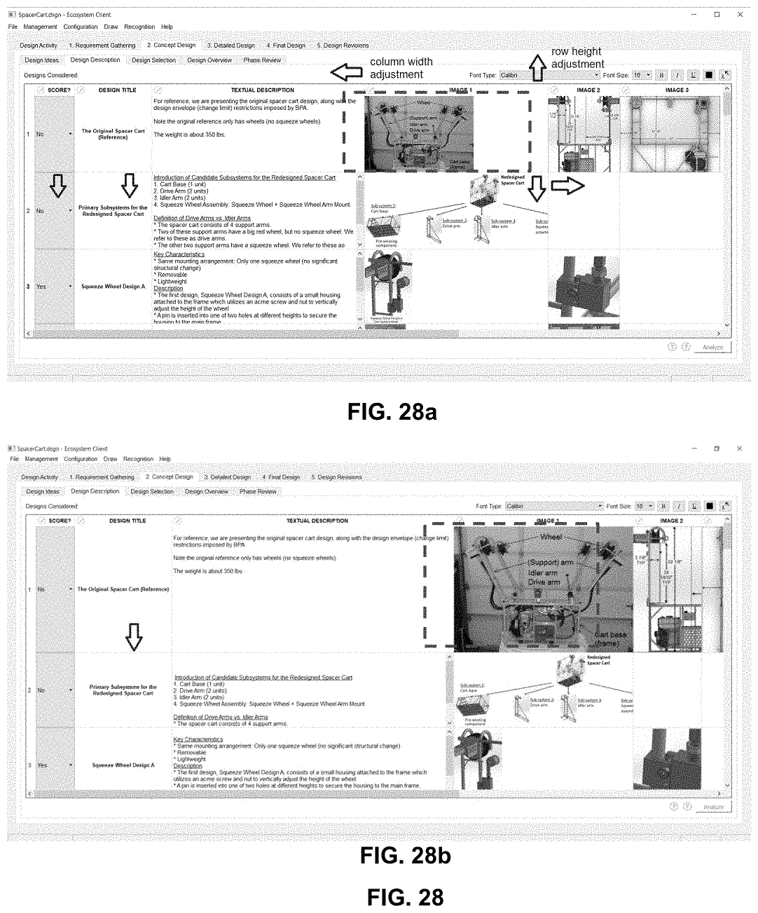

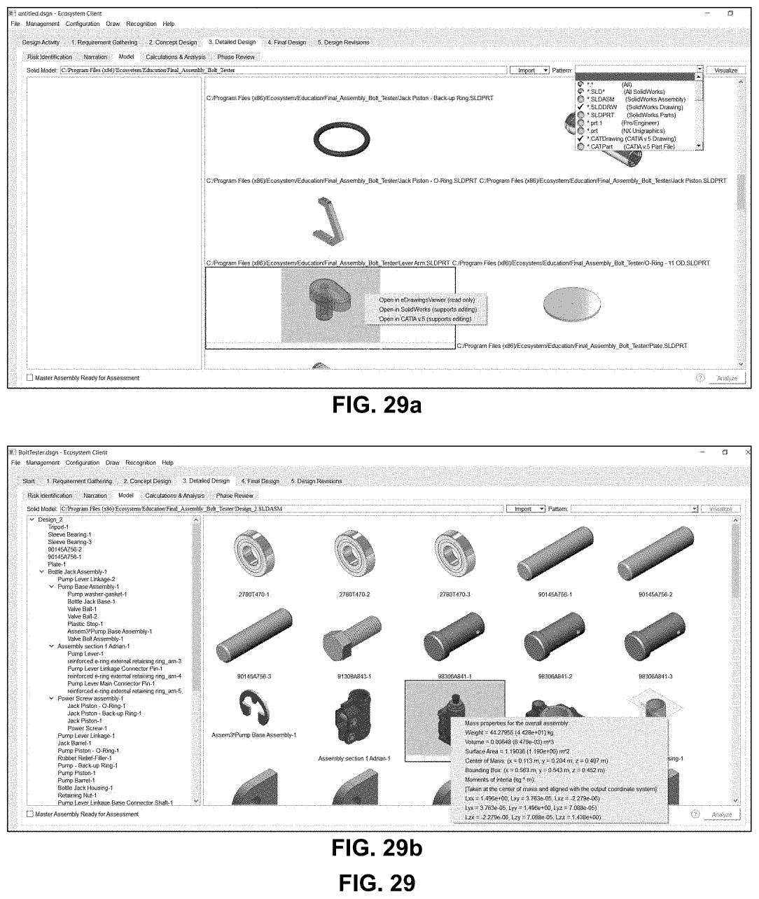

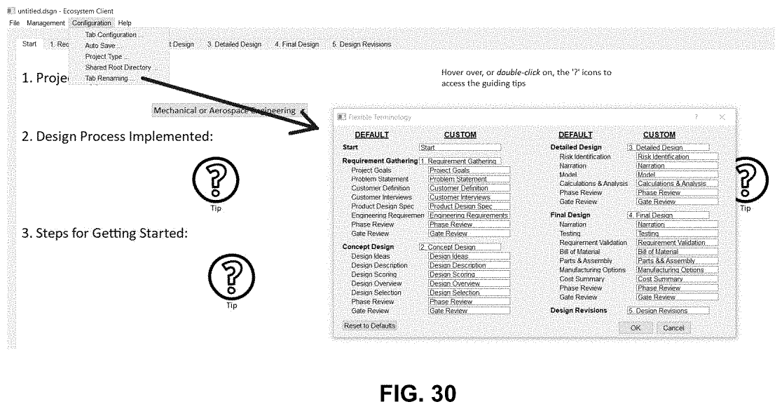

FIG. 28a and FIG. 28b illustrate how the size of images imported into the Design Description tab can be automatically resized, upon the user adjusting the column width or row height of the table into which the images are imported. FIG. 29a presents the results of a recursive search for part and assembly files from a root directly. Upon right-clicking on specific part file, the user can open up the part file in an eDrawingsViewer, SolidWorks or CATIA directly from the Ecosystem design software. FIG. 29b presents a SolidWorks assembly that has been imported into the Ecosystem design software. Upon right-clicking on a specific part file, the user can access mass properties and other SolidWorks meta-data extracted. FIG. 30 illustrates tab renaming capabilities in the Ecosystem design software.

5. Automatic Requirement Verification in Content with Model-Based System Engineering

At a high level, the engineering requirements are verified through an association with the files containing the relevant design information, as illustrated in FIG. 5 and FIG. 31. The SysML tools provide access to the data structures needed for the automatic requirement verification. As opposed to implementing subsystem decomposition as shown in FIG. 8-FIG. 14, this decomposition can be carried out within the SysML framework, and the relevant data structures accessed and analyzed through an interface with these tools. FIG. 31 illustrates how the SysML plugin for automatic requirement verification can fit into a representative tool environment at a large design organization (a proponent of sound SE practices)

### 1. High-Level Description of a “Distributed” Approach to Automatic Requirement Verification

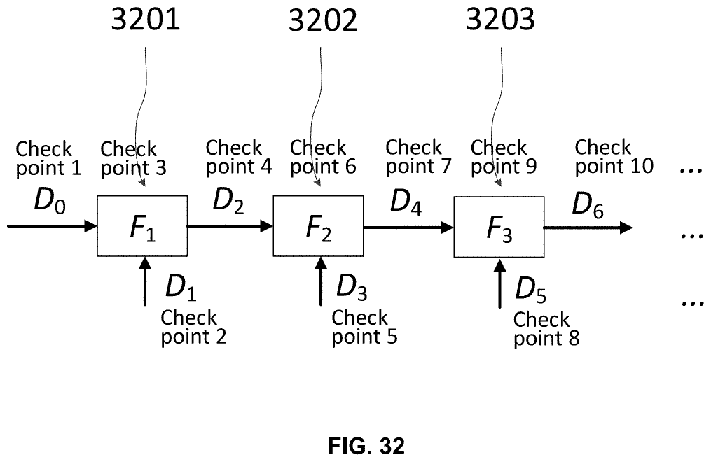

FIG. 32 presents a generic function chain from a SysML project to which we apply the automatic requirement verification. Each function has activities, and each activity requires data. We start at the begin of the data flow, work our way down the function chain, and apply checks at each step along the way:
1. At Check Point 1, we apply checks to the input data, D₀, to the first function,
2. Next, at Check Point 2, we apply checks to D₁, i.e., other input data to the first function,
3. Check Point 3: Upon checking the inputs to the first function, F₁, we next apply checks to activities within the function itself.
4. Check Point 4: Upon completing the checks for the first module in the function chain, we turn our attention to the input data, D₂, to the 2^{nd} module, F₂.
5. Check Point 5: We also apply checks to D₃, the other input data to the 2^{nd} function, F₂.
6. Check Point 6: Upon checking the inputs to the second function, F₂, we next apply checks to activities within the function itself.
7. Check Point 7: Upon completing the checks for the 2^{nd} module in the function chain, we turn our attention to the input data, D₄, to the 3^{rd} module, F₃.
8. Check Point 8: We also apply checks to D₅, the other input data to the 3^{rd} function, F₃.
9. Check Point 9: Upon checking the inputs to the third function, F₃, we next apply checks to activities within the function itself.
10. This process continues until the end of the function chain.
   4. Splitting up the Function Chain Resulting from Design Process (A Simple Approach)

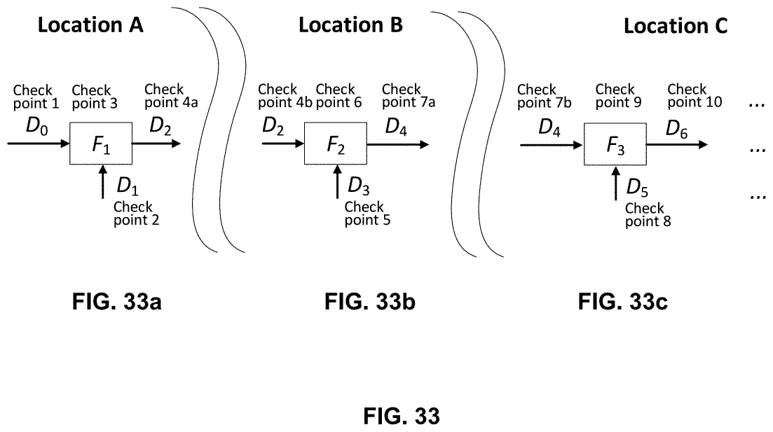

FIG. 33 presents a generic function chain from a SysML project to which we apply the automatic_requirement verification. Each function has activities, and each activity may require data. We start at the begin of the data flow, work our way down the function chain, and apply the checks along the way. The checks are first applied to the input data and then to the functions. F₁ represents a function with activities at step j in the process. D₀ and D₁ represent the input data to function F₁. D₂ represents the data produced by function
1. At Check Point 1, we apply checks to the input data, D₀, to the first function,
We first verify if the input data D₀ is available and then verify the input data D₀ for completeness.
2. Next, at Check Point 2, we apply checks to D₁, i.e., other input data to the first function,
We similarly verify the input data D₁ for availability and completeness.
3. Check Point 3: Upon checking the inputs to the first function, F₁, we next apply checks to activities within the function itself.
4. Check Point 4: Upon completing the checks for the first module in the function chain, we turn our attention to the input data, D₂, to the 2^{nd} module, F₂.
5. Check Point 5: We also apply checks to D₃, the other input data to the 2^{nd} function, F₂.
6. Check Point 6: Upon checking the inputs to the second function, F₂, we next apply checks to activities within the function itself.
7. Check Point 7: Upon completing the checks for the 2^{nd} module in the function chain, we turn our attention to the input data, D₄, to the 3^{rd} module, F₃.
8. Check Point 8: We also apply checks to D₅, the other input data to the 3^{rd} function, F₃.
9. Check Point 9: Upon checking the inputs to the third function, F₃, we next apply checks to activities within the function itself.
10. This process continues until the end of the function chain.

FIG. 33 presents a “distributed” version of FIG. 32. In FIG. 33, the computation associated with the functions F₁, F₂ and F₃ may take place at different locations.

### 5. Splitting up the Verification by Subsystems and Standardizing the Interface (the Preferred Approach)

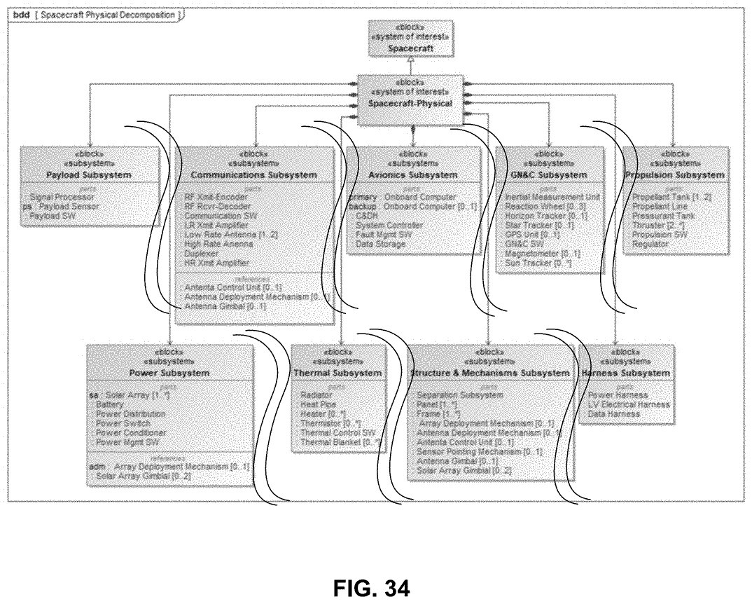

The preferred approach, outlined in FIG. 34, consists of splitting the automatic verification by sub-systems and standardizing the interfaces. Each sub-system may be verified by a separate partner (i.e., in a “distributed” fashion). Each partner on a multidisciplinary project may launch a separate design tool for low-level analysis, i.e., to retrieve the lower-level input data needed for the higher-level requirements. They might choose to launch the Cameo Simulation Toolkit, for some of the analysis. Separate partners might use separate tools from OpenCAE system environment. But they would commonly use SysML for the high-level system modeling.

2. Conforming the Proposed Approach with the NASA Systems Environment

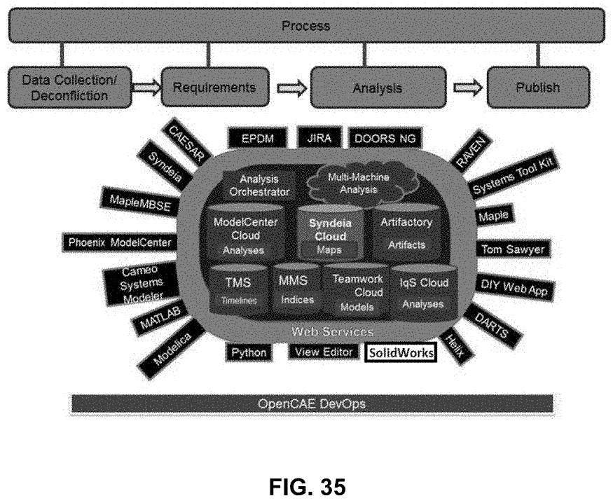

The proposed approach can be adapted to the OpenCAE systems environment without much difficulty. Whereas FIG. 15, and FIG. 16 outline an approach for extracting the meta data from SolidWorks parts, assemblies or Bill of Materials, for the purpose of automatically verifying requirements related to product cost, weight or dimensions, (KarbanCrawfordTrancho 2018) describes a method for automatically verifying requirements, such as a timing requirement, on basis of low-level data obtained through simulation using the Cameo Simulation Toolkit. This is a similar principle as outlined in (SteingrimssonFanKulkarni 2020) (SteingrimssonFanKulkarni 2020). FIG. 35 presents a modified version of the OpenCAE systems environment, one supporting an interface to SolidWorks.

### 3. Formulation of Requirements for a Small Satellite Example (FireSat)

### 1. The Space Mission Design Process

Table 34 summarizes the Space Mission Design Process (SMAD) (AndrewKetsdever 2019). The SMAD Process resembles the design process outlined in FIG. 19.

2. Mission Statement and Mission Objectives from the FireSat Example

The Mission Statement for the FireSat example reads as follows (AndrewKetsdever 2019): “Because forest fires have an increasing impact on recreation and commerce and ever higher public visibility, the United States needs a more effective system to identify and monitor them. In addition, it would be desirable (but not required) to monitor forest fires for other nations; collect statistical data on fire outbreaks, spread, speed, and duration; and provide other forest management data. Ultimately, the Forest Service's fire-monitoring office and rangers in the field will use the data. Data flow and formats must meet the needs of both groups without specialized training and must allow them to respond promptly to changing conditions.”

TABLE 34
The Space Mission Design Process as outlined in (AndrewKetsdever2019).

| Typical | |
|---|---|
| Flow | Step |
| 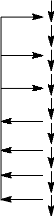 | $\begin{matrix}Define \\ Objective\end{matrix} \{ \begin{matrix}1. & Define broad objectives and constraints . \\ 2. & Estimate quantitative mission needs and requirements\end{matrix} .$ $\begin{matrix}Characterize \\ the \\ Mission\end{matrix} = \{ \begin{matrix}2. & Define alternative mission concepts . \\ 3. & Define alternative mission architectures . \\ 4. & Identify system drivers for each . \\ 5. & Characterize mission concepts and architectures\end{matrix} .$ $\begin{matrix}\begin{matrix}Evaluate \\ The\end{matrix} \\ Mission\end{matrix} = \{ \begin{matrix}6. & Identify critical requirements . \\ 7. & Evaluated mission utility . \\ 8. & Define mission concept ( baseline )\end{matrix} .$ $\begin{matrix}Define \\ Requiremets\end{matrix} = \{ \begin{matrix}9. & Define system requirements . \\ 10. & …\end{matrix}$ llocate requirements to system elements. |

### 3. Mission Objectives for the FireSat Example

The FireSat example lists the following Mission Objectives (AndrewKetsdever 2019):

Primary Objective: “To detect, identify, and monitor forest fires throughout the United States, including Alaska and Hawaii, in near real time.”

Secondary Objectives:
(a) “To demonstrate to the public that positive action is underway to contain forest fires.”
(b) “To collect statistical data on the outbreak and growth of forest fires.”
(c) “To monitor forest fires for other countries.”
(d) “To collect other forest management data.”4. Functional Requirements, Operational Requirements and Constraints from the FireSat Example

Table 35 lists the functional requirements for the FireSat example (AndrewKetsdever 2019). Table 36 lists the operational requirements and Table 37 the constraints.

TABLE 35
Functional Requirements from the FireSat example (AndrewKetsdever 2019).

| Requirement | Factors Impacting Requirement | FireSat Example |
|---|---|---|
| Performance | Primary objective, payload size, | 4 temperature levels |
| | orbit, pointing | 30 m resolution |
| | | 500 m location accuracy |
| Coverage | Orbit, swatch width, number of | Daily coverage of 750 million |
| | satellites, scheduling | acres in continental U.S. |
| Responsiveness | Communications architecture, | Send registered mission data |
| | processing delays, operations | within 30 min to up to 50 users |
| Secondary Mission | As above | 4 temperature levels for pest |
| | | management |

TABLE 36
Operational Requirements from the FireSat example(AndrewKetsdever 2019).

| | Factors Impacting | |
|---|---|---|
| Requirement | Requirement | FireSat Example |
| Duration | Experiment or operations, | Mission operational at least 10 years |
| | level of redundancy, altitude | |
| Availability | Level of redundancy | 98% excluding weather, 3-day maximum outage |
| Survivability | Orbit, hardening, electronics | Natural environment only |
| Data Distribution | Communications | Up to 500 fire-monitoring offices +2,000 |
| | architecture | rangers worldwide (max. of 100 simultaneous |
| | | users) |
| Data Content, Form and | User needs, level and place | Location and extent of fire on any of 12 map |
| Format | of processing, payload | bases, average temperature for each 30 m² grid |

TABLE 37
Constraints from the FireSat example (AndrewKetsdever 2019).

| Requirement | Factors Impacting Requirement | FireSat Example |
|---|---|---|
| Cost | Manned flight, number of | <$20M/yr + R&D |
| | spacecraft, size and complexity, | |
| | orbit | |
| Schedule | Technical readiness, program size | Initial operating capability within 5 years, final |
| | | operating capability within 6 years |
| Regulations | Law and policy | NASA mission |
| Political | Sponsor, whether international | Responsive to public demand for action |
| | program | |
| Environment | Orbit, lifetime | Natural |
| Interfaces | Level of user and operator | Comm. Relay and interoperable through NOAA |
| | infrastructure | ground stations |
| Development | Sponsoring organization | Launch on STS or expendable; No unique |
| Constraints | | operations people at data distribution nodes |

5. Formulation of Requirements from the FireSat Example in SysML

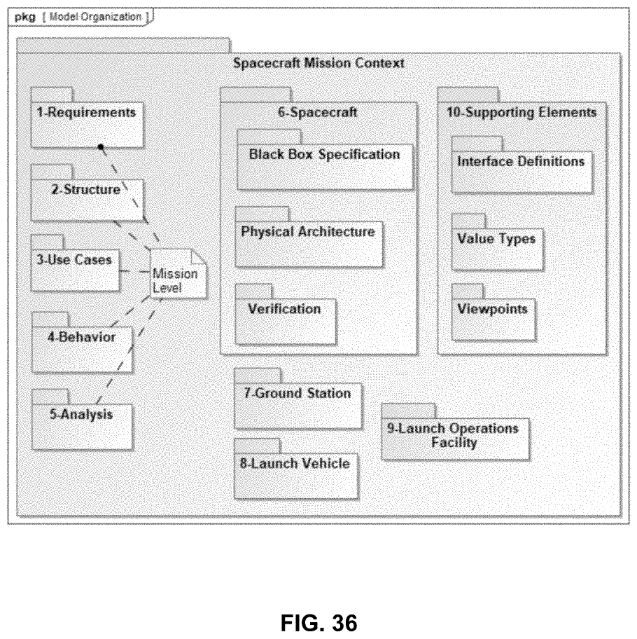

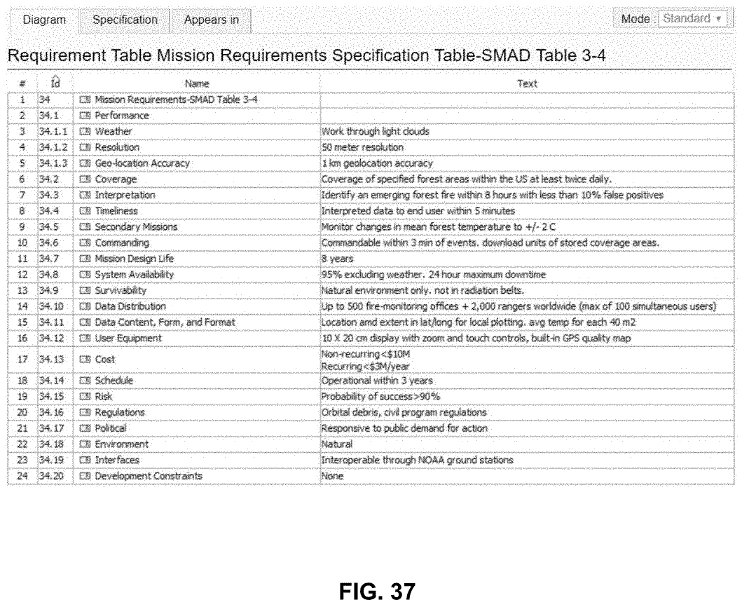

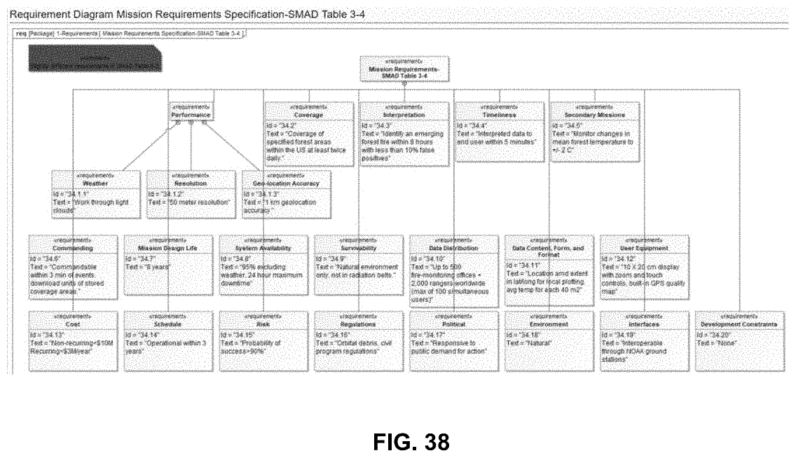

FIG. 36, FIG. 37 and FIG. 38 present in SysML the space craft mission context, the mission requirement specification table and the mission requirement specification diagram from the FireSat example (FriedenthalOster 2022).

4. Relevance of Subsystem Decomposition for the Gateway to that of the FireSat Example

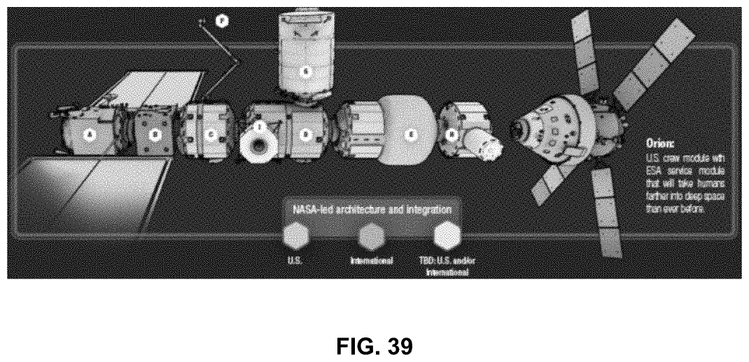

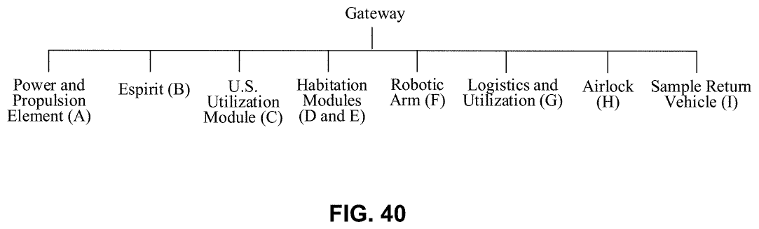

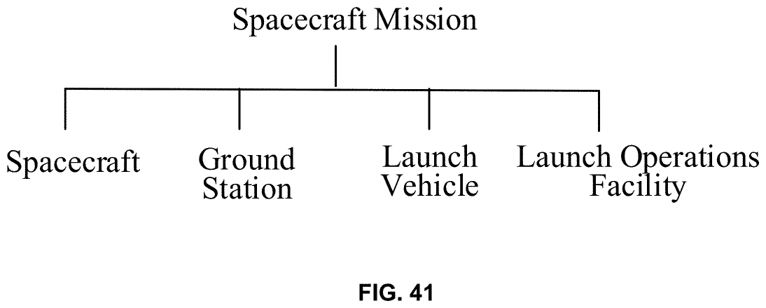

FIG. 39 and FIG. 40 present subsystem decomposition for the Gateway. FIG. 41 outlines analogous decomposition for the FireSat example.

### 5. Automatic Requirement Verification Applied to a Small Satellite Example (FireSat)

1. Towards Automatic Verification of Requirements from the FireSat Example

At a high level, the engineering requirements are verified through an association with the files containing the relevant design information, as illustrated in FIG. 5. In Table 2, the requirements are grouped into 24 standardized categories. For each category, the relevant source files containing the design files with information needed for verification of requirements from that category are identified. These design files instruct the verification algorithm where to look for the design parameters of interest.

TABLE 38
Steps towards automatic verification of the requirements listed in Table 35 and Table 36.

| | Data Needed for Automatic | |
|---|---|---|
| Requirement | Verification | Difficulty |
| Performance | Temp. levels, resolution and | Probably not easy |
| | location accuracy | |
| Coverage | Imagery from specified forest | Not too difficult, given simple pattern recognition? |
| | area within the US | |
| Responsiveness | Registered mission data (available | Fairly easy, given availability of data |
| | locally?) | |
| Secondary Mission | 4 temperature levels for pest | Fairly easy, if given data. Needs further study. |
| | management | |
| Duration (Longevity) | Level of redundancy, altitude and | Not easy, but possible (Monte Carlo analysis) |
| | more | |
| Availability | Level of redundancy | Not easy, but possible |
| Survivability | Data on orbit, hardening and | Not easy, but possible |
| | electronics | |
| Data Distribution | Data from communications | Relatively easy to verify no. of simultaneous users |
| | architecture | |
| Data Content, Form | Location, extent of fire and avg. | Probably not easy, but doable (w/simple pattern |
| and Format | temp per 30 m² grid | recogn?) |

TABLE 39
Steps towards automatic verification of the Constraints listed in Table 37.

| Requirement | Data Needed for Automatic Verification | Difficulty |
|---|---|---|
| Cost | From NASA mission ($20M/yr. + R&D | Partial automation (of part cost) not |
| | cost) | difficult? |
| Schedule | Granular schedule with sub-activities | Easy to extrapolate progress & compare |
| | | w/target? |
| Regulations | Law and policy (from NASA mission) | Public info; Easy to hard code into model? |
| Political | Sponsor, whether international program | Easy if data on public demands is |
| | | synthesized? |
| Environment | Data on orbit and lifetime? | Could predict lifetime through reliability |
| | | analysis? |
| Interfaces | Comm. relay and interoperable through | N/A? |
| | ground station? | |
| Development | Launch on STS or expendable; no | N/A |
| Constraints | unique people | |

2. Towards Expanding on the Set of Requirements that Can Be Automatically Verified in SysML

Our approach for extending the set of requirements, that can be automatically verified in SysML, includes the following steps:
1. We apply the general approach of FIG. 31-FIG. 34 to the requirements from the FireSat SysML example (Table 35, Table 36 and Table 37).
2. Along the lines of Table 38 and Table 39, we will map out the categories of requirements of interest and assess the relative difficulty for automatic verification.
3. We build up our case through judicious crafting of SysML examples for the categories of interest.

### 6. Digital Assistants for Science and Engineering (Continuation-in-Part)

As a replacement for the Latent Semantic Analysis (LSA) in the querying (search) engine described in (Steingrimsson 2018b), one can utilize a neural network that processes text by “vectorizing” words. A two-layer neural network can be implemented using a facility like Word2Vec (Word2Vec 2022). The LSA outlined in (Steingrimsson 2018b) may prove somewhat slow in implementation, due to the matrix calculations involved. FIG. 42 illustrates an adapted version of the querying engine with a neural network replacing the LSA.

Word2Vec is a technique for natural language processing. The Word2Vec algorithm utilizes a neural network model to infer word association from a large corpus of text. Once trained, such a neural network model can identify synonymous words or suggest additional words for a partial sentence. Word2Vec represents each distinct word with a vector containing a specific list of numbers. The vectors are carefully selected such that the cosine similarity between the vectors characterizes the level of semantic similarity between the words represented by those vectors (Word2Vec 2022).

### 7. Smart Modeling & Simulation: “Plug-and-Play” for Modeling Engineering Structures

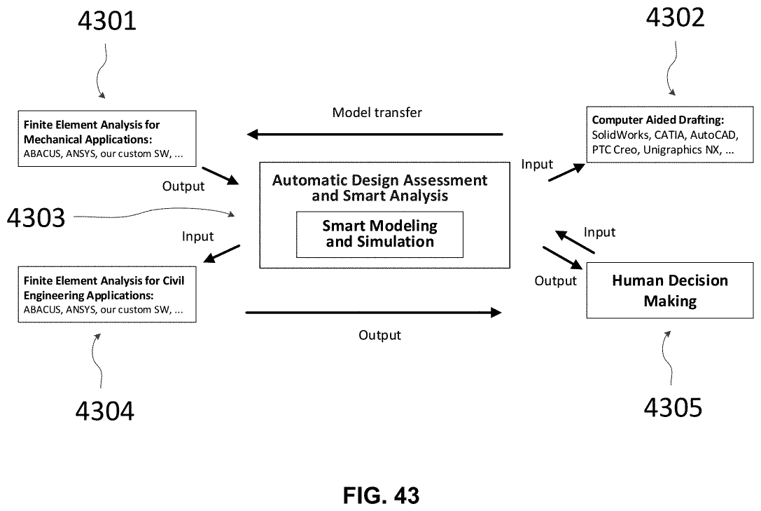

The Smart Modeling and Simulation is an automated system for creating simulation models, performing rapid simulations and interactively interpreting the results. As a result, the industry may save much time and efforts in finite element (FE) simulation of their products and processes. FIG. 43 summarizes the high-level approach.

SMS is a front-end module, with automated scripts for analysis, ready-made geometries for plug-and-play, providing multi-physics analyses capabilities based on the existing proven tools, and a 1-button solution for meshing and multi-physics analyses. It provides local and global analyses capability, in addition to complex multi-physics, such as chemo-thermo-piezo-viscoelasticity and coupled-acoustic-structure physics.

### 7.1 High-Level System Structure and Primary Starting Point

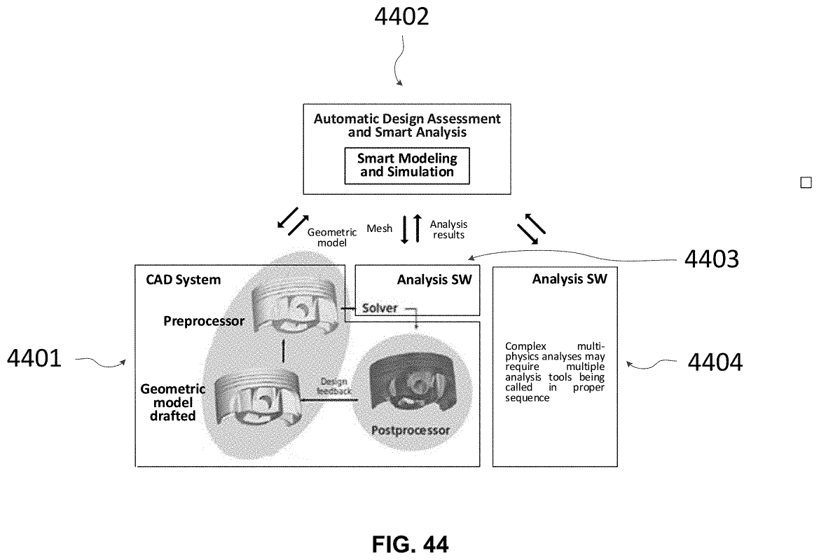

FIG. 44 show how the CAD systems and analysis SW can be launched from a high-level SMS interface. The geometry model is imported from the CAD system to the analysis tool through the SMS interface.

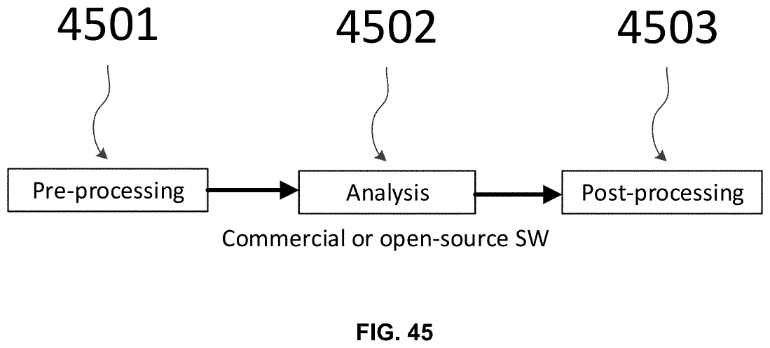

The Smart Modeling and Simulation system offers interfaces to commercial or open-source SW, per FIG. 45, along with custom pre-processing and post-processing routines. The user interface may utilize the OpenGL graphics library, and the analysis routines may be written in Fortran. Hence, the SW can be portable. The Smart Modeling and Simulation system is capable of creating geometries and launching analyses. It has ready-made geometries, but no interface to CAD tools. The Ecosystem for Design Assessment and Verification is capable of providing such interfaces (Steingrimsson 2018), (SteingrimssonKulkarni 2020). The Ecosystem is already capable of reading in and decoding CAD files, as shown in FIG. 15-FIG. 18.

### 7.2 Plug-and-Play and Ready-Made Geometries

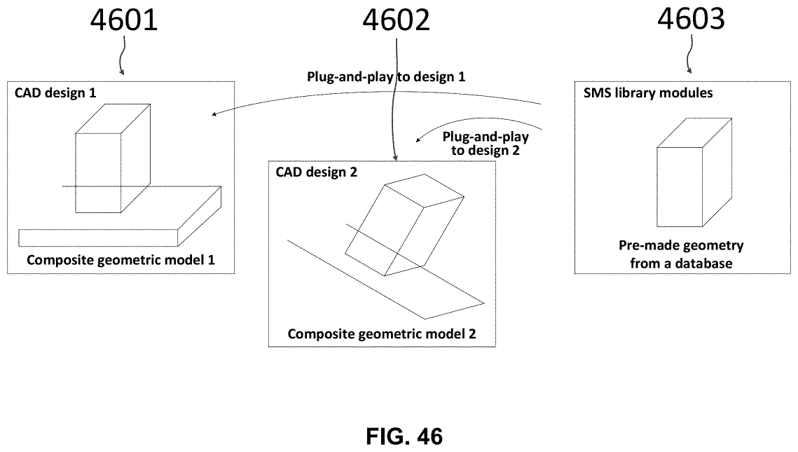

The Smart Modeling and Simulation system is capable of plugging pre-defined, or user made, geometric models into a variety of CAD programs. The user is provided with the ability to quickly create models using standard drag-and-drop with wide variety of ready-made components from a database. FIG. 46 summarizes the operation of plug-and-play at a high level.

The primary challenge with the technical implementation of our plug-and-play approach involves defining the geometric models that can be imported to or from the CAD tools of interest. To this end, we have embarked on identification of the data structures that the Application Program Interfaces (APIs) for these CAD tools. Our assumption is that designers will be primarily importing models using one of the open CAD formats (e.g., STL, STEP, DXF or IGES).

1. Starting Point Wor work on Ready-Made Geometries

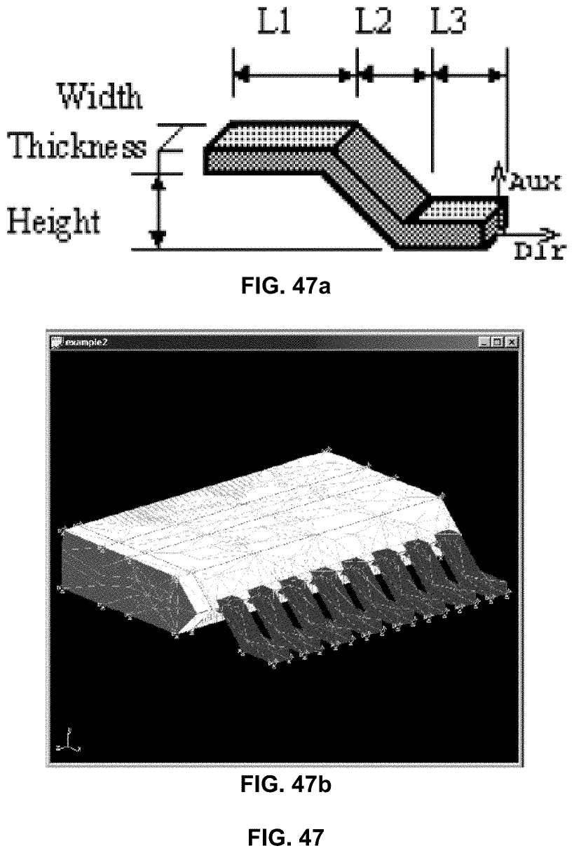

FIG. 47a and FIG. 47b present an example of a geometric model created using a Smart Modeling and Simulation system. Here the ready-made geometry consists of a lead frame. A half of a Quad Flat Package (QFP) is subjected to temperature loading and the thermo-mechanical effects analyzed. The lead frame has the following dimensions: Ll=5 mm, L2=1.5 mm, L3=2 mm, Width=1 mm, Thickness=0.6 mm, and Height=1.5 mm. These properties can be easily edited. The underlying method can correspondingly be extended to other products.

2. Specifics on the Importing of Read-Made Geometries into the CAD tools of interest

Table 40 and Table 41, replicated from (SteingrimssonKulkarni 2020), offer specifics on our approach for importing or exporting the geometric models through the APIs for the primary CAD tools of interest. Through an add-on to tools like Solidworks, one can export the geometric models directly into an Extended Markup Language (XML) file containing the structure of the model and parameters of the parts (DassaultSystemes 2017)

### 3. Other Notes of Importance

All geometries are parametric. This is really convenient, and allows users to easily

TABLE 40
Salient properties of the APIs for the primary CAD and analysis SW of interest.

| | CAD | | | | FEA | | CFD |
|---|---|---|---|---|---|---|---|
| Feature | Solidworks | PTC Creo | AutoCAD | CATIA | ABAQUS | ANSYS | StarCCM |
| Properties of APIs and | C++ Macros | VB API & | ObjectARX ® | C#, C++ | ODB C++ | See | Java API |
| plugins provided | & Add-Ins | C++ toolkit | (ObjectARX | & VB | API | (ParaView | (CdAdapco |
| | (Solidworks | (ApiSupport | 2015) | plugins | (StackOverflow | 2015) | 2015) |
| | API 2015), | 2015) | | (CatiaV5 | 2015) | | |
| | (Solidworks | | | 2015) | | | |
| | 2015) | | | | | | |
| Structure of output files | Structured | Proprietary | See | Proprietary | For access, | See | Text (see |
| | storage (Pole | | Table 41 | | see | (ANSYS | Table 41) |
| | 2015) | | | | (StackOverflow | 2015) | |
| | | | | | 2015) | | |
| Comprehensive code book | See | See | See | See | See | See | See |
| for tokens in output files | (DassaultDevGuide | (PtcCreo | (AutoDesk | (CatiaV5 | (Abaqus | (Ansys | (CdAdapco |
| | 2016) | 2016) | 2013) | 2015) | 2016) | 2015) | 2016) |

TABLE 41
More on the strategy for decoding the content of the output files from the primary
CAD and FEA tool of interest.

| Design | File | Output | Text or | Method of decoding the content of an entire data |
|---|---|---|---|---|
| Tool | Type | Format | Binary? | files |
| Solidworks | Part | .SLDPRT, | Binary | (Pole 2015) provides generic mechanism for decoding |
| | Assembly | .SLDASM | | the output. ‘PreviewPNG’ is the stream name for image |
| | | | | thumbnails. |
| PTC Creo | Part | .prt.1 | | Decodable using Paraview or Open Cascade, once |
| (Pro/Engineer) | Assembly | .asm.1 | | converted into the STEP (STP) or STL formats |
| | | | | (ParaView 2015), (OpenCascade 2015) |
| AutoCAD | Part | .ipt (Inventor) | | Decodable using Paraview or Open Cascade, once |
| (Inventor, | Assembly | .iam (Inventor) | | converted into the STEP (STP) or IGES formats |
| IntelliCAD) | | | | (ParaView 2015), (OpenCascade 2015) |
| | Native draw | .dwg | | LibreDWG (LibreCAD 2015), (GNU 2015) (as |
| | | | | opposed to OpenDWG (SourceForge 2015)) |
| CATIA | Part | .CATPART | Binary | Decodable using Paraview or Open Cascade, once |
| | Assembly | .CATPRODUCT | | converted into the STEP (STP) or IGES formats |
| | | | | (ParaView 2015), (OpenCascade 2015) |
| ABAQUS | Analysis input file (.inp) | | Text | Decoded, for example, using a Python interface (abapy |
| | | | | 2015) |
| | Output database (.odb) | | Binary | Decoded using the Abaqus ODB C++ API |
| | | | | (StackOverflow 2015) |
| ANSYS | Results | .rst, | Binary | Decodable using ParaView or OpenFOAM (ParaView |
| | | | | 2015), (OpenFOAM 2015) |
| Star CCM | STARCD | cel/vrt/inp | Text | Decodable using ParaView or OpenFOAM (ParaView |
| | EnSight | .case | Text | 2015), (OpenFOAM 2015) |
| Open | Interchange | .dxf | Text | Import/export logic can be extracted from FreeCAD |
| Formats | | | | (FreeCAD 2015) |
| (Cross- | | | | |
| Vendor) | | | | |

generate the FEA meshes.

Various geometries have already been built and put into a database resembling the Solidworks toolbox. Users can continue to add their own geometries to the SMS system and store in the database.

In case users elect to use an external CAD tool, such as Solidworks or AutoCAD, to build library modules, these can be imported into the SMS system and used to build smart structures.

s7.3 Inter-Operability

Consistent with the mandate to
1. Minimally modify existing analysis and simulation codes to support automated interoperability with CAD models;
2. Demonstrate interoperability of existing analysis and simulation codes with legacy and emerging types of CAD models;
3. Demonstrate automatic interfacing and composition of different types of analysis and simulation codes and apply them to CAD models from different sources; we have, per Table 40 and Table 41, furnished the SMS system with the ability to operate on a wide variety of CAD formats.
   1. Ability to Extract Thumbnail Images from a Variety of CAD Formats

The SMS system leverages capabilities from the Ecosystem for Design Assessment and Verification for automatically interfacing with a number of CAD tools (SteingrimssonKulkarni 2020). The Ecosystem can recursively search archives of parts and assembly files, from past design projects, extract thumbnail images in real time and visualize. As shown in FIG. 29a and FIG. 29b, designers working on new design project can harvest past designs, by running searches over the repositories storing the past designs, quickly relate (visually) to the content, and compile a shortlist of candidates resembling the new design of interest. Designers can then right-click on images from the shortlist, and open up in the e-Drawings Viewer, Solidworks or CATIA v.5, for closer look, ultimate verification, or if desired, editing.

### 2. Specifics on Our Approach for Addressing the Inter-Operability Requirements

In terms of inter-operability, the SMS system needs to be able to
1. Interface with (read input files) from any of the CAD tools.
2. Modify imported modules and create composite structures (geometric models) through plug-and-play.
These may be modules created in, and imported from, other CAD tools.
3. Create input files for the analysis tools (say, ABAQUS, ANSYS and ComSol).
The input files are expected to contain material properties, among other things.
4. Automatically launch the analysis tools from the SMS system, using the input file just created.

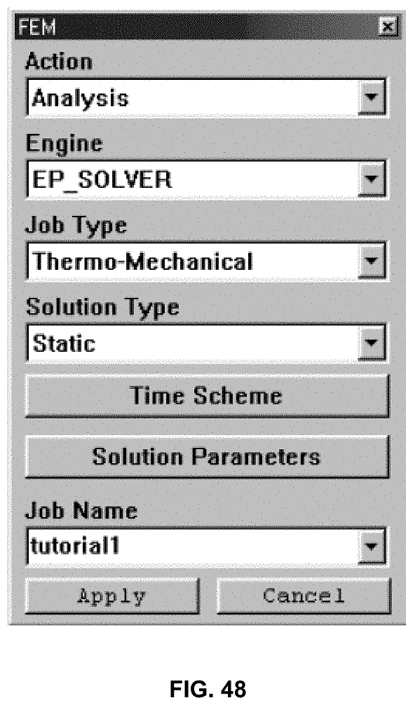

We address these requirements as follows:
1. The interfacing with the CAD tools is achieved utilizing the APIs provided by the vendors of the tools of interest. Table 40 and Table 41 summarize our approach for decoding the output from the CAD and analysis tools of interest and importing into the SMS system.
2. The SMS system is capable of accounting for a global model for the whole sensor as well as much more refined local models (meshes) to determine stress fields in local areas.
3. The SMS system is capable of launching an FE solver with solution parameters (from an input file), as shown in FIG. 48 and FIG. 49.
5. The SMS system is capable of employing facilities from the Ecosystem for Design Assessment and Verification for launching the e-Drawings Viewer, Solidworks and CATIA through a high-level interface similar to the one presented in FIG. 13-FIG. 14 or in FIG. 17-FIGS. 18.
For the applications of interest, we locate in the registry and extract the path to the executable used to launch the application. We then use this information, in the SMS system, to launch a new process. In the case of Solidworks, the path to the executable is stored in

```
appPathSolidworks:
  a_bSuccess = process.startDetached(
    appPathSolidworks );
```

### 3. Other Notes of Importance

FIG. 15 and FIG. 16, together with the patent (SteingrimssonKulkarni 2020), provide further specifics on how to import Solidworks part and assembly files utilizing wrappers that incorporate the Solidworks Document Manager.

### 8. Nonlinear Analysis for Civil Engineering Structures

### 8.1 Essence of Proposed Innovation: Modeling of Stress Interactions at Macroscopic Level for Inelastic Range

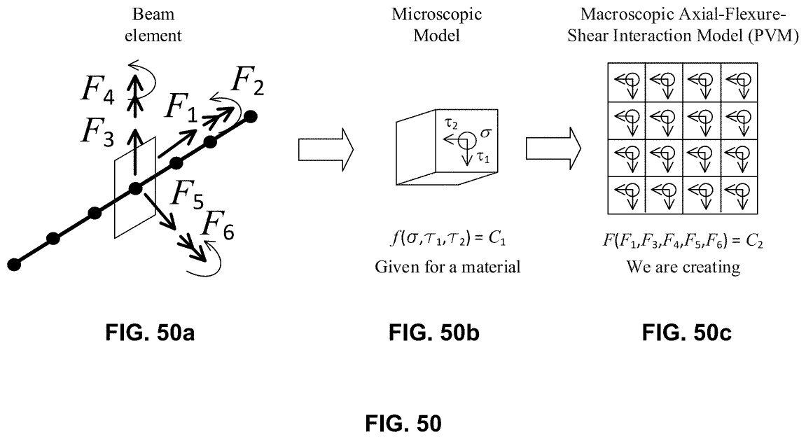

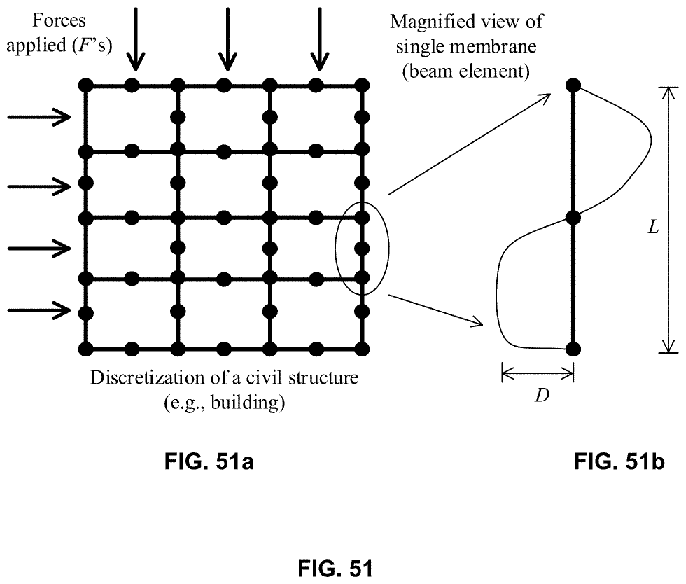

FIG. 50 summarizes the proposed innovation. FIG. 51 defines the key terms. Each node in the beam element has six (6) degrees of freedom. These degrees are captured in the 6-element force vector

F=(F₁,F₂,F₃,F₄,F₅,F (1)

In elastic range, there is a linear relationship between the force vector, F, the stiffness matrix, k, and the displacement matrix, M:

{F}=[k]{M} (2)

Similarly, there is a linear relationship between the normal stress σ, the shear stress, τ, the compliance matrix, C, and the strain, ε:

$$( \begin{matrix}σ \\ τ\end{matrix} ) = [ C ] \{ ε \} \qquad ( 3 )$$

For inelastic beam formations, the beam sections experience interaction between the normal and shear stresses. In the inelastic (nonlinear) range, a relationship similar to (3) is traditionally modeled as

(F₁,F₃,F₄,F₅,F6)=ϕ(σ,τ), (4)

where again σ represents the normal stress, and τ the shear stress, for a particular beam element. At microscopic level, the interactions for the inelastic analysis can be modeled through a function

f(σ,τ₁,τ₂)=C₁, (5)

which can be determined for any given material. This type of modeling is good for one small beam element, but is not good for analysis of an entire building.

Our innovation pertains to modeling of stress interactions (creation of dependencies) for surfaces on a macroscopic level. We combine interaction of stress-resultants to derive a model for an entire section:

F(F₁,F₃,F₄,F₅,F₆)=C₂. (6)

We incorporate multi-level iterations into the force-based beam such that they outperform the stiffness-based beams in inelastic range. The preliminary results corroborate our ability. We refer to (6) as an Axial-Flexure-Shear Interaction Model (PVM). It is good both for economical seismic analysis and for design.

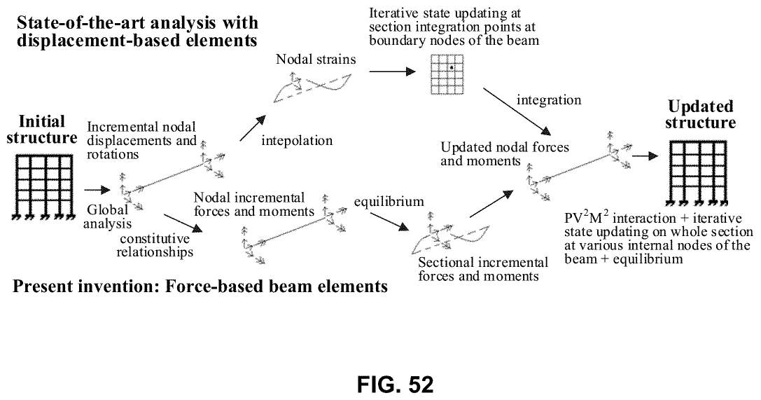

FIG. 52 presents comparison with the operation of traditional, displacement-based beam elements, employed by commercial FEA SW, such as ABAQUS or ANSYS.

### 8.2 Reasons as to Why the Innovation is Transformative

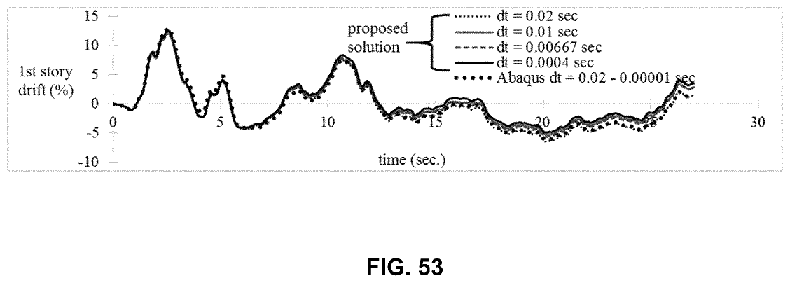

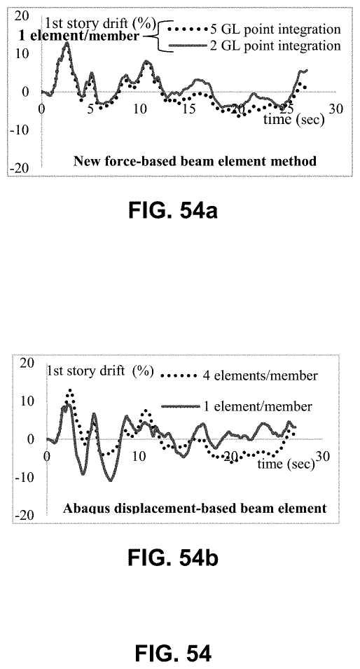

We have observed, from rigorous finite element analysis, that the inelastic shear stress and strain distribution over steel flanged beam cross-sections under pure shear is highly nonlinear; and it can be approximated by two different parabolic variations for the elastic and plasticized segments of the section (BelegaRay 2017). They have already verified some two-dimensional (2D) force-based steel beams with the proposed PVM interaction model, and compared against ABAQUS beam model created with inelastic brick elements (BelegaRay 2017). FIG. 53 shows that, for the case of a 27 sec earthquake, one can attain nearly same accuracy with coarser time steps for the force-based method as with commercial FEA SW (ABAQUS). ABAQUS assumes variable time steps (does not support fixed time steps). As usual, there is a trade-off between accuracy and coarseness of the time steps (dt) and discretization (element/member). The force-based method allows for faster results (allows for larger time steps to achieve given accuracy). In FIG. 54, the force-based methods yield more accurate results compared to commercial FEA SW (ABAQUS), but with coarser discretization. GL refers to the number of discretization points per membrane.

### 9. How to Make the Invention

9.1. Improving Productivity through Automatic Requirement Verification by Providing Plug-Ins for Established Design Tools—ML-Based Approaches to Engineering Design—Generative Designs

FIG. 15 provides a high-level overview of the algorithm for recursively extracting the assembly/component dependence, along with the mass properties and the bounding box. In Step 1, we initialize the Windows Component Object Model (COM) communication protocol (MicrosoftCOM 2018). We do this before using smart pointers from the Active Template Library (ATL), so that the COM is available (MicrosoftDeveloper 2018). ATL is a library of C++ templates provided by Microsoft that simplify the programming of COM objects. In Step 2, we are calling an API function specific to the highest level object in the SolidWorks API. This is a part of the standard mechanism for initializing the SolidWorks API (DassaultSystemes 2018). Step 3 configures the SolidWorks such that it automatically closes down after completion of the routine. In Step 4, we launch the SolidWorks from within the Ecosystem. OpenDoc6( ) opens an existing document and returns a pointer to the document object. By forcing a rebuild of the assembly in Step 5, we ensure the mass properties can be properly extracted, even in the case of the user providing an improperly built assembly as input. In Step 6, we are querying for the bounding box at the assembly level. The fact that one does not need to compute the bounding box from the components (manually account for overlap between the components) is quite convenient. In Step 7, we need to get the model extension, in order to be able to invoke the mass properties on the model extension object. In Step 8, we are clearing the list of selected components. In Step 9, we recursively traverse the assembly tree and add components to the list of selected components. In Step 10, we query for the mass properties for the list of selected components (here the overall assembly).

FIG. 16 presents an outline of the algorithm for extraction of Bill of Material from a generic SolidWorks assembly, part or drawing file. For importing the Bill of Material, we are not launching SolidWorks from within the Ecosystem through the SolidWorks API, but instead utilizing the SolidWorks Document Manager (DassaultSystemesSolidWorks 2018). Hence, the Ecosystem can extract the Bill of Material regardless of whether SolidWorks is installed on the customer system or not (the SolidWorks Document Manager ships with the Ecosystem design SW). In Steps 1-5, we are utilizing a so called Obj ectFactory (EsriDeveloperNetwork 2018), to enable the 64-bit library for BOM extraction (Steps 7, 9 and 12) to run within the 32-bit Ecosystem application. The Obj ectFactory provides access to members that allow automation clients to create arbitrary objects within the application's process space (EsriDeveloperNetwork 2018). For explanation of the functions used in Steps 8 — 12, refer to the SolidWorks API help (DassaultSystemes 2018), (DassaultSystemesSolidWorks 2018)

The e-Design Assessment Engine can interface with SolidWorks, through an API, such as described in FIG. 15, FIG. 16, and in (SteingrimssonKulkarni 2020), or with similar design tools from PTC, AutoCAD or Siemens. Siemens already has a mechanism in place for importing designs into the NX tool. Siemens can automatically launch simulations, to check given parts for manufacturability, check for wear resistance, and more. They also have an interface with inventory management system already built in. If a given part fulfills the requirements, the NX tool can check to see if the part is available from the inventory system. If a given part passes the requirement verification, but is not available in inventory, the NX tool offers provisions for automatically ordering the part form a supplier.

The Teamcenter suite from Siemens can be viewed as a housing facility that links materials data, analysis files and other data. TeamCenter can be linked with other design software like HEEDS for heat transfer, STAR-CCM+ for CFD/FEA and NX for CAD/CAE so it is like a design/simulation environment. The Ecosystem design software can be integrated within this, just like Siemens has already done with GRANTA. In the case of GRANTA, the integration was handled by the Siemens Digital Industries division.

More specifically, in the case of Siemens, one can use the NX Open APIs to interface with the NX tool. NX Open represents a collection of APIs that allow creation of custom applications for NX through an open architecture using well-known programming languages (C/C++, Visual Basic, C#, Java, and Python). One can automate complex and repetitive tasks, integrate third party applications, and customize the NX interface in your preferred programming language (SiemensProgramming 2022).

9.2 Automatic Assessment against ABET Learning Outcomes 1-7—Improving Productivity of Design Instructors or Engineering Departments

### 1. Automation in Grading of Designers' Reports

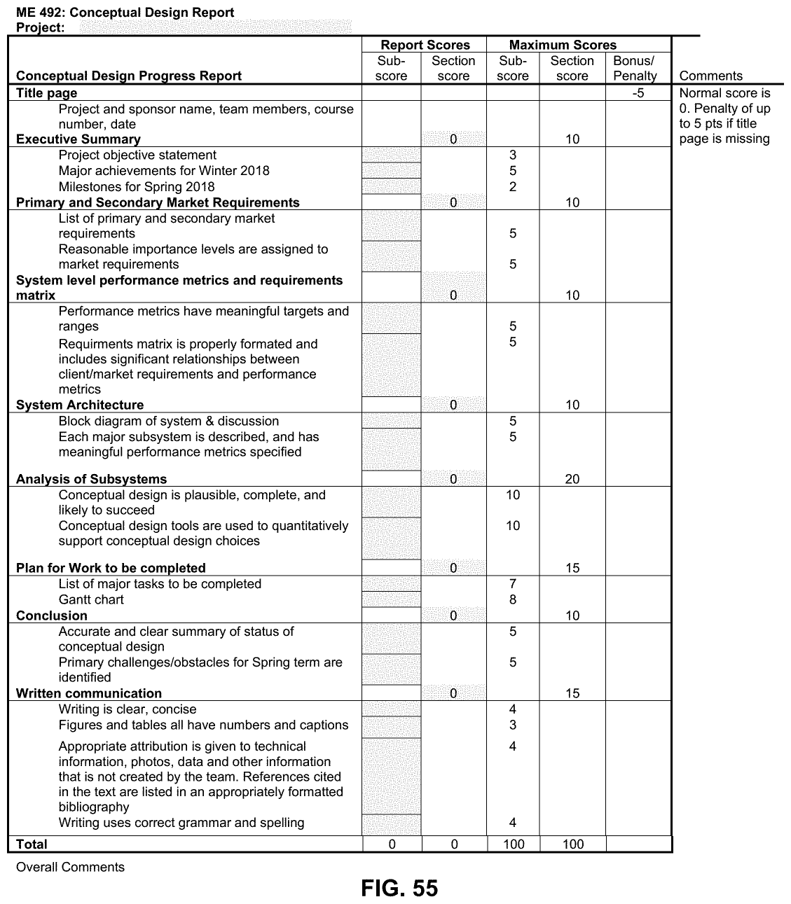

Since instructors may have their own grading rubrics, such as shown in FIG. 55, we assume that specific instructor rubrics are broken down into items, populating a repository with all the items, and compiling for specific instructors (university departments) customized templates based on the items in the repository. Since there is not a single way of grading students' work, the Ecosystem design SW is capable of providing such custom populated templates. Then instructors can pick the templates they like. The grading reports are not unique, but consist of a list of items. Instructors can choose the items to be included in a given, custom report.

The Ecosystem can do more than just provide the customized templates, accept the instructors input, accept reports submitted by students, compile the content and provide assessment results (say, a grade). It can also detect easy vs. hard graders, detect patterns of consistent vs. inconsistent grading, etc. Moreover, the Ecosystem can provide early, automatically generated indication to the students about the grade (or grade range) that they seem to be heading towards. The anticipated grade (or grade range) may involve information of significant interest to the students, even if the estimate was presented with proper caveats, e.g., related to instructor verificaiton. The Ecosystem design software may offer relatively broad grade range early on in a given term. But the grade range may narrow down (converge onto a specific grade) as the term progresses.

While the emphasis here is on automatic assessment of design work against ABET learning outcomes using surveys, the Ecosystem can also accept surveys as input. According to (ABETassessment101 2022), the single most method for assessment is the locally developed survey. Before sending out a survey, it is important to consider what constitutes an effective survey? Ref (ABETassessment101 2022) notes that the results of the surveying will only be as good as the planning and quality of the survey instrument, and offers some tips on effective surveying.

Opportunities exist for the Ecosystem to interface with tools for learning management or with student information systems, through an API, similar to what we have done for SolidWorks. This includes Moodle Ref (WikipediaMoodle 2022), Desire-to-Learn (D2L) Ref. (D2L 2022), Blackboard Learn Ref. (Wikipedia BlackboardLearn 2022) or Canvas Ref (Canvas 2022). According to Ref. (WikipediaMoodle 2022), Moodle is a free and open-source learning management system, written in PRP, and used for blended learning, distance education, flipped classroom and other online schemes in schools, universities, workplaces and other sectors. According to Ref. (D2L 2022), D2L offers flexible and robust learning solutions for most stages of life, from earliest days of school to higher education and the working world. According to Ref. (WikipediaBlackboardLearn 2022), Blackboard Learn is a web-based virtual learning environment and learning management system developed by Blackboard Inc. According to Ref. (Canvas 2022), the Canvas learning management system is built to make teaching and learning easier for everyone, from the littlest learners to college faculty to business leaders. According to Ref (EdLink 2022), student information systems serve as a main record-keeping platform for key actions like student information, maintaining the data store of student's official grades, attendance records, disciplinary actions, and other administrative information. Student information systems are often geared toward users, such as school admins, who need to collect, visualize and report large amounts of student data. A learning management system, on the other hand, serves as a platform for delivering digital teaching materials, assignments and assessments to students (EdLink 2022).

### 2. Automation in Team Formation

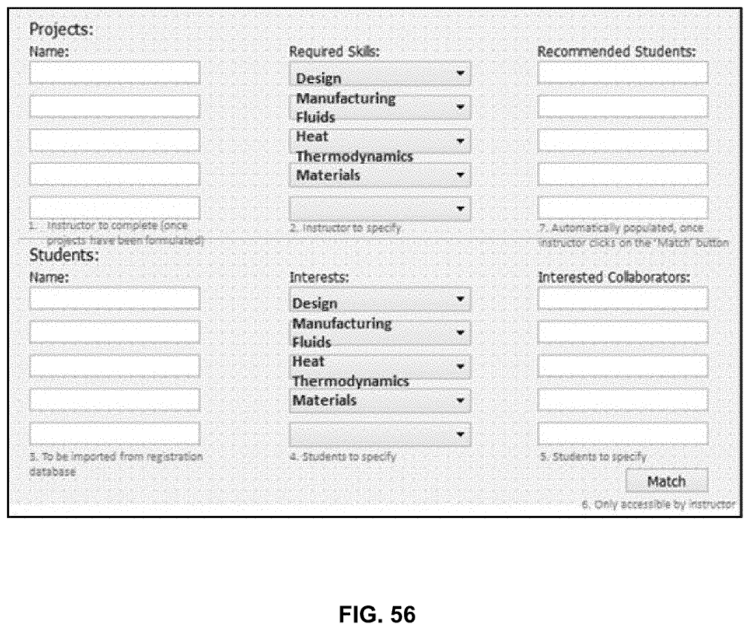

The team formation facility, shown in FIG. 56, allows instructors to match students (designers) up with projects. The full functionality would only be accessible to instructors through the supervisor mode. Designers (students) would only have partial access. Students would see the projects listed, would be able to list their qualifications, specify collaborators they wanted to work with, and bid on the projects. But the students might not see what their fellow students had bid on or specified as preferred collaborators. Only instructors would have access to the Match function.

In case of mechanical design, the drop-down for Required Skills and Interests would include items, such as
1. Design
2. Manufacturing
3. Fluids
4. Heat
5. Thermodynamics
6. Materials

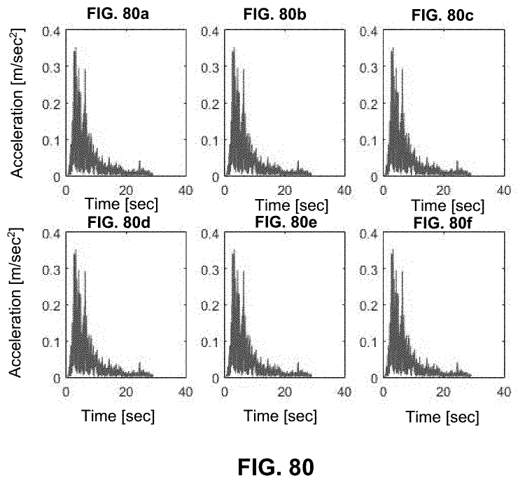

The Ecosystem can support various methods for matching students up with projects:
1. 1-to-1 Matching between Required Skills and Student Interest.
   Here one assumes the students come into the design class with similar skill set (no professional experience, similar classes under their belt, maybe some internship experience).
   FIG. 80 implicitly assumes this method.
2. Students form full teams.
   Once the students have formed a full team (of 4 or 5), they can sign up for any of the vailable projects.
   The left overs would be taking the projects that the other teams have not already taken.
   Here, there is an incentive for people to form teams, because then they can get on the projects they like.
3. Students sign up for particular projects
   First come, first served.
   As soon as a team is filled up, other people go on a waiting list.
4. Instructor Randomly Assigns Students to Projects
   The underlying assumption here is that design teams are supposed to consist of people, not necessarily of collaborators.
3. Separate Instructor and Student Modes

In regards to visibility of submitted (uploaded) content, the instructor vs. student modes supported by the Ecosystem design software resemble the supervisor vs. designer modes outlined in (SteingrimssonKulkarni 2020).

9.3 Automatic Requirement Verification in Context with Model-Based System Engineering

### 1. Subsystem Decomposition in SysML

1. General Observation about Requirement Diagrams and the System Decomposition Process in SysML

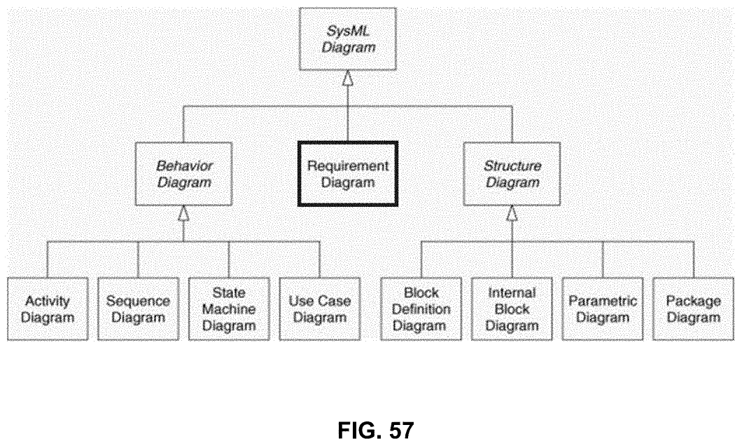

SysML supports nine diagrams, including Requirement Diagrams (highlighted as blue in FIG. 57). FIG. 58 presents a general SysML system decomposition process. This system decomposition aligns well with the system decomposition provided in FIG. 8-FIG. 12. Each subsystem has its own inputs and outputs, which translate into requirements for that subsystem. FIG. 8-FIG. 14 and FIG. 17 demonstrate how the Ecosystem design software can verify requirements, related to cost weight and dimensions, either at the system or sub-system level. As long as the sub-system requirements are fulfilled, you don't need to bother about the specifics of the sub-system implementation (unless the sub-system gets decomposed into sub-sub-systems).

### 2. System Requirements in SysML

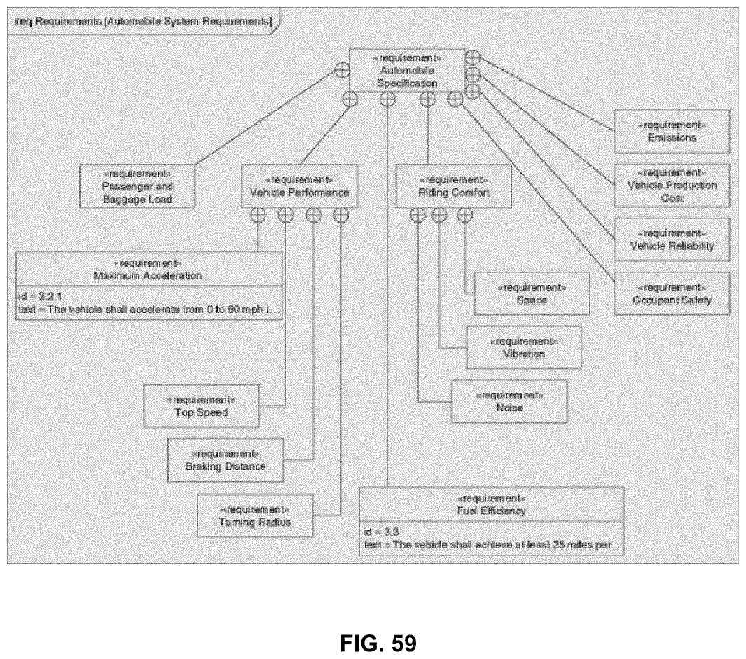

FIG. 59 further shows how SysML represents text-based requirements and their relationship with other requirements, design elements and test cases to support requirement traceability.

### 3. Sub-system Requirements in SysML

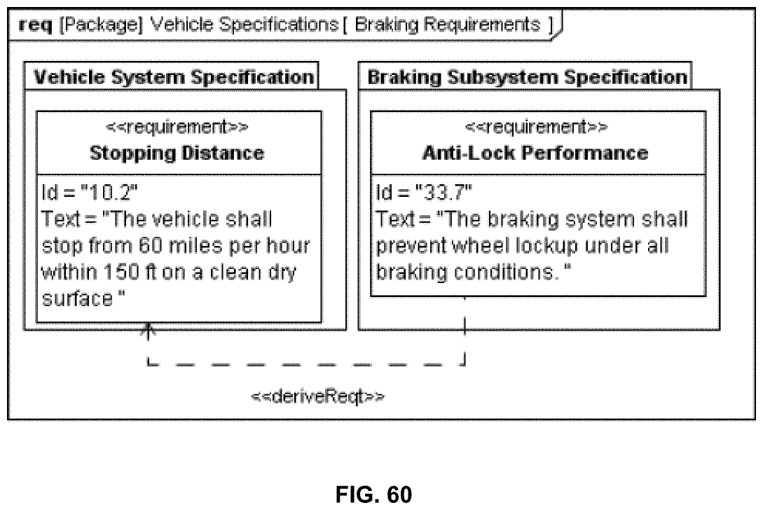

FIG. 60 illustrates how derived requirements can be represented in SysML.

### 4. Requirement Verification in SysML

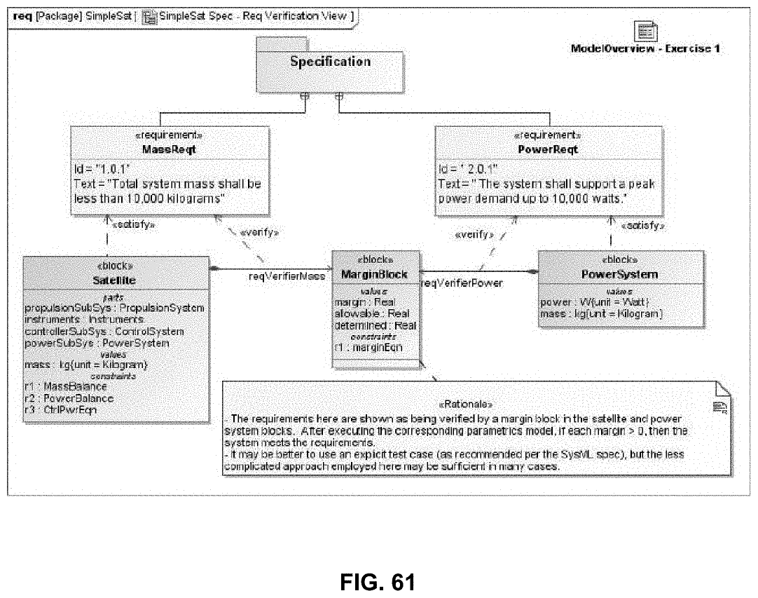

SysML allows certain requirements to be verified via interaction based on a parametric model. In FIG. 61, a requirement is shown as being verified by a margin block between a satellite and power system blocks. After executing the corresponding parametric model, if the margin >0, then the system meets the requirement (Paredis 2018). As Ref. (Karban 2016) further confirms, it is possible to express and verify certain requirements in a SysML tool, with appropriate extensions. However, this wasn't easy, even for a team consisting of some world authorities on SysML modeling (from NASA JPL and No Magic). This invention seeks to expand on these capabilities.

### 2. Software Engineering Aspects of the SysML Plugin

For essential background information on software engineering aspects of the SysML plugin, refer to the SysML Plugin Developer Guide from No Magic (NoMagicDeveloperGuide 2022), to (GitHubOpenMbee 2022) or to (GitHubJpllmce 2022). Note that SysML is not a tool, but a system modeling language specification. The language specification is copyrighted, but available open source and without a licensing restriction.

1. Approaches to Providing Plugin with Access to the Necessary Design Files

There are two primary routes for the plugin to gain access to the source files from which the design parameters of interest, mentioned in FIG. 5, are extracted:
(a) Option A: To the extent the SysML tool has already captured this information (the design parameters), they can be made available to the plugin.
(b) Option B: If the design parameters are not available, the plugin can ask the host application to prompt for these parameters. Upon installation of the plugin, given menus of the host application would be updated accordingly (and/or SysML specific menus introduced).

### 2. Specifics on Development of the Plugin

The plugin consists of a Java application (a .jar file) developed in the Eclipse Integrated Development Environment (IDE). Based on analysis primarily of (NoMagicDeveloperGuide 2022), the following is worth noting:
1. The Open Java API of MagicDraw or a Cameo Suite product, such as Cameo Systems Modeler, provides instructions on how to implement custom plugins, add actions to the menus or tool bars, change UML model elements and create new patterns.
2. Only code from the scope OpenAPI should be used to extend the modeling tool. OpenAPI contains code for public usage, stable through builds and versions (NoMagicDeveloperGuide 2022).
3. No Magic provides a set of plugin samples in >modeling tool installationdirectory/openapi/examples. By using these examples, designers can find out how to use the OpenAPI (NoMagicDeveloperGuide 2022).
4. No Magic also provides detailed Javadoc, with detailed description of classes, their attributes and operations. JavaDoc is located in >modeling tool installation directory>\openapi\docs (NoMagicJavaDocs 2022).
5. Plugins are the only one way to change the functionality of a No Magic modeling tool. A plugin must contain the following resources: (a) A directory; (b) Compiled java files, packaged into a jar file; (c) A plugin descriptor file; and (d) Optional files used by the plugin(NoMagicDeveloperGuide 2022).
6. On every startup, a modeling tool scans the plugins directory, and searches for subdirectories there (NoMagicDeveloperGuide 2022):
If a subdirectory contains the plugin descriptor file, the plugin's manager reads the descriptor file.
If requirements specified in a descriptor file are fulfilled, the plugin's manager loads a specified class (the specified plugin class must be derived from the com.nomagic. magicdraw. plugins. Plugin class). Then a method init( ) of the loaded class is called. The init( ) method can add GUI components using actions architecture or do other activities and return from the method. The init( ) method is called only if isSupported( ) returns true.
FIG. 62 depicts the function of the plugin.
7. The writing of a Java plugin for MagicDraw or a Cameo Suite product involves the following, primary steps (NoMagicDeveloperGuide 2022):
(a) Create your plugin folder in a plugins folder. Create a myplugin folder in the plugins folder in the installation directory of the modeling tool.
(b) Write the plugin code.
The plugin must contain at least one class derived from the com.nomagic. magicdraw. plugins.Plugin class.
(c) Compile the plugin and pack into a .jar file.
To create a .jar file, use a jar command in the plugins directory:
   jar-cf myplugin\myplugin.jar myplugin*.class
(d) Write the plugin descriptor.
The plugin descriptor is a file named plugin.xml. This file should be placed in the myplugin folder.
8. Using the Java Native Interface (JNI), we may initially create a Java wrapper around our existing C++code.

### 3. Summary Review of Plugin Support Provided by Particular SysML Tools

Table 42 presents an overview over the plugin support provided by popular SysML modeling tools. It appears most of the SysML tools provide support for a java (jar) plugin. We understand that MagicDraw has been the SysML tool primarily used at NASA JPL for the past several years, even though there is no institutional standard enforced. In (Karban 2016), the authors use the Cameo Simulation Toolkit extension to perform the analysis needed for certain requirements listed in the paper.

3. Towards SysML v.2 — Addressing Portability through Standardization of the Tool API

### 1. The SysML-1.x Standard Does Not Specify a Tool API

Portability is a major concern, and needs to be accounted for:
If you build a plugin for Papyrus, it may only work in Papyrus.
If you build a plugin for MagicDraw, it may work only in MagicDraw (and even only for the version you developed it against, since the Magicdraw API tends to change between versions).

### 2. SysML-2.x Will Have an API as a Part of the Standard

But it exists only as requirements at this point (OmgSystemsModeling 2022):

“The SysML® v2 RFP was issued on December 8, 2017. This culminated an 18-month effort to develop the requirements for the next-generation systems modeling language, which is intended to improve the precision, expressiveness, and usability over SysML vl. The requirements reflect lessons-learned from applying model-based systems engineering with SysML since its adoption more than 10 years ago.”
We foresee the the plugin for the automatic requirement verification such that it complies with the SysML v2 standard.
Alternatively, as a back-up, in case a decision on the v.2 standard is postponed, the plugin can be tailored towards MagicDraw. MagicDraw seems to be the SysML tool most widely used at NASA. Further, No Magic seems to offer a very good SysML Plugin Developer Guide (NoMagicDeveloperGuide 2022). Moreover, the sample open-source SysML plugins, per (1) and (2) above, have been developed for MagicDraw.
As a 2^{nd} back-up, in case the MagicDraw API is found not to offer adequate stability (in case No Magic is found to change the way they implemented certain parts of the standard), we might end up working off the source code provided by the open-source tools (Modelio and Papyrus).

### 4. Extending the Standarized APIs of SysML—2.x to the Subsystem

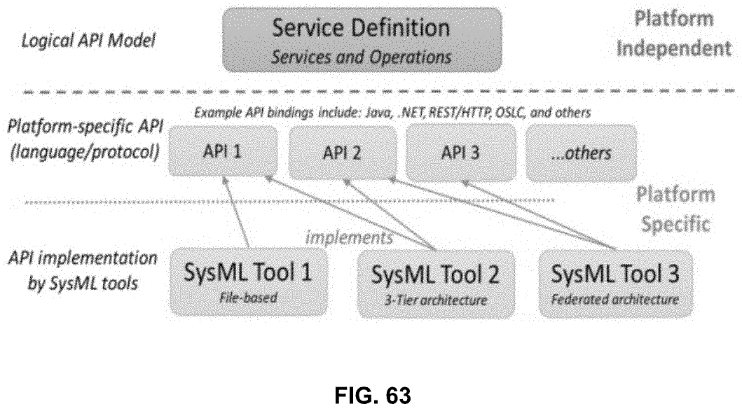

To enable disparate subsystems built in different locations by different owners to all work cohesively work together, we propose extending the standardized APIs of SysML-2.x to the subsystems. FIG. 63 shows how standard APIs and services provide mechanism for interoperability.

### 5. Requirement Verification in Terms of “Point Estimators” (or Standardized “History” in API)

In order to separately verify requirements of subsystems built by different vendors, on a multi-disciplinary design project, one needs to
1. Construct the verification algorithms in the form of “point estimators”.
2. Incorporate data structures capturing “history” in the standardized APIs.

Here one can leverage mechanism for verification of requirements, both at the system and the sub-system level, illustrated in FIG. 5, FIG. 8-FIG. 14 and FIG. 17-FIG. 18.

TABLE 42
Specifics related to the plugin support provided by a few, common SysML tools.

| SysML Tool | Open Source? | Phase | Specifics on Plugin Support |
|---|---|---|---|
| IBM Rational Rhapsody | No | II | Java applications that can respond to any of the |
| | (commercial) | | events defined in the Rhapsody Callback API |
| | | | (IbmKnowledgeCenter 2022) |
| Cameo Systems | | | Similar as for MagicDraw (same vendor). |
| Modeler | | | |
| Enterprise Architect | | | Provides addins for Model Driven Generation |
| | | | (ModelingDesignSparx 2022) |
| MagicDraw [21] | | | MagicDraw already provides a SysML plugin, |
| | | | which can be downloaded for evaluation from |
| | | | (NoMagicSysMlPlugin 2022) |
| Visual Paradigm | | | Provides support for plugins written in Java |
| | | | (VisualParadigmPlugin 2022) |
| Papyrus | Yes | I | All plug-ins must compile and run with Java 1.7 |
| | | | (Execution Environment = JavaSE-1.7) |
| | | | (EclipsePapyrusStandards 2022) |
| Modelio | | | Refer to |
| | | | https://forge.modelio.org/projects/modelio/wiki |

### 9.4. Smart Modeling & Simulation: “Plug-and-Play” for Modeling Engineering Structures

### 1. User Interface

The SMS system can provide a user-friendly interface for visualization and navigation in CAD and analysis systems. In addition to the inter-operability requirements above, the SMS system can provide means for
1. Geometry editing & importing
2. Applying loads
3. Defining other constraints
4. Creating FE models (meshes)
5. Defining material properties
6. Multi-physics analysis

The user interface resembles that of open-source CAD programs, such as FreeCAD (FreeCAD 2015), or 3D visualization programs, such as ParaView (ParaView 2015), but provides key functionality in terms of “plug-and-play” of pre-defined library modules.

### 1. Geometry Editing & Importing

The geometry editing may resemble that of FIG. 49. Our solution mimics similar solutions provided by the major CAD vendors (DassaultSystemes 2017).

### 2. Applying Loads

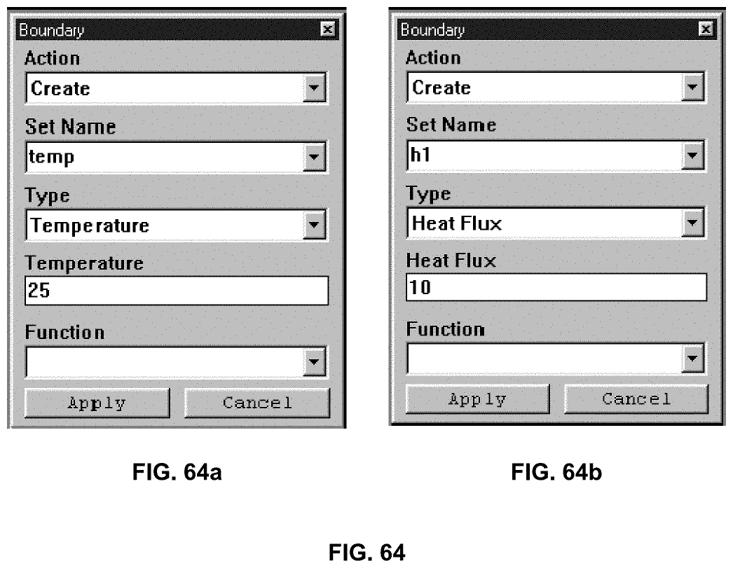

FIG. 64a and FIG. 64b capture our solution for applying the loads. FIG. 64a and FIG. 64b shows an example from a static thermal problem where the mechanical response of a 100 mm×200 mm rectangular bar subjected to thermal loading is solved. Here one edge is fixed at the temperature of 25° C., but thermal flow of 10 W/mm² applied to the opposite edge.

The auto-configuration aspects of the user interface are outlined in the section titled “Auto-Configuration: Towards 1-Button Meshing”. Suffice to say that the menu will feature ASTM, ASME, ASC, IEEE and JDEC standards as line item options. The user will be able to select these standards as options, and have the key properties (dimensions) of the ready-made components, as well as the loading, set accordingly.

### 3. Defining Other Constraints

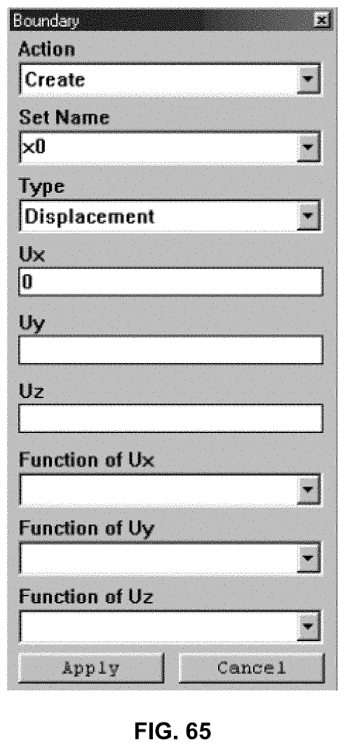

The loads specified in FIG. 64a and FIG. 64b comprise only a subset of the boundary conditions supported. FIG. 65 captures another such conditions. In FIG. 59, we are presenting mechanical boundary condition of x=0 for a y symmetrical interface of a cylinder subjected to thermal loading. The inner radius is 10 mm with a temperature of 25° C., and the outer radius is 20 mm with a temperature of 100° C. This is a static thermal problem where the mechanical response of a quarter of the cylinder is studied.

### 4. Creating FE Models (Meshes)

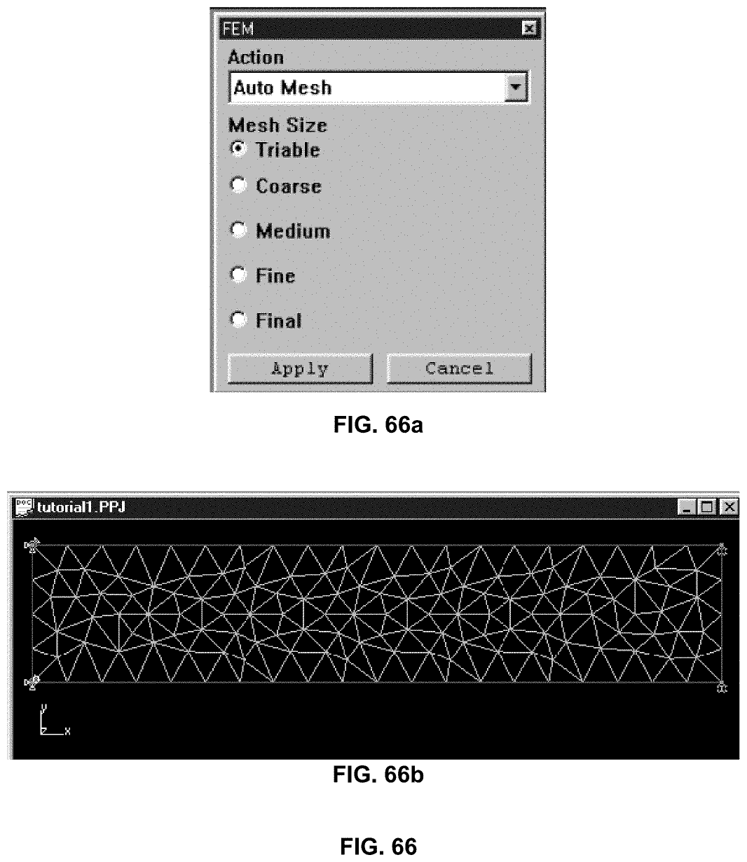

The Smart Modeling and Simulation system also provides means for generating FE models (meshes), from the geometric model provided, and feeding into the analysis tool (solver) of choice. It even supports auto-mesh generation. FIG. 66a presents the FE modeling interface from the Smart Modeling and Simulation system. FIG. 66b shows an auto-generated mesh corresponding to fine mesh size being selected in FIG. 66a. In the Section titled “Auto-Configuration: Towards 1-Button Meshing”, we will be further addressing the auto-configuration capabilities of the Smart Modeling and Simulation system.

### 5. Defining Material Properties

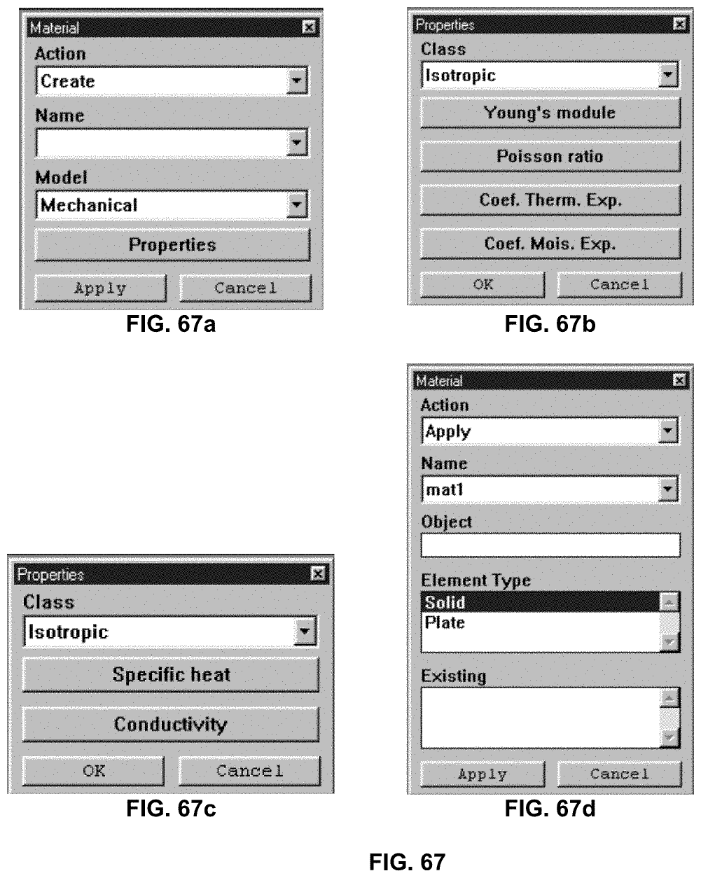

The user interface of the SMS system also supports specification of material properties. FIG. 67a — FIG. 67d provide insight into how the material properties are specified. One can integrate links to material databases as line item options into the material selection steps. One can also pre-populate some options with items from the material databases. The Section titled “Material Models” provides coverage of the advanced material models that the SMS system supports.

### 6. Multi-Physics Analysis

Section titled “Advanced Analysis” addresses our approach for accounting for complex multi-physics through numerical solution of the underlying mathematical equations. From programming standpoint, this is a matter of
Presenting to the user a list of options to choose from outlining the complex analyses of possible interest,
Predefining the sequence in which the corresponding analysis tools will be called, in case the user selects a given option from the list,
Ensure that data will be transferred seamlessly between analysis tools, as needed for proper execution of the numerical solutions.

### 2. Auto-Configuration: Towards 1-Button Meshing

Most of the analyses in the SMS system is automatic, including the automatic mesh generation. Although automatic generation of high-quality meshes is far from trivial, and designers frequently apply semi-automated heuristic procedures, that rely on human expertise and manual processing, we are here mainly focusing on the big picture, in particular on how to incorporate our vision of 1-button meshing into the user interface from the Section titled “User Interface”.

1. Recommended Route for Incorporating 1-Button Meshing: 3D interface

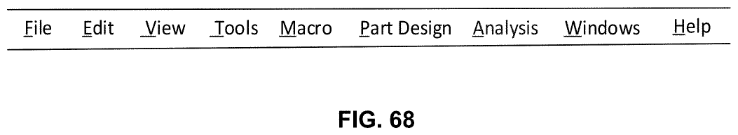

At a high level, the Smart Modeling and Simulation system incorporates into the user interface of a fortified 3D CAD tool, simply by lumping the primary functions (aside from the ready-made geometries and plug-and-play) into an Analysis section of the main menu, such as shown in FIG. 68. Within the 3D CAD-like tool, the Analysis section, along with the auto-configuration facilities, is here shown as fairly compartmentalized, but it also can blend more in with the rest of the system.

With regards to the user interface, the 1-button mesh solution is shown in FIG. 69. The user can receive visual verification of the estimated mesh quality, but scripts (input files) associated with individual analysis tools reside beneath the hood.

2. Alternative Route: 2D Interface with LabView-like Linking of Modules

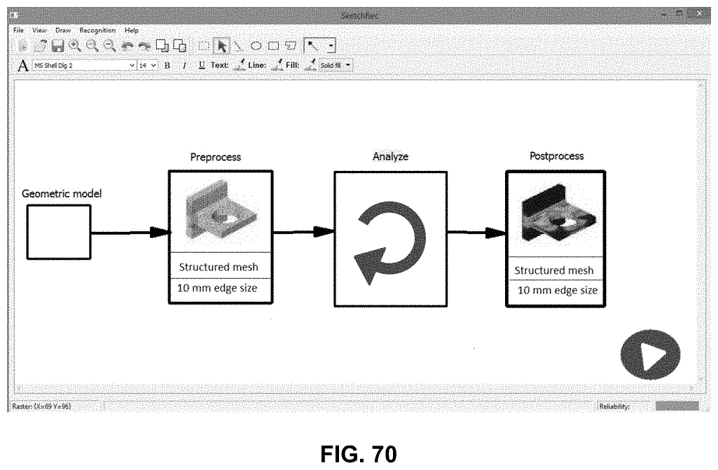

An alternative route involves a 2D block-based solution, such as the one shown in FIG. 70, with linking capabilities resembling that of LabView from National Instruments.

### 3. Material Models

The front-end has to generate an input file for ABAQUS, ANSYS and ComSol, and the material properties need to be included in the input file. In this way, the front-end can work with various analysis tools. Material properties comprise one of the items needed to be able to generate the input file.

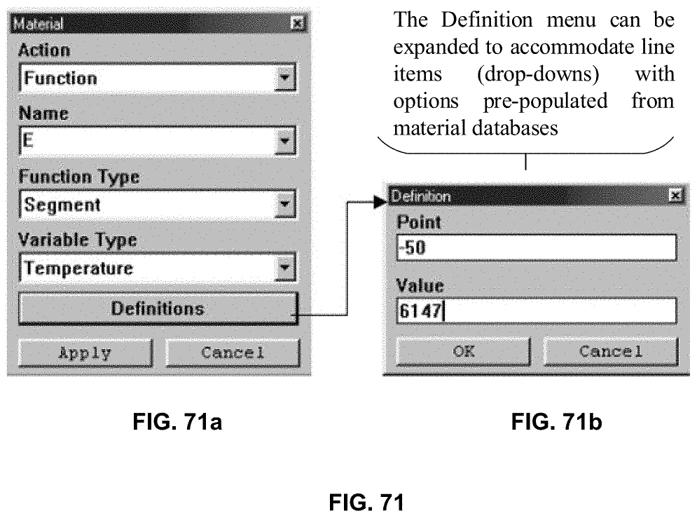

As noted above, our plan is to integrate links to material databases as line item options into the material selection steps. FIG. 71 explains how the Definition menu of the Smart Modeling and Simulation system can accommodate line items (drop-downs) with options pre-populated from the material databases.

The material models supported by the SMS system include

### 1. Visco-Plasticity

This is a category of models, some of which analysis SW, such as ABAQUS, do provide.
The user is able to create a visco-plasticity model in the SMS system and import into analysis software, such as ABAQUS.

### 2. Piezo-Electricity

### 3. Acoustic-Structures

Similarly, these are categories of models, some of which analysis software, such as ABAQUS, does provide.
The user is able to create models of this type in the SMS system, and import into analysis software, such as ABAQUS or ANSYS.
   4. Elasticity with Temperature-Moisture-Degree of Cure Dependent Properties
It is our understanding that analysis software, such as ABAQUS, does not offer material
models of this type.
If engineers employed by FEA vendors, such as ABAQUS, were able to derive mathematical equations describing the complex underlying multi-physics couplings, there is little doubt they would be able to develop material models capturing numerical solutions to these equations.

### 5. Hygro-Thermo-Visco-Elasticity

Again, it is our understanding that analysis software, such as ABAQUS, does not offer material models accounting for complex multi-physics interactions of this type.

### 6. Chemo-Hygro-Thermo-Piezoelectricity

### 7. Chemo-Thermo-Piezo-Viscoelasticity

These models are governed by complex mathematical equations which analysis software like ABAQUS, to our understanding, is not able to formulate and solve (probably since the equations are difficult to derive).
   4. Advanced Analysis: Accounting for Complex Multi-Physics through Proper Mathematical Models and Sequencing

The SMS system can provide unique multi-physics, such as chemo-hygro-thermo-piezoelectric analyses, which other simulation software has not been able to provide. The analysis software supported, and the sequence in which they are called, depends largely on the physical problem at hand. The general approach consists of the following:
1. We start out by looking at the physical problems at hand, and determine the underlying mathematical equations.
1. For the fields of interest, we next look at the analysis SW available.
Table 43 lists primary analysis tools for some key areas of interest.
2. Based on the equations describing the physical phenomena, we formulate numerical solutions.
For the numerical solution, we employ generic data structures that capture the underlying relationships and store our “master solution”.
3. As we implement the numerical solutions to the mathematical equations, the computation is carried out in certain “master order”.

TABLE 43
Primary analysis tools for some key fields of interest.

| Field of Analysis | Software (Company) |
|---|---|
| Heat Transfer Analysis | ABAQUS |
| | ANSYS |
| | ADINA |
| Fluid flow | Autodesk |
| Electromagnetics Analysis | Altair Hyperworks |
| | ANSYS |
| | COMSOL |
| Chemical Process Analysis | EPANET |
| Moisture Diffusion Analysis | EPANET |

This “master order” determines which part of the computation the SMS system can handle, which portions can be offloaded, to which analysis tool the computation should be offloaded, and in which order.

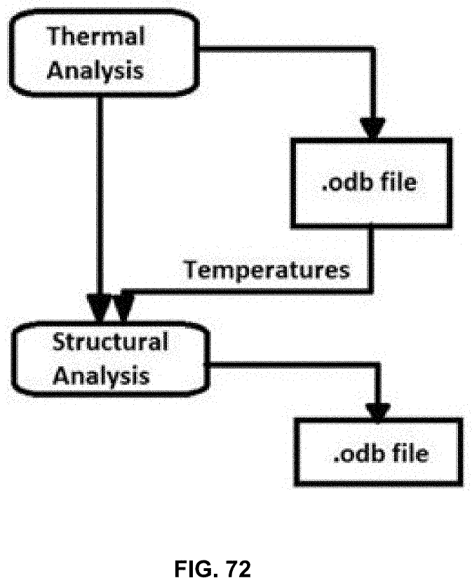

FIG. 72 presents an illustration of sequential thermal-stress analysis. Here, .odb refers to ABAQUS binary output database files. The generic nature of the approach makes the SMS system suitable for application in multiple areas, including mechanics, aerodynamics, thermal, electro-magnetics, fracture, aero-elastic, noise, vibration and transport phenomena.

### 9.5. Digital Assistants for Science and Engineering

Semantic similarity is a metric defined over a set of documents or terms, where the concept of a distance between items is based on the similarity (or likeness) of their meaning, i.e., semantic content, as opposed to lexicographical similarity. Through a numerical description obtained according to the comparison of information supporting their meaning or describing their nature, mathematical tools can be utilized to estimate the strength of semantic relationships between the units of language, concepts or instances. The concept of semantic similarity is sometimes confused with the term semantic relatedness. Semantic relatedness refers to any relation between two terms, whereas semantic similarity only captures “is a” relations. For instance, a “car” is similar to a “bus”, but is also related to “road” and “driving” (SemanticSimilarity 2022).

Cosine similarity is a measure of similarity between two sequences of numbers. For defining the cosine similarity, the sequences are viewed as vectors in an inner product space. The cosine similarity is defined as the cosine of the angle between them, i.e., the dot product of the vectors divided by their lengths (CosineSimilarity 2022).

Word2Vec represents a group of group of related models that have been used to produce word embeddings. These models consist of shallow, two-layer neural networks that can be trained to reconstruct linguistic contexts of words. Word2Vec accepts as input a large corpus of text and generates a vector space, with typical dimension of the order of several hundreds, with each unique word in the corpus being assigned to a corresponding vector in the space. Word vectors are located in the vector space such that words that share common contexts in the corpus are positioned close to one another in the space (Word2Vec 2022).

Word embedding refers to a terms used in natural language processing for representation of words for text analysis, typically in the form of a real-valued vector that encodes the meaning of the word such that the words that are closer in the vector space are expected to be similar in meaning (WordEmbedding 2022).

The results from training the neural networks accessible through Word2Vec can be sensitive the values of the configuration parameters selected (Word2Vec 2022). First, in regards to the training algorithm selected, a Word2Vec model can be trained with hierarchical softmax and/or negative sampling. The hierarchical softmax method utilizes a Huffman tree to reduce the calculations needed to approximate the conditional log-likelihood that the training algorithm seeks to maximize. The negative sampling method, on the other hand, seeks to minimize the log-likelihood of sampled negative instances. Second, in regards to the sub-sampling selected, words with frequency above a certain threshold can be subsampled, to speed up training, since high-frequency words tend to provide limited new information. Third, in regards to the dimensionality selected, the quality of word embedding increases with increased dimensionality. However, after reaching certain threshold, the marginal gain tends to diminish. The dimensionality of the vectors is typically set at 100-1,000. Fourth, in regards to the context window selected, the size of the context window determines how many words before and after a given word are included as context words to that specific word (World2Vec 2022).

### 9.6. Providing Nonlinear Analysis of Civil Structures

### 1. Set-Up, Configuration of Inputs, and Definition of Corresponding Output Responses

This section presents observations related to the acceleration, story shear, and drift responses for a given building. The section covers linear dynamic analyses of three-dimensional elastic building with rigid floors. The section covers the user inputs, how to populate floor and story data, and lastly how to view the responses of a sample building produced by a 30 sec earthquake.

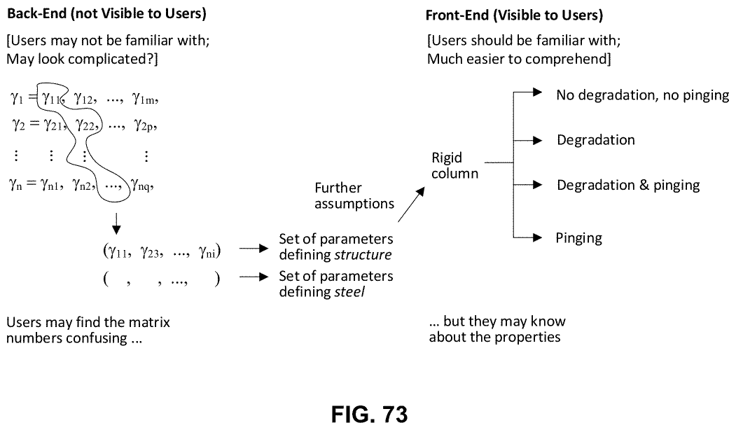

FIG. 73 captures the essence of a user friendly interface for nonlinear analysis of civil engineering structures. The user interface has been designed such as to provide civil designers familiar with linear structural analysis, such as provided by SAP 2000, with intuitive inroad into nonlinear structural analysis. The civil designers can choose some instances of the parameters for the rigid column of interest. The user interface simplifies the parameter selection process. It relies on minimal set of assumptions, for speed (efficiency) sake, and yet provides access to nonlinear analysis capabilities.

### 1. Sample Building

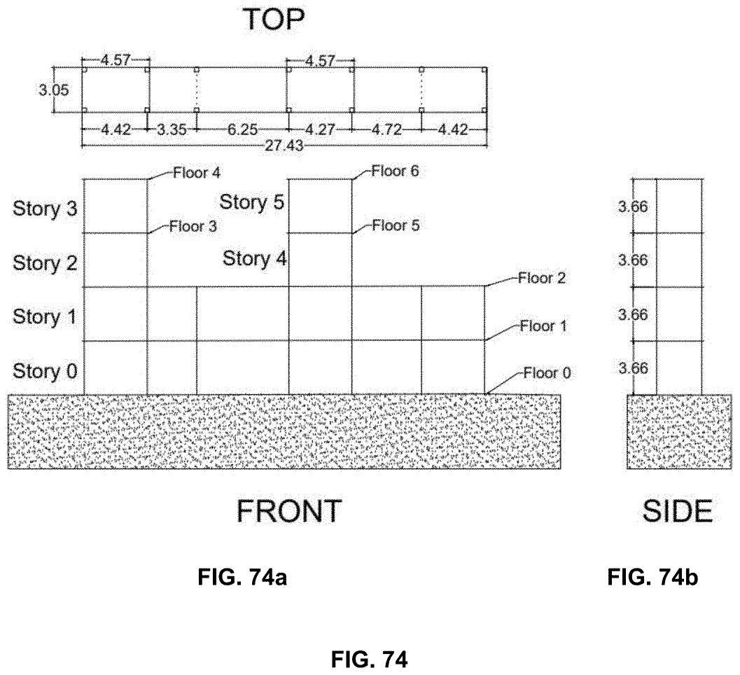

The building structure assumed, shown in FIG. 74, consists of 5 stories and 6 floors.

### 2. User Inputs

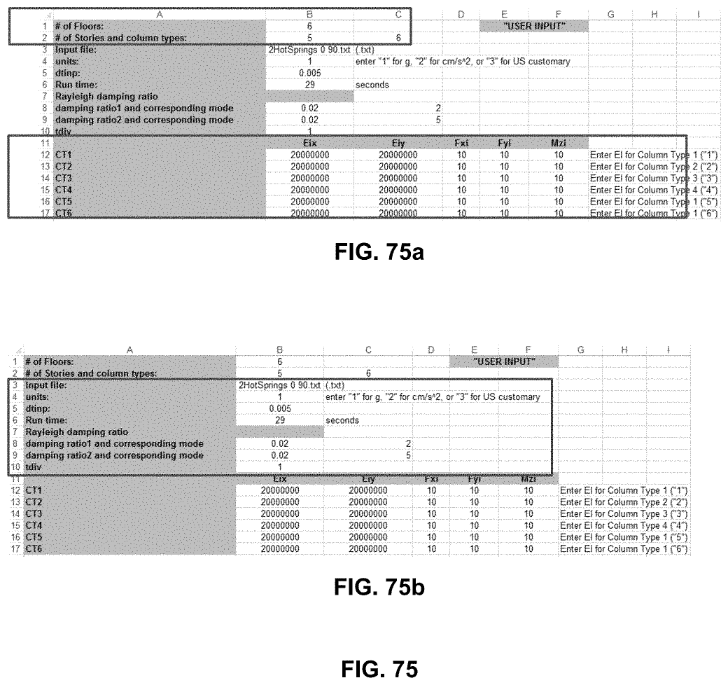

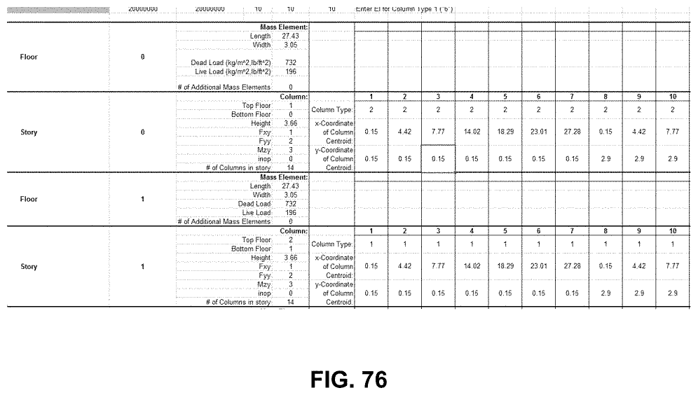

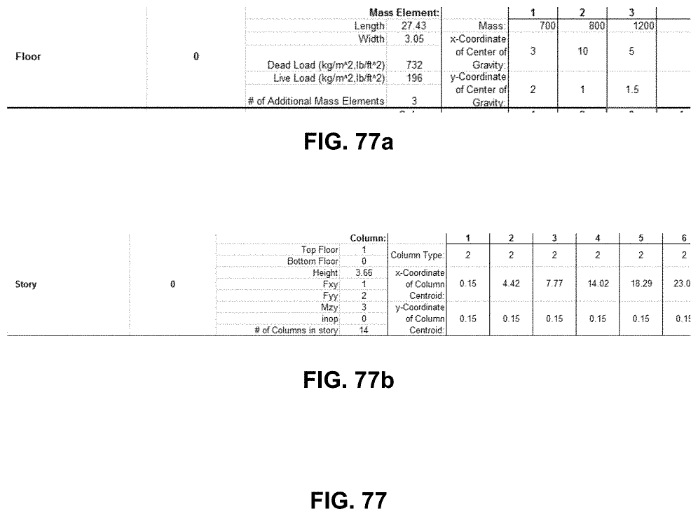

The user defined inputs are specified through the Excel spread sheet file, “Bookl.xlsx”. FIG. 75, FIG. 76 and FIG. 77 capture the content of the Excel spread sheet file. Theses inputs are partitioned into building inputs and acceleration analysis inputs.

### 3. Building Inputs

The inputs for the building will start with the number of floors in the building, this value will be placed in cell B1 as shown in FIG. 75a. The next input is the number of stories in the building and number of column types which will be placed in cells B2 and C2, respectively. The last information entered is the characteristics of the column types. In this example there are six column types used as shown in cell C2 in FIG. 75a. Each column type is defined and the user will input the Eᵢₓ, E_{iy}, Fₓᵢ, F_{yi}, and M_{zi} for each column type as shown in FIG. 75a.

### 4. Acceleration Analysis Inputs

The inputs for the acceleration analysis will start with the specification of the earthquake acceleration file used, in this example an acceleration file, “2HotSprings 0 90.txt”, is used. It is important to include the extension onto the file name in cell B3 as shown in FIG. 75b. The next input is the units used in the acceleration file insert “1” for “g”, “2” for “cm/s²”, or “3” for “US Customary” in cell B4 as shown in FIG. 75b, in this example the units used in the acceleration file “2HotSprings 0 90.txt” were in units of “g” therefore a “1” was placed in cell B4. The next inputs are specific to the analysis process, these inputs are dtinp, run time, Rayleigh damping ratio and their corresponding mode, and last is the tdiv. These values are placed in cells B5 to B10 as shown in FIG. 75b.

### 5. Populating Floor and Story Data

Once the Building and Acceleration Analysis inputs are set, the excel spreadsheet will for a drop down input form for the floor and story data for each floor and story in the building as shown in FIG. 76. Each floor and story has specific data which the user needs input in given cell next to the prompt. The following subsections will go over just what data is needs to be entered for the floors and the stories.

### 6. Populating Floor Data

The floor data needed for each floor of the building is the length and width of the floor as shown in FIG. 77a. The next data to enter is the dead and live load associated with the floor, this value needs to be in force per unit area format (i.e. kg/m²). Lastly is the number of additional mass elements on the floor, if there are no additional mass elements on the floor enter “0”. When a number other than 0 is entered in the cell, in this example 3 is entered, this will open an input form which will require the user to input the mass of the mass element, as well as the x and y coordinate of the point mass as shown in FIG. 77a.

### 7. Populating Story Data

The story data needed for each story of the building is the top and bottom floor of the story, the height of the story, the F_{xy},F_{yy}, and M_{zy} as shown in FIG. 77b. The input prompt also allows the user to either choose linear (enter 0) or nonlinear (enter 1) methods to observe the acceleration responses for each story. The last input is the number of columns in the story, in this example floor 0 has 14 columns. When a number other than 0 is inserted in this cell, an input form will appear where the user needs to input the column type, in this example there were 6 column types, and for story 0 the columns used were column type 2. Also, the user needs to input the x and y coordinate of the centroid of each column in the story as shown in FIG. 77b.

### 8. Viewing Acceleration, Story Shear and Drift Responses

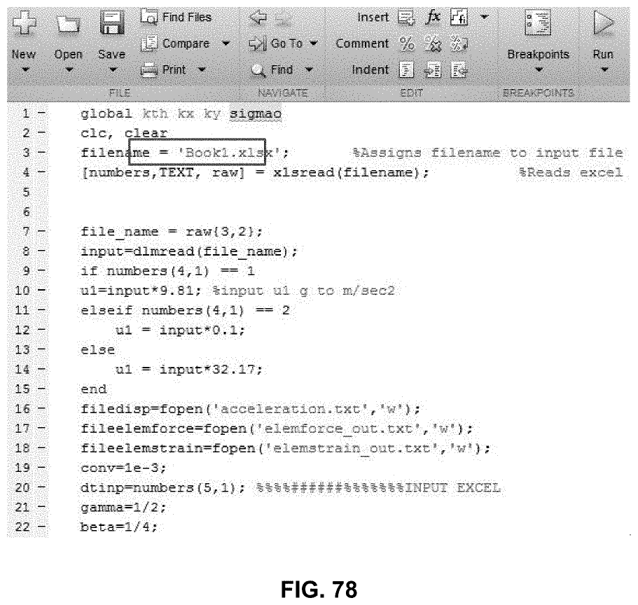

After inputting all data into the spreadsheet, the spreadsheet (Bookl.xlsx) should be saved in a file location with the matlab file (NEW_TRIAL.m) and the earthquake acceleration data (2HotSprings 0 90.txt), this will allow matlab to access these files when prompted in the matlab code. Next, open the matlab file (NEW_TRIAL.m) and it will look like FIG. 78. The only thing to be changed in this code is the excel file. After the Excel file name and extension are verified and the files (Bookl.xlsx, NEW_TRIAL.m, and 2HotSprings 0 90.txt) are in the same directory, the code can be executed by pressing the “Run” button at the top right corner as shown in FIG. 78. The code will run in the command window and when it finishes it form three output text files which will be located in the file directory. These files are labeled acceleration.txt, elemforce_out.txt, and elemstrain out.txt which are the acceleration, story shear, and drift responses respectively.

2. Results from Base Simulation and Base Isolation Simulation

Here, we set all column stiffness (kₓ and k_{y}) in the building to a constant stiffness, excluding the bottommost (0) story. For Case 1, the bottommost (0) story column stiffness will have a large stiffness value. This will be the fixed based simulation, which represents infinite stiffness. For Case 2, the column stiffness of the bottommost (0) story the column stiffness will be varied at small stiffness values, these will be the base-isolated simulation, representing low stiffness. The overall objective of this section is to understand the benefit of isolation.

### 1. Setup of Base Simulation—Case 1

As previously stated, the column stiffness of all columns (excluding story 0) is set to a constant k_{y} and kₓ value which is 2×10⁷N. In Case 1 the column stiffness values of Story 0 is set to 2×10¹⁰⁰ N.

### 2. Results of Base Simulation—Case 1

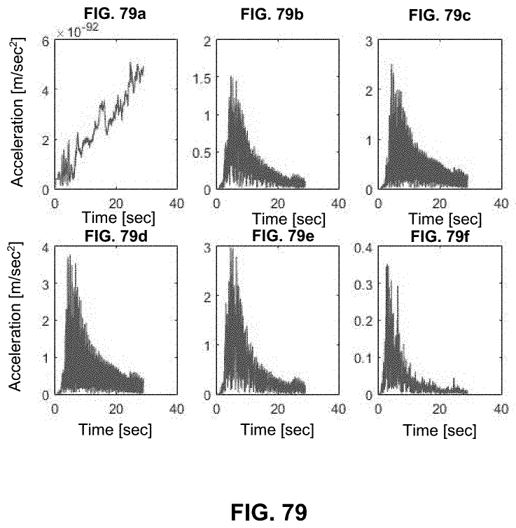

The base case can be thought of as a fixed base which means Story 0 has infinite stiffness. As presented in Table 44 and FIG. 79 Story 0 has a maximum acceleration response of 0 which is expected because of its extremely high stiffness value of 2×10¹⁰⁰ N of its columns. Stories 1-5 also experience maximum acceleration responses ranging from 1.5171 to 3.7699 m/s² as presented in Table 45, this is not ideal. To address this concern base isolation should be considered and is addressed in the following subsection.

### 3. Setup of Base-Isolated Simulation—Case 2

As previously stated, the column stiffness of all columns (excluding story 0) is set to the constant kₓ and k_{y} values of 2×10⁷N. In Case 2 the column stiffness values of Story 0 is varied by magnitude as follows: 2×10¹ N, 2×10² N, 2×10³ N, 2×10⁴ N, and 2×10⁵ N. The response of each floor will be observed for each stiffness value.

TABLE 44
Maximum acceleration response for each story for base simulation.

| Story | Maximum Acceleration (m/s²) |
|---|---|
| 0 | 0 |
| 1 | 1.5171 |
| 2 | 2.5209 |
| 3 | 3.7699 |
| 4 | 2.9807 |
| 5 | 2.9807 |

TABLE 45
Maximum acceleration response for each story for Base-Isolated Simulation with
Story 0 kₓ and k_{y} = 2 × 10¹ N, 2 × 10² N, 2 × 10³ N, 2 × 10⁴ N, and 2 × 10⁵ N.

| | Maximum Acceleration Response for Variable stiffness value (m/s²) | | | | |
|---|---|---|---|---|---|
| Story | Stiff. = 20 N | Stiff. = 200 N | Stiff. = 2,000 N | Stiff. = 20,000 N | Stiff. = 200,000 N |
| 0 | 0.3530 | 0.3530 | 0.3531 | 0.3539 | 0.3771 |
| 1 | 0.3530 | 0.3530 | 0.3531 | 0.3541 | 0.3793 |
| 2 | 0.3530 | 0.3530 | 0.3531 | 0.3534 | 0.3736 |
| 3 | 0.3530 | 0.3530 | 0.3531 | 0.3534 | 0.3729 |
| 4 | 0.3530 | 0.3530 | 0.3530 | 0.3531 | 0.3722 |
| 5 | 0.3530 | 0.3530 | 0.3530 | 0.3531 | 0.3722 |

4. Results of Base-Isolated Simulation (Story 0 kₓ and k_{y}=2×10¹ N)—Case 2

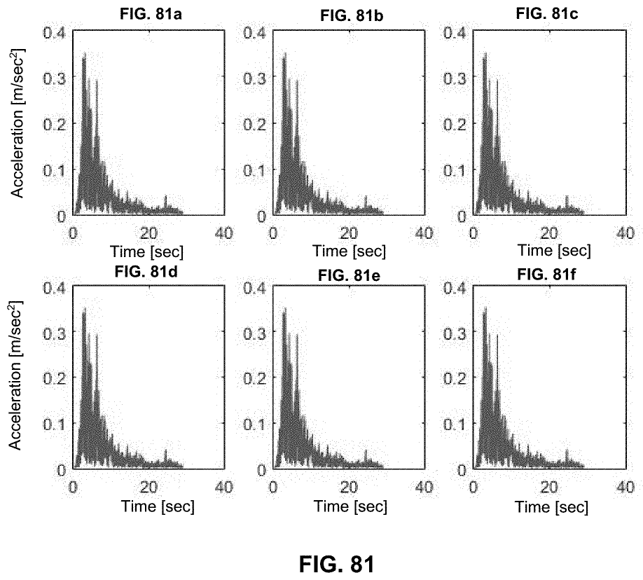

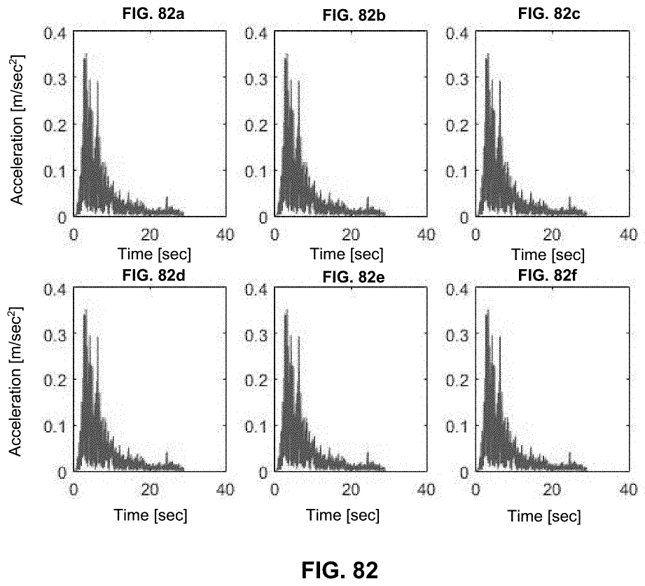

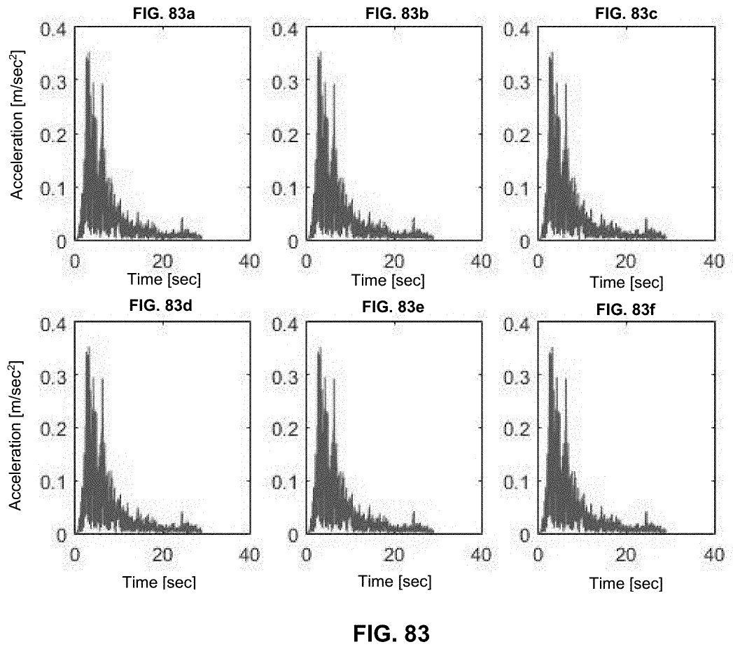

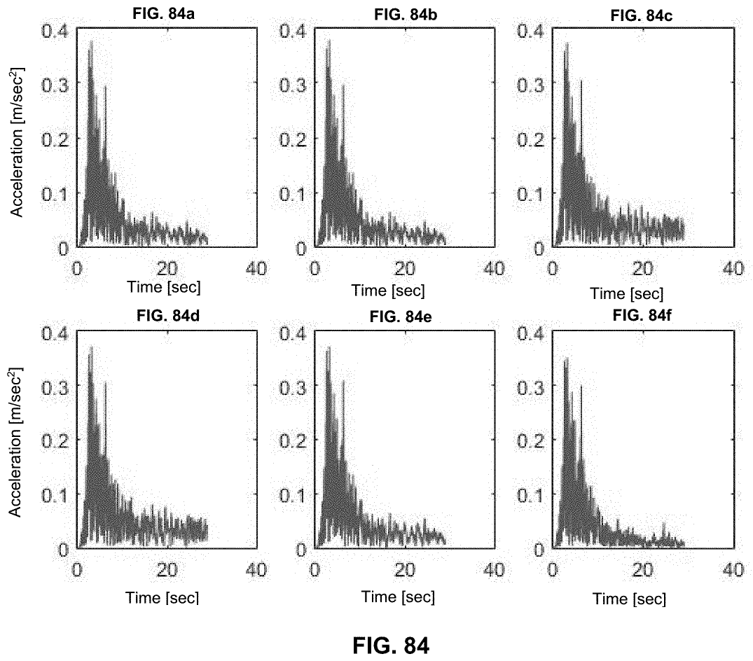

The base-isolated simulation can be thought of as the base having a very low stiffness which means Story 0 is the isolated base which should minimize the acceleration response in all stories. As presented in Table 44 (column 2), Story 0 has a maximum acceleration response of 0.3530 m/s², this indicates by using a small stiffness value of 2×10¹ N for the columns of Story 0 resulted in a smaller acceleration response as opposed to the base case. Stories 1-5 also experience maximum acceleration responses of 0.3530 m/s² as presented in Table 44. This indicates that by isolating Story 0 the acceleration responses of the upper stories will be smaller than in the base case which had a relatively infinite story stiffness. Also presented in Table 45 and FIG. 80-FIG. 84 are the maximum acceleration responses for Stories 1 — 5 for a given Story 0 stiffness value which was varied by magnitude. The results indicates that the acceleration response in the stories depends on the stiffness value of Story 0′s columns. As the Story 0 column stiffness is increased the acceleration responses in the upper stories also increases which shows the benefit of base isolation.

### 10. How to Use the Invention

### 1. For Automatic Verification of Engineering Requirements

The invention outlines a generalized framework for automatic design assessment and smart analysis, a concept that applies across different fields of engineering design. As explained in (SteingrimssonKulkarni 2020), the invention can be used to verify requirements for design projects large or small, such as
1. New student design projects with a relatively small team (e.g., capstone);
2. Ongoing student design projects with a large or small team (e.g., Formula or BAJA SAE);
3. Industry project at a small or medium-sized design organization; or
4. Projects at large design organizations (e.g., where the e-Design Assessment Engine is integrated into an enterprise system for requirement management).

### 2. For Teaching Engineering Students Proper Design Techniques

The Ecosystem design software is targeted, in part, towards educational institutions that teach courses on engineering design. The Ecosystem design software allows the instructors (or mentors) to assess students' performance with less subjectivity, and on a continual basis. The Ecosystem design software also provides students with means to stimulate their creativity during the design process, by enabling quick explorations of variations of key design ideas (note vector objects can be moved around, no need to redraw).

### 3. For Training Entry-Level Engineers on the Internal Design Processes of Given Organizations

Similarly, the Ecosystem design software is also flexible enough to teach entry-level designers effective design techniques, leading to productivity enhancements that would result in increased competiveness, higher quality, and shorter time-to-market.

### 4. For Helping Experienced Engineers Avoid Design Oversights (Through Improved Design Making)

The Ecosystem design software can help all practicing engineers stay on track throughout the design project, ensure efficient compliance with the design processes and minimize the chance of unproductive activities or oversights.

Similar benefits can be achieved by using the engine for automatic design assessment and smart analysis, not as a part of an integrated design Ecosystem, but integrated into existing platforms for requirement management, product development management, produce life cycle management or collaborative produce development.

### 5. For Helping Designers or Supervisors Track Progress, Save Cost and Achieve Timely Completion

The supervisor layer allows managers to viewing logs related to design activities and progress (archived alerts). The Ecosystem design software can help supervisors in terms of producing seamless and expeditious reports and responses related to design activities. It can also help in terms of tracking resource expenditures and projecting completion dates.

6. For reducing timeSspent on for Mechanical CAD Data Preparation (For Minimizing Human Intervention), and for Improved Performance Through “Plug-and-Play”

The design Ecosystem can facilitate usage of new and legacy engineering simulation tools on complex geometric models with minimal human intervention or preprocessing. Traditionally, mechanical CAD data preparation has dominated many CAE activities, hindering use of advanced engineering simulation tools, and resulted in excessive cost across a broad range of design and manufacturing activities. The types of engineering simulation tools involved include, but are not limited to, analysis of mechanics, aerodynamics, thermodynamics, electromagnetics, fracture, aero-elasticity, noise, vibrations and transport phenomena.

7. For harvesting Information from Design Repositories for Improved Design Decision Fidelity, Through Application of Big Data Analytics

The big data analysis facilities can be used to harvest from existing design repositories. The design Ecosystem can help designers immediately find designs of interest. But in addition, the cross-correlations provided through the big data analytics enables designers to gleam as much information as possible from prior designs and feed into future designs. This may benefit large multi-national organizations which may have different design teams working on similar proj ects.

### 8. For Rapid Identification of Relevant Design Material, Through Application of Big Data Analytics, Say, For Post-Mortem Failure Analysis

There is significant interest in big data analytics, especially within automotive industry. Lots of data is being collected from fleets of vehicles. The data is being uploaded to cloud systems, where it is analyzed using big data and machine learning algorithms. Then, information of interest can be communicated back to the drivers, or used internally, say, for post-mortem failure analysis.

### 9. As Interface (Add-On or Plugin) to CAD Packages

The Engine for Automatic Design Assessment and Smart Analysis, or other parts of the design Ecosystem, can be integrated into CAD tools, such as AutoCAD, CATIA, PTC Creo, Unigraphics NX or SolidWorks, for example as a plug-in, and hence can benefit engineers involved in detailed design.

### 10. As Interface (Add-On or Plugin) to Tools for Design Validation

The design Ecosystem supports interfaces with tools for design validation, e.g., with the FEA tools used to validate the stress analysis.

### 11. As Interface (Add-On or Plugin) to Tools for Requirement Management

The Engine for Automatic Design Assessment and Smart Analysis can be integrated as an add-in, through a web API, into existing systems for requirements management, such as IBM Rational DOOR, IBM Rational Team Concert or Cockpit. In this way, the Engine for Automatic Design Assessment and Smart Analysis can furnish these systems with capabilities for automatic verification of design requirements.

### 12. As Interface (Add-On or Plugin) to the Tools for Product Lifecycle Management, Produce Data Management or Collaborative Product Development

Similarly, the Engine for Automatic Design Assessment and Smart Analysis can be integrated into the Product Lifecycle Management, Data Product Management or other tools for Collaborative Product Development (existing ecosystems) through the APIs provided. These tools include, but are not limited to, the Siemens Team Center, SolidWorks PDM, CATIA Enovia PLM, PTC Windchill, Autodesk Fusion 360 PLM, and the Arena Solutions PLM.

### 13. For Shortening the Time it Takes Engineering Departments to Prepare Data for ABET Reporting

The ABET scoring sheets, shown in FIG. 79, constitute objective data that can be collected and included in the package reported by engineering departments to ABET for accreditation.

### 14. For Improving the Productivity of Instructors of Engineering Design Classes

The facilities for ABET reporting, scoring against instructor grading rubric, and team formation, can help improve the productivity of instructors of engineering design classes.

### 15. For Accelerating, Reducing Overhead Labors, and Improving the Quality of Systems Development Through Model-Based System Engineering

Over course of the past decade or two, MB SE technology has matured as evidenced by development of SysML tools and frameworks that support engineers in development efforts from requirements through hardware and software implementation. MBSE holds significant promise for accelerating, reducing overhead labors, and improving the quality of systems development.

### 16. For Automatic Verification of Engineering Requirements for Design Projects Modeled Using the SysML System Modeling Language

As noted above, serious attempts to use SysML at NASA have mostly been aimed at early project lifecycle phases, where it's important to keep track of design parameters such as mass, and power against a design that is in flux. Team-X has focused on pre-project design trades, along with studies that may demonstrate a mission concept yielding at least one potential solution that makes sense. Other teams have used SysML in later phases of missions.

### 17. For Reducing the Cognitive Workload of Engineers and Scientists and Fostering Creativity or Productivity

As noted above, NASA is interested in digital assistants that can reduce the cognitive workload of its engineers and scientists, so that they can concentrate their talents on innovation and discovery. Digital assistant solutions can target tasks characterized as research, engineering, operations, data management and analysis (of science data, ground and flight test data or simulation data), business or administrative (NasaDigitalAssistants 2020). The digital assistants can range in capability from low-level cognitive tasks, such as information search, information categorization and mapping, information surveys or semantic comparison, to expert systems and to autonomous ideation (NasaDigitalAssistants 2020).

### 18. For Recommending an Action in Real-Time to Operators of a Facility, Vehicle or Other Physical Asset

The digital assistant can recommend an action in real-time to operators of a facility, vehicle, or other physical asset. The digital assistant can work from a corpus of system information such as design artifacts, operator manuals, maintenance manuals, and operating procedures to correctly identify the current state of a system given sensor data, telemetry, component outputs, or other real-time data. The digital assistant can then use the same information to autonomously recommend a remedial action to the operator when it detects a failure, to warn the operator when their actions will result in a hazard or loss of a mission objective, or to suggest a course of action to the operator that will achieve a new mission objective given by the operator.

### 19. For Automating Traces Among the Artifacts and ro Assess Completeness and Consistency Oftraced Content

The digital assistant can uses the semantic, numeric, and graphical content of engineering artifacts (e.g., requirements, design, verification) to automate traces among the artifacts and to assess completeness and consistency of traced content. The digital agent can use semantic comparison to determine whether the full scope of a requirement may be verified based on the description(s) of the test case(s) traced from it. Similarly, the digital assistant can identify from design artifacts any functional, performance, or non-functional attributes of the design that do not trace back to requirements.

### 20. For Improving Productivity and Accuracy in Analysis of Mechanical (Structural) Designs

Smart Modeling and Simulation systems provide numerous advantages over conventional finite element applications, including plug-and-play, inter-operability, auto-configuration, access to advanced material models, plus the ability to account for complex multi-physics through proper mathematical models and sequencing. SMS is a front-end module, with automated scripts for local or global analysis, ready-made geometries for plug-and-play, and a 1-button solution for meshing and multi-physics diagnosis.

21. For Integrating Design, Analysis and Manufacturing, and for Reducing the Time and Costs Associated with Design and Manufacturing

Smart Modeling and Simulation provides the opportunity to integrate design, analysis and manufacturing, and can reduce the time and costs associated with design and manufacturing. This is not possible using traditional design tools, which require that a separate tool be performed at the end of the design process, thus reducing the opportunities for the early modifications that can improve the performance of the design and analysis process as well as of the product.

### 22. For Advanced Modeling and Simulation of Complex Multi-Physics Interactions

The Smart Modeling and Simulation system can be used for advanced modeling and simulation of complex multi-physics interactions. The SMS system supports materials models involving visco-plasticity, piezo-electricity, acoustics, hygro-thermo-visco-elasticity, chemo-hygro-thermo-piezoelectricity and chemo-thermo-piezo-viscoelasticity.

### 23. For Nonlinear Analysis of Civil Engineering Structures

This invention offers an efficient user interface for cheap, nonlinear analysis of civil engineering structures. Nonlinear structural analysis requires several assumptions that designers at civil design companies may not be very familiar with. There is need for software capable of conducting nonlinear analysis with relative efficiency (without too many assumptions).

This invention allows civil designers to model buildings with minimal information, with ease, and yet get reasonable results.

This invention provides a module for nonlinear analysis of civil engineering structures, one that is easy to operate, and which can be integrated into the Ecosystem for Design Assessment and Verification.

24. For Improving the Accuracy of the Analysis of Civil Engineering Structures, Either Through a Plugin or an Add-On to Existing Software Used for Analysis of Such Structures (e.g., ANSYS, ABAQUS, SAS 2000 or OpenSys) or as a Part of an Integrated Ecosystem Design Software

For the design of civil engineering structures, this invention presents new nonlinear dynamic analysis and design software tools for fixed-base and base-isolated frame structures that outperform the existing, displacement-based academic and commercial software in several aspects. The novel, force-based beam element approach takes into account the axial-biaxial shear-biaxial flexure interaction surface, and adds multi-level, iterative, robust and economical dynamic solution methods for three-dimensional beam elements. The force-based element approach proposed has the potential to impact current computational and design procedures for strong ground motions (earthquakes), by providing accuracy superior to the present displacement-based elements.

### 11. Further Examples of the Invention

Thus, it will be appreciated by those skilled in the art that the present invention is not restricted to the particular preferred embodiments described with reference to the drawings, and that variations may be made therein without departing from the scope of the invention

This invention claims

1. A method for querying a database, for the purpose of efficiently identifying archived database items matching a new user input query, for reducing the cognitive workload of the user, and for fostering creativity or productivity, a method utilizing
a representation step, involving a sequence of text processes, for purpose of identifying vocabulary of terms in the user input query or in corpus of database items,
a weighting step, in which a weighting scheme is applied to the vocabulary of terms, with resultant weights becoming values in a matrix for latent semantic analysis or provided to a neural network,
a comparison step, based on latent semantic analysis or a neural network approach, in which the degree of relevance between the input query and the corpus of database items is predicted, for the purpose of efficiently matching the input query with the corpus items, a retrieval step, for retrieving the database corpus items most relevant to the user input query, wherein the method for querying the database is collectively referred to as a digital assistant.

2. An apparatus for automatic design assessment or smart analysis, one that utilizes entities from engineering design proj ects, for the purpose of aiding with human decision making, for improving productivity of practicing engineers, their supervisors, of design instructors or of academic departments, the apparatus comprising;
in one embodiment of the invention, a front-end module featuring a user interface, for passing input information, configuration information, design requirements, product design specifications, learning outcomes, instructor grading rubrics, templates or data needed for the automatic design assessment and analysis to a database,
in one embodiment of the invention, one or more interface to tools for design or analysis, including computer aided design, computer assisted engineering or finite-element analysis, for passing information related to specific designs being assessed or analyzed to the automatic design assessment or smart analysis, one or more processors;
memory coupled to the one or more processors and storing instructions, which, when executed by the one or more processors, causes the one or more processors to perform operations comprising:
operations for accessing the database storing the input information, configuration information, requirements, product design specifications, learning outcomes, instructor grading rubrics, templates or data needed for the automatic design assessment and analysis,
operations for accessing information related to specific designs, stored in a database or in memory,
operations involving assessment or analysis of the designs or design models against design requirements, learning outcomes, instructor grading rubric or templates, referred to as an engine for automatic design assessment and smart analysis, and
operations for reporting results from the assessment or analysis back to the user, through the front-end module or for archiving the results,
wherein the engine for automatic design assessment and smart analysis is presented either as an integrated apparatus or as a plugin or add-on, integrated through an application program interface, to tools for product design, product life cycle management, product data management, computer assisted engineering, computer aided design, finite element analysis, computational fluid dynamics or systems engineering.

3. A method for automatic design assessment or smart analysis, one that utilizes entities from engineering design projects, for the purpose of aiding with human decision making, for improving productivity of practicing engineers, their supervisors, of design instructors or of academic departments, a method that further utilizes
in one embodiment of the invention, a step for accessing a user interface, for passing input information, configuration information, design requirements, product design specifications, learning outcomes, instructor grading rubrics, templates or data needed for the automatic design assessment and analysis to the database,
in one embodiment of the invention, a step for accessing one or more interface to tools for design or analysis, including product life cycle management, product data management, computer assisted engineering, computer aided design, finite element analysis, computational fluid dynamics or systems engineering, for passing information related to specific designs being assessed or analyzed to the automatic design assessment or smart analysis.
a database access step, for accessing a database storing input information, configuration information, requirements, product design specifications, learning outcomes, instructor grading rubrics, templates or data needed for the automatic design assessment and analysis,
an assessment or analysis access step, for assessing or analyzing designs or design models against design requirements, learning outcomes, instructor grading rubric or templates, and
a reporting step, for reporting results from the assessment or analysis back to the user, through the user interface or for archiving the results.

4. The apparatus for automatic design assessment or smart analysis according to claim 2, wherein engineering requirements are represented in all-numeric format, for the purpose of facilitating automatic verification of the engineering requirements.

5. A method according to claim 3 for automatically assessing or verifying requirements related to weight of a product, a method utilizing aggregation of individual component weight from an assembly level, a sub-assembly level, a sub-sub-assembly level or lower levels, all the way down to the individual component level, in order to estimate the overall weight of the product.

6. A method according to claim 3 for automatically assessing or verifying requirements related to overall component cost of a product, a method utilizing aggregation of individual component cost from an assembly level, a sub-assembly level, a sub-sub-assembly level or lower levels, all the way down to the individual component level, in order to estimate the overall component cost of the product.

7. A method according to claim 3 for automatically assessing or verifying requirements related to an engineering design, a method that estimates the dimensions of the engineering design through a bounding box derived at the assembly level, as opposed to the component level, in order to efficiently account for overlap between components.

8. A method according to claim 3 for automatically assessing or verifying requirements related to an engineering design, a method utilizing data from tessellation, together with a bounding box, to improve estimation of dimensions of the engineering design.

9. A method according to claim 3 for automatically assessing or verifying requirements related to reliability of an engineering design, a method utilizing Monte Carlo simulations.

10. A method, for automatically assessing quality of design work relative to each stage in a given design process, for the purpose of efficient learning and productive team design, a continuous improvement method operating on pages from standardized e-design notebooks, a method further utilizing:
an optional recognition step for carrying out incremental recognition of graphics, text or equation objects, and for producing vector graphics,
an optional image logic step, which is capable of producing an intermediate output containing the vector graphics,
a data mining step, for extracting information relevant to the design process from the vector objects recognized,
an assessment step, for assessing the information extracted and producing itemized grades with associated confidence levels, where the assessment can be carried out using surveys,
an evaluation step, for interpreting the itemized grades using a programmable assessment rubric,
a decision making step, for producing itemized decisions based on the itemized grades,
a configurable supervisory review step, for allowing supervisors te track design progress, by reviewing logs of status or design alerts, derive budget or cost estimates, or te project a completion date,
a communication step, for communicating information about necessary actions among designers, to a mentor, supervisor or sponsor, and
a database access step, for storing or retrieving information related to target outcomes, design objectives, the assessment rubric, design indicators, minimum relevance thresholds, design questions, summary of known pitfalls, reference designs, books, standards and websites, or other meaningful responses, or dictionaries with the valid objects supported by the graphics, text or equation recognition.

11. The method for automatic design assessment or smart analysis according to claim 3, wherein design work is automatically assessed against learning outcomes, by associating the learning outcomes with performance indicators for learning.

12. The method for automatic design assessment or smart analysis according to claim 11, wherein the performance indicators are assessed using one or more rubric, consisting of countable, discrete or binary metrics, that is metrics that can be evaluated using a computer, and wherein a separate rubric can be constructed for each design phase.

13. The method for automatic design assessment or smart analysis according to claim 3, wherein the method is capable of interfacing with student information systems or systems for learning management, comprising of Moodle, Desire-to-Learn, Blackboard or Canvas.

14. The method for automatic design assessment or smart analysis according to claim 3, wherein requirements for a model of a design, that is constructed using a system modeling language, are verified by analyzing each module in a function chain, contained within the design, sequentially, starting from the beginning, and by applying checks at each step along the chain.

15. The method for automatic design assessment or smart analysis according to claim 3, wherein requirements for a model of a design, that is constructed using a system modeling language, are verified by analyzing each module in a function chain, contained within the design, sequentially, starting from the beginning, and by applying checks at each step along the chain, and wherein the evaluation of each function is possibly carried out at a different location.

16. The method for automatic design assessment or smart analysis according to claim 3, wherein requirements for a parametric model of a design, that is constructed using a system modeling language, are verified through interactions or through use of one or more margin blocks.

17. The apparatus for automatic design assessment or smart analysis according to claim 2, wherein the smart analysis provides access to ready-made geometries or components from a database for plug-and-play.

18. The apparatus for automatic design assessment or smart analysis according to claim 2, wherein the smart analysis supports inter-operability.

19. The apparatus for automatic design assessment or smart analysis according to claim 2, wherein the smart analysis supports auto-configuration.

20. The apparatus for automatic design assessment or smart analysis according to claim 2, wherein the smart analysis provides access to advanced material models.

21. The apparatus for automatic design assessment or smart analysis according to claim 2, wherein the smart analysis has the ability to account for complex multi-physics (or support multi-physics diagnosis) through mathematical models and sequencing.

22. The apparatus for automatic design assessment or smart analysis according to claim 2, wherein the smart analysis has the ability to support automated scripts for local and global analysis.

23. The apparatus for automatic design assessment or smart analysis according to claim 2, wherein the smart analysis has the ability to support automatic mesh generation.

24. The apparatus for automatic design assessment or smart analysis according to claim 2, wherein the smart analysis has the ability to support a one-button solution for meshing or multi-physics diagnosis.

25. The apparatus for automatic design assessment or smart analysis according to claim 2, wherein the smart analysis utilizes force-based beam elements for the analysis.
